(19) United States
(12) Patent Application Publication
(10) Pub. No.: US 2016/0268519 A1
(43) Pub. Date: Sep. 15, 2016

(54) ORGANOMETALLIC COMPOUND AND ORGANIC LIGHT-EMITTING DEVICE INCLUDING THE SAME

(71) Applicant: Samsung Electronics Co., Ltd., Suwon-si (KR)

(72) Inventors: Whail CHOI, Seoul (KR); Byoungki CHOI, Hwaseong-si (KR); Yoonhyun KWAK, Seoul (KR); Ohyun KWON, Yongin-si (KR); Sangdong KIM, Seoul (KR); Banglin LEE, Suwon-si (KR); Aram JEON, Suwon-si (KR); Kyuyoung HWANG, Anyang-si (KR)

(21) Appl. No.: 15/008,686

(22) Filed: Jan. 28, 2016

(30) Foreign Application Priority Data
Mar. 13, 2015 (KR) 10-2015-0035157

(51) Int. Cl. H01L 51/00; C09K 11/06; C09K 11/02; C07F 15/00

(52) U.S. Cl. CPC H01L 51/0094; H01L 51/0072; C07F 15/0033; C09K 11/06; C09K 11/025; H01L 51/5012

(57) ABSTRACT

An organometallic compound represented by Formula 1:

M(L₁)ₙ₁(L₂)ₙ₂ Formula 1
wherein in Formula 1, M, L₁, L₂, n1, and n2 are the same as described in the specification.

### CROSS-REFERENCE TO RELATED APPLICATION

This application claims priority to and the benefit of Korean Patent Application No. 10-2015-0035157, filed on Mar. 13, 2015, in the Korean Intellectual Property Office, the content of which is incorporated herein in its entirety by reference.

### BACKGROUND

1. Field

The present disclosure relates to an organometallic compound and an organic light-emitting device including the same.

2. Description of the Related Art

Organic light-emitting devices (OLEDs) are self-emission devices that have wide viewing angles, high contrast ratios, and short response times. In addition, the OLEDs exhibit high luminance, driving voltage, and response speed characteristics, and produce full-color images.

A typical organic light-emitting device includes an anode, a cathode, and an organic layer that is disposed between the anode and the cathode and includes an emission layer. A hole transport region may be disposed between the anode and the emission layer, and an electron transport region may be disposed between the emission layer and the cathode. Holes provided from the anode may move toward the emission layer through the hole transport region, and electrons provided from the cathode may move toward the emission layer through the electron transport region. The holes and the electrons are recombined in the emission layer to produce excitons. These excitons change from an excited state to a ground state to thereby generate light.

Different types of organic light emitting devices are known. However, there still remains a need in OLEDs having low driving voltage, high efficiency, high brightness, and long lifespan.

### SUMMARY

Provided are an organometallic cyclic compound and an organic light-emitting device including the same.

Additional aspects will be set forth in part in the description which follows and, in part, will be apparent from the description, or may be learned by practice of the presented exemplary embodiments.

According to an aspect of an exemplary embodiment, an organometallic compound is represented by Formula 1:

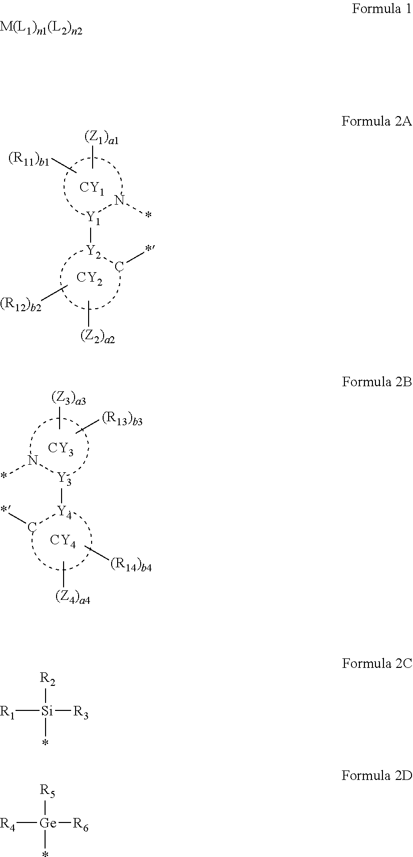

wherein, in Formula 1, M is selected from Ir, Pt, Os, Ti, Zr, Hf, Eu, Tb, Tm, and Rh,

in Formula 1, L₁ is selected from ligands represented by Formula 2A,

in Formula 1, L₂ is selected from ligands represented by Formula 2B,

L₁ and L₂ in Formula 1 are different from each other,

in Formula 1, n1 and n2 are each independently selected from 1 and 2, and a sum of n1 and n2 may be selected from 2 and 3,

in Formula 2A, Y₁ and Y₂ are each independently selected from C and N, and Y₃ and Y₄ in Formula 2B are each independently selected from C and N,

in Formulae 2A and 2B, CY₁ and CY₃ are each independently selected from a C₁-C₆₀ heterocyclic group, CY₂ and CY₄ may be each independently selected from a C₅-C₆₀ carbocyclic group and a C₁-C₆₀ heterocyclic group, wherein CY₁ and CY₂ may be optionally bound to each other additionally via a first linking group, and wherein CY₃ and CY₄ may be optionally bound to each other additionally via a second linking group,

in Formulae 2A and 2B, Z₁ to Z₄ are each independently selected from a hydrogen, a deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₂-C₆₀ heteroaryloxy group, a substituted or unsubstituted C₂-C₆₀ heteroarylthio group, a substituted or unsubstituted C₃-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —B(Q₃)(Q₄), and —P(═O)(Q₅)(Q₆),

a1 to a4 are each independently an integer selected from 0 to 4,

in Formula 2A, R₁₁ and R₁₂ are each independently selected from groups represented by Formula 2C, b1 and b2 may be each independently an integer selected from 0 to 3, and a sum of b1 and b2 may be 1 or greater,

in Formula 2B, R₁₃ and R₁₄ are each independently selected from groups represented by Formula 2D, b3 and b4 may be each independently an integer selected from 0 to 3, and a sum of b3 and b4 may be 1 or greater,

in Formulae 2C and 2D, R₁ to R₆ are each independently selected from a hydrogen, a deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₂-C₆₀ heteroaryloxy group, a substituted or unsubstituted C₂-C₆₀ heteroarylthio group, a substituted or unsubstituted C₃-C₆₀ heteroarylalkyl group, a substituted or unsubstituted monovalent non-aromatic condensed polycyclic group, a substituted or unsubstituted monovalent non-aromatic condensed heteropolycyclic group, and —Si(Q₅₁)(Q₅₂)(Q₅₃),

when b3 is 1 or greater, at least one selected from R₄ to R₆ in Formula 2D is optionally bound to adjacent Z₃ to form a C₂-C₁₀ saturated or unsaturated ring,

when b4 is 1 or greater, at least one selected from R₄ to R₆ in Formula 2D is optionally bound to adjacent Z₄ to form a C₂-C₁₀ saturated or unsaturated ring,

in Formulae 2A and 2B, * and *′ each indicates a binding site to M in Formula 1, * in Formula 2C indicates a binding site to CY₁ or CY₂ in Formula 2A, and * in Formula 2D indicates a binding site to CY₃ or CY₄ in Formula 2B,

at least one of substituents of the substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₇-C₆₀ arylalkyl group, substituted C₁-C₆₀ heteroaryl group, substituted C₂-C₆₀ heteroaryloxy group, substituted C₂-C₆₀ heteroarylthio group, substituted C₃-C₆₀ heteroarylalkyl group, substituted monovalent non-aromatic condensed polycyclic group, and substituted monovalent non-aromatic condensed heteropolycyclic group is selected from:

a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, a monovalent non-aromatic condensed heteropolycyclic group, —N(Q₁₁)(Q₁₂), —B(Q₁₃)(Q₁₄), and —P(═O)(Q₁₅)(Q₁₆);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, and a monovalent non-aromatic condensed heteropolycyclic group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, a monovalent non-aromatic condensed heteropolycyclic group, —N(Q₂₁)(Q₂₂), —B(Q₂₃)(Q₂₄), and —P(═O)(Q₂₅)(Q₂₆); and

—N(Q₃₁)(Q₃₂), —B(Q₃₃)(Q₃₄), and —P(═O)(Q₃₅)(Q₃₆),

wherein Q₁ to Q₆, Q₁₁ to Q₁₆, Q₂₁ to Q₂₆, Q₃₁ to Q₃₆, and Q₅₁ to Q₅₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₂-C₆₀ heteroaryloxy group, a substituted or unsubstituted C₂-C₆₀ heteroarylthio group, a substituted or unsubstituted C₃-C₆₀ heteroarylalkyl group, a substituted or unsubstituted monovalent non-aromatic condensed polycyclic group, and a substituted or unsubstituted monovalent non-aromatic condensed heteropolycyclic group.

According to an aspect of another exemplary embodiment, an organic light-emitting device includes:

a first electrode;

a second electrode; and

an organic layer disposed between the first electrode and the second electrode,

wherein the organic layer includes an emission layer and at least one organometallic compound represented by Formula 1.

The organometallic compound may be included in the emission layer, the organometallic compound included in the emission layer may serve as a dopant, and the emission layer may further include a host.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1 is a schematic cross-sectional view of an organic light-emitting device according to an embodiment.

### DETAILED DESCRIPTION

Reference will now be made in detail to exemplary embodiments, examples of which are illustrated in the accompanying drawings, wherein like reference numerals refer to like elements throughout. In this regard, the present exemplary embodiments may have different forms and should not be construed as being limited to the descriptions set forth herein. Accordingly, the exemplary embodiments are merely described below, by referring to the FIGURES, to explain aspects. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

An organometallic compound is represented by Formula 1:

M(L₁)ₙ₁(L₂)ₙ₂ Formula 1

wherein, in Formula 1, L₁ may be selected from ligands represented by Formula 2A, and in Formula 1, L₂ may be selected from ligands represented by Formula 2B.

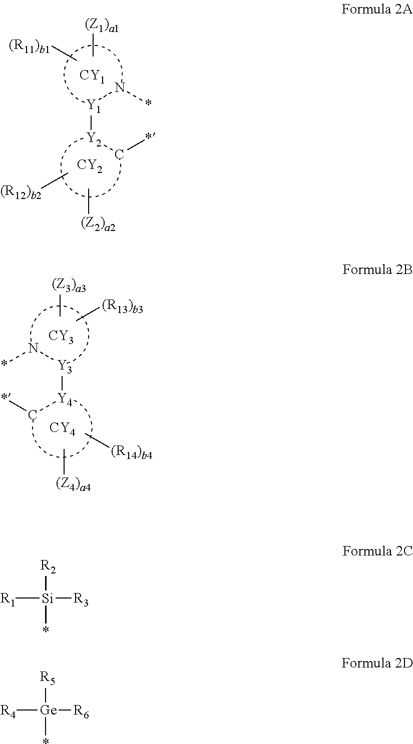

* and *′ in Formulae 2A and 2B each indicates a binding site to M in Formula 1.

In Formula 1, M may be selected from iridium (Ir), platinum (Pt), osmium (Os), titanium (Ti), zirconium (Zr), hafnium (Hf), europium (Eu), terbium (Tb), thulium (Tm), and rhodium (Rh).

In some embodiments, in Formula 1, M may be selected from iridium, platinum, osmium, and rhodium.

In some embodiments, in Formula 1, M may be Ir or Pt.

In Formula 1, L₁ and L₂ may be different from each other, in Formula 1, n1 and n2 may be each independently 1 or 2, and a sum of n1 and n2 may be 2 or 3.

In Formula 2A, Y₁ and Y₂ may be each independently selected from carbon (C) and nitrogen (N), and in Formula 2B, Y₃ and Y₄ may be each independently selected from C and N.

In some embodiments, in Formula 2A, Y₁ to Y₄ may be C, but embodiments are not limited thereto.

in Formulae 2A and 2B, CY₁ and CY₃ may be each independently selected from a C₁-C₆₀ heterocyclic group, CY₂ and CY₄ may be each independently selected from a C₅-C₆₀ carbocyclic group and a C₁-C₆₀ heterocyclic group, wherein CY₁ and CY₂ may be optionally bound to each other additionally via a first linking group, and wherein CY₃ and CY₄ may be optionally bound to each other additionally via a second linking group. The C₅-C₆₀ carbocyclic group and the C₁-C₆₀ heterocyclic group may be “a monocyclic group” or “a polycyclic group”.

In some embodiments, in Formulae 2A and 2B, CY₁ and CY₃ may be each independently selected from a pyridine, a pyrimidine, a pyrazine, a triazine, a quinoline, an isoquinoline, a quinazoline, a quinoxaline, a triazole, an imidazole, and a pyrazole, and CY₂ and CY₄ may be each independently selected from a benzene, a naphthalene, a pyridine, a pyrimidine, a pyrazine, a triazine, a quinoline, an isoquinoline, a quinazoline, a quinoxaline, a carbazole, a dibenzofuran, and a dibenzothiophene.

In some embodiments, in Formulae 2A and 2B, CY₁ and CY₃ may be each independently selected from a pyridine, a pyrimidine, a pyrazine, a triazine, a triazole, an imidazole, and a pyrazole, and CY₂ and CY₄ may be each independently selected from a benzene, a naphthalene, a pyridine, a pyrimidine, a pyrazine, a carbazole, a dibenzofuran, and a dibenzothiophene.

In some embodiments, in Formulae 2A and 2B, CY₁ and CY₃ may be each independently selected from a pyridine, a pyrimidine, a pyrazine, and a triazine, and CY₂ and CY₄ may be each independently selected from a benzene, a naphthalene, a carbazole, a dibenzofuran, and a dibenzothiophene, but embodiments are not limited thereto.

In some embodiments, in Formulae 2A and 2B, CY₁ and CY₃ may be a pyridine, CY₂ may be a benzene or a dibenzofuran, CY₄ may be selected from a benzene, a naphthalene, a carbazole, a dibenzofuran, and a dibenzothiophene, but embodiments are not limited thereto.

In some embodiments, in Formulae 2A and 2B, CY₁ and CY₃ may be a pyridine, CY₂ may be a benzene or a dibenzofuran, and CY₄ may be a benzene, but embodiments are not limited thereto.

In Formula 2A, CY₁ and CY₂ may be optionally bound to each other additionally via a first linking group, and in Formula 2B, CY₃ and CY₄ may be optionally bound to each other additionally via s second linking group. The first linking group and the second linking group may be each independently selected from linking groups represented by Formula 6:

*-(Z₃₁)_{b10}-*′ Formula 6

wherein, in Formula 6, Z₃₁ may be selected from *—O—*′, *—S—*′, *—N(Q₄₁)-*′, *—C(Q₄₂)(Q₄₃)-*′, *—C(Q₄₄)=C(Q₄₅)-*′, and

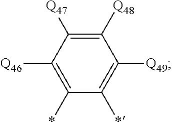

Q₄₁ to Q₄₉ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a pyridinyl group, and a pyrimidinyl group; and

a phenyl group, a naphthyl group, a pyridinyl group, and a pyrimidinyl group;

b10 may be an integer selected from 1 to 10, and when b10 is 2 or greater, a plurality of Z₃₁ may be identical to or different from each other.

In some embodiments, in Formula 6, Q₄₁ to Q₄₉ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a pyridinyl group, and a pyrimidinyl group; and

a phenyl group, a naphthyl group, a pyridinyl group, and a pyrimidinyl group; but embodiments are not limited thereto.

In some embodiments, in Formula 2A, CY₁ and CY₂ may be optionally bound to each other additionally via the first linking group, and/or in Formula 2B, CY₃ and CY₄ may be optionally bound to each other additionally via the second linking group, and the first linking group and the second linking group may be each independently represented by *—C(Q₄₄)=C(Q₄₅)-*′ or

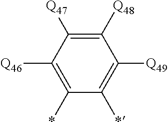

(that is, when in Formula 6, b10=1), wherein Q₄₄ to Q₄₉ may be each independently selected from a hydrogen, C₁-C₁₀ alkyl group and C₁-C₁₀ alkoxy group, but embodiments are not limited thereto.

In Formulae 2A and 2B, Z₁ to Z₄ may be each independently selected from a hydrogen, a deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₂-C₆₀ heteroaryloxy group, a substituted or unsubstituted C₂-C₆₀ heteroarylthio group, a substituted or unsubstituted C₃-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —B(Q₃)(Q₄), and —P(═O)(Q₅)(Q₆).

In some embodiments, in Formulae 2A and 2B, Z₁ to Z₄ may be each independently selected from

a hydrogen, a deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₁₄ aryl group, a C₁-C₁₄ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₁₄ aryl group, a C₁-C₁₄ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₁₄ aryl group, a C₁-C₁₄ heteroaryl group, a monovalent non-aromatic condensed polycyclic group, and a monovalent non-aromatic condensed heteropolycyclic group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₁₄ aryl group, a C₁-C₁₄ heteroaryl group, a monovalent non-aromatic condensed polycyclic group, and a monovalent non-aromatic condensed heteropolycyclic group; and

—N(Q₁)(Q₂), —B(Q₃)(Q₄), and —P(═O)(Q₅)(Q₆);

wherein, Q₁ to Q₆ may be each independently selected from a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₁₄ aryl group, a C₆-C₁₄ aryl group substituted with at least one selected from a C₁-C₂₀ alkyl group and C₆-C₁₄ aryl group, a C₁-C₁₄ heteroaryl group, a monovalent non-aromatic condensed polycyclic group, and a monovalent non-aromatic condensed heteropolycyclic group.

In some embodiments, in Formulae 2A and 2B, Z₁ to Z₄ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group;

a cyclopentyl group, a cyclohexyl group, a cycloheptyl group, a cyclooctyl group, an adamantanyl (adamantyl) group, a norbornanyl (norbornyl) group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group; and

—B(Q₃)(Q₄) and —P(═O)(Q₅)(Q₆),

wherein Q₃ to Q₆ may be each independently selected from

—CH₃, -CD₃, -CD₂H, -CDH₂, —CH₂CH₃, —CH₂CD₃, —CH₂CD₂H, —CH₂CDH₂, —CHDCH₃, —CHDCD₂H, —CHDCDH₂, —CHDCD₃, -CD₂CD₃, -CD₂CD₂H, and -CD₂CDH₂;

an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group; and

an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group, each substituted with at least one selected from a deuterium, a C₁-C₁₀ alkyl group, and a phenyl group.

In some embodiments, in Formulae 2A and 2B, Z₁ to Z₄ may be each independently selected from

a hydrogen, a deuterium, —F, a cyano group, a nitro group, —SF₅, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group;

a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group, each substituted with at least one selected from a deuterium, —F, -CD₃, -CD₂H, -CDH₂, —CF₃, —CF₂H, —CFH₂, a cyano group, a nitro group, a C₁-C₁₀ alkyl group, a C₁-C₁₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group; and

—B(Q₃)(Q₄) and —P(═O)(Q₅)(Q₆),

wherein Q₃ to Q₆ may be each independently selected from

—CH₃, -CD₃, -CD₂H, -CDH₂, —CH₂CH₃, —CH₂CD₃, —CH₂CD₂H, —CH₂CDH₂, —CHDCH₃, —CHDCD₂H, —CHDCDH₂, —CHDCD₃, -CD₂CD₃, -CD₂CD₂H, and -CD₂CDH₂;

an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group; and

an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group, each substituted with at least one selected from a deuterium, a C₁-C₁₀ alkyl group, and a phenyl group.

In some embodiments, in Formulae 2A and 2B, Z₁ to Z₄ may be each independently selected from a hydrogen, a deuterium, —F, a cyano group, a nitro group, —SF₅, —CH₃, -CD₃, -CD₂H, -CDH₂, —CF₃, —CF₂H, —CFH₂, groups represented by Formulae 9-1 to 9-19, and groups represented by Formulae 10-1 to 10-36:

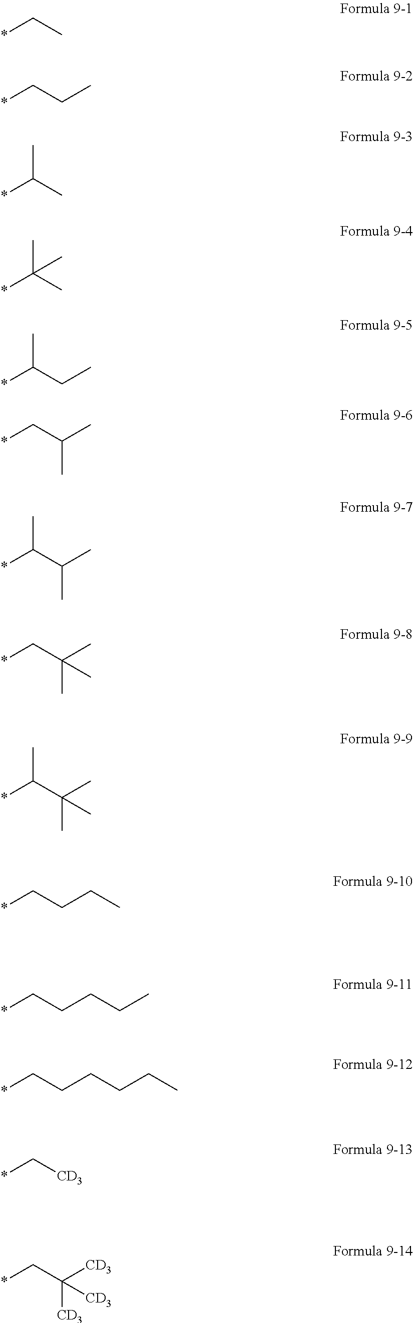

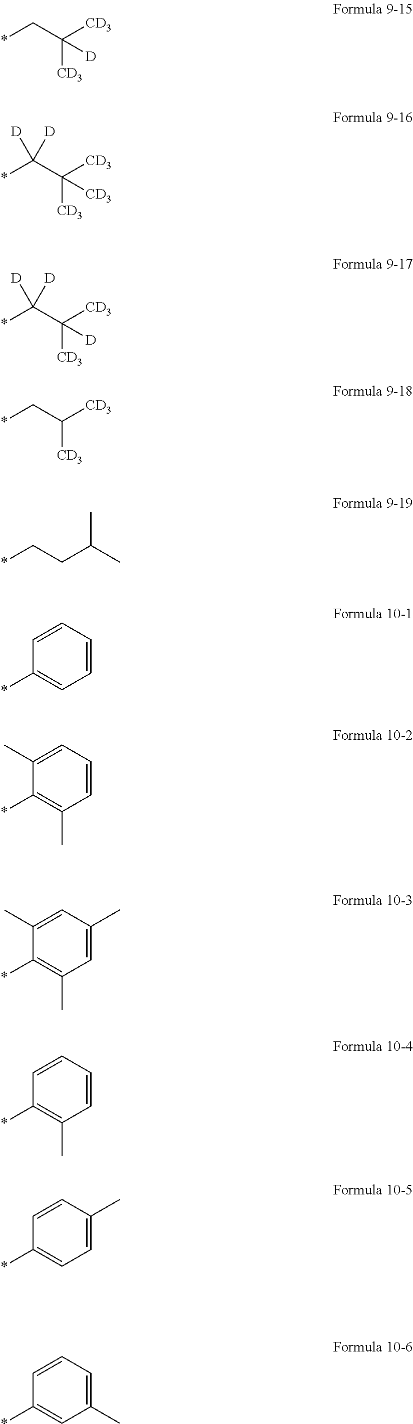

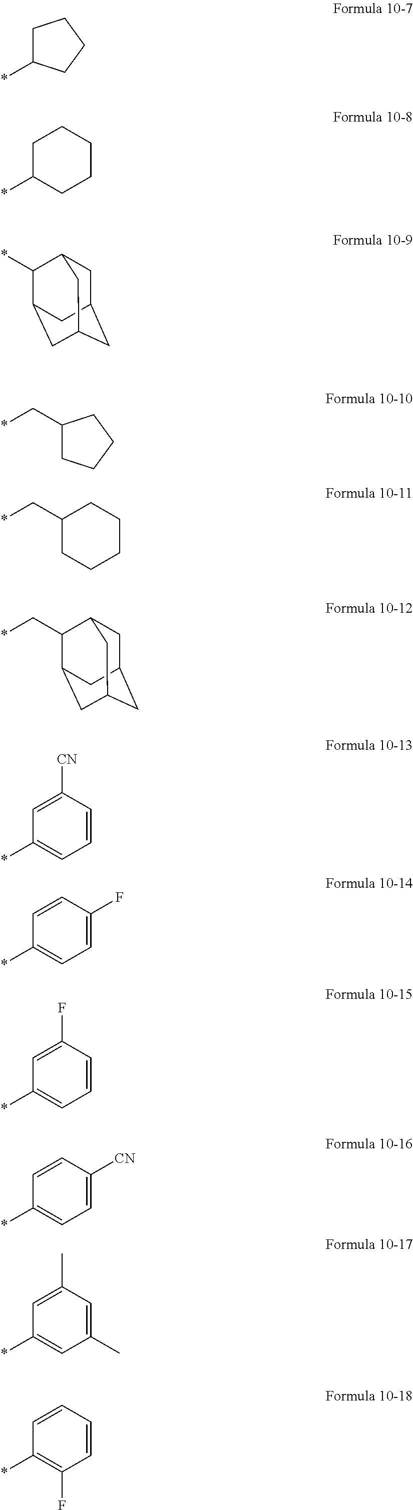

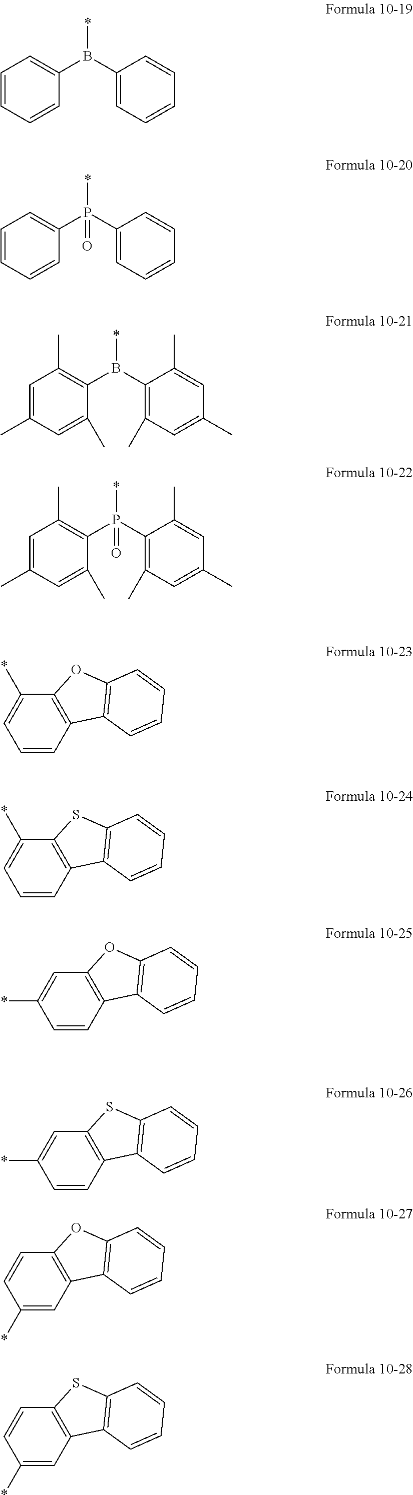

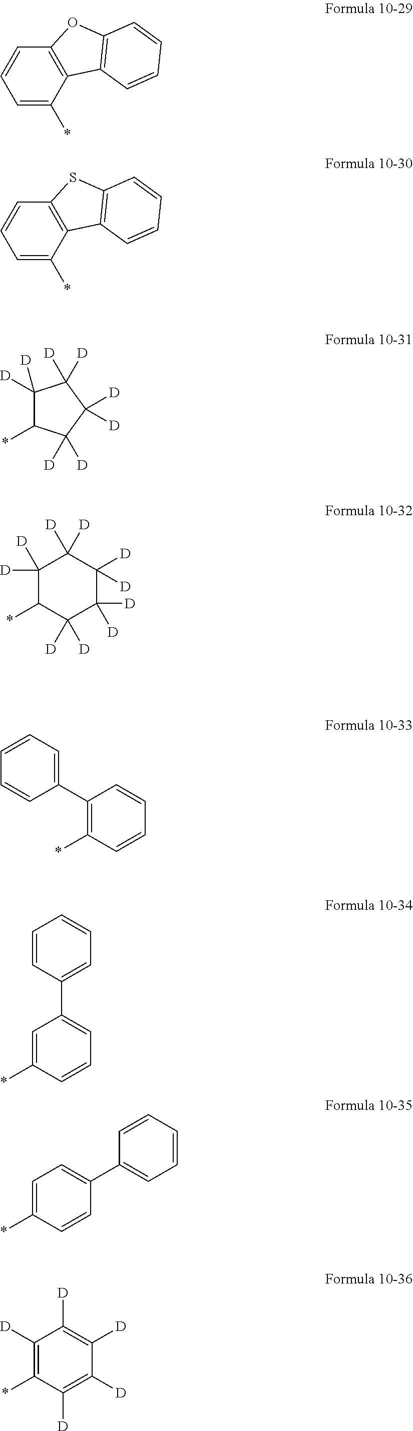

In Formulae 9-1 to 9-19 and 10-1 to 10-36, * indicates a binding site to a neighboring atom.

In Formulae 2A and 2B, a1 to a4 may be each independently an integer selected from 0 to 4. When a1 is 2 or greater, a plurality of Z₁ may be identical to or different from each other, when a2 is 2 or greater, a plurality of Z₂ may be identical to or different from each other, when a3 is 2 or greater, a plurality of Z₃ may be identical to or different from each other, and when a4 is 2 or greater, a plurality of Z₄ may be identical to or different from each other.

In Formula 2A, R₁₁ and R₁₂ may be each independently represented by Formula 2C, b1 and b2 may be each independently an integer selected from 0 to 3, and a sum of b1 and b2 may be 1 or greater. That is, a ligand represented by Formula 2A essentially includes at least one group represented by Formula 2C as a substituent.

In Formula 2B, R₁₃ and R₁₄ may be each independently represented by Formula 2D, b3 and b4 may be each independently an integer selected from 0 to 3, and a sum of b3 and b4 may be 1 or greater. That is, a ligand represented by Formula 2B essentially includes at least one group represented by Formula 2D as a substituent.

In some embodiments, in Formula 2A, b1 may be 1 or 2, and b2 may be 0.

In some embodiments, in Formula 2A, b1 may be 1, and b2 may be 1.

In some embodiments, in Formula 2A, b1 may be 1, and b2 may be 0.

In some embodiments, in Formula 2B, b3 may be 1 or 2, and b4 may be 0.

In some embodiments, in Formula 2B, b3 may be 1, and b4 may be 1.

In some embodiments, in Formula 2B, b3 may be 1, and b4 may be 0.

In some embodiments, in Formulae 2A and 2B, b1 and b3 may be 1, and b2 and b4 may be 0, but embodiments are not limited thereto.

In Formulae 2C and 2D, R₁ to R₆ may be each independently selected from a hydrogen, a deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₂-C₆₀ heteroaryloxy group, a substituted or unsubstituted C₂-C₆₀ heteroarylthio group, a substituted or unsubstituted C₃-C₆₀ heteroarylalkyl group, a substituted or unsubstituted monovalent non-aromatic condensed polycyclic group, a substituted or unsubstituted monovalent non-aromatic condensed heteropolycyclic group, and —Si(Q₅₁)(Q₅₂)(Q₅₃).

In some embodiments, in Formulae 2C and 2D, R₁ to R₆ may be each independently selected from

a hydrogen, a deuterium, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₁₄ aryl group, a C₁-C₁₄ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₁₄ aryl group, a C₁-C₁₄ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₁₄ aryl group, a C₁-C₁₄ heteroaryl group, a monovalent non-aromatic condensed polycyclic group, and a monovalent non-aromatic condensed heteropolycyclic group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₁₄ aryl group, a C₁-C₁₄ heteroaryl group, a monovalent non-aromatic condensed polycyclic group, and a monovalent non-aromatic condensed heteropolycyclic group.

In some embodiments, in Formulae 2C and 2D, R₁ to R₆ may be each independently selected from

a hydrogen, a deuterium, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group; and

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group.

In some embodiments, in Formulae 2C and 2D, R₁ to R₆ may be each independently selected from

a hydrogen, a deuterium, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group; and

a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group, each substituted with at least one selected from a deuterium, —F, -CD₃, -CD₂H, -CDH₂, —CF₃, —CF₂H, —CFH₂, a cyano group, a nitro group, a C₁-C₁₀ alkyl group, a C₁-C₁₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group, but embodiments are not limited thereto.

In some embodiments, in Formulae 2C and 2D, R₁ to R₆ may be each independently selected from a hydrogen, a deuterium, —CH₃, -CD₃, -CD₂H, -CDH₂, —CF₃, —CF₂H, —CFH₂, groups represented by Formulae 9-1 to 9-19, and groups represented by Formulae 10-1 to 10-18.

In some embodiments,

in Formulae 2C and 2D, R₁ to R₆ may be each independently selected from —CH₃, -CD₃, -CD₂H, -CDH₂, groups represented by Formulae 9-1 to 9-19, and a phenyl group,

in Formula 2C,

R₁ to R₃ may be identical to one another; or

R₁ and R₂ may be different from each other, and R₁ and R₃ may be identical to each other, and

in Formula 2D,

R₄ to R₆ may be identical to one another; or

R₄ and R₅ may be different from each other, and R₄ and R₆ may be identical to each other.

In some embodiments, in Formulae 2C and 2D, R₁ to R₆ may be each independently selected from a methyl group, an ethyl group, a propyl group, a butyl group, -CD₃, and a phenyl group.

When, in Formula 2B, b1 is 1 or greater, at least one of R₄ to R₆ in Formula 2D may be optionally bound to adjacent Z₃ to form a C₂-C₁₀ saturated or unsaturated ring (for example, refer to Formulae 2B(4) to 2B(10) below).

When in Formula 2B, b2 is 1 or greater, at least one of R₄ to R₆ in Formula 2D may be optionally bound to adjacent Z₄ to form a C₂-C₁₀ saturated or unsaturated ring.

In some embodiments, in Formula 1, L₁ may be selected from Formulae 3-1 to 3-130:

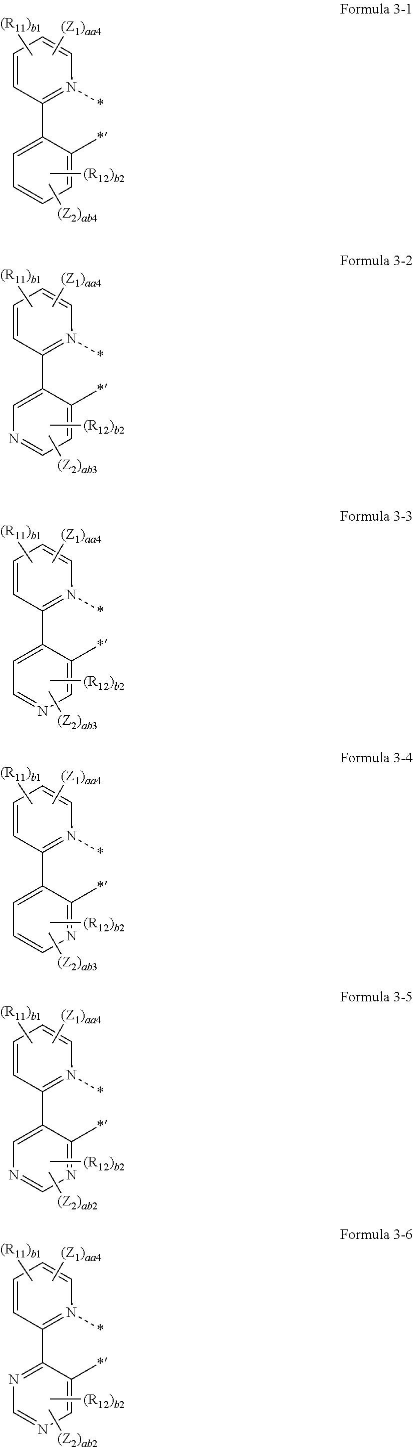

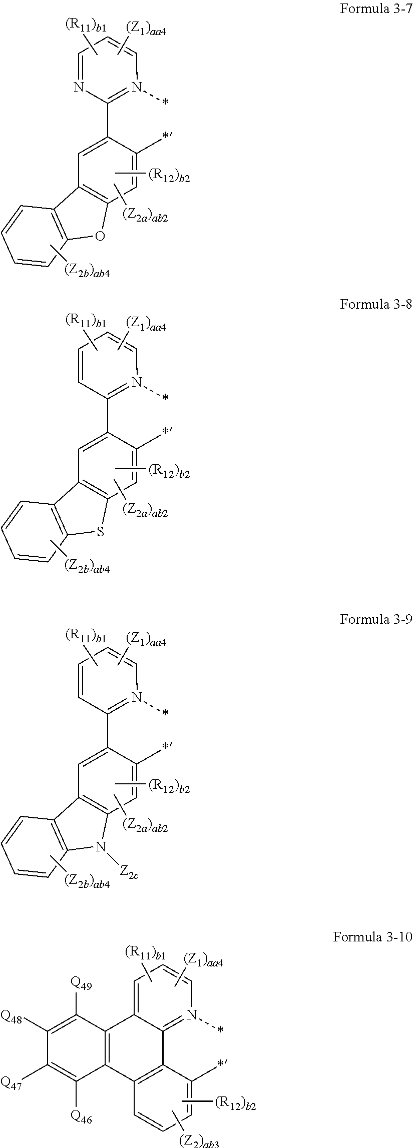

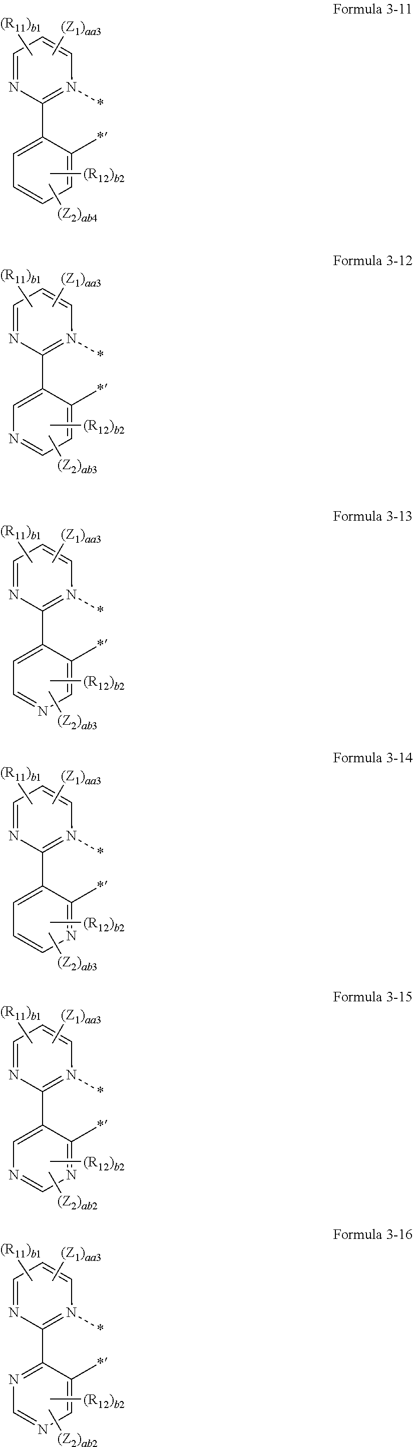

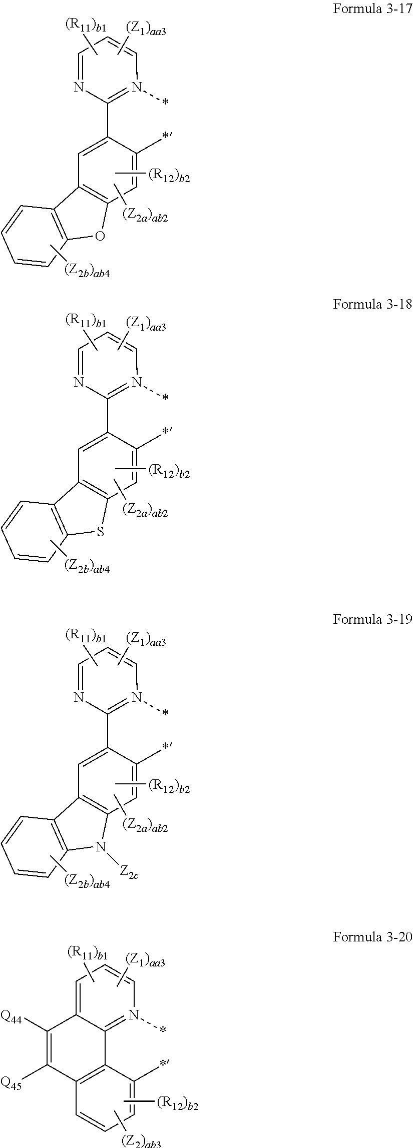

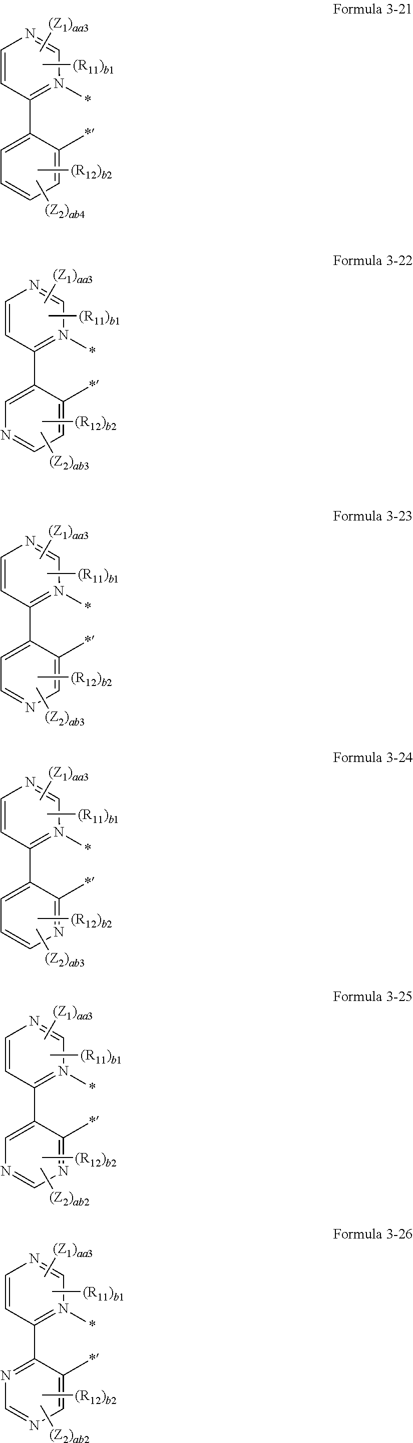

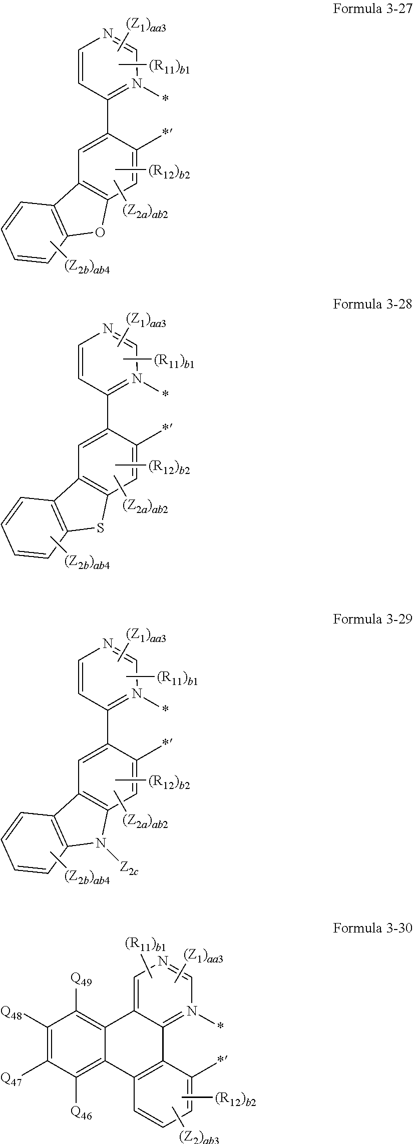

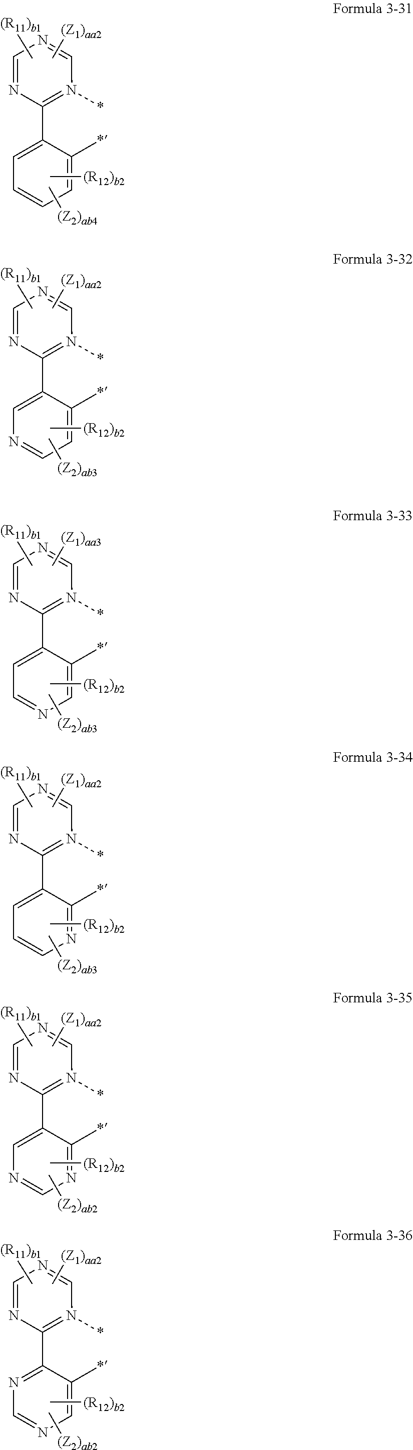

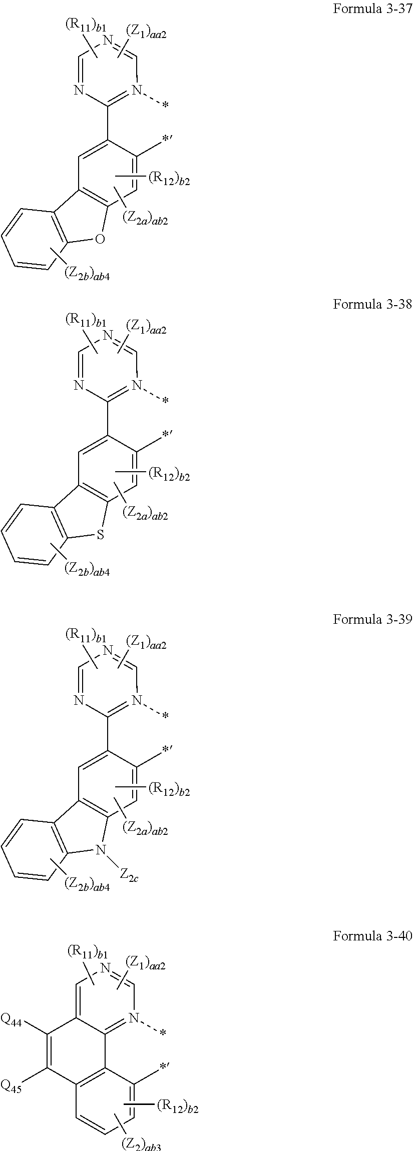

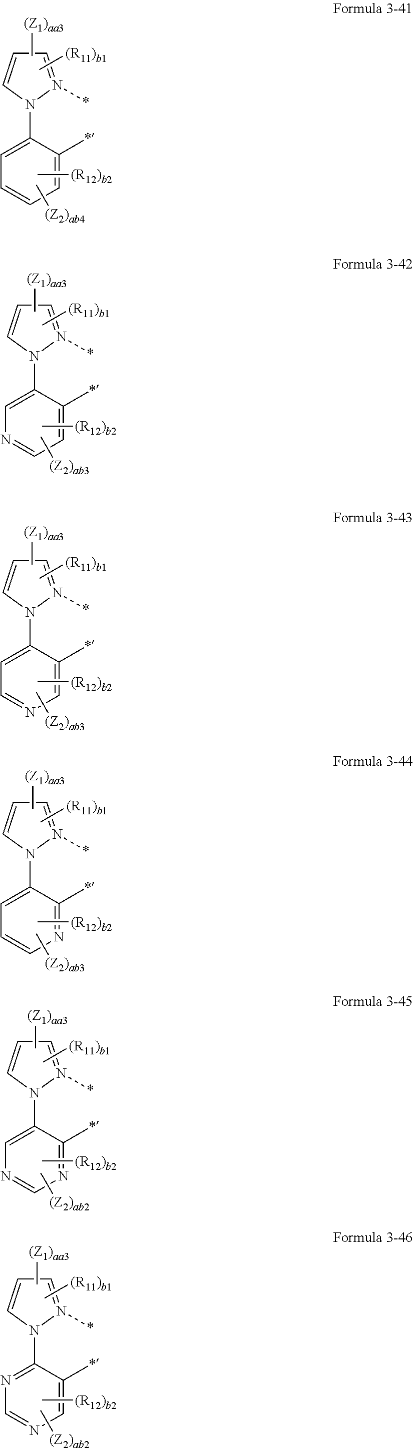

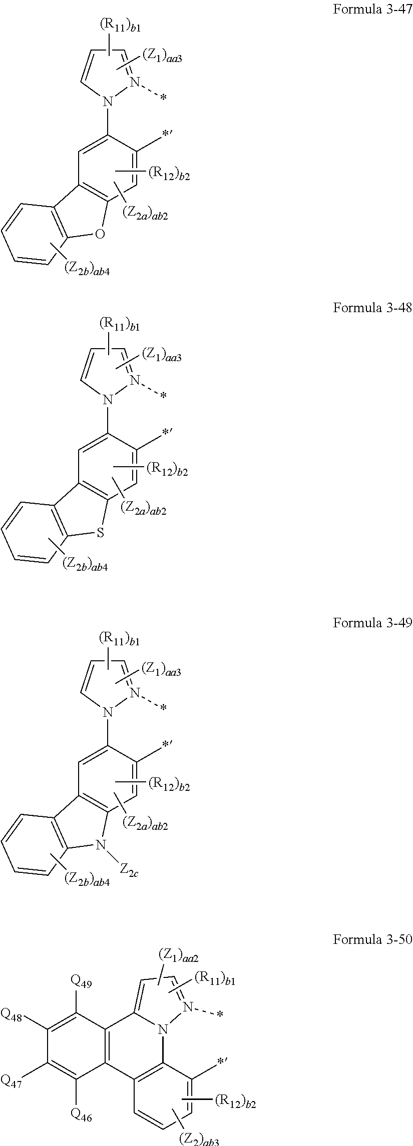

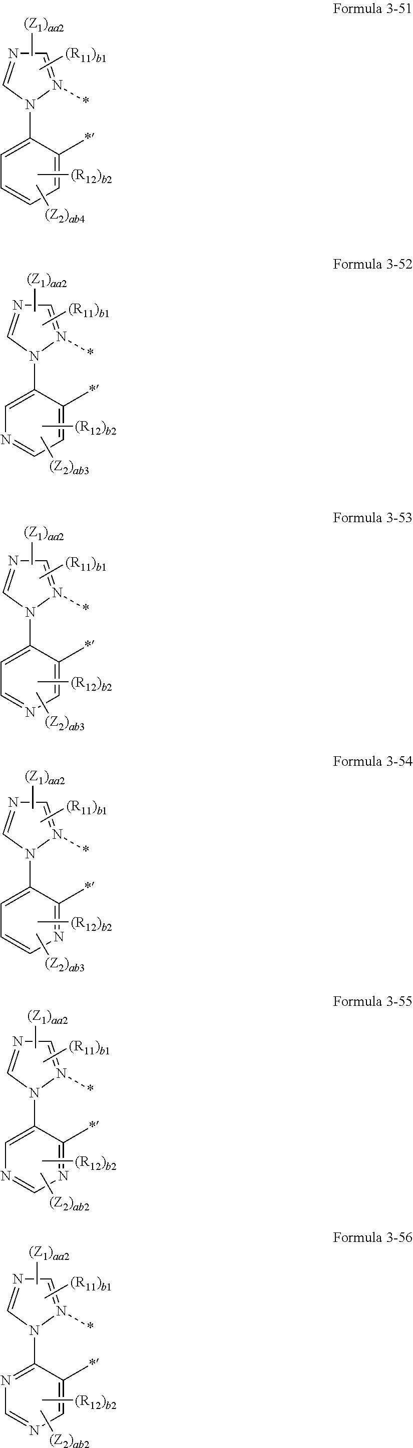

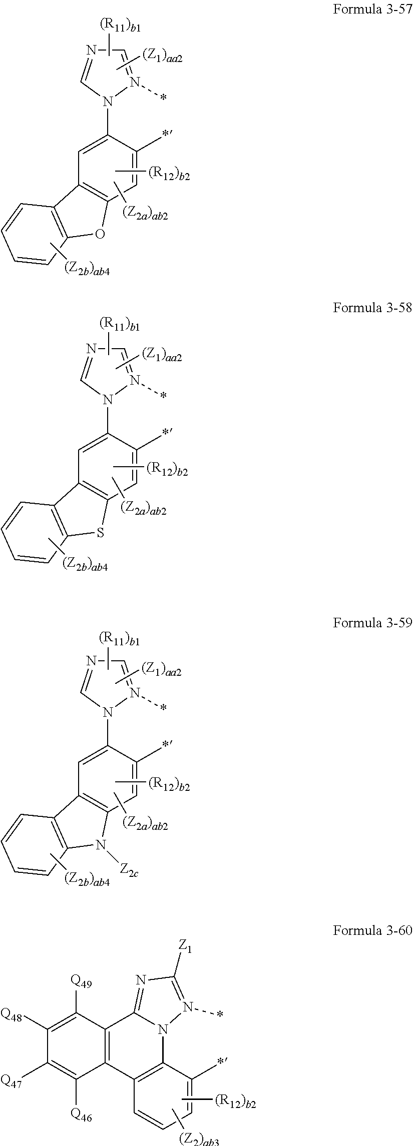

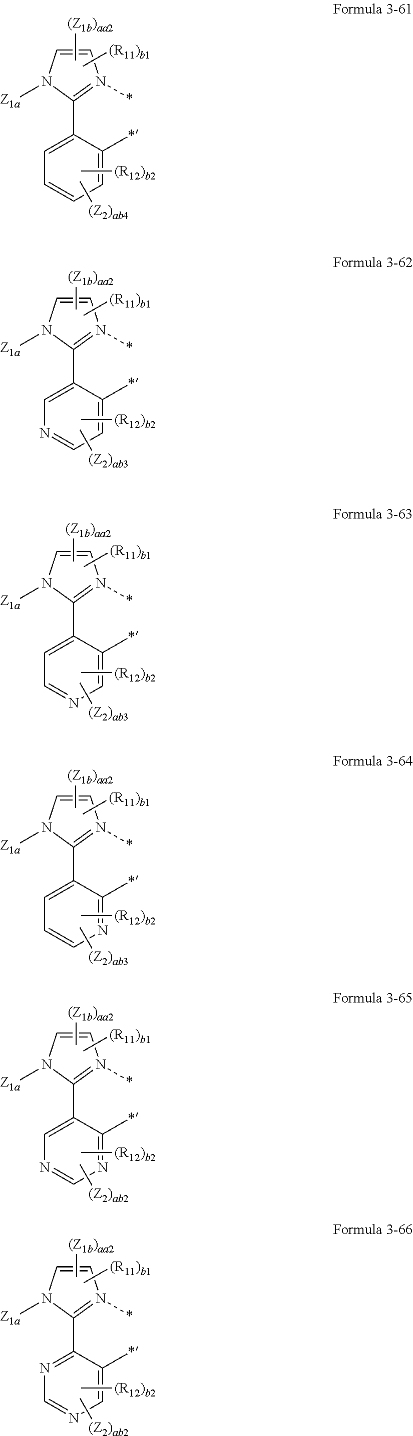

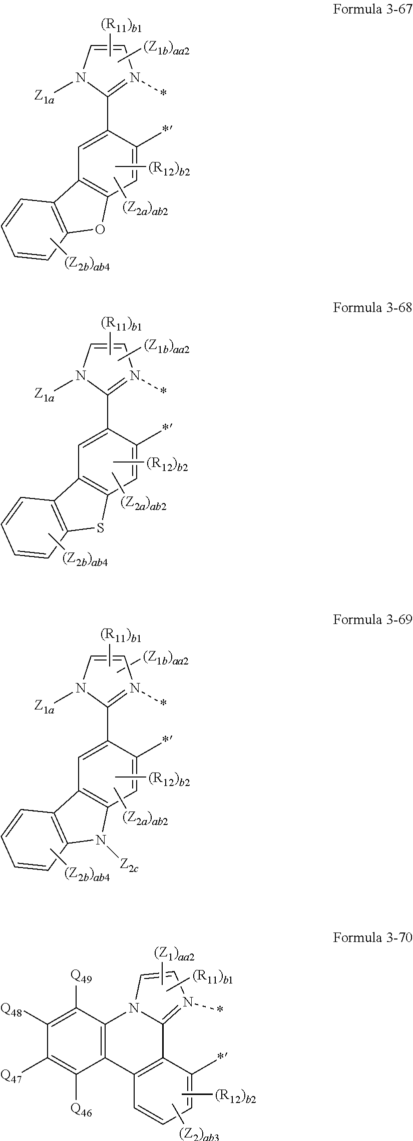

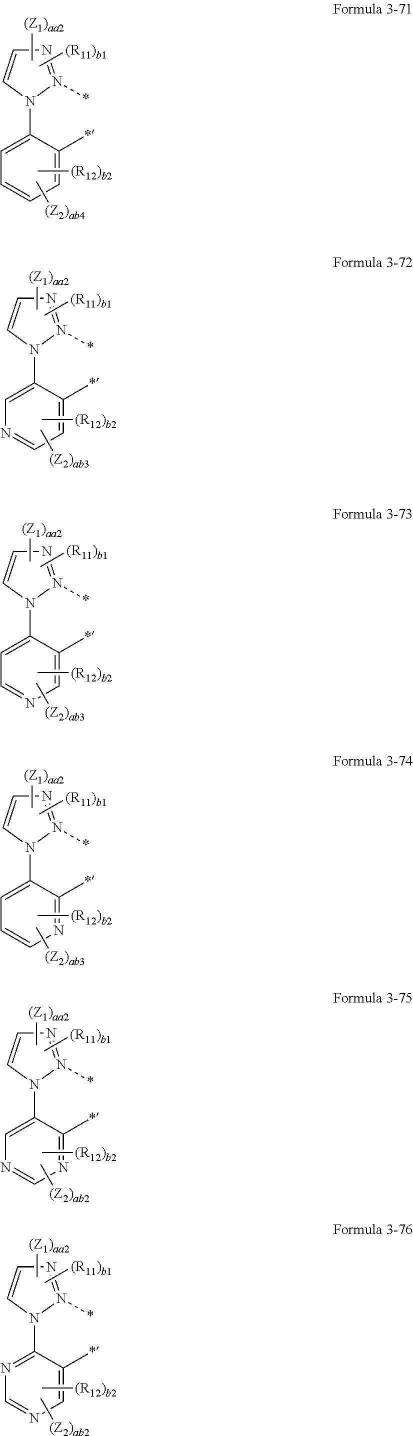

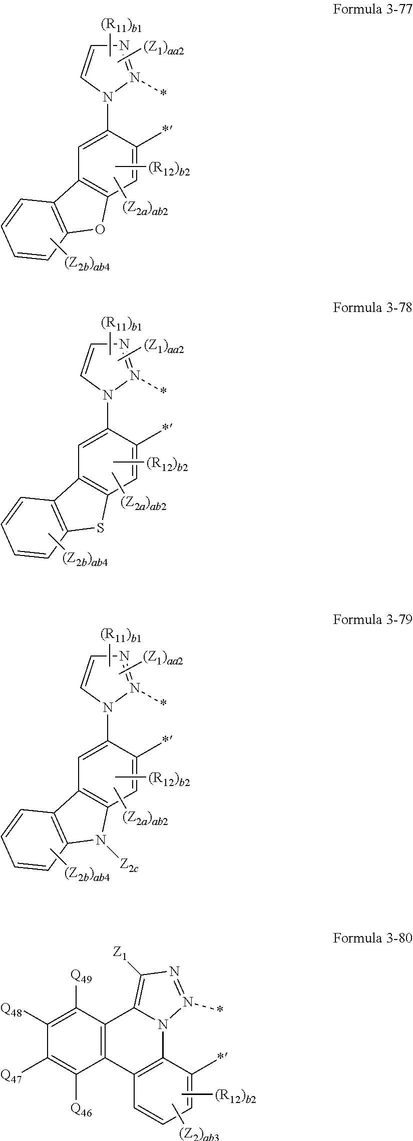

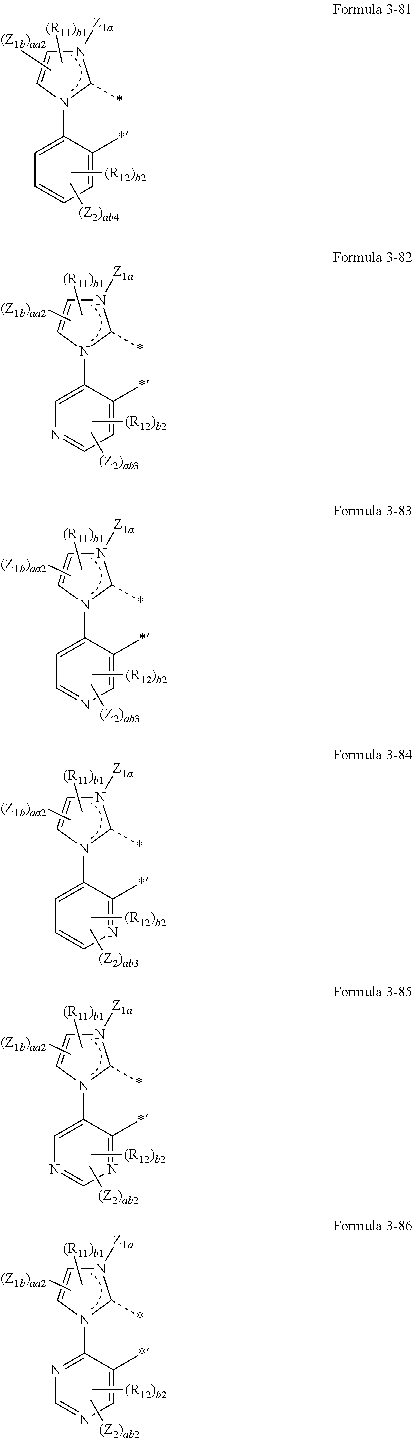

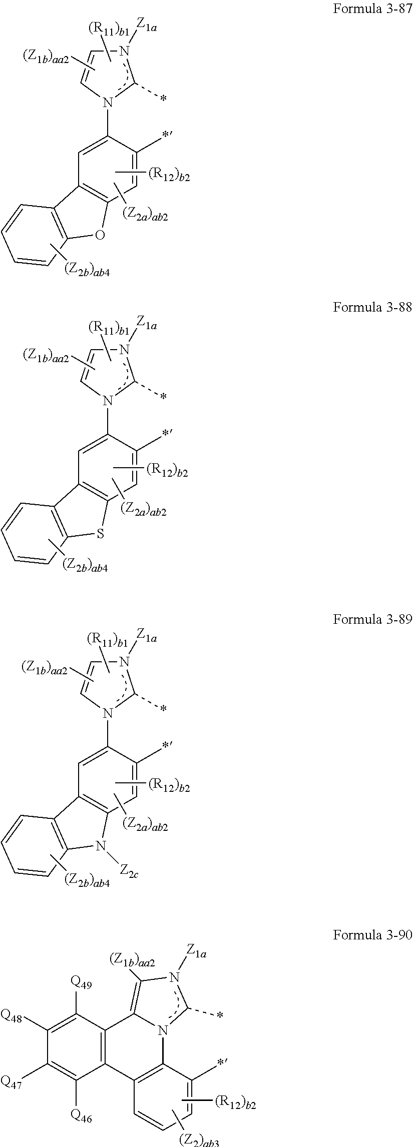

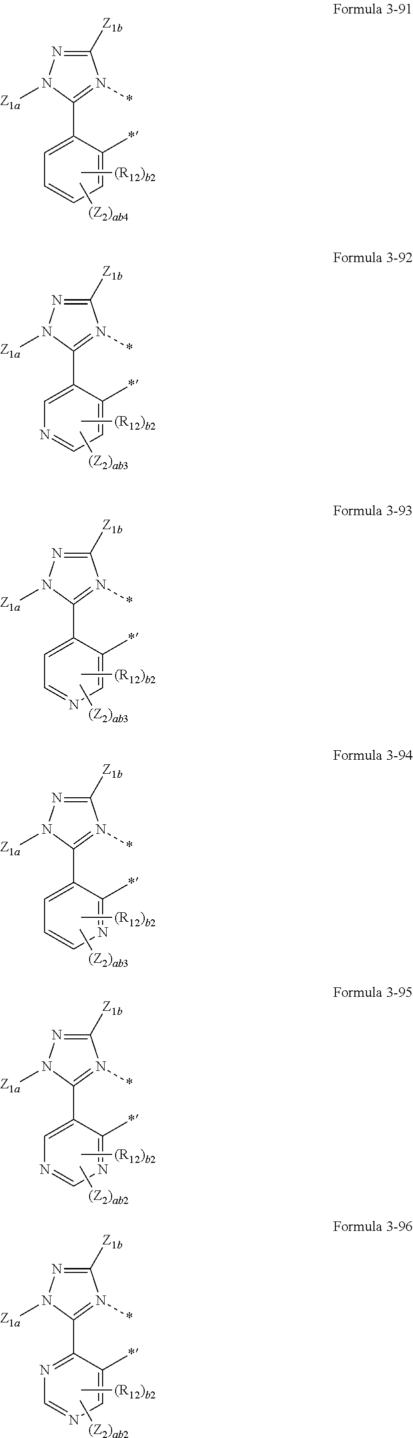

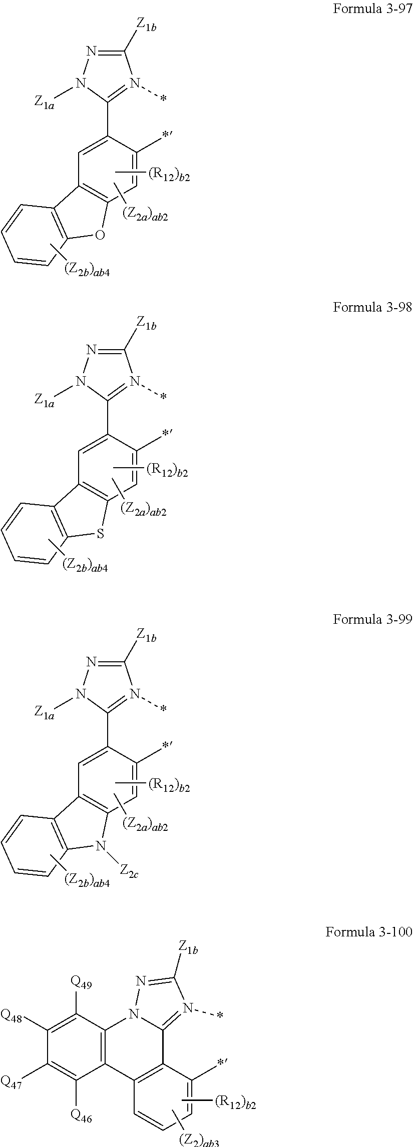

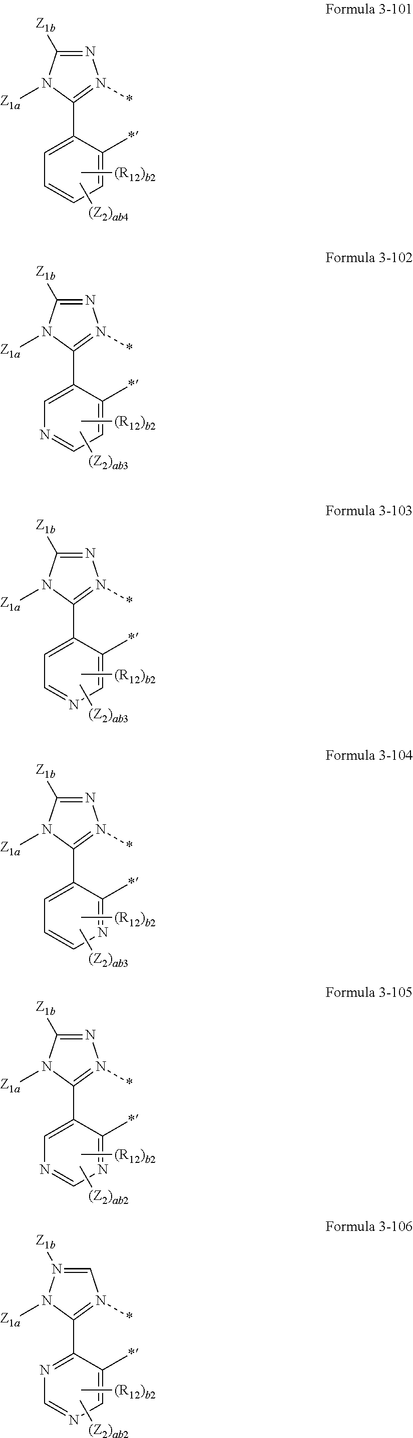

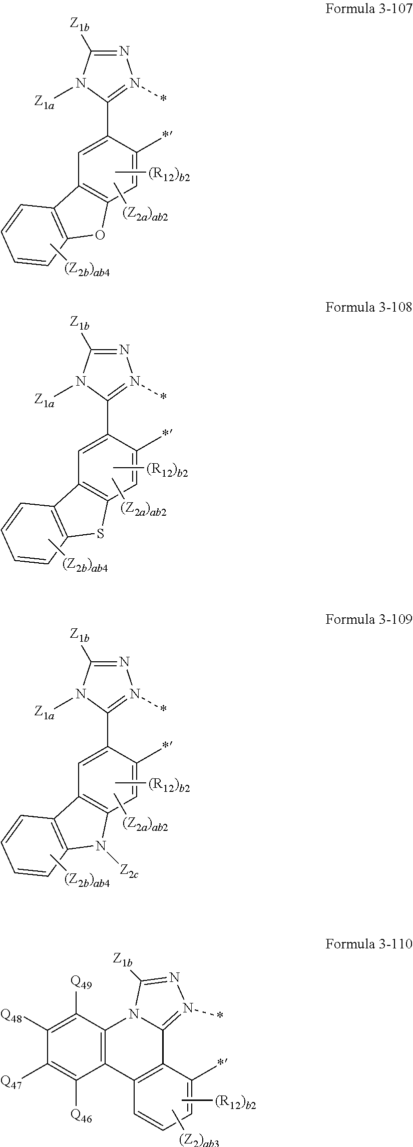

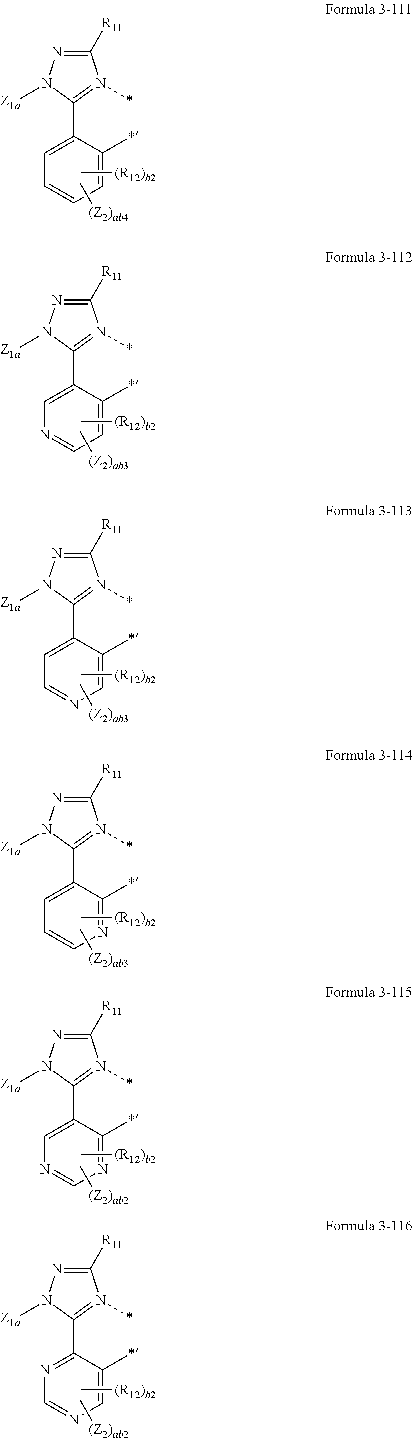

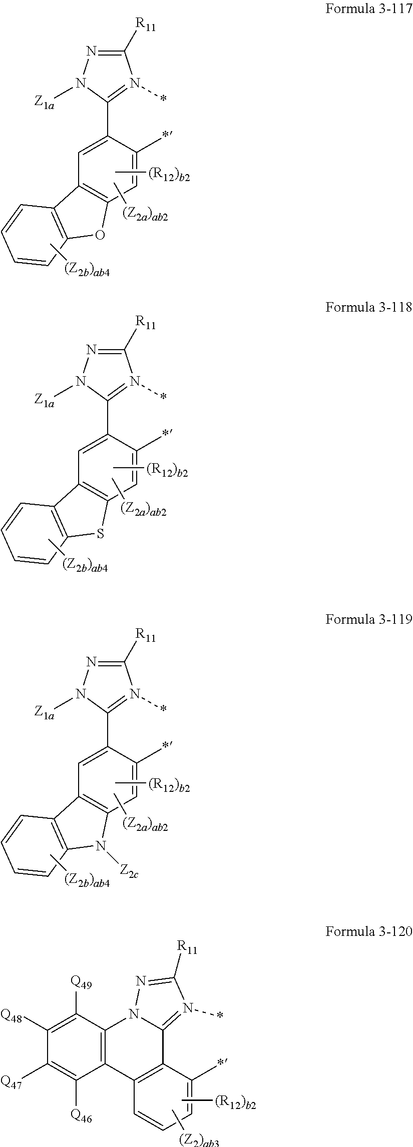

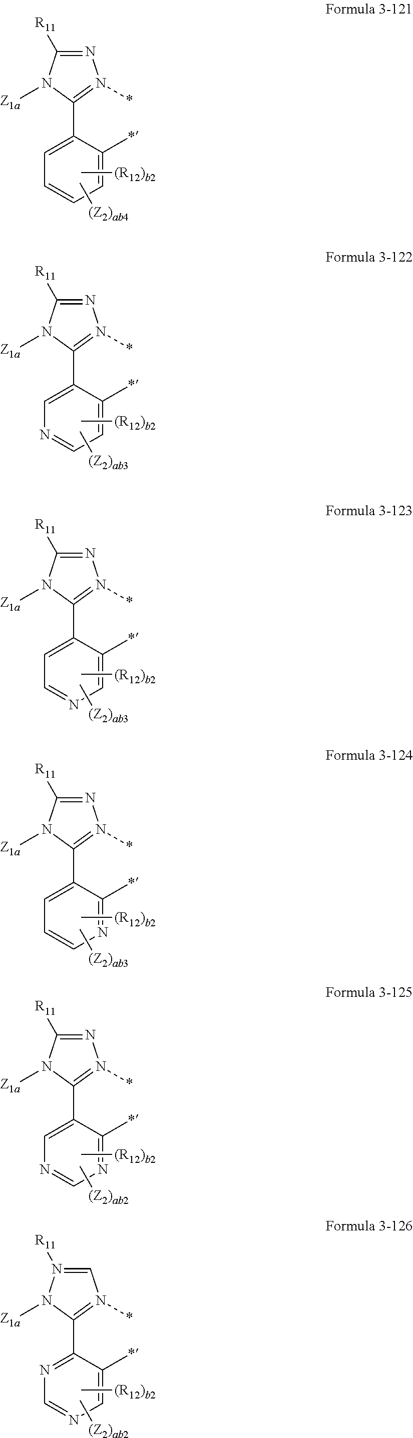

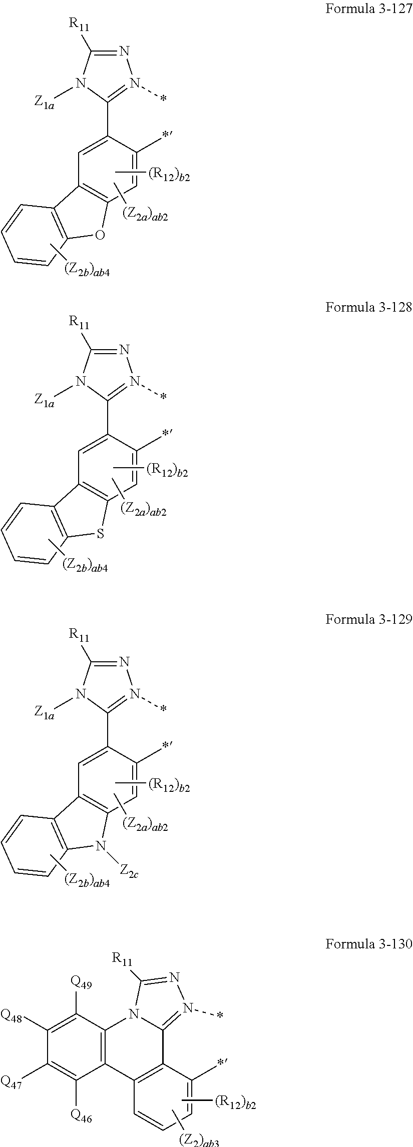

wherein, in Formula 3-1 to 3-130, descriptions of Z₁ and Z₂ may be the same as defined in the present disclosure,

descriptions for Z₁ₐ and Z_{1b} may be each independently the same with as Z₁,

descriptions for Z₂ₐ, Z_{2b}, and Z_{2c} may be each independently the same with as Z₂,

Q₄₄ to Q₄₉ are each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a pyridinyl group, and a pyrimidinyl group; and

a phenyl group, a naphthyl group, a pyridinyl group, and a pyrimidinyl group,

aa2 and ab2 may be each independently selected from 1 and 2,

aa3 and ab3 may be each independently an integer selected from 1 to 3,

aa4 and ab4 may be each independently an integer selected from 1 to 4,

R₁₁ and R₁₂ may be selected from groups represented by Formula 2C,

b1 and b2 may be each independently selected from 0, 1, and 2, a sum of b1 and b2 may be 1 or greater, and b2 in Formulae 1-111 to 1-130 may be selected from 1 and 2, and

* and *′ each indicates a binding site to M.

In some embodiments, in Formulae 3-1 to 3-130,

Z₁, Z₂, Z₁ₐ, Z_{1b}, Z₂ₐ, Z_{2b}, and Z_{2c} may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group; and

—N(Q₁)(Q₂), —Si(Q₃)(Q₄)(Q₅), —B(Q₆)(Q₇), and —P(═O)(Q₈)(Q₉),

wherein, Q₁ to Q₉ may be each independently selected from

—CH₃, -CD₃, -CD₂H, -CDH₂, —CH₂CH₃, —CH₂CD₃, —CH₂CD₂H, —CH₂CDH₂, —CHDCH₃, —CHDCD₂H, —CHDCDH₂, —CHDCD₃, -CD₂CD₃, -CD₂CD₂H, and -CD₂CDH₂;

an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group; and

an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group, each substituted with at least one selected from a deuterium and a C₁-C₁₀ alkyl group,

aa2 and ab2 may be each independently selected from 1 and 2,

aa3 and ab3 may be each independently an integer selected from 1 to 3,

aa4 and ab4 may be each independently an integer selected from 1 to 4,

R₁₁ and R₁₂ may be selected from groups represented by Formula 2C,

b1 and b2 may be each independently selected from 0, 1, and 2, a sum of b1 and b2 may be 1 or greater, and b2 in Formulae 1-111 to 1-130 may be selected from 1 and 2, and

* and *′ each indicates a binding site to M in Formula 1.

In some embodiments, in Formula 1, L₁ may be selected from ligands represented by Formulae 3-1A to 3-1J:

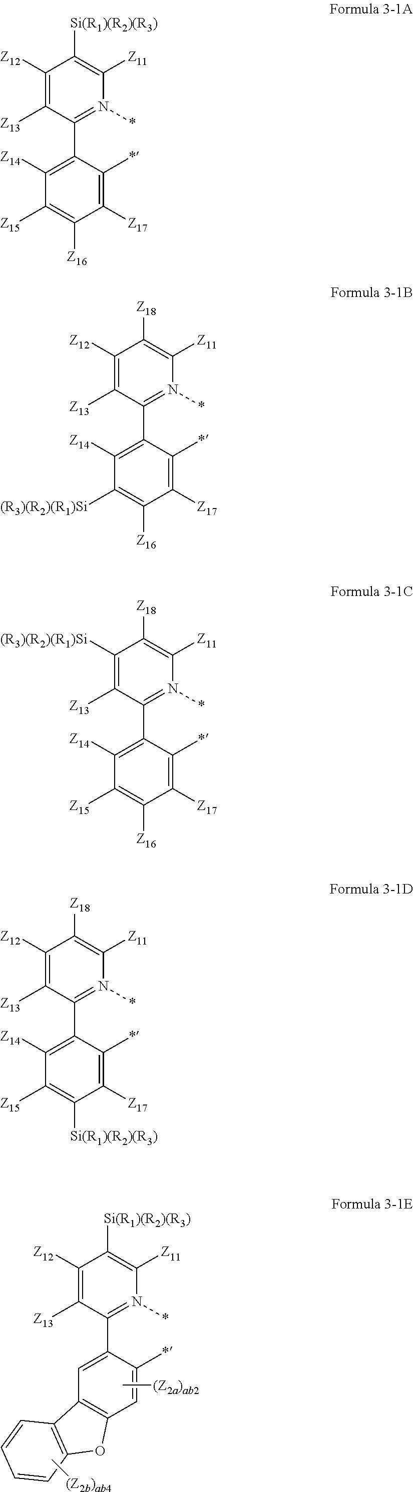

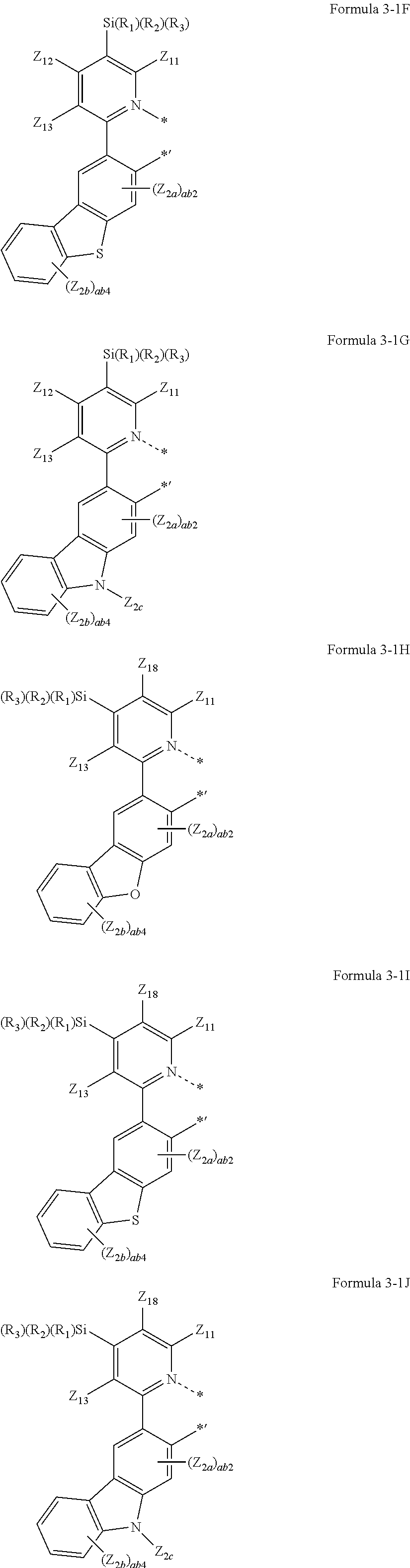

wherein, in Formulae 3-1A to 3-1J,

descriptions for Z₁₁ to Z₁₃ and Z₁₈ may be the same with as Z₁ provided herein,

descriptions for Z₁₄ to Z₁₇ and Z₂ₐ to Z_{2c} may be the same with as Z₂ provided herein,

ab2 may be an integer selected from 0 to 2,

ab4 may be an integer selected from 0 to 4,

descriptions of R₁ to R₃ may be the same as defined herein, and

* and *′ each indicates a binding site to M in Formula 1.

In some embodiments, in Formula 1, L₁ may be selected from ligands represented by Formulae 3-1A and 3-1E.

In some embodiments, in Formula 1, L₁ may be selected from ligands represented by Formulae 3-1A and 3-1E, and Z₁₂ in Formula 3-1A may not be a hydrogen.

In some embodiments, in Formula 1, L₁ may be selected from ligands represented by Formulae 3-1A and 3-1E, and Z₁₂ in Formula 3-1A may not be a hydrogen and a methyl group.

In some embodiments, in Formula 1, L₁ may be selected from ligands represented by Formulae 3-1(1) to 3-1(114):

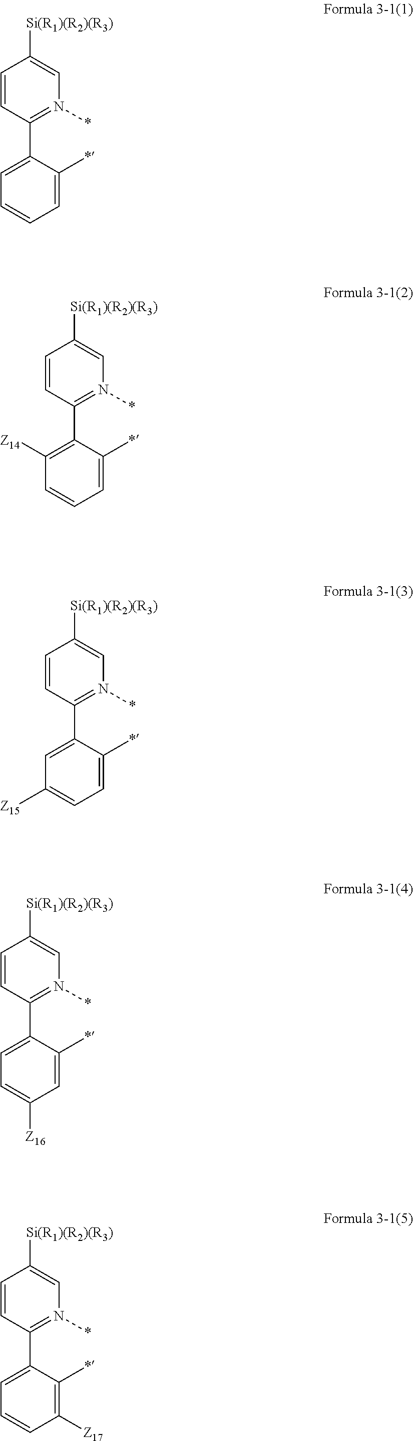

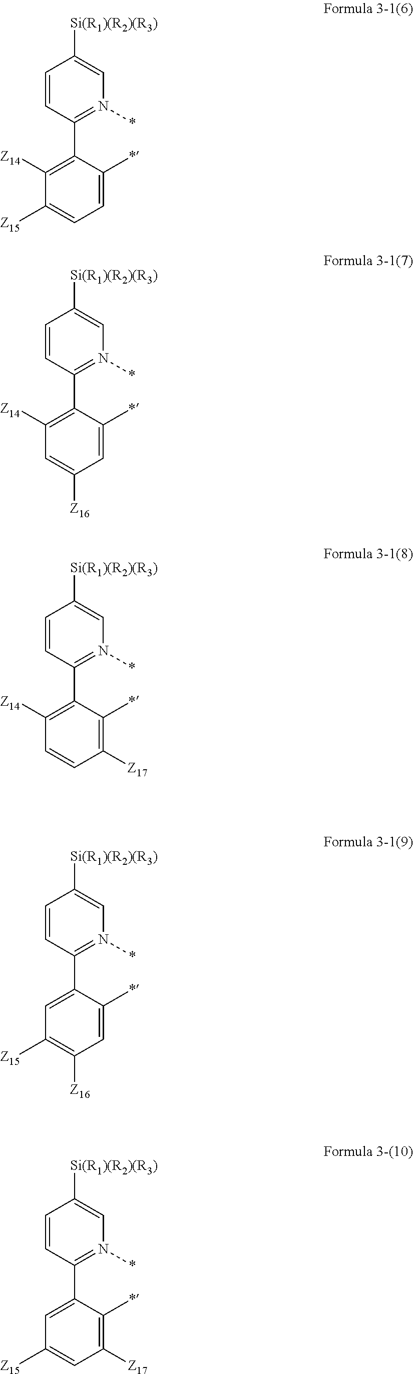

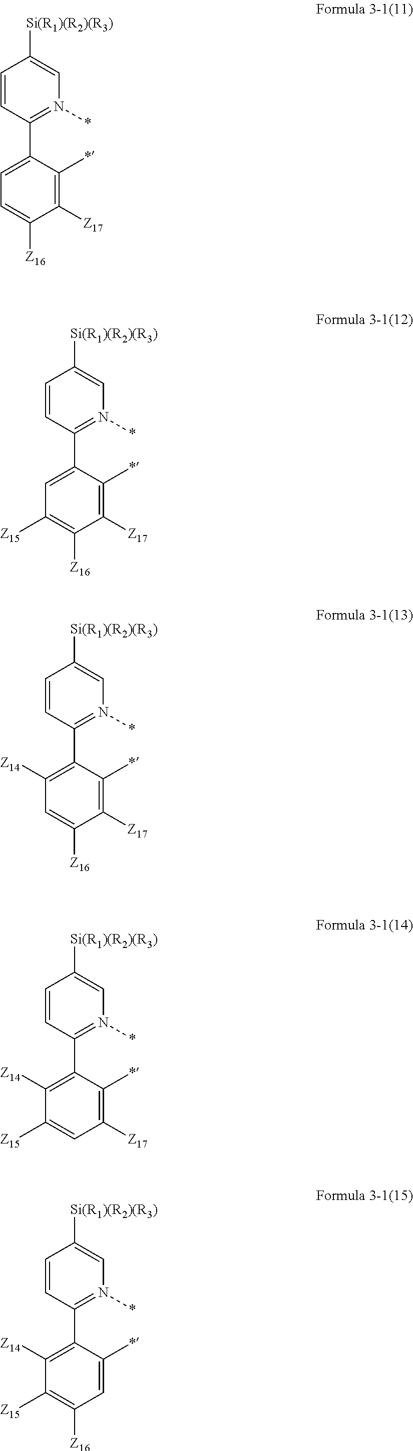

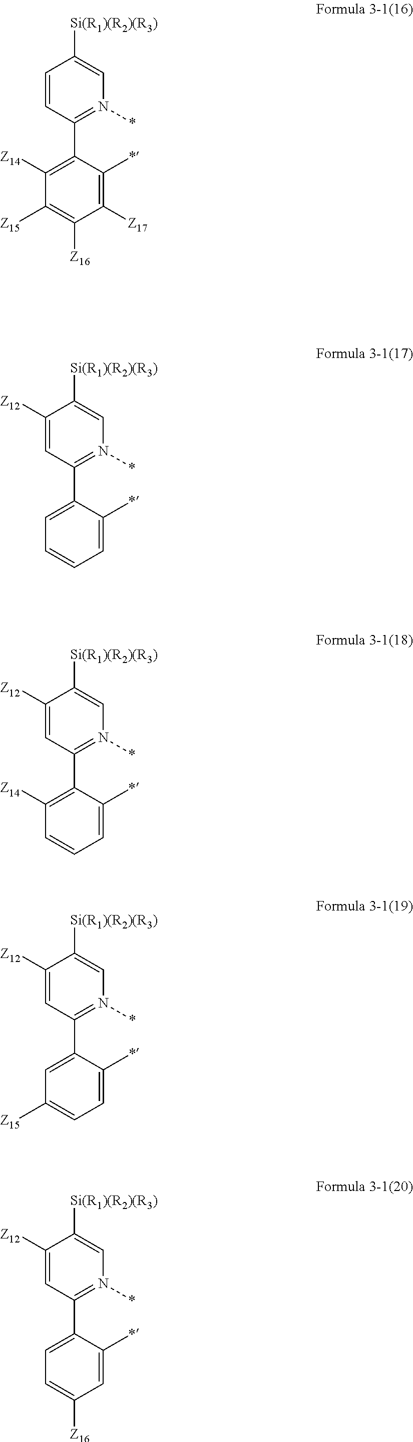

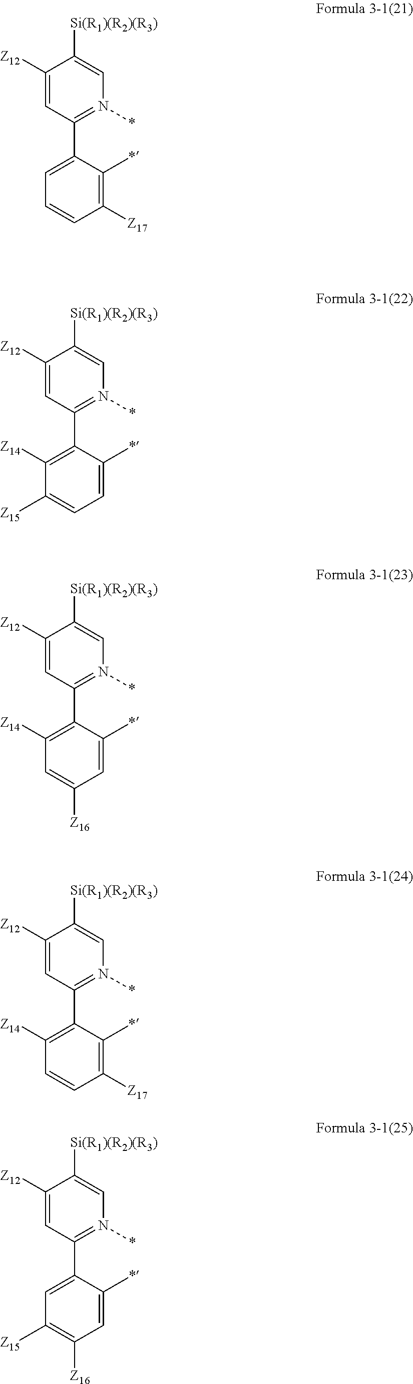

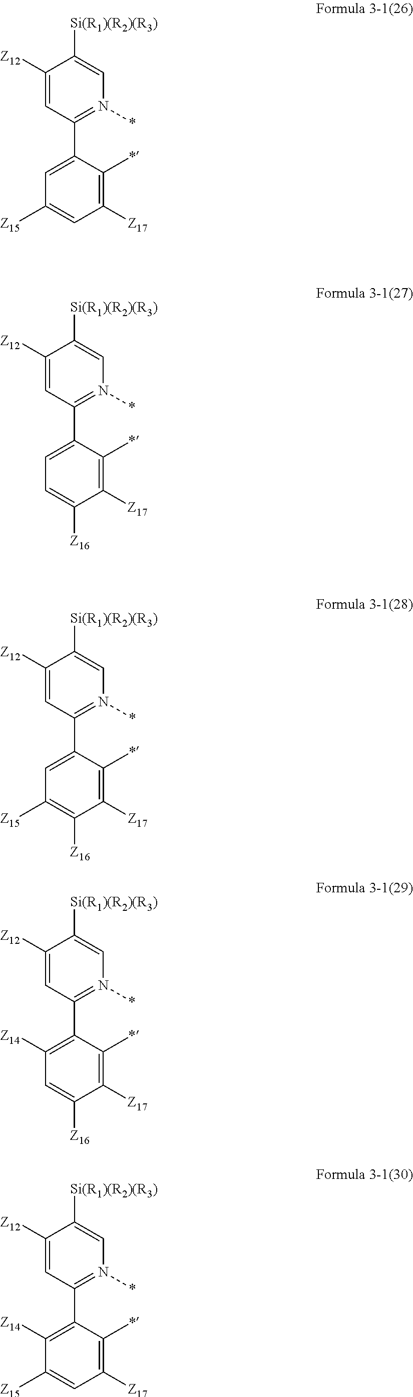

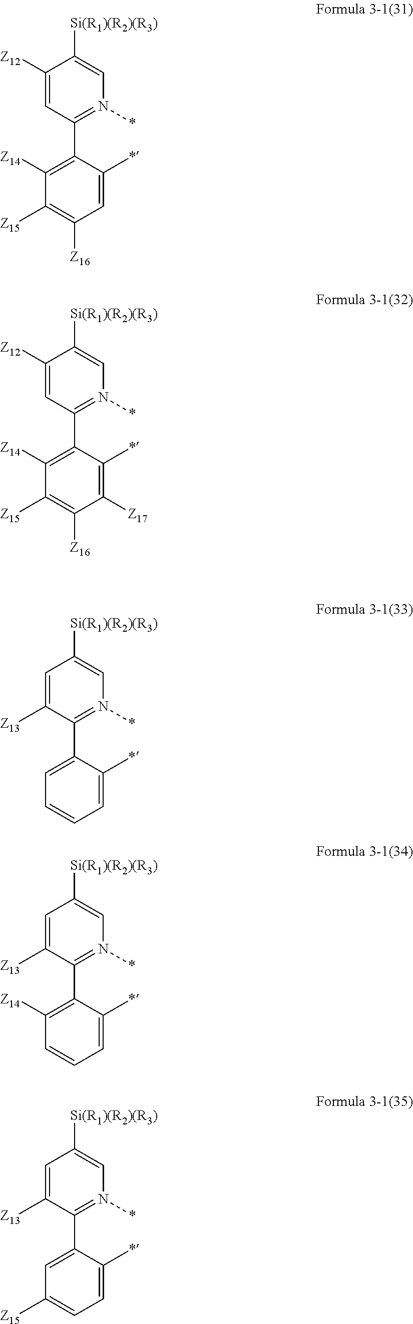

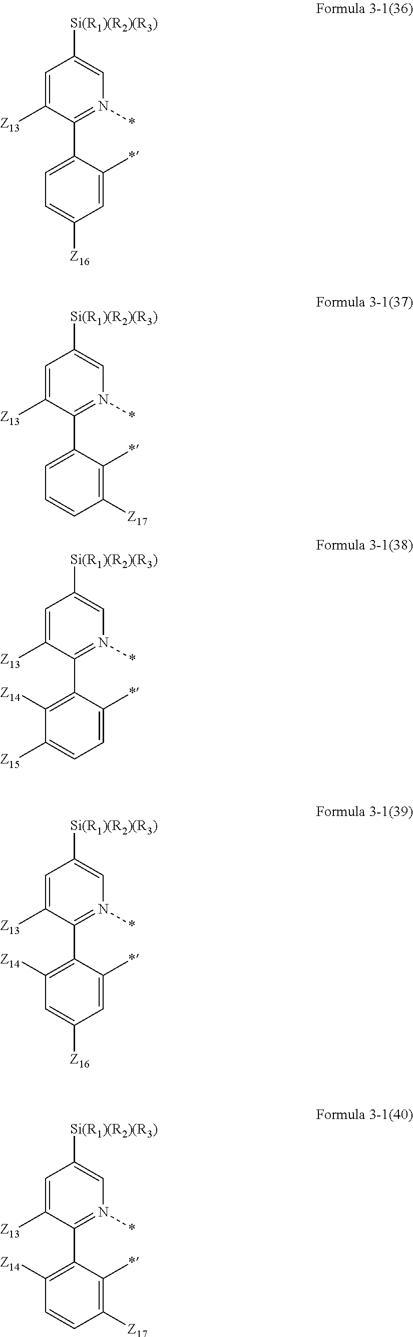

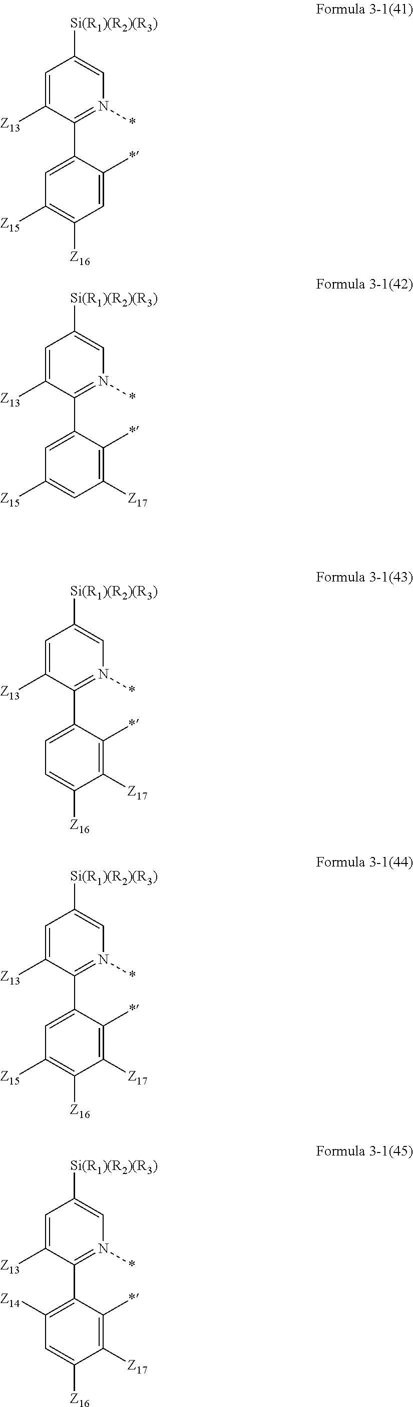

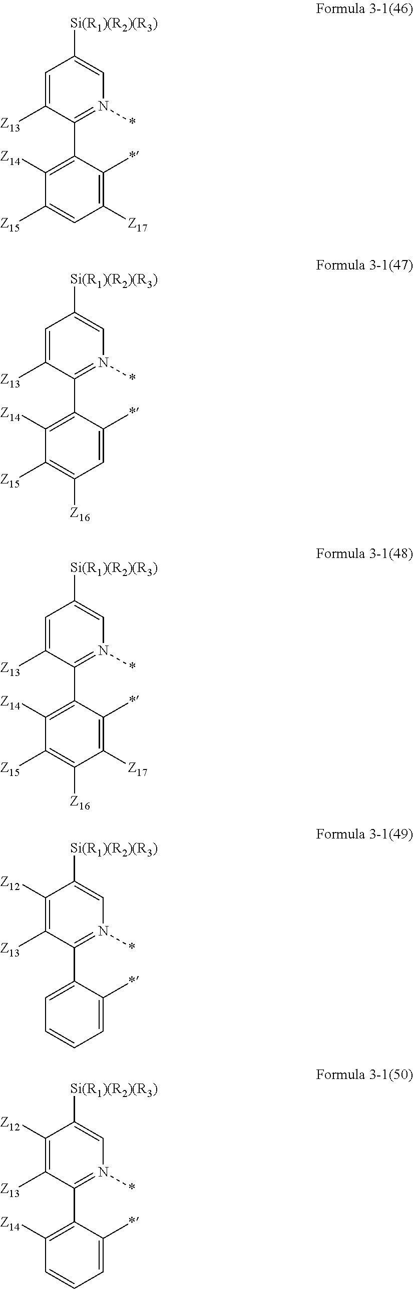

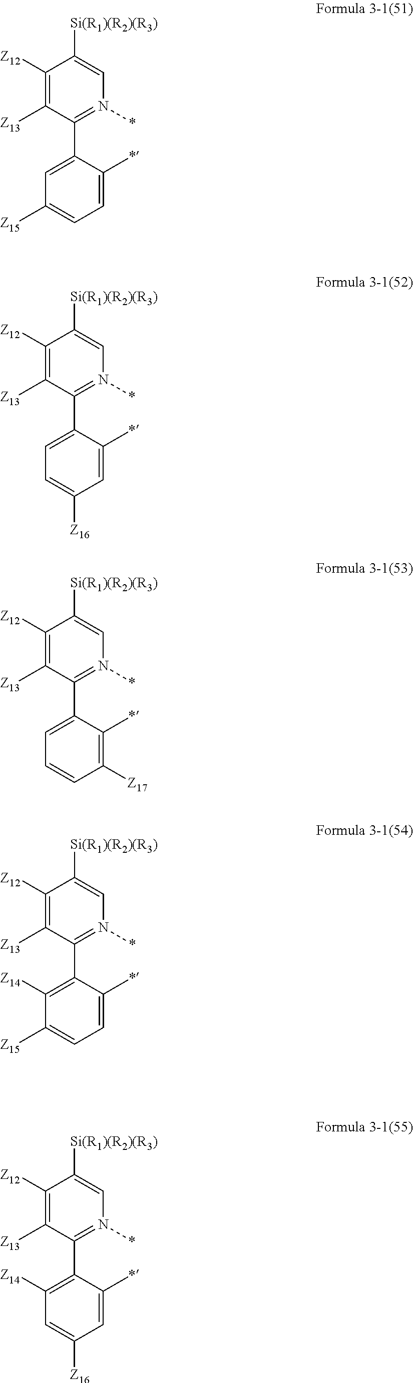

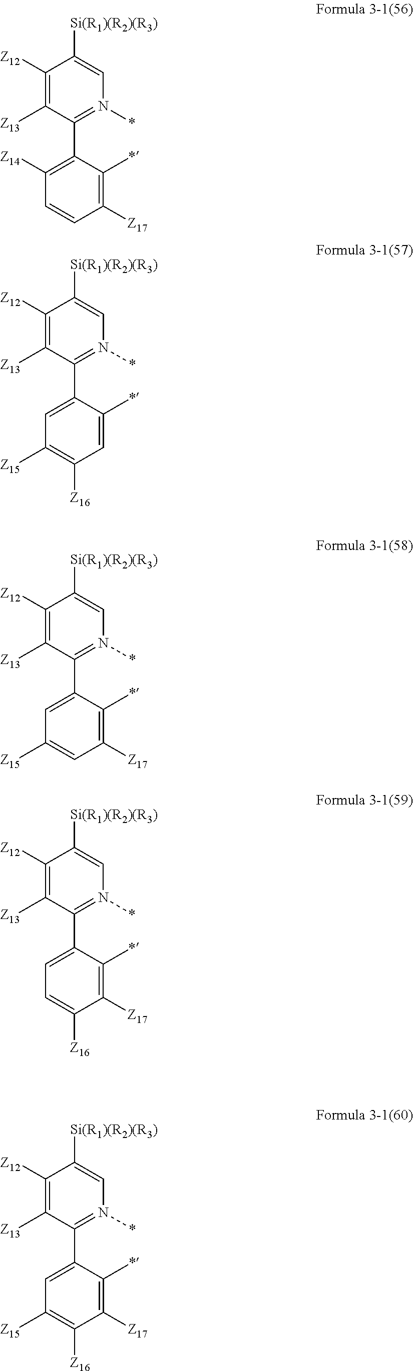

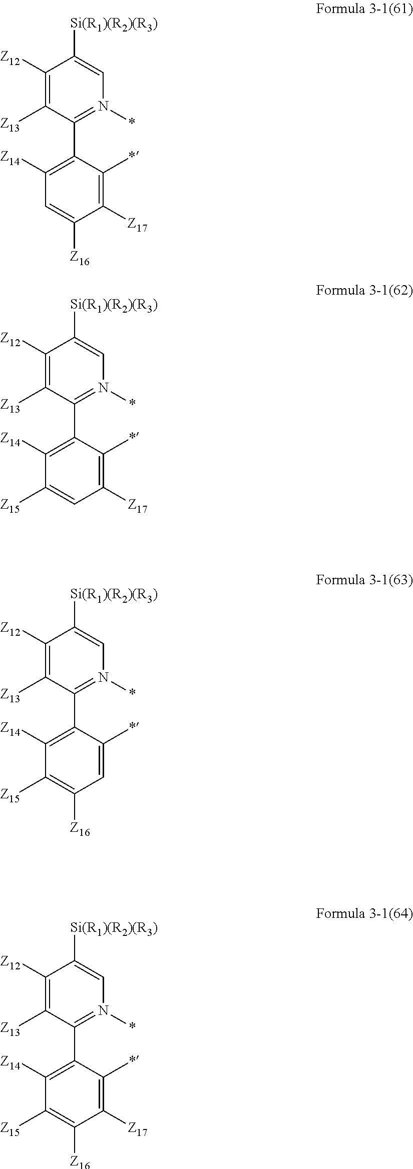

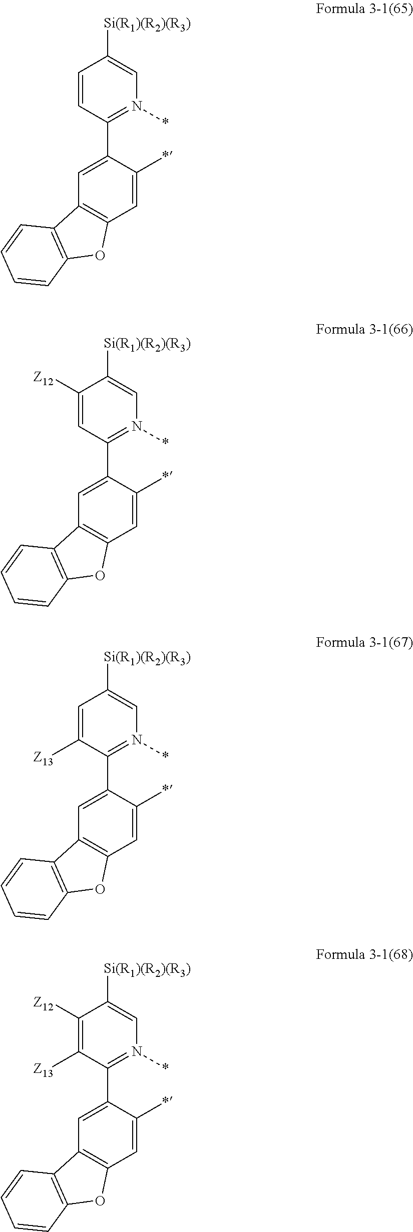

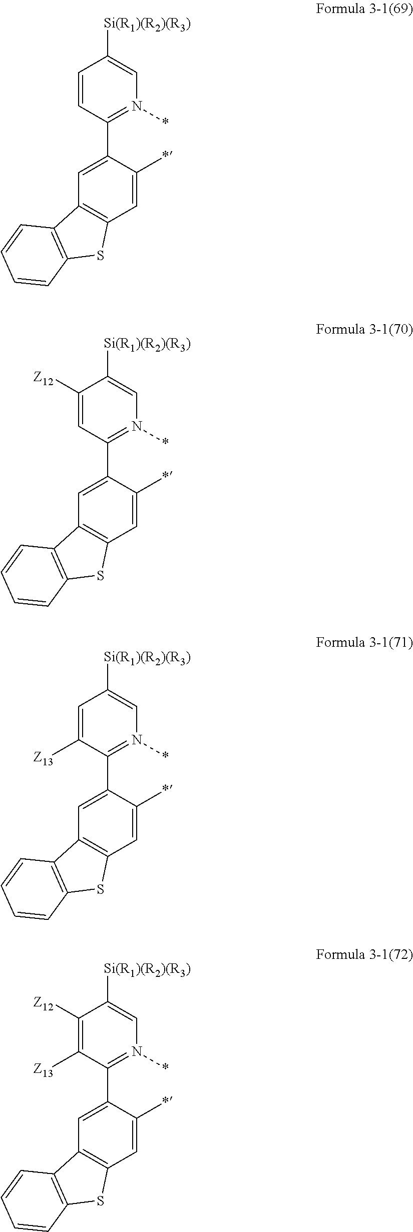

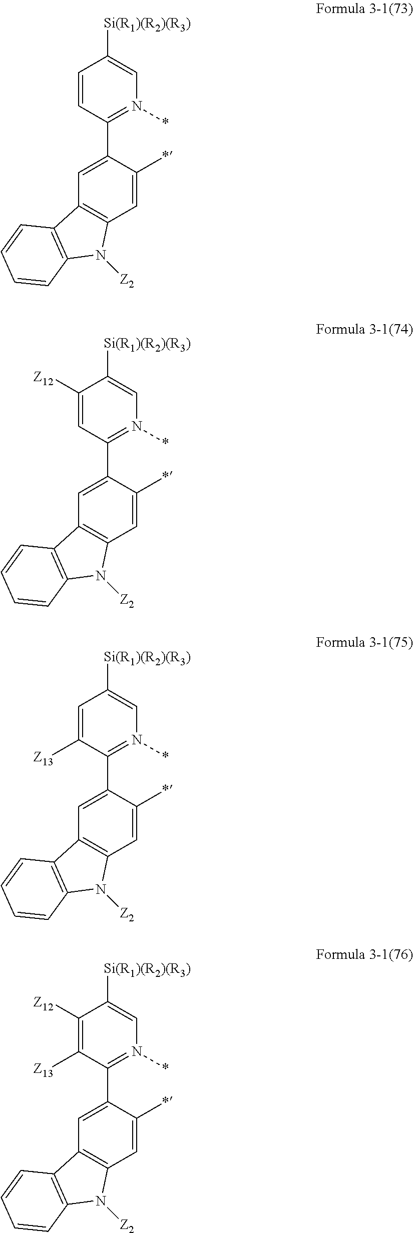

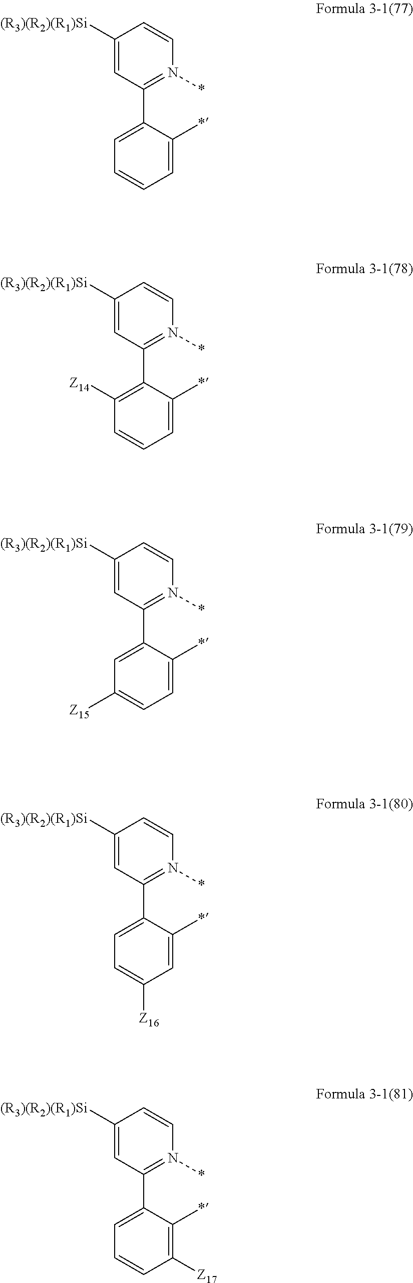

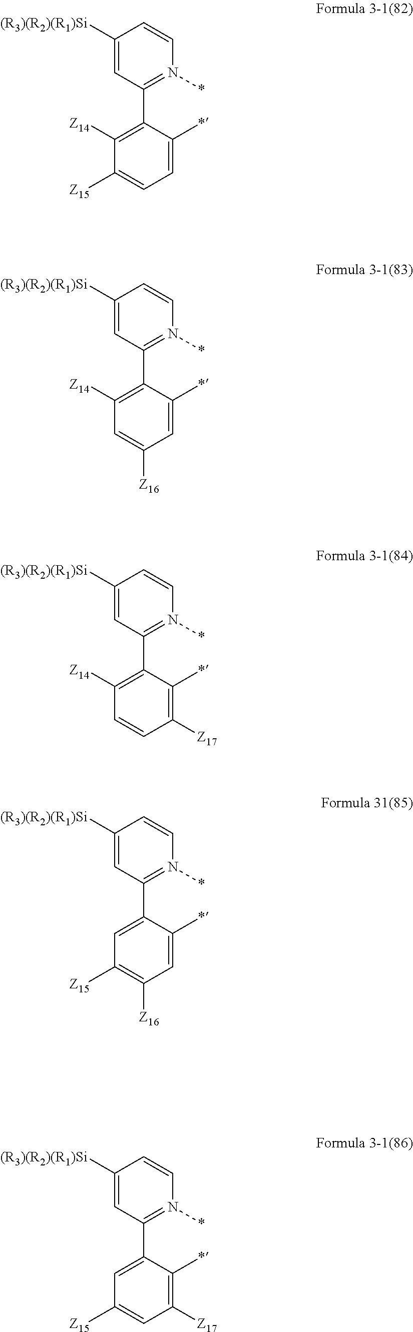

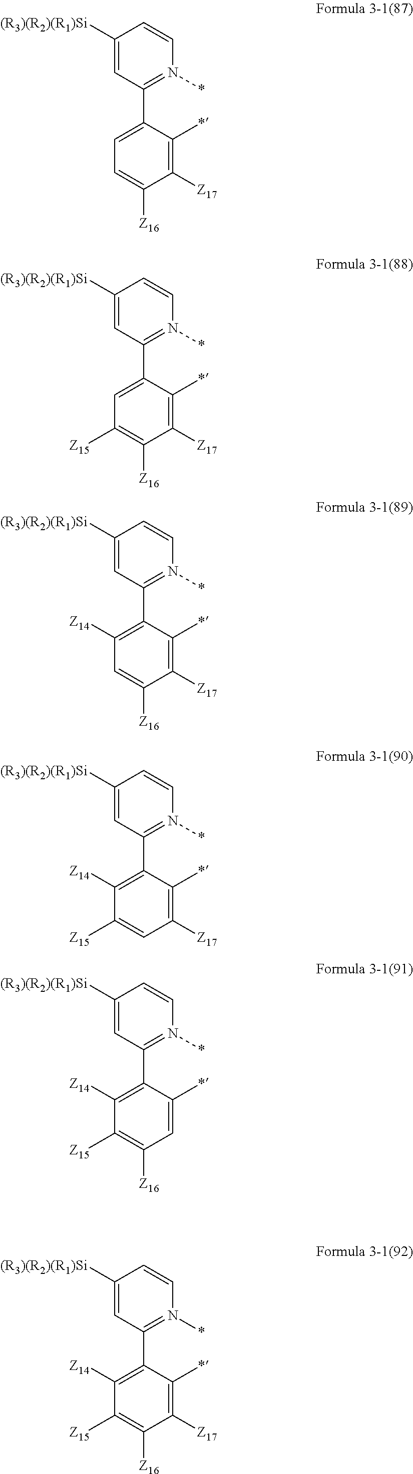

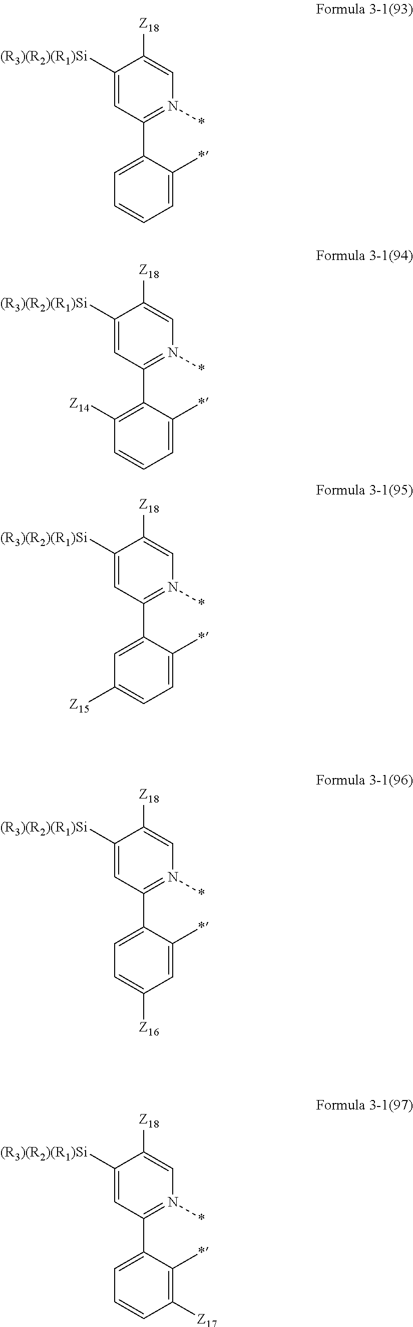

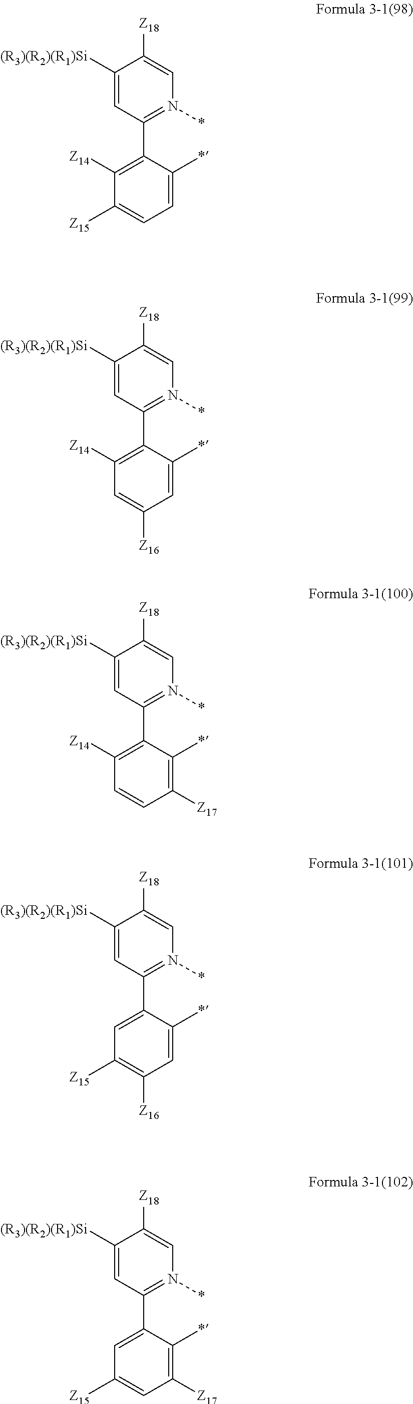

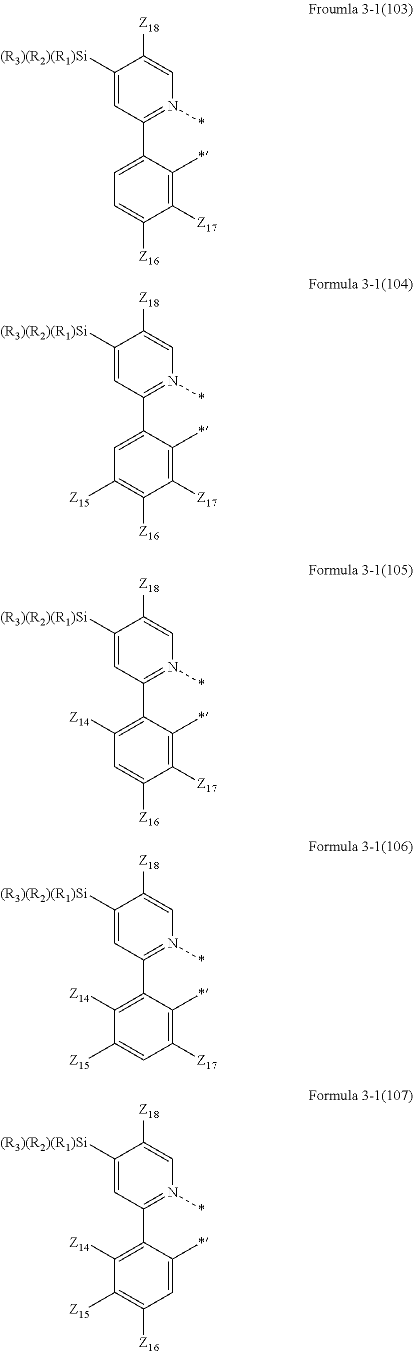

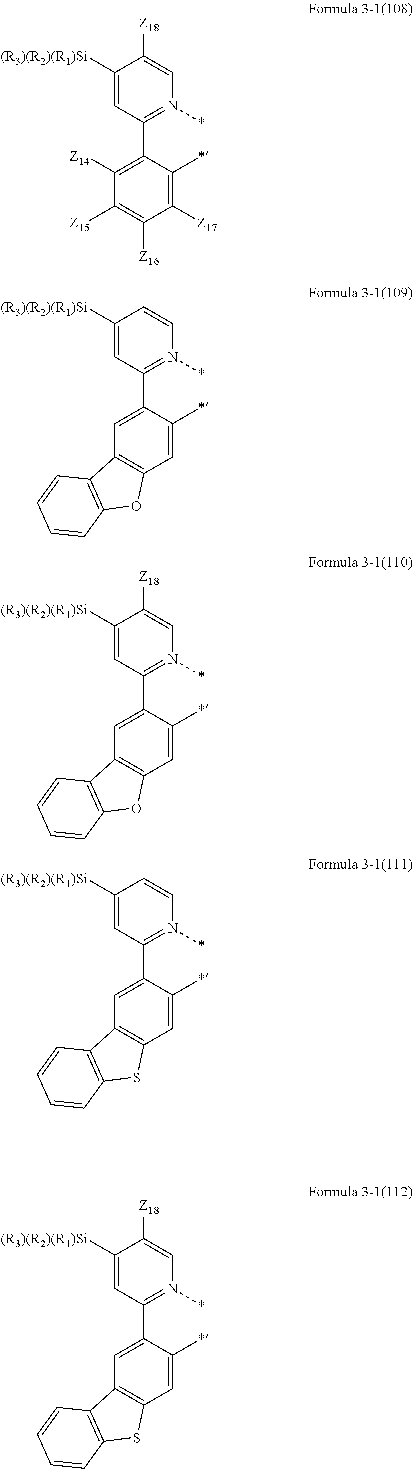

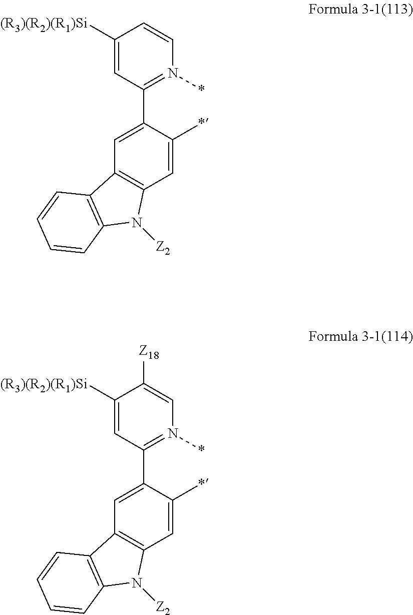

wherein, in Formulae 3-1(1) to 3-1(114), descriptions of Z₁₂, Z₁₃, and Z₁₈ may be the same in connection with Z₁ provided herein, descriptions of Z₂ and Z₁₄ to Z₁₇ may be the same in connection with Z₂ provided herein, and * and *′ each indicates a binding site to M in Formula 1; however, in Formulae 3-1(1) to 3-1(114), Z₂ and Z₁₂ to Z₁₈ may not be a hydrogen.

In some embodiments, in Formulae 3-1(1) to 3-1(114),

Z₂ and Z₁₂ to Z₁₈ may be each independently selected from a deuterium, —F, a cyano group, a nitro group, —SF₅, —CH₃, -CD₃, -CD₂H, -CDH₂, —CF₃, —CF₂H, —CFH₂, groups represented by Formulae 9-1 to 9-19, and groups represented by Formulae 10-1 to 10-36,

R₁ to R₃ may be each independently selected from —CH₃, -CD₃, -CD₂H, -CDH₂, groups represented by Formulae 9-1 to 9-19, and a phenyl group, and

* and *′ may each indicates a binding site to M in Formula 1, but embodiments not limited thereto.

In some embodiments, in Formula 1, L₂ may be selected from ligands represented by Formulae 2B(1) to 2B(10):

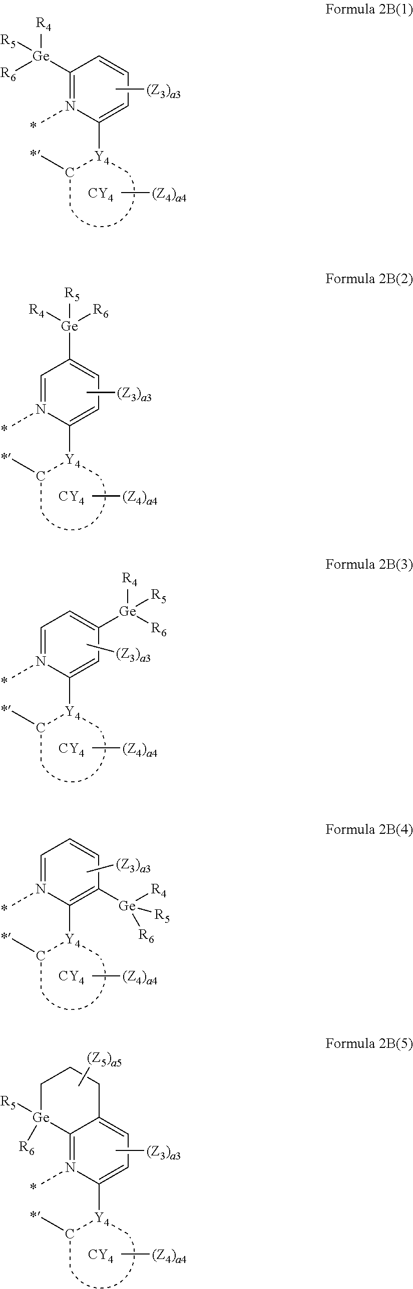

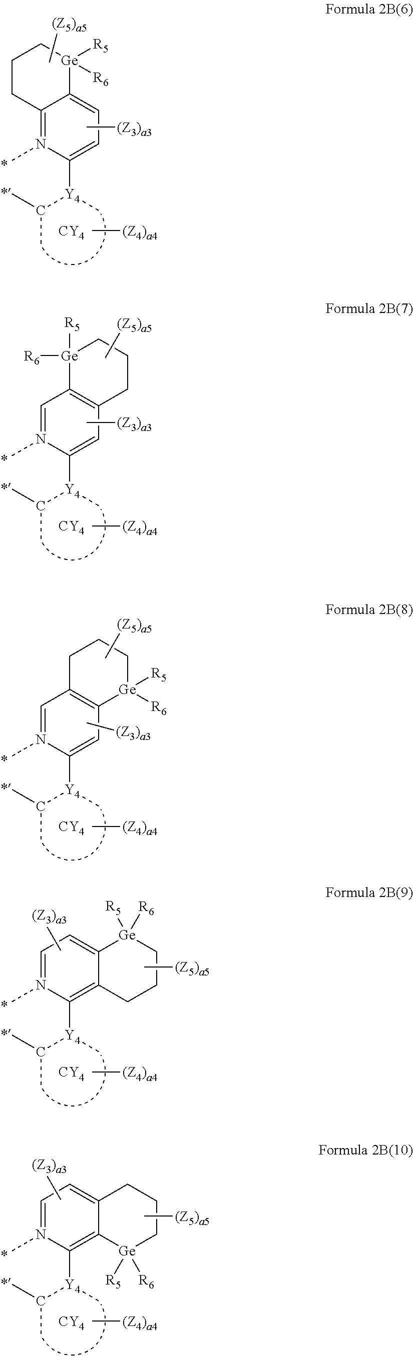

wherein, in Formulae 2B(1) to 2B(10),

descriptions for Z₃, Z₄, a3, a4, and R₄ to R₆ may be the same as defined herein,

CY₄ may be selected from a benzene, a naphthalene, a carbazole, a dibenzofuran, and a dibenzothiophene,

description for Z₅ may be the same with as Z₃,

a5 may be an integer selected from 1 to 6, and

* and *′ each indicates a binding site to M in Formula 1.

In some embodiments, in Formula 1, L₂ may be selected from ligands represented by Formulae 2B-1 to 2B-114:

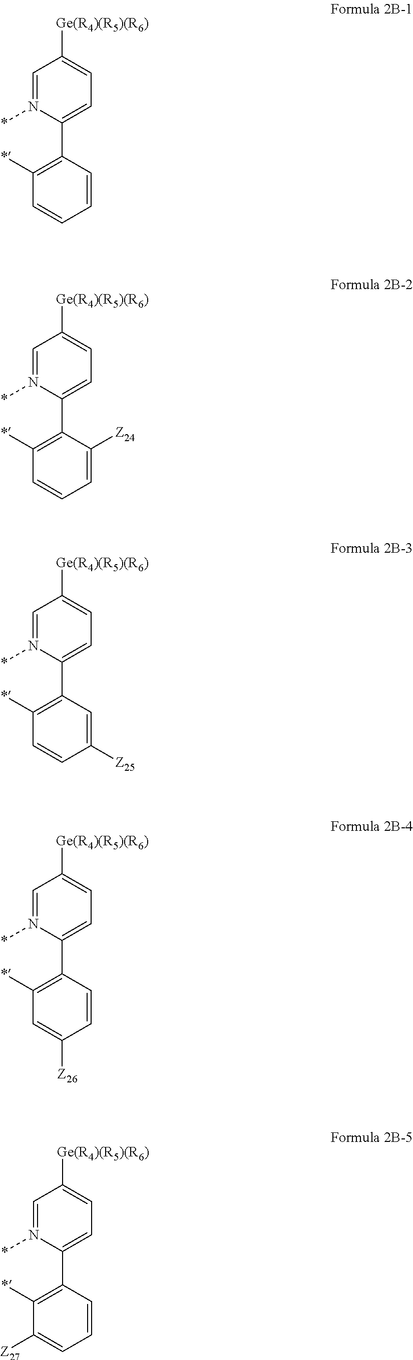

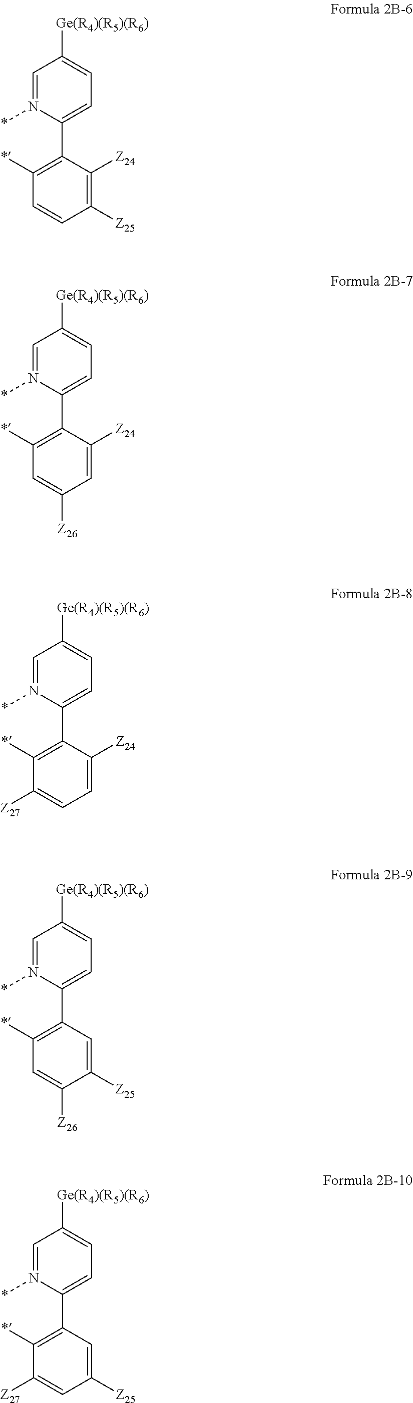

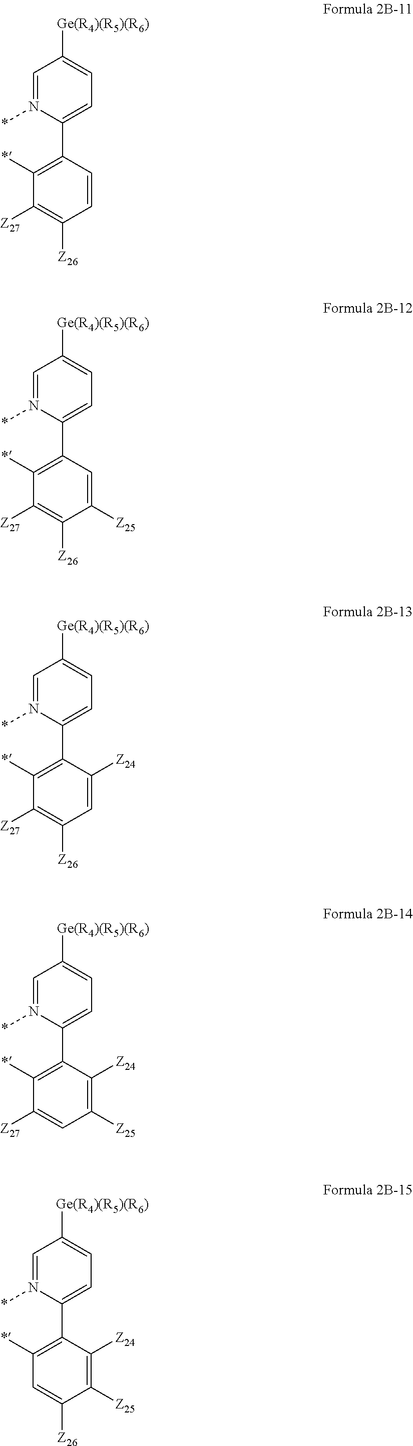

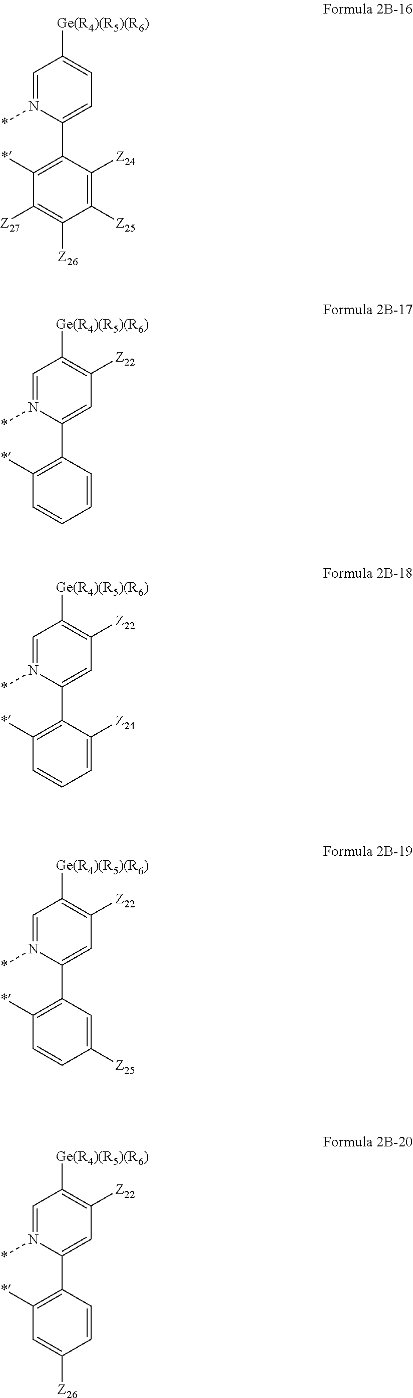

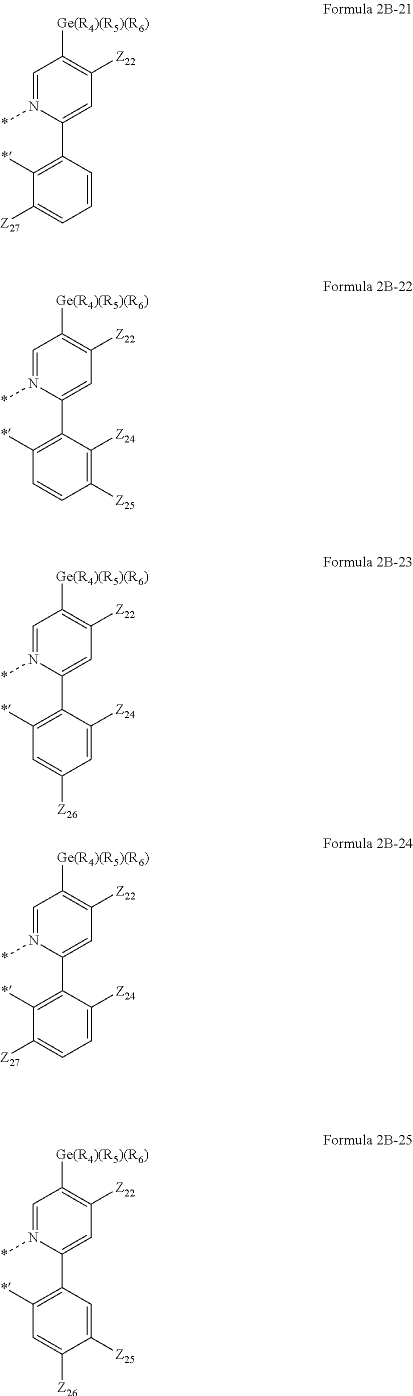

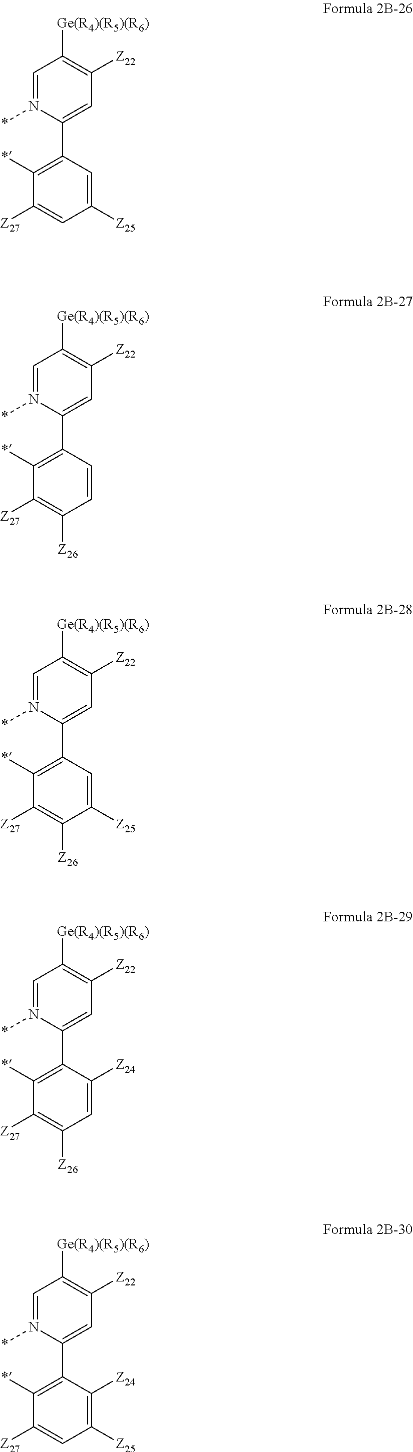

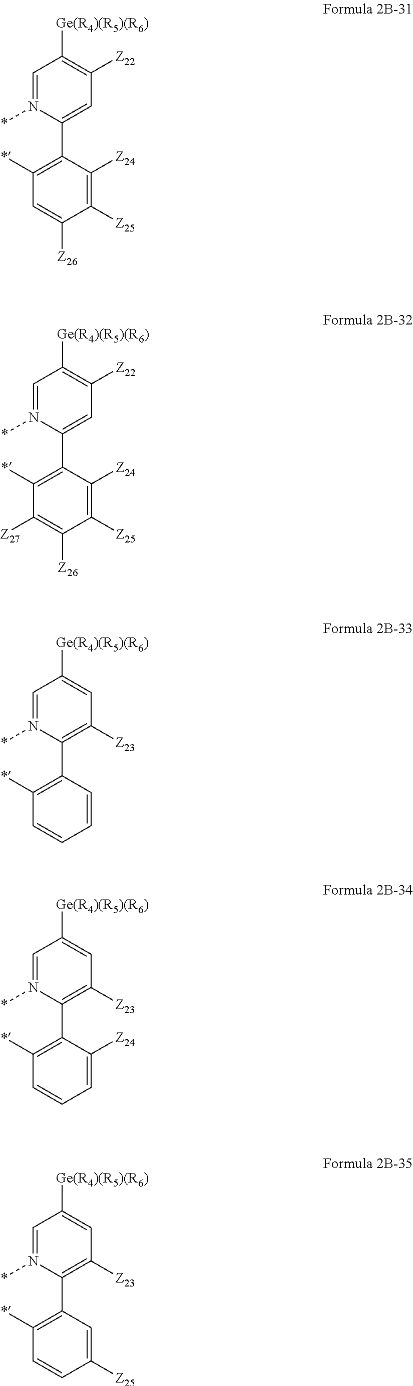

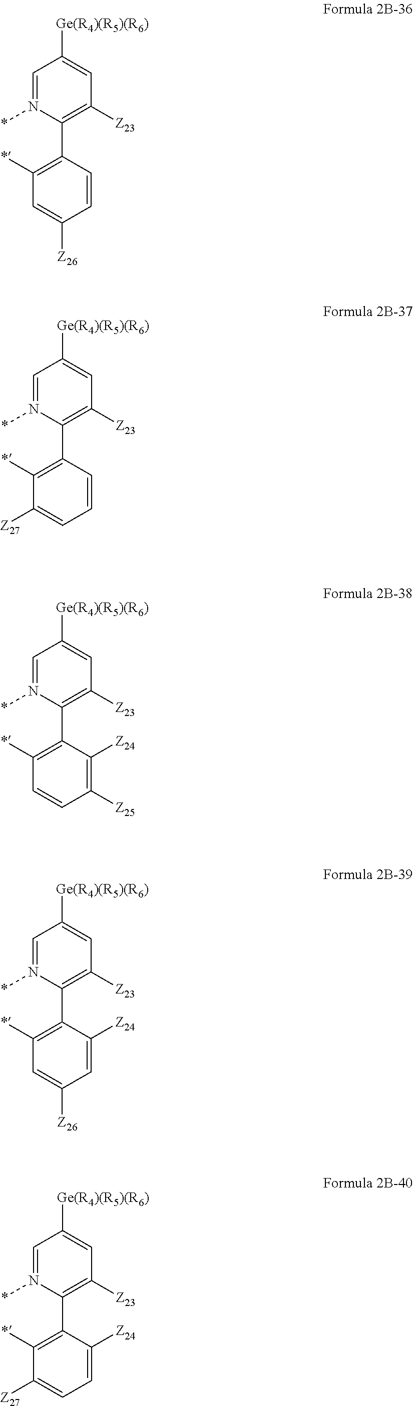

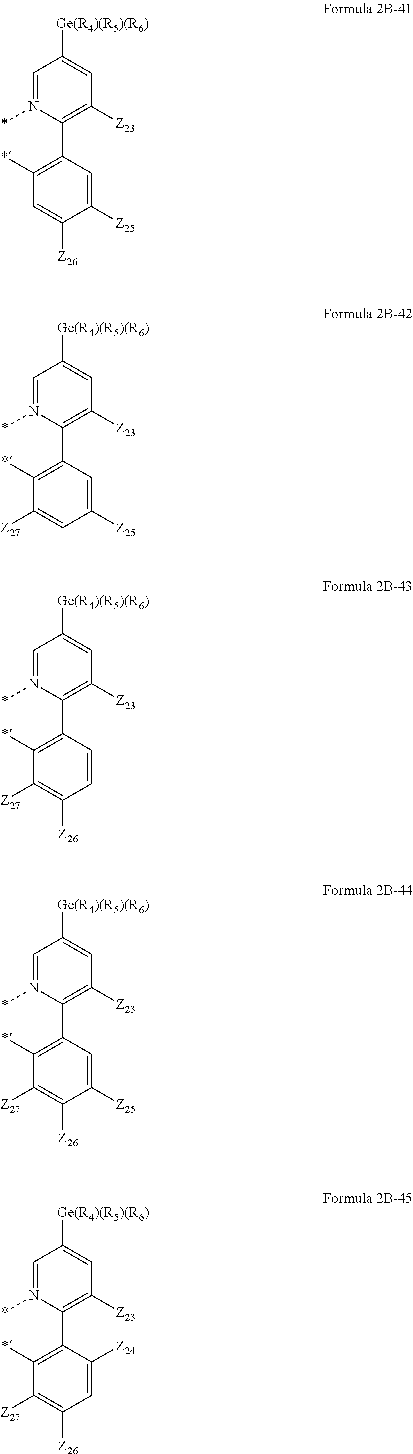

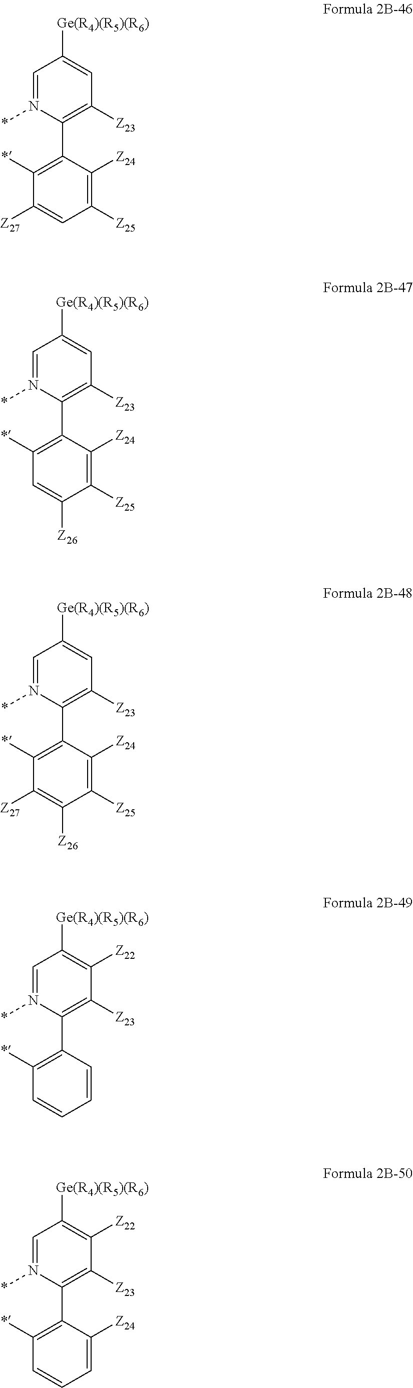

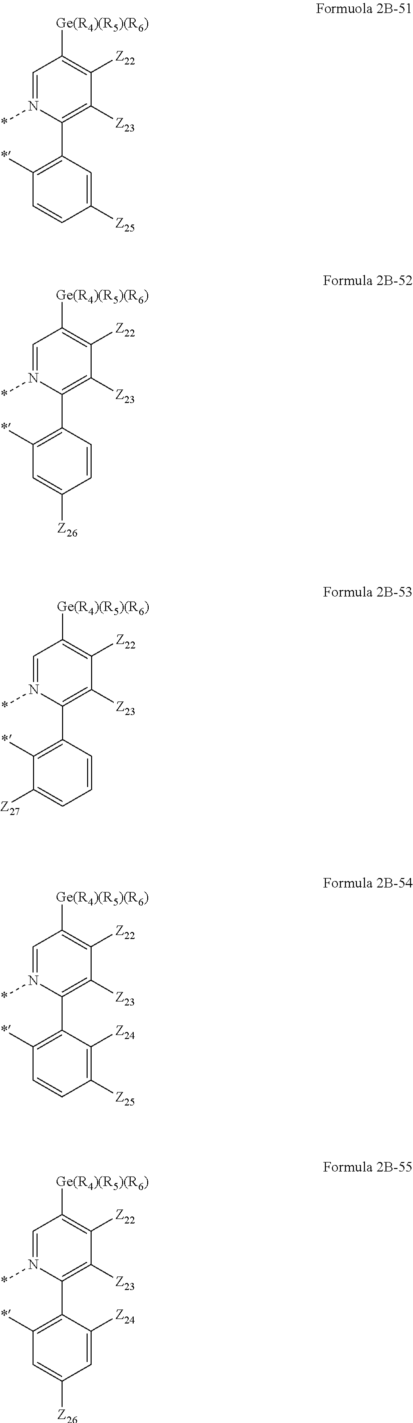

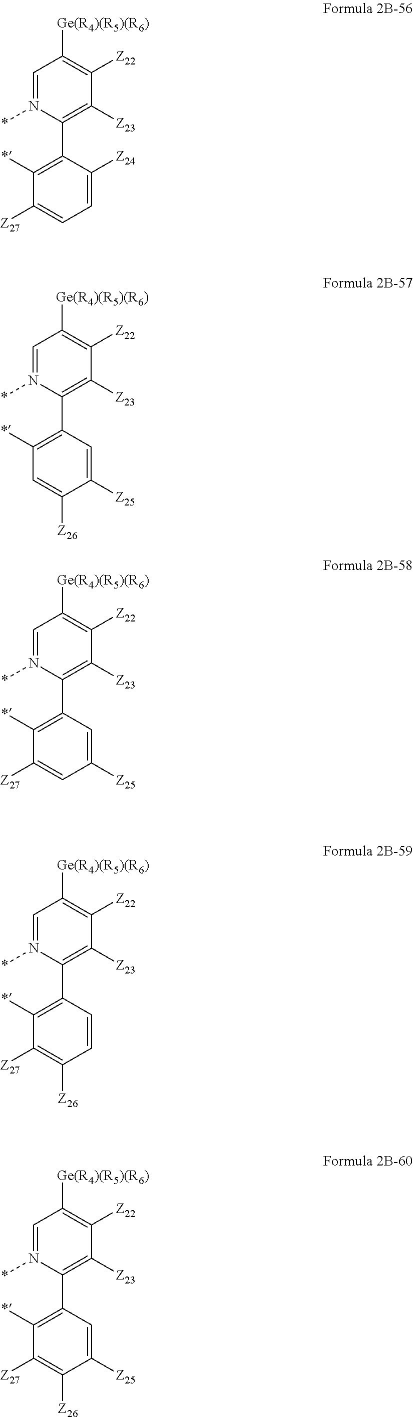

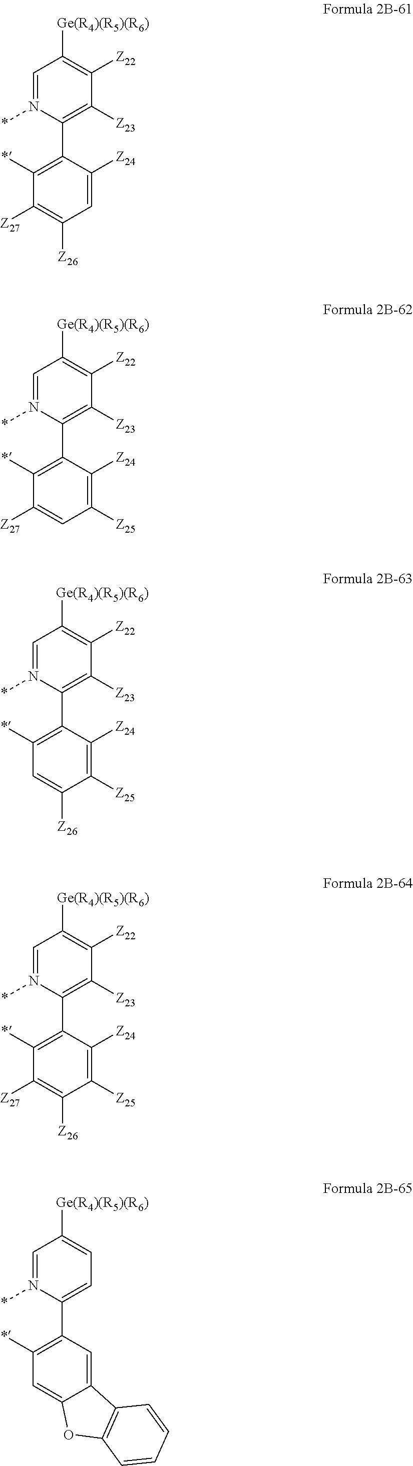

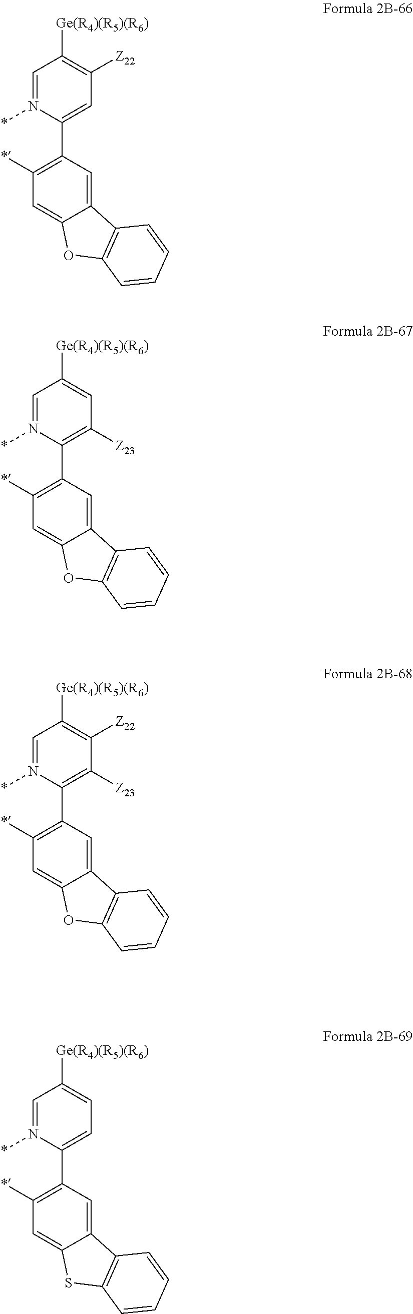

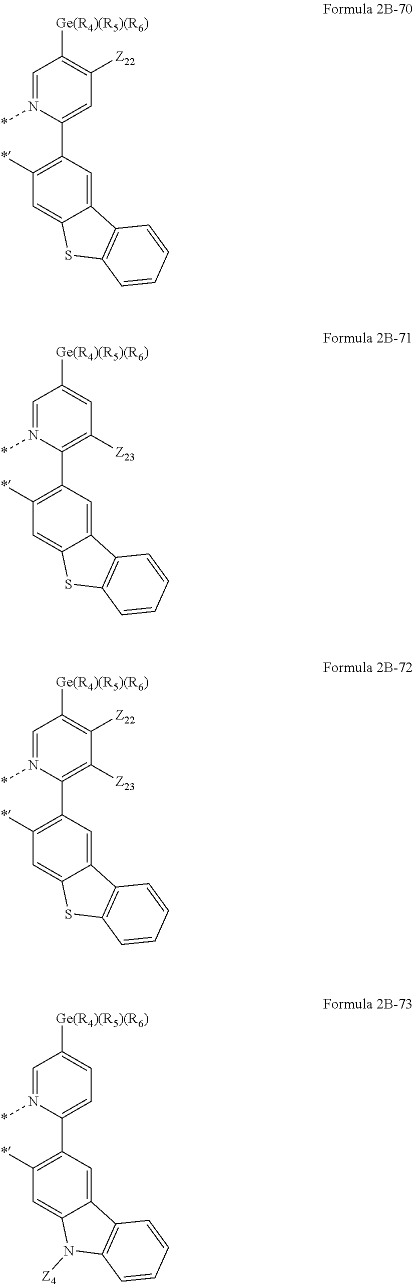

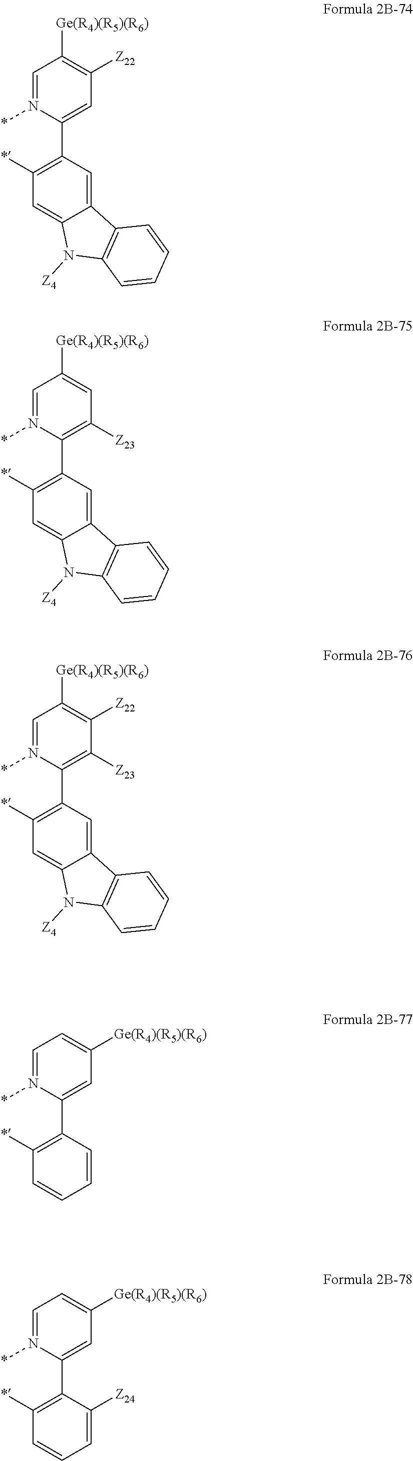

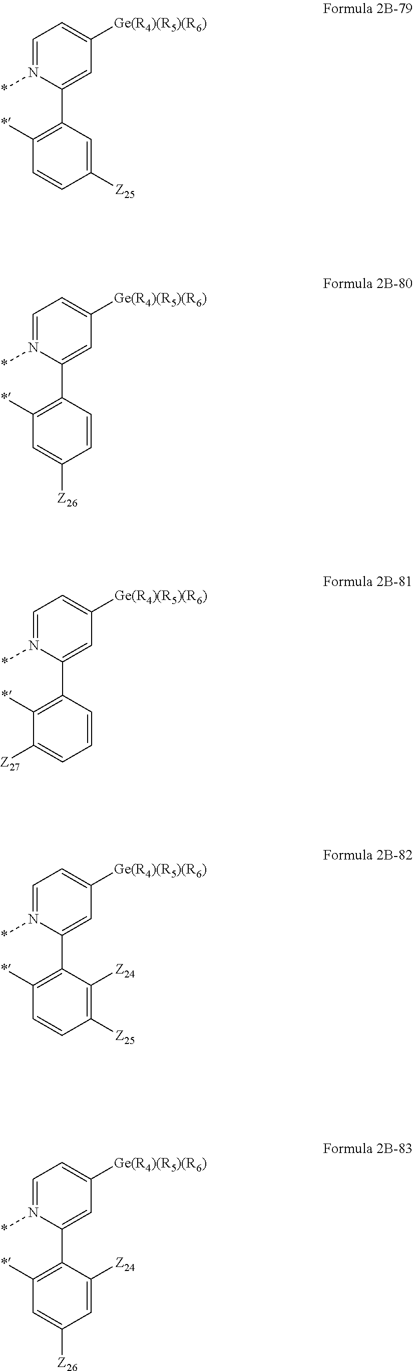

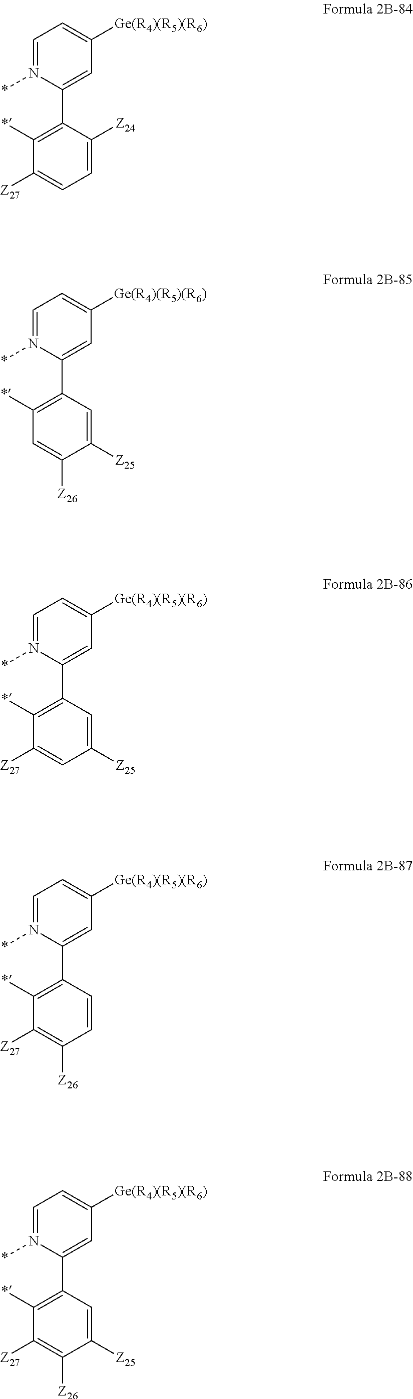

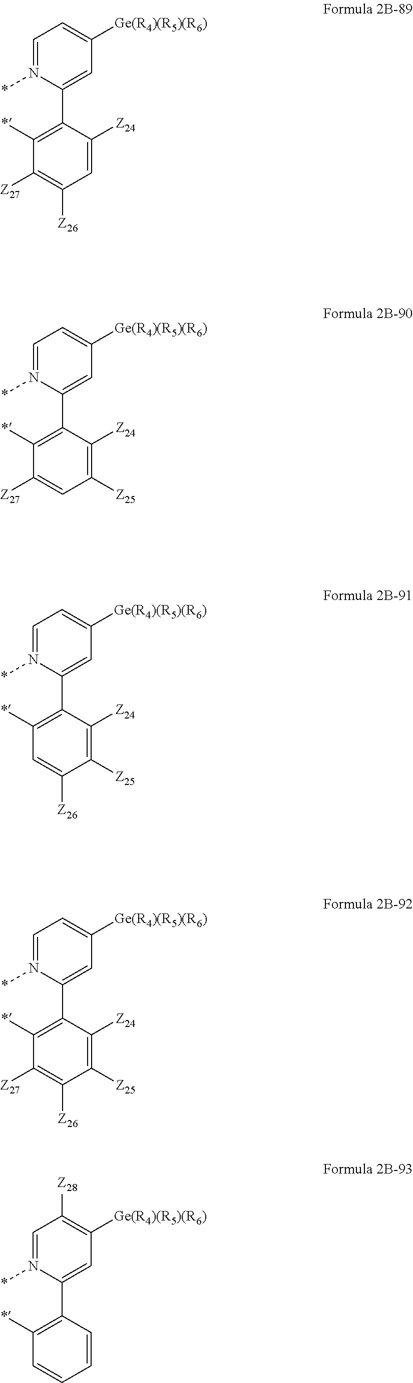

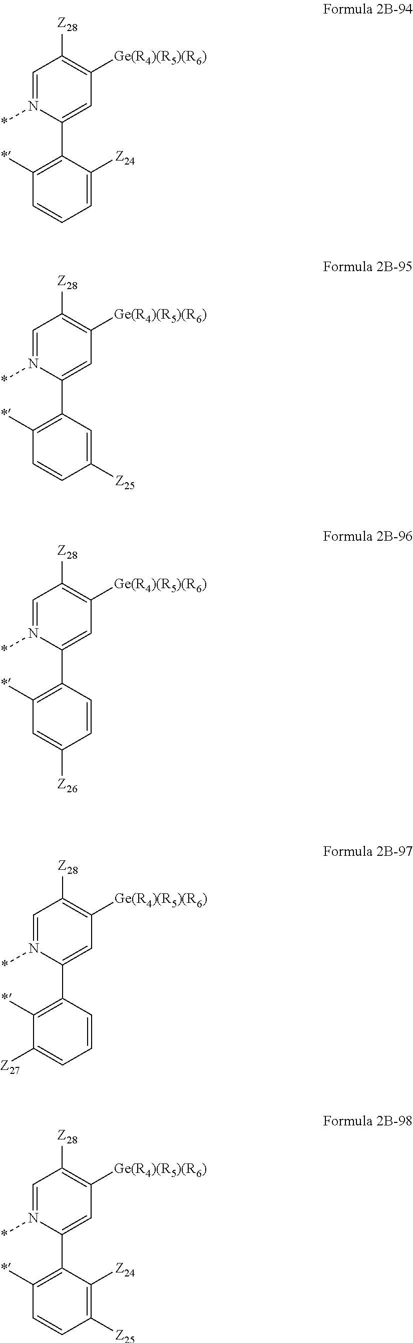

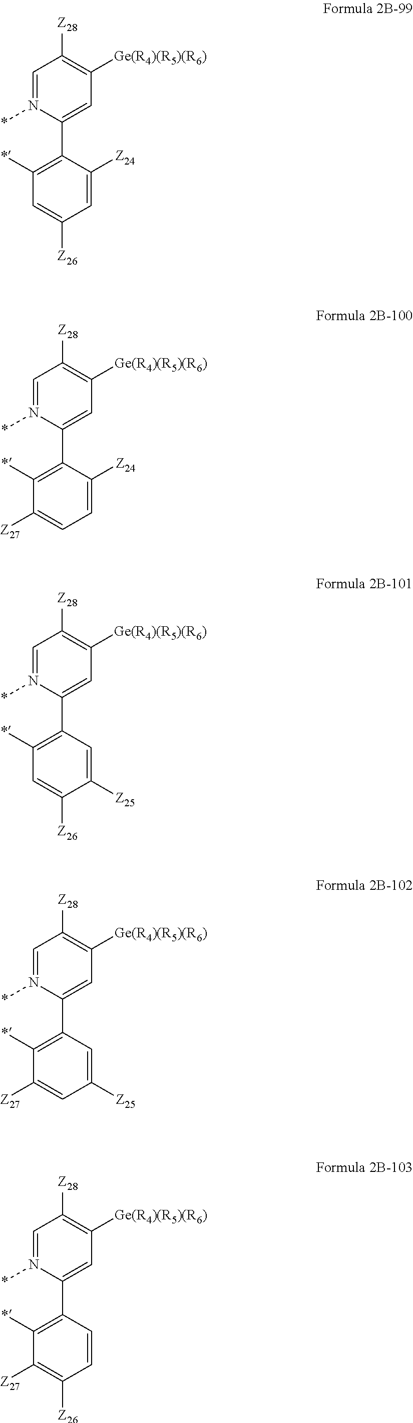

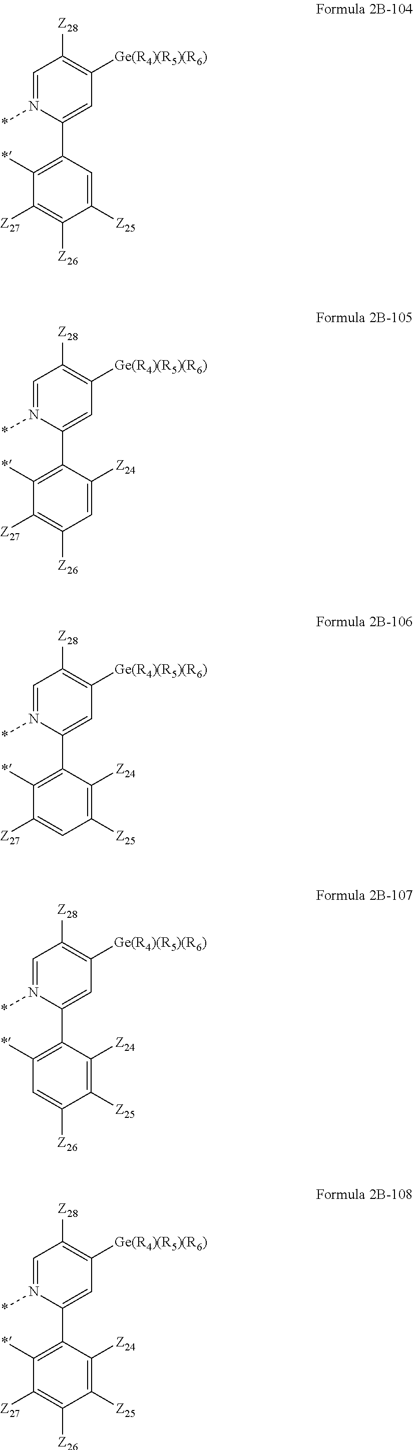

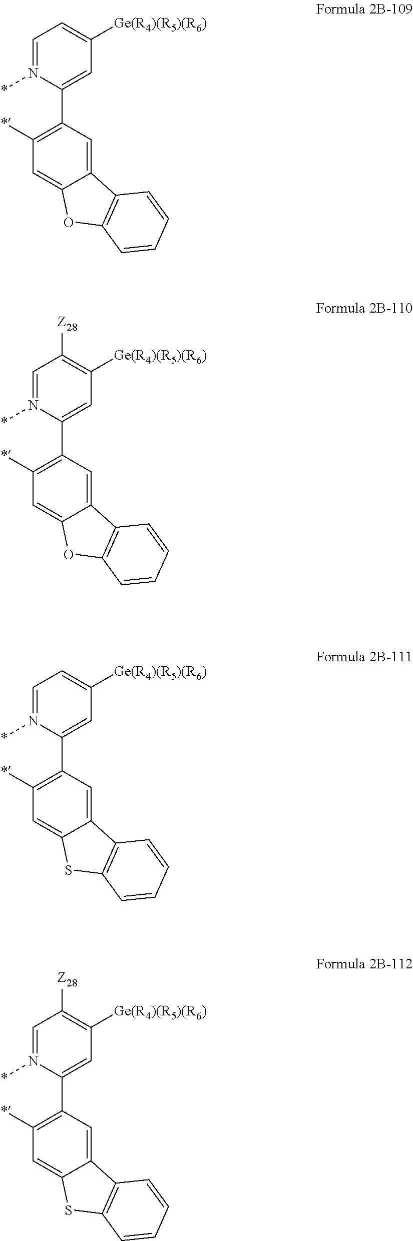

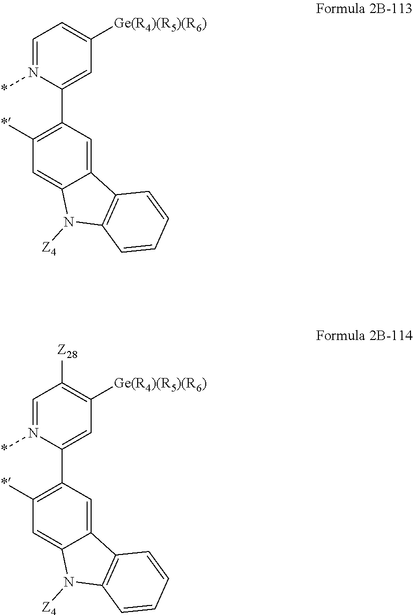

wherein, in Formula 2B-1 to 2B-114,

descriptions of Z₂₂, Z₂₃, and Z₂₈ may be the same in connection with as Z₃ provided herein,

descriptions of Z₂₄ to Z₂₇ may be the same in connection with as Z₄ provided herein, and

* and *′ each indicates a binding site to M in Formula 1.

In some embodiments, in Formulae 2B-1 to 2B-114,

R₄ to R₆ may be each independently selected from

a hydrogen, a deuterium, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group; and

a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group, each substituted with at least one selected from a deuterium, —F, -CD₃, -CD₂H, -CDH₂, —CF₃, —CF₂H, —CFH₂, a cyano group, a nitro group, a C₁-C₁₀ alkyl group, a C₁-C₁₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group, and

Z₄ and Z₂₂ to Z₂₈ may be each independently selected from

a deuterium, —F, a cyano group, a nitro group, —SF₅, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group;

a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group, each substituted with at least one selected from a deuterium, —F, -CD₃, -CD₂H, -CDH₂, —CF₃, —CF₂H, —CFH₂, a cyano group, a nitro group, a C₁-C₁₀ alkyl group, a C₁-C₁₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group; and

—B(Q₃)(Q₄) and —P(═O)(Q₅)(Q₆), wherein Q₃ to Q₆ may be each independently selected from

—CH₃, -CD₃, -CD₂H, -CDH₂, —CH₂CH₃, —CH₂CD₃, —CH₂CD₂H, —CH₂CDH₂, —CHDCH₃, —CHDCD₂H, —CHDCDH₂, —CHDCD₃, -CD₂CD₃, -CD₂CD₂H, and -CD₂CDH₂;

an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group; and

an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group, each substituted with at least one selected from a deuterium, a C₁-C₁₀ alkyl group, and a phenyl group, and

* and *′ may each indicates a binding site to M in Formula 1, but embodiments not limited thereto.

In some embodiments, in Formulae 2B-1 to 2B-114,

Z₄ and Z₂₂ to Z₂₈ may be each independently selected from a deuterium, —F, a cyano group, a nitro group, —SF₅, —CH₃, -CD₃, -CD₂H, -CDH₂, —CF₃, —CF₂H, —CFH₂, groups represented by Formulae 9-1 to 9-19, and groups represented by Formulae 10-1 to 10-36,

R₄ to R₆ may be each independently selected from —CH₃, -CD₃, -CD₂H, -CDH₂, groups represented by Formulae 9-1 to 9-19, and a phenyl group, and

* and *′ each indicates a binding site to M in Formula 1.

In Formula 1, n1 and n2 may be each independently 1 or 2, and a sum of n1 and n2 may be 2 or 3.

In some embodiments, M may be Ir, and a sum of n1 and n2 may be 3; or M may be Pt, and a sum of n1 and n2 may be 2, but embodiments are not limited thereto.

In some embodiments, in Formula 1, n2 may be 1.

The organometallic compound represented by Formula 1 may be neutral, not in a form of a salt consisting of pairs of ions.

In some embodiments, in Formula 1,

M may be Ir, and the sum of n1 and n2 may be 3; or M may be Pt, and the sum of n1 and n2 may be 2,

L₁ may be selected from ligands represented by Formulae 3-1 to 3-130,

L₂ may be selected from ligands represented by Formulae 2B(1) to 2B(10) (for example, ligands represented by Formulae 2B-1 to 2B-114), and

the organometallic compound represented by Formula 1 may be neutral, but embodiments are not limited thereto.

In some embodiments, in Formula 1,

M may be Ir, and the sum of n1 and n2 may be 3; or M may be Pt, and the sum of n1 and n2 may be 2,

L₁ may be selected from ligands represented by Formulae 3-1A to 3-1J,

L₂ may be selected from ligands represented by Formulae 2B(1) to 2B(10) (for example, ligands represented by Formulae 2B-1 to 2B-114), and

the organometallic compound represented by Formula 1 may be neutral, but embodiments are not limited thereto.

In some embodiments, in Formula 1,

M may be Ir, and the sum of n1 and n2 may be 3; or M may be Pt, and the sum of n1 and n2 may be 2,

L₁ may be selected from ligands selected from Formulae 3-1A and 3-1AE,

L₂ may be selected from ligands represented by Formulae 2B(1) to 2B(10) (for example, ligands represented by Formulae 2B-1 to 2B-114), and

the organometallic compound represented by Formula 1 may be neutral, but embodiments are not limited thereto.

In some embodiments, in Formula 1,

M may be Ir, and the sum of n1 and n2 may be 3; or M may be Pt, and the sum of n1 and n2 may be 2,

L₁ may be selected from ligands represented by Formulae 3-1(1) to 3-1(114),

L₂ may be selected from ligands represented by Formulae 2B(1) to 2B(10) (for example, ligands represented by Formulae 2B-1 to 2B-114), and

the organometallic compound represented by Formula 1 may be neutral, but embodiments are not limited thereto.

The organometallic compound may be selected from Compounds 1 to 110, but embodiments are not limited thereto:

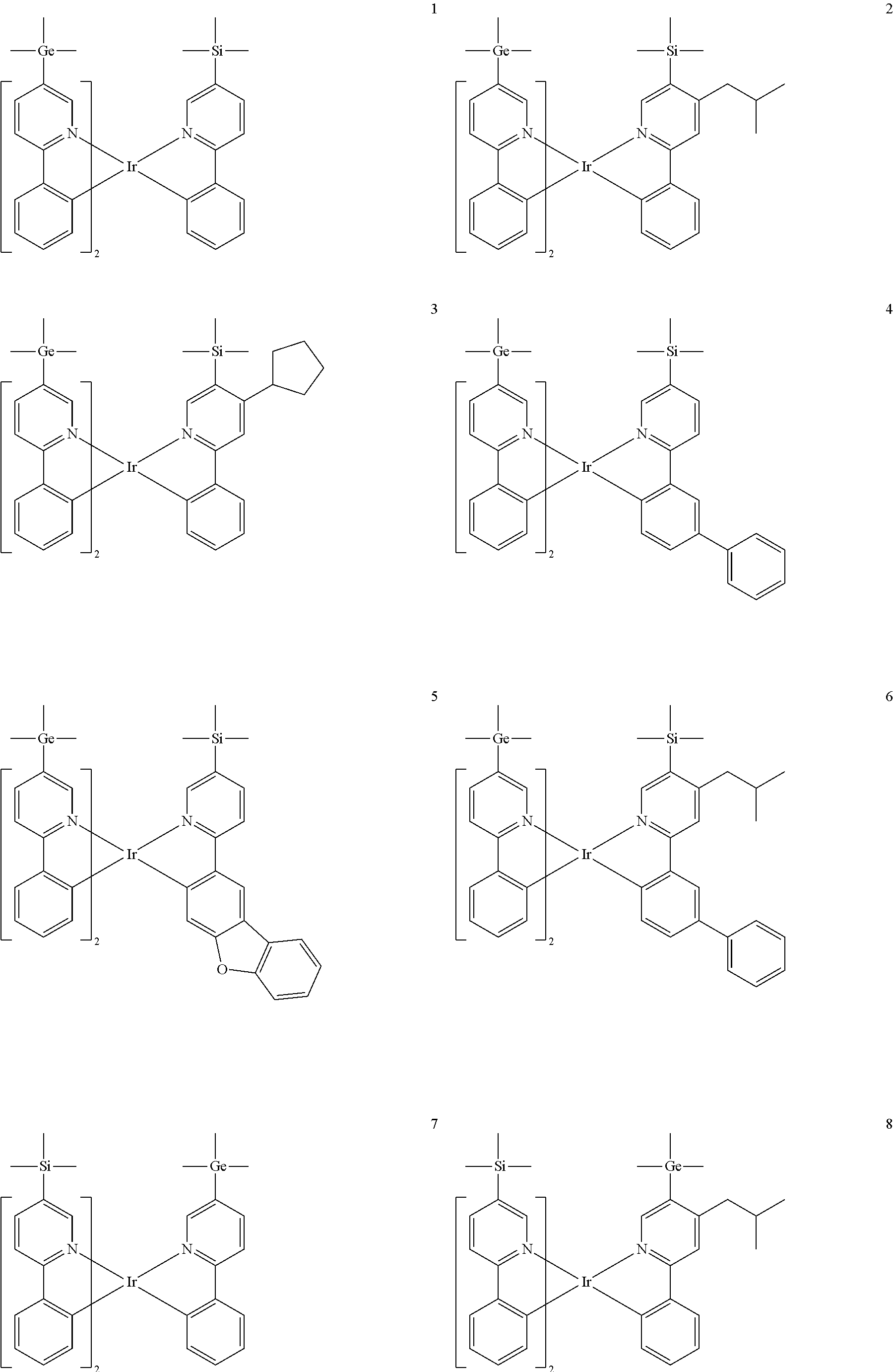

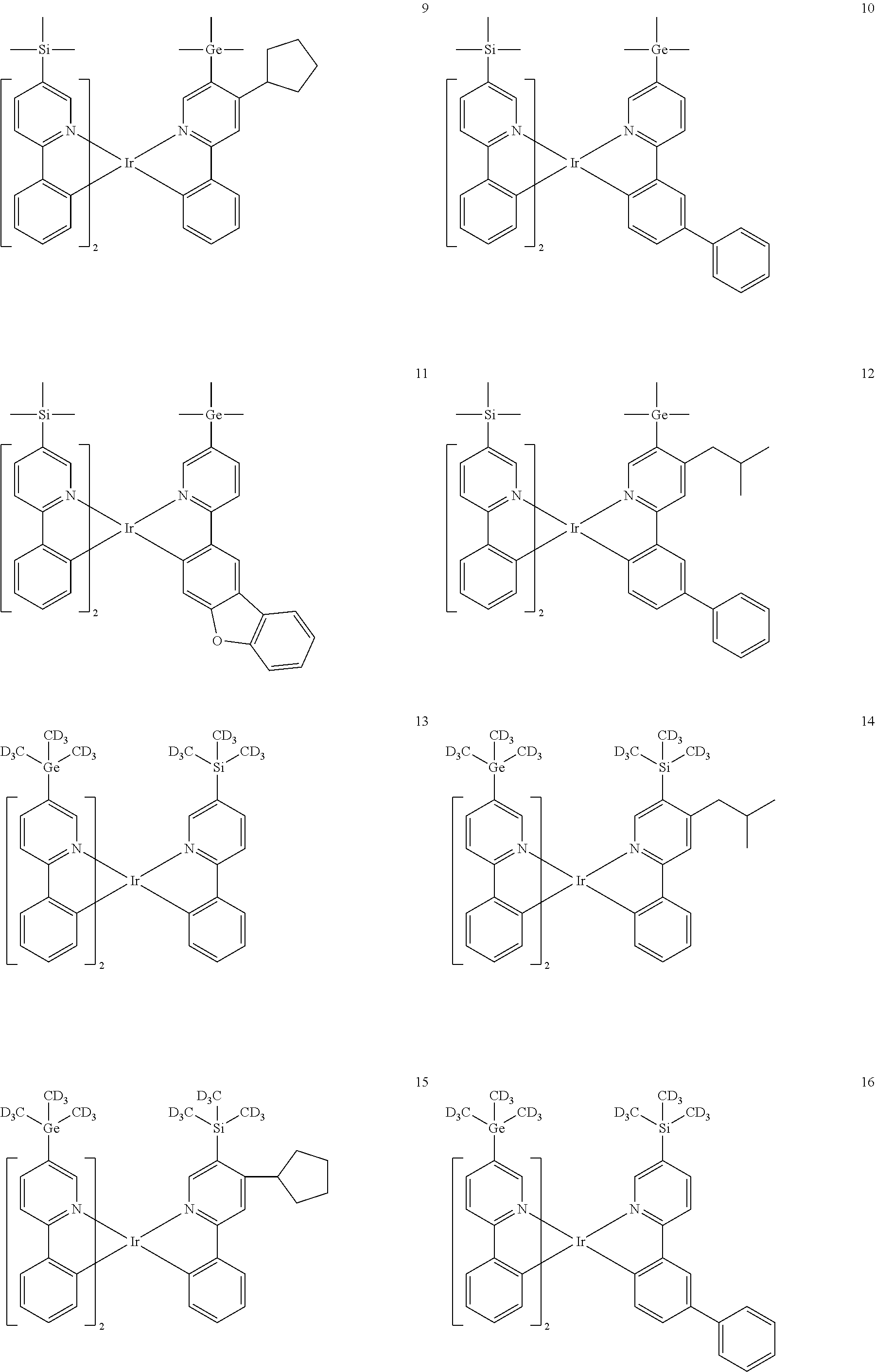

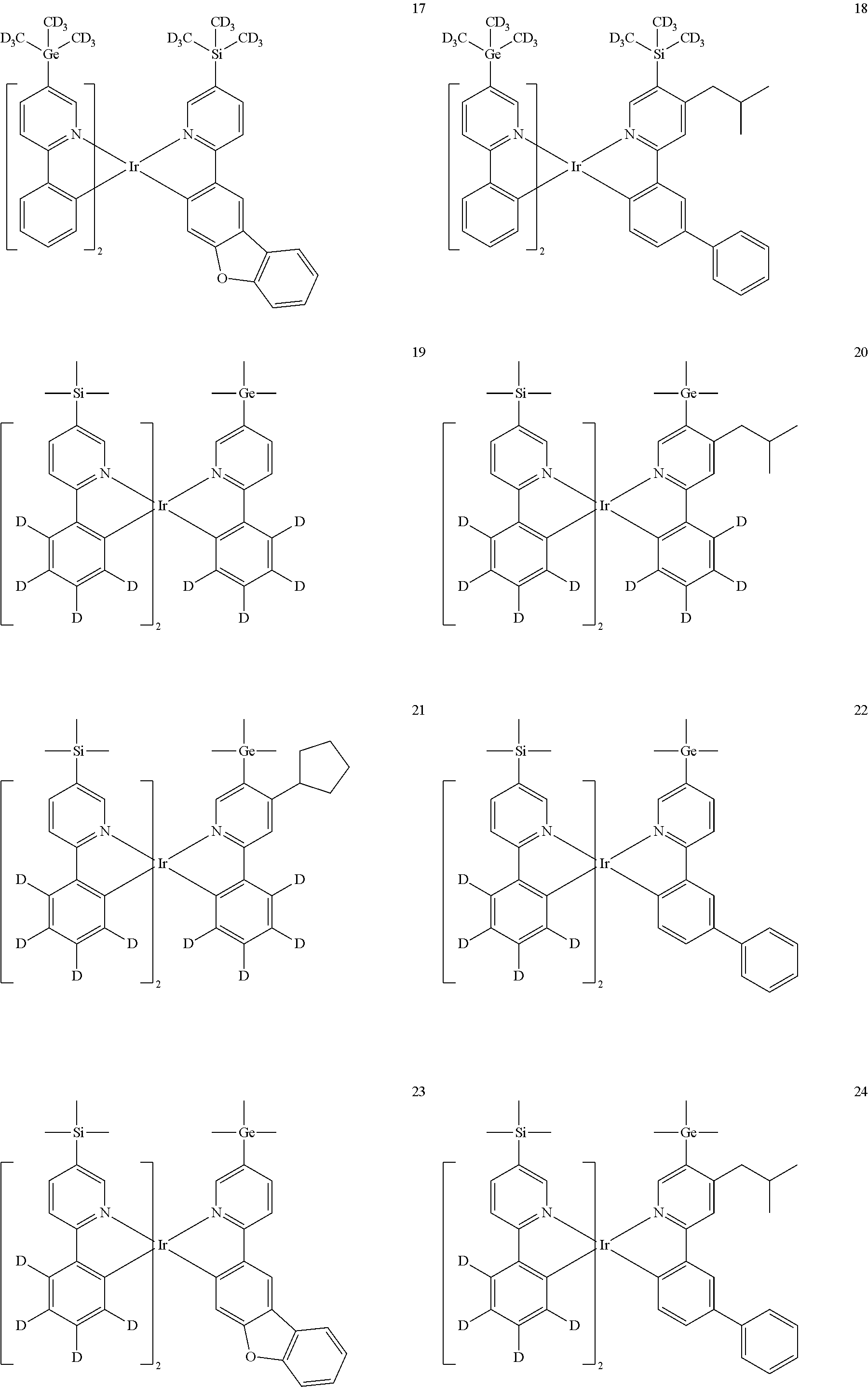

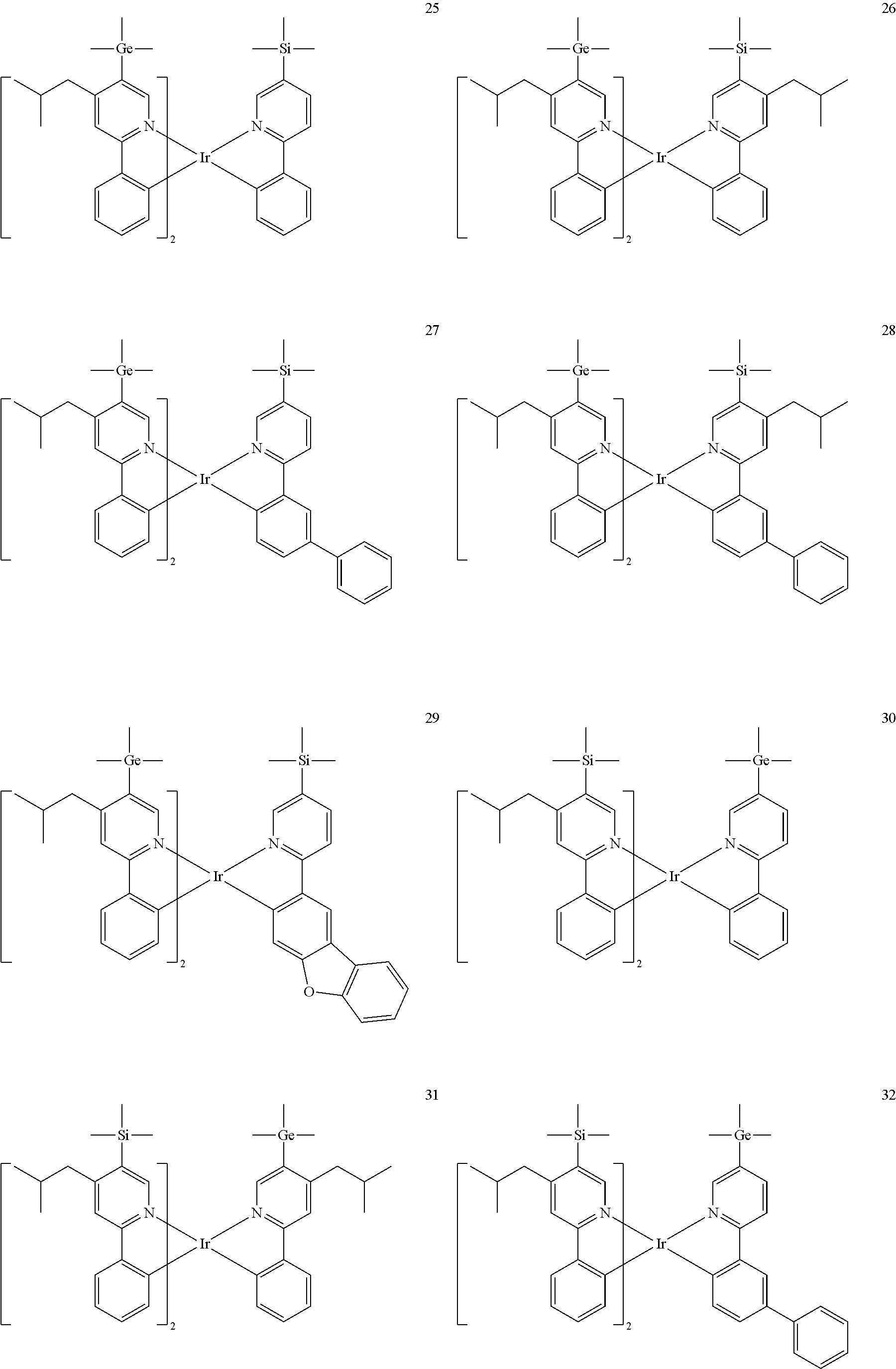

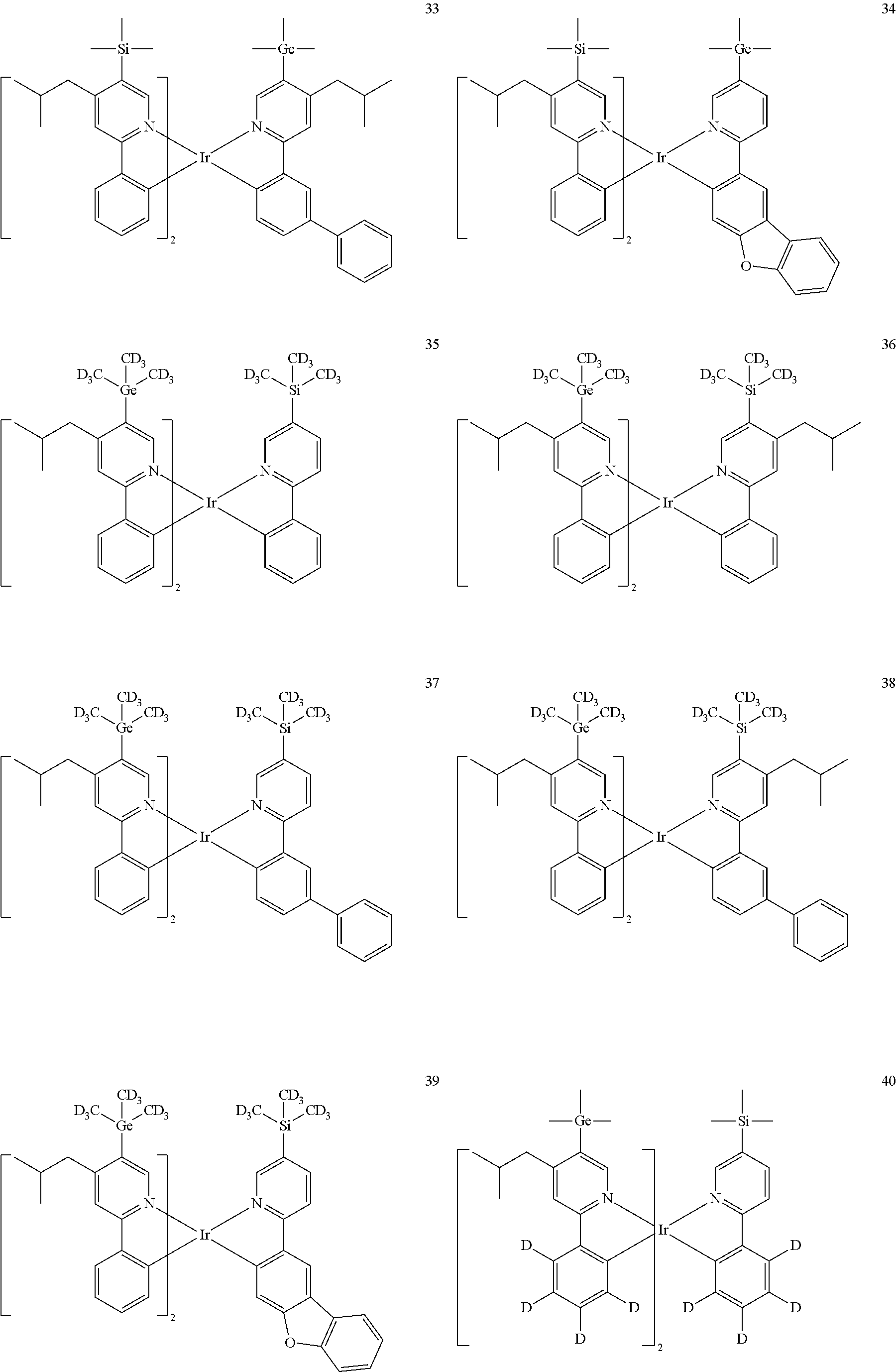

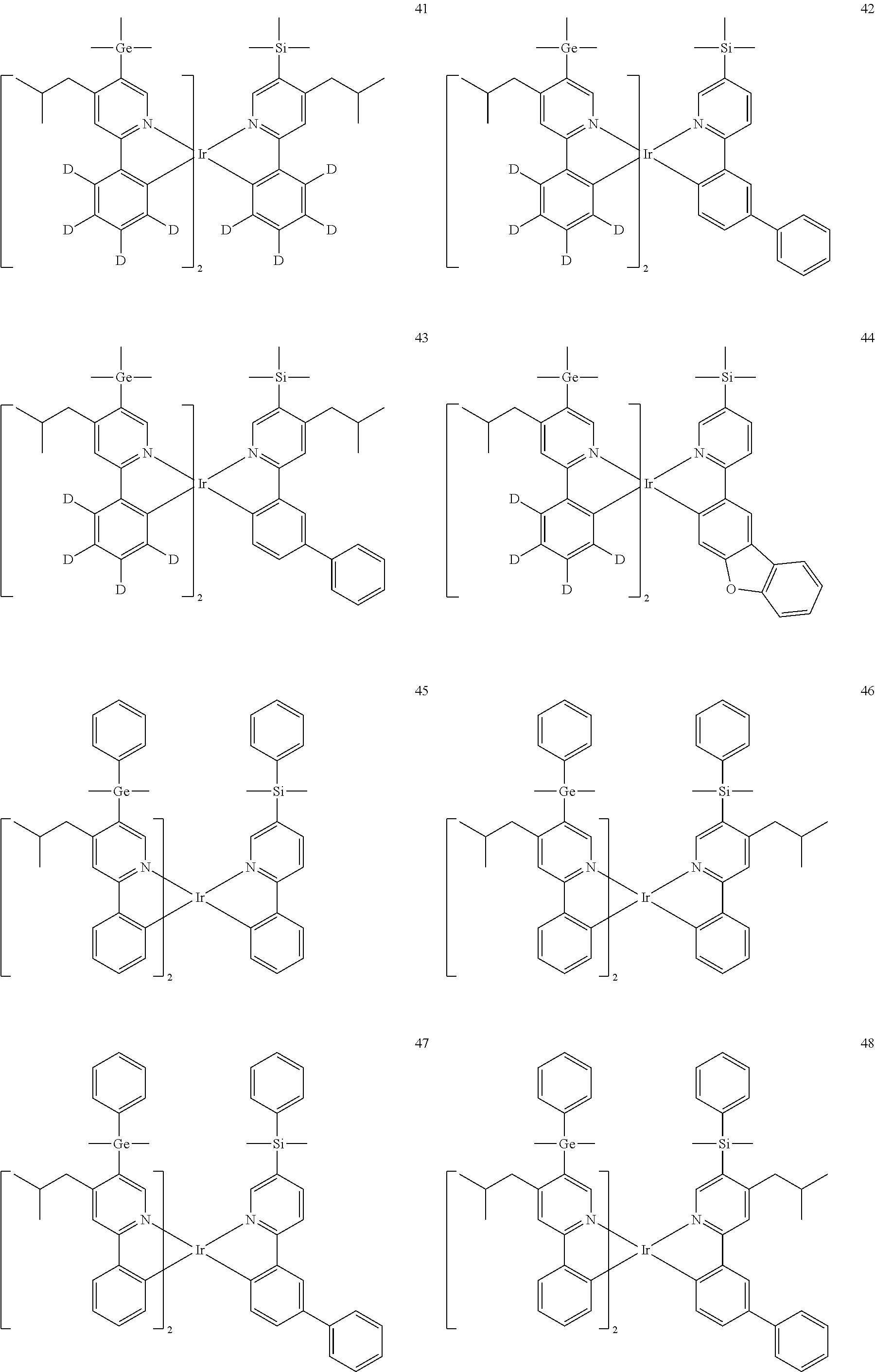

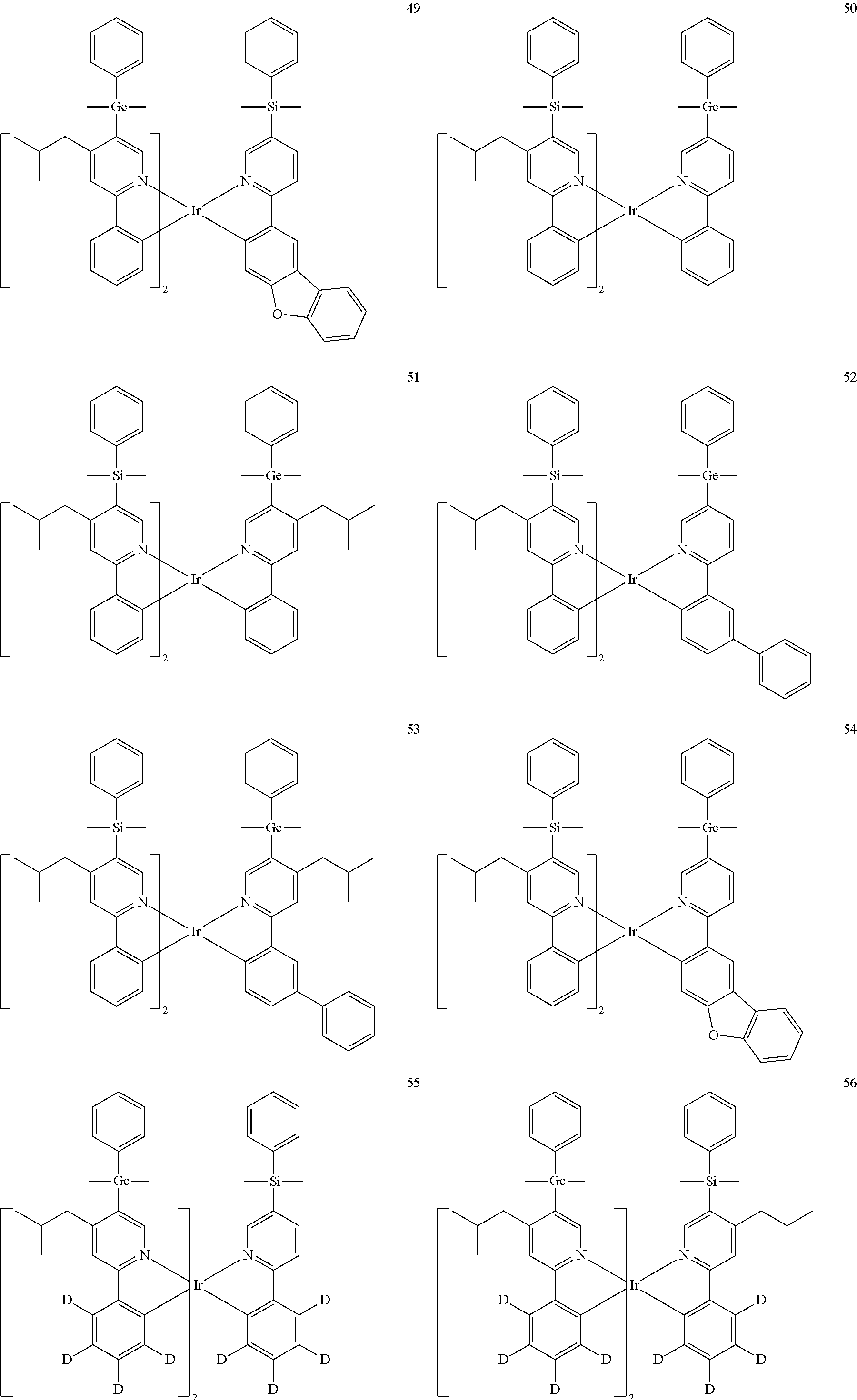

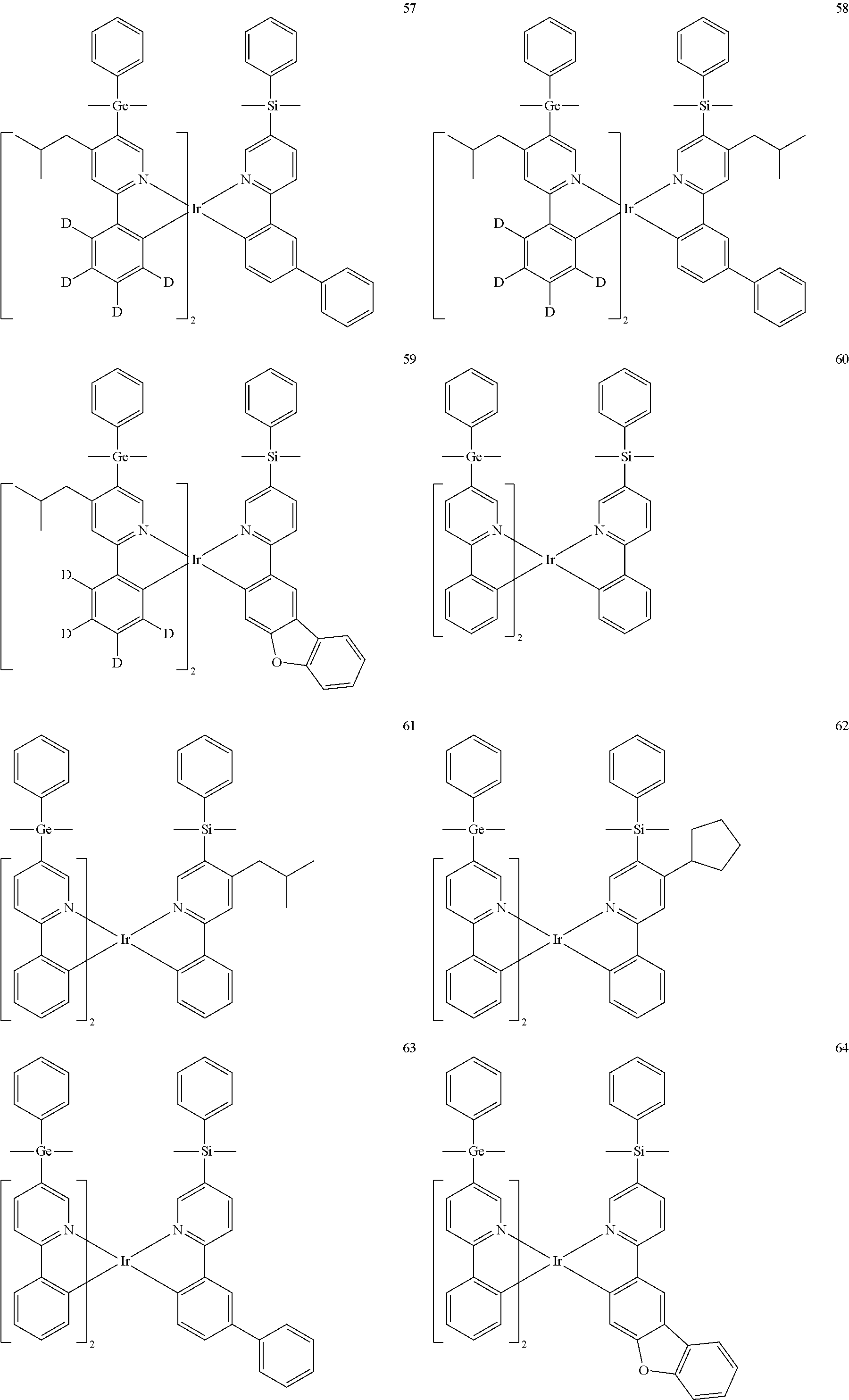

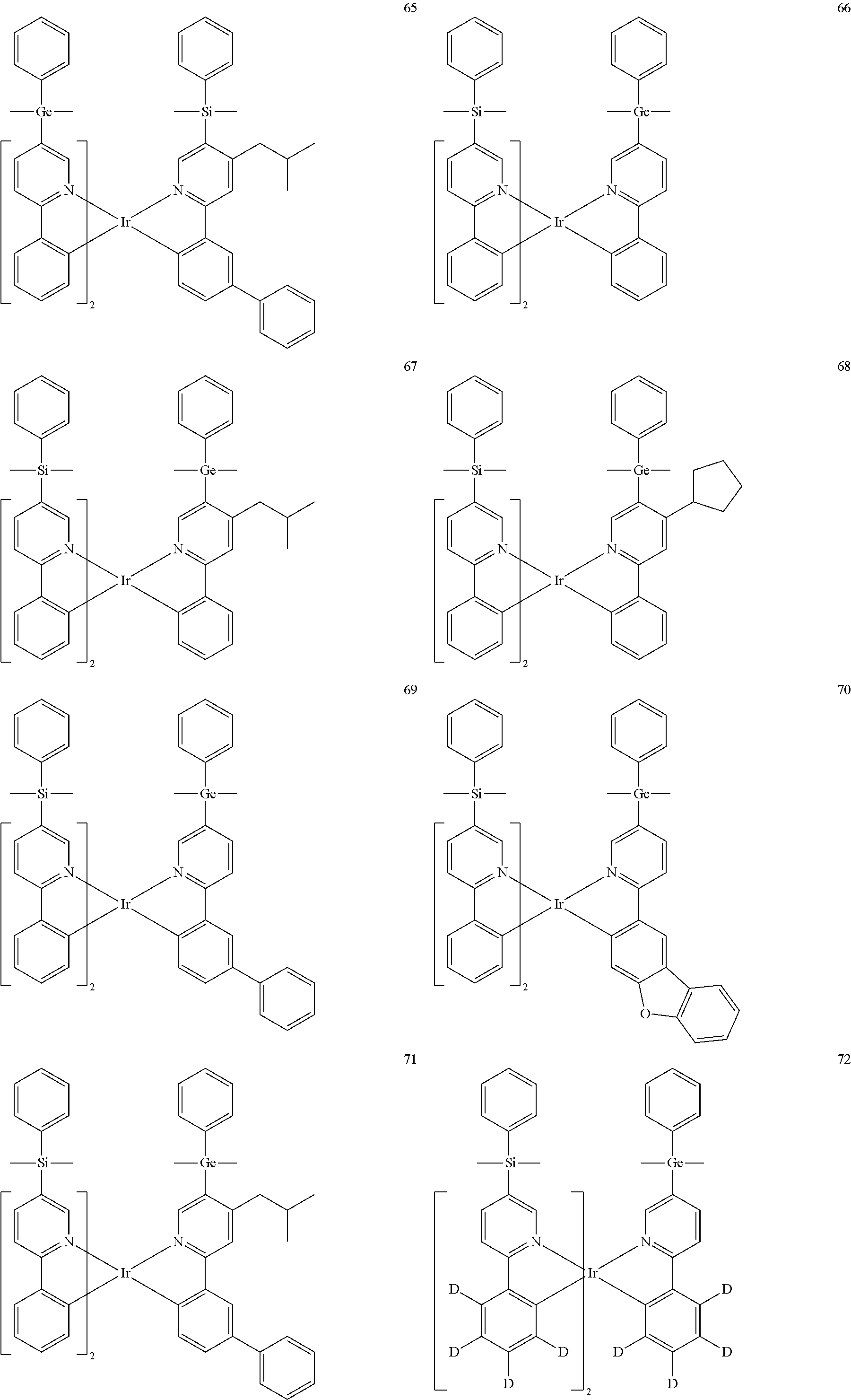

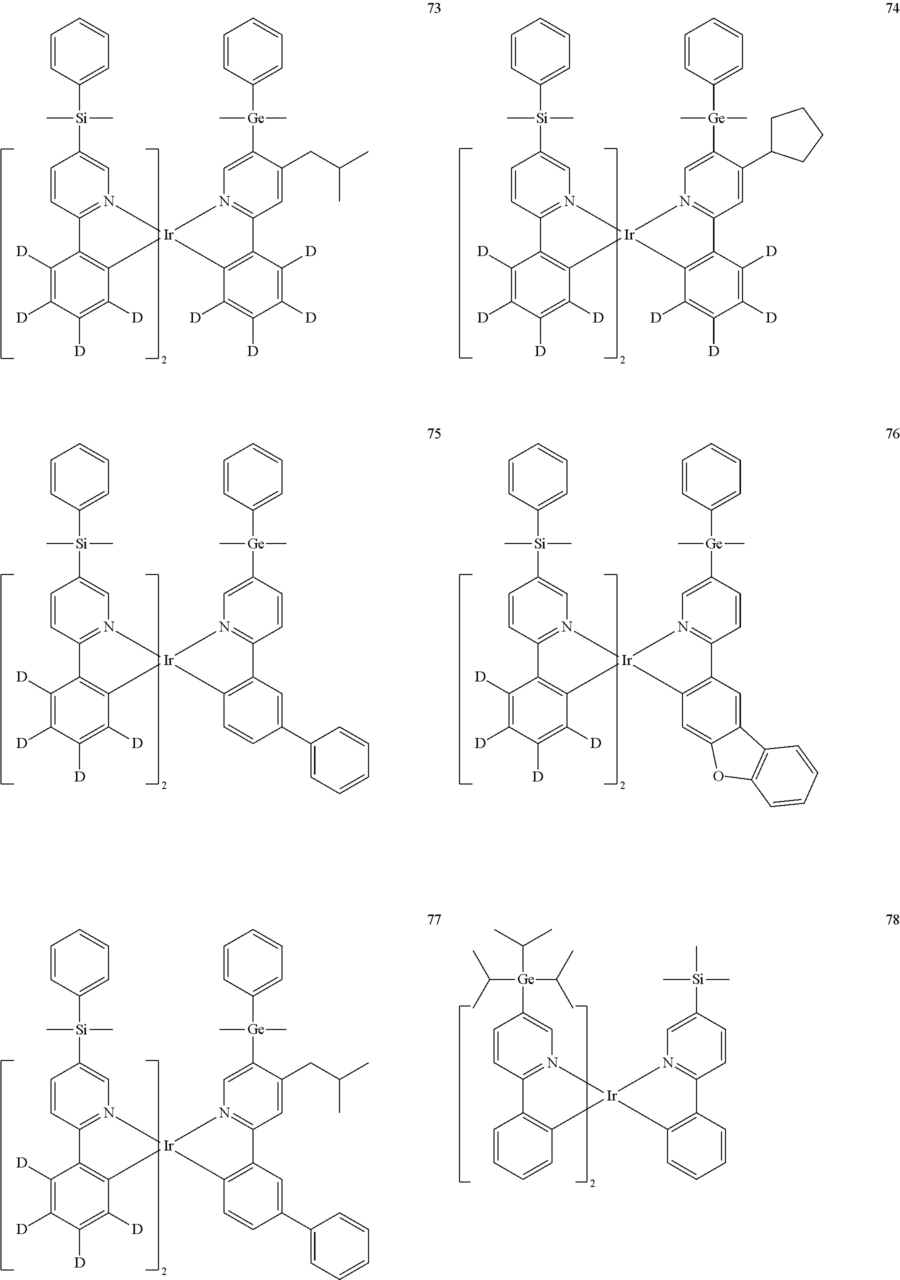

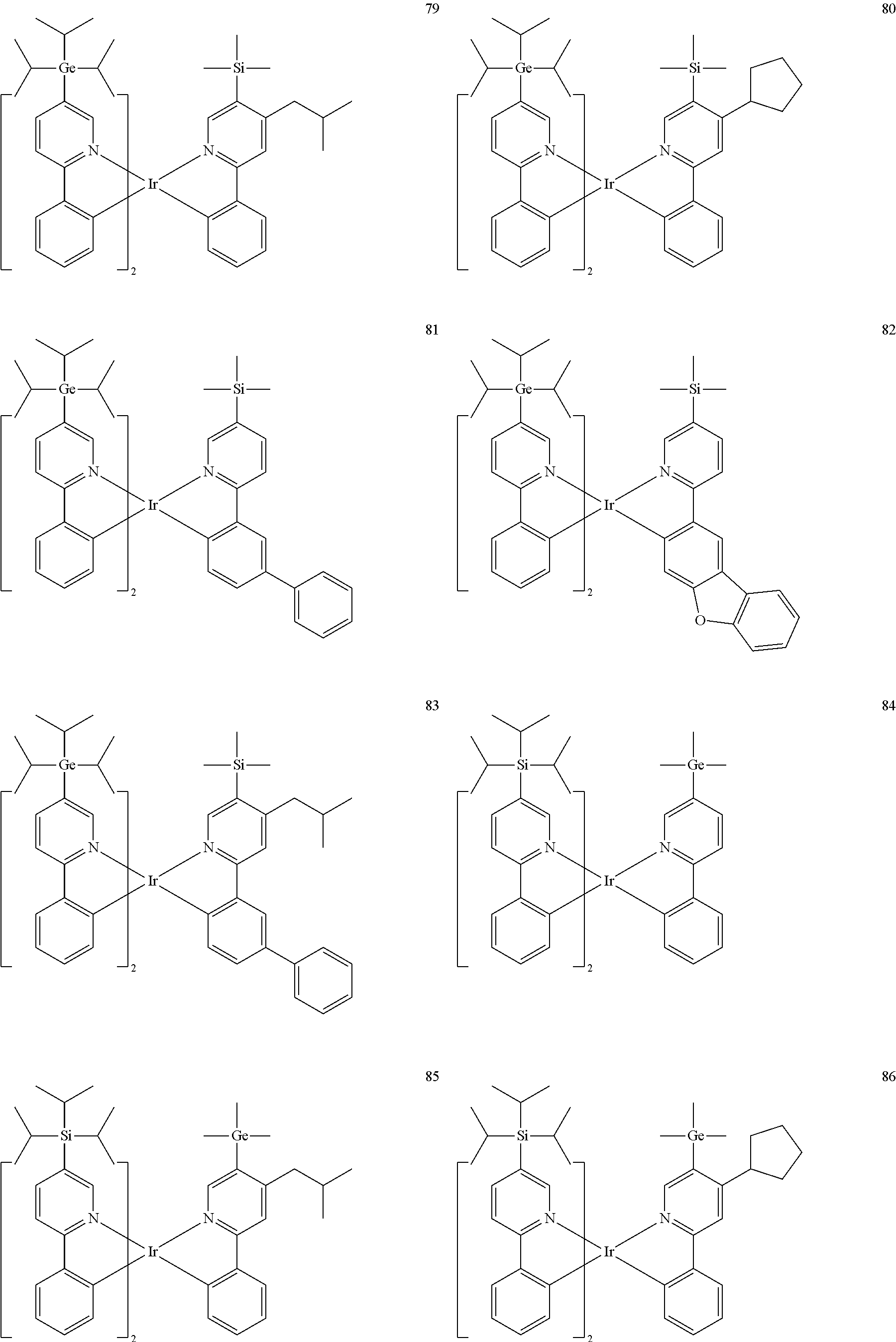

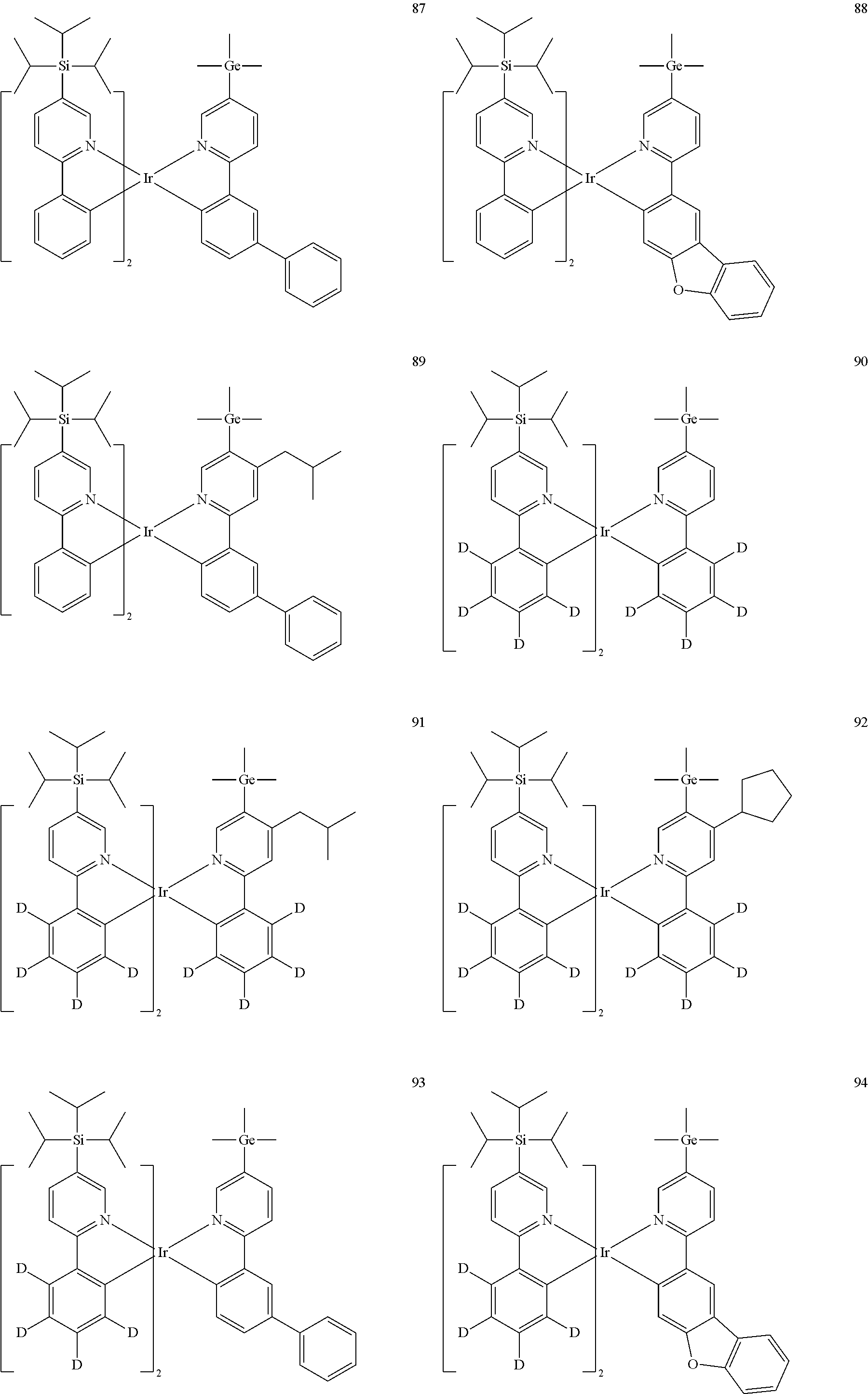

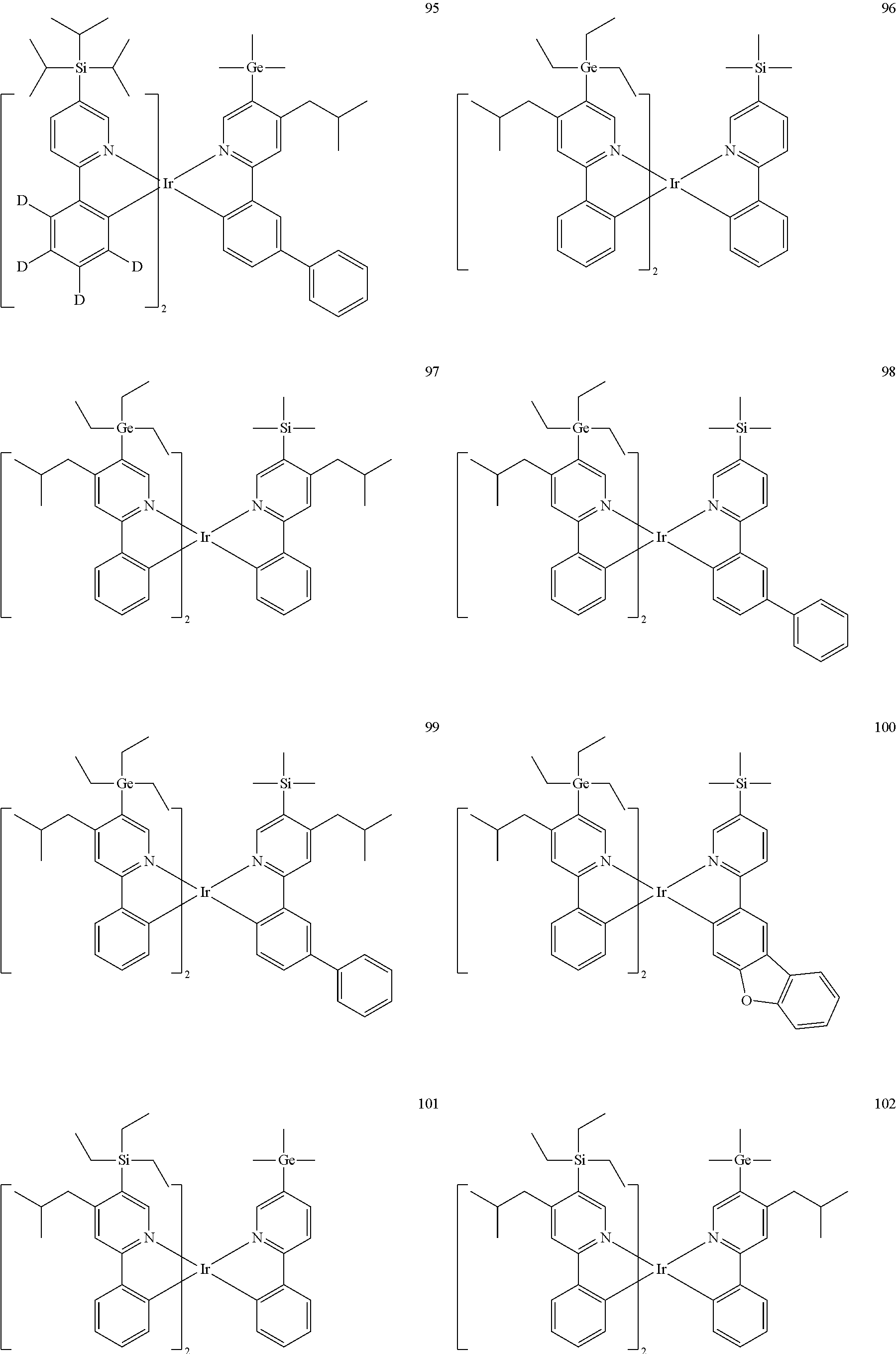

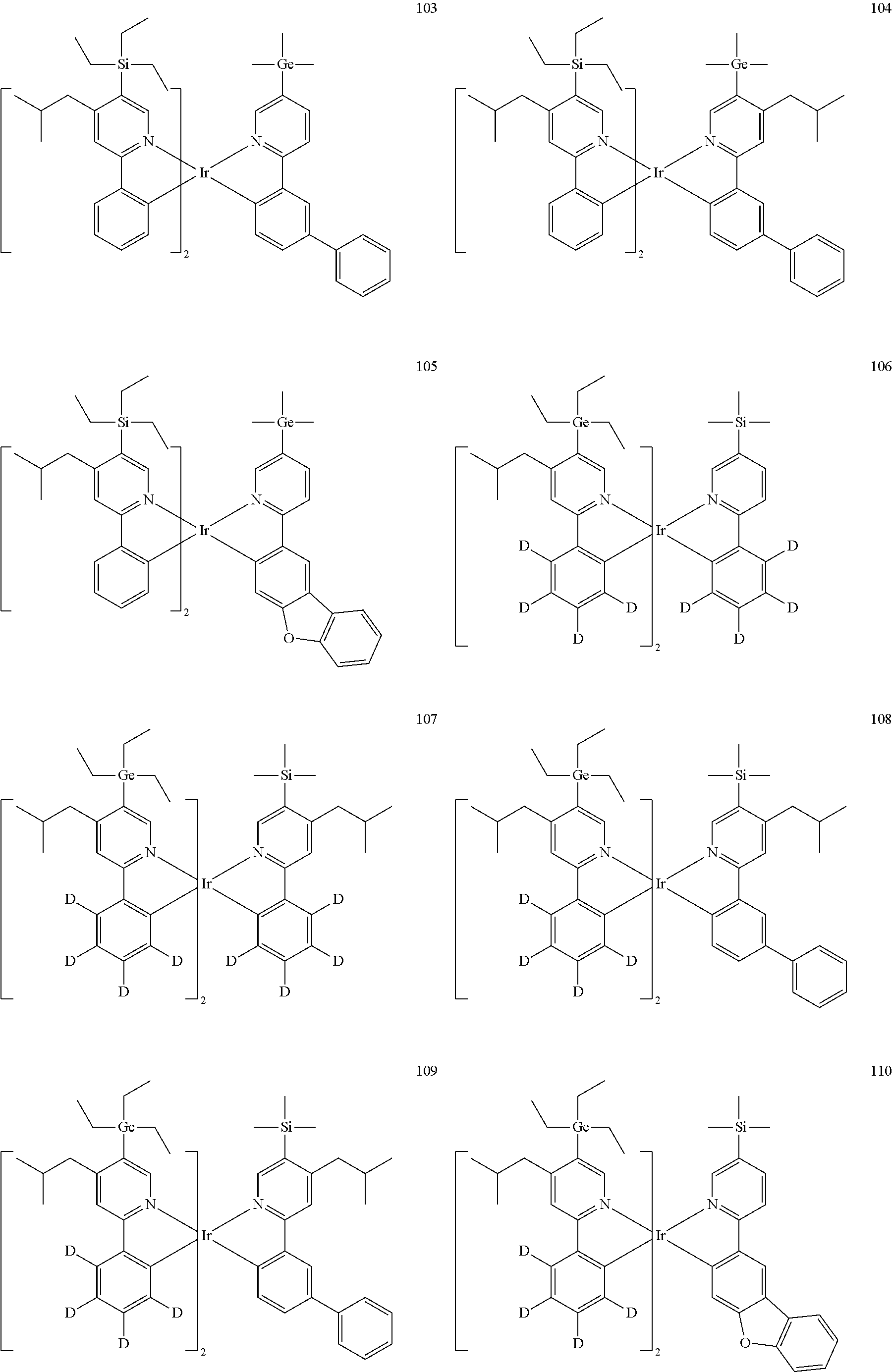

In Formula 1, n1 and n2 may be 1 or 2. That is, since n1 is not 0, the organometallic compound represented by Formula 1 essentially includes a ligand represented by Formula 2A. In addition, the ligand represented by Formula 2A is an N—C bidentate ligand that is bound to metal M in Formula 1 through a carbon and a nitrogen. Therefore, the organometallic compound represented by Formula 1 may have excellent thermal stability.

Further, the ligand represented by Formula 2A essentially includes at least one silyl group represented by Formula 2C. Thus, the organometallic compound represented by Formula 1 may have a high T₁ energy level.

Here, the organometallic compound represented by Formula 1 may have a ligand represented by Formula 2B, and the ligand represented by Formula 2B essentially has at least one group represented by Formula 2D as a substituent. The group represented by Formula 2D includes “Ge”. Thus, an electronic device including the organometallic compound represented by Formula 1, for example, an organic light-emitting device including the same may have a high efficiency.

For example, the highest occupied molecular orbital (HOMO), lowest unoccupied molecular orbital (LUMO), and triplet (T₁) energy level of some of the organometallic compounds were evaluated by using a Gaussian function according to the density functional theory (DFT) method (structure optimization was performed at the B3LYP and 6-31G(d,p) level). The results thereof are shown in Table 1.

TABLE 1

| Compound No. | HOMO (eV) | LUMO (eV) | T₁ energy level (eV) |
|---|---|---|---|
| 1 | −4.784 | −1.198 | 2.594 |
| 2 | −4.752 | −1.164 | 2.594 |
| 7 | −4.797 | −1.230 | 2.572 |
| 26 | −4.687 | −1.085 | 2.615 |
| 30 | −4.729 | −1.140 | 2.608 |
| 31 | −4.695 | −1.104 | 2.614 |

Referring to Table 1, it was found that the compound is suitable for as a material for an organic light-emitting device.

A method of synthesizing the organometallic compound represented by Formula 1 may be understood to one of ordinary skill in the art by referring to Synthesis Examples used herein.

Therefore, the organometallic compound represented by Formula 1 may be suitable for use in an organic layer of an organic light-emitting device, for example as a dopant in an emission layer of the organic layer. Thus, according to another aspect, there is provided an organic light-emitting device that may include:

a first electrode;

a second electrode; and

an organic layer disposed between the first electrode and the second electrode,

wherein the organic layer includes an emission layer and at least one organometallic compound represented by Formula 1.

Since the organic light-emitting device has an organic layer including the condensed cyclic compound represented by Formula 1, the organic light-emitting device may have a low driving voltage, high efficiency, high power, high quantum efficiency, long lifespan and excellent color-purity.

The organometallic compound represented by Formula 1 may be used in a pair of electrodes in an organic light-emitting device. For example, the organometallic compound represented by Formula 1 may be included in the emission layer. In this regard, the organometallic compound may serve as a dopant and the emission layer may further include a host (in other words, an amount of the organometallic compound represented by Formula 1 may be smaller than that of the host).

As used herein, “(for example, the organic layer) including at least one organometallic compound” means that “(the organic layer) including an organometallic compound of Formula 1, or at least two different organometallic compounds of Formula 1”.

For example, the organic layer may include only Compound 1 as the organometallic compound. In this regard, Compound 1 may be included in the emission layer of the organic light-emitting device. Alternatively, the organic layer may include Compound 1 and Compound 2 as the organometallic compounds. In this regard, Compound 1 and Compound 2 may be included in the same layer (for example, both Compound 1 and Compound 2 may be included in the emission layer).

The first electrode may be an anode, which is a hole injection electrode, and the second electrode may be a cathode, which is an electron injection electrode. Alternatively, the first electrode may be a cathode, which is an electron injection electrode, and the second electrode may be an anode, which is a hole injection electrode.

For example, the first electrode may be an anode, the second electrode may be a cathode, and the organic layer may include:

i) a hole transport region disposed between the first electrode and the emission layer, wherein the hole transport region includes at least one selected from a hole injection layer, a hole transport layer, and an electron blocking layer; and

ii) an electron transport region disposed between the emission layer and the second electrode wherein the electron transport region includes at least one selected from a hole blocking layer, an electron transport layer, and an electron injection layer.

As used herein, the term the “organic layer” refers to a single and/or a plurality of layers disposed between the first electrode and the second electrode in an organic light-emitting device. The “organic layer” may include not only organic compounds but also organometallic complexes including metals.

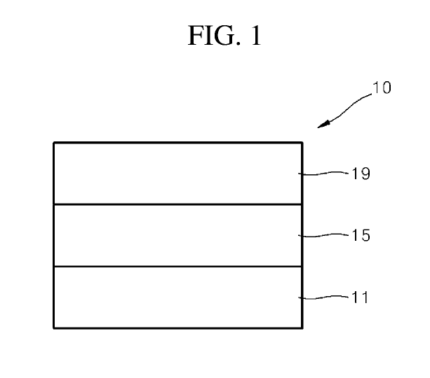

FIG. 1 is a schematic view of an organic light-emitting according to an embodiment. Hereinafter, a structure and a method of manufacturing the organic light-emitting device according to an embodiment will be described with reference to FIG. 1. The organic light-emitting device 10 includes a first electrode 11, an organic layer 15, and a second electrode 19, which are sequentially layered in the stated order.

A substrate may be additionally disposed under the first electrode 11 or on the second electrode 19. The substrate may be a conventional substrate that is used in an organic light-emitting device, such as glass substrate or a transparent plastic substrate, each having excellent mechanical strength, thermal stability, transparency, surface smoothness, ease of handling, and water repellency.

The first electrode 11 may be formed by vacuum-depositing or sputtering a material for forming the first electrode on the substrate. The first electrode 11 may be an anode. The material for the first electrode 11 may be selected from materials with a high work function for an easy hole injection. The first electrode 11 may be a reflective electrode, a semi-transmissive electrode, or a transmissive electrode. The material for the first electrode 11 may be selected from indium tin oxide (ITO), indium zinc oxide (IZO), tin oxide (SnO₂), and zinc oxide (ZnO). Alternatively, a metal such as magnesium (Mg), aluminum (Al), aluminum-lithium (Al—Li), calcium (Ca), magnesium-indium (Mg—In), and magnesium-silver (Mg—Ag).

The first electrode 11 may have a single layer structure or a multi-layer structure including a plurality of layers. For example, the first electrode 11 may have a triple-layer structure of ITO/Ag/ITO, but embodiments are not limited thereto.

The organic layer 15 may be disposed on the first electrode 11.

The organic layer 15 may include a hole transport region, an emission layer, and an electron transport region.

The hole transport region may be between the first electrode 11 and the emission layer.

The hole transport region may include at least one selected from a hole injection layer, hole transport layer, electron blocking layer, and buffer layer.

The hole transport region may include a hole injection layer only or a hole transport layer only. In some embodiments, the hole transport region may include a hole injection layer and a hole transport layer which are sequentially stacked on the first electrode 11. In some embodiments, the hole transport region may include a hole injection layer, a hole transport layer, and an electron blocking layer, which are sequentially stacked on the first electrode 11.

When the hole transport region includes a hole injection layer (HIL), the hole injection layer may be formed on the first electrode 11 by using a suitable method, such as vacuum-deposition, spin coating, casting, and Langmuir-Blodgett (LB) method.

When a hole injection layer is formed by vacuum-deposition, for example, the vacuum-deposition may be performed at a deposition temperature in a range of about 100° C. to about 500° C., at a vacuum degree in a range of about 10⁻⁸ to about 10⁻³ torr, and at a deposition rate in a range of about 0 Angstroms per second (Å/sec) to about 100 Å/sec, though the conditions may vary depending on a compound that is used as a hole injection material and a structure and thermal properties of a desired hole injection layer, but conditions for the vacuum-deposition are not limited thereto.

When a hole injection layer is formed by spin-coating, the spin coating may be performed at a coating rate in a range of about 2,000 revolutions per minute (rpm) to about 5,000 rpm, and at a temperature in a range of about 80° C. to 200° C. for removing a solvent after the spin coating, though the conditions may vary depending on a compound that is used as a hole injection material and a structure and thermal properties of a desired HIL, but is not limited thereto.

The conditions for forming a hole transport layer and an electron blocking layer may be inferred based on the conditions for forming the hole injection layer.

The hole transport region may include at least one selected from m-MTDATA, TDATA, 2-TNATA, NPB, β-NPB, TPD, a spiro-TPD, a spiro-NPB, methylated-NPB, TAPC, HMTPD, 4,4′,4″-tris(N-carbazolyl)triphenylamine (TCTA), polyaniline/dodecylbenzene sulfonic acid (Pani/DBSA), poly(3,4-ethylenedioxythiophene)/poly(4-styrenesulfonate) (PEDOT/PSS), polyaniline/camphor sulfonic acid (Pani/CSA), (polyaniline)/poly(4-styrenesulfonate) (PANI/PSS), a compound represented by Formula 201 below, and a compound represented by Formula 202 below:

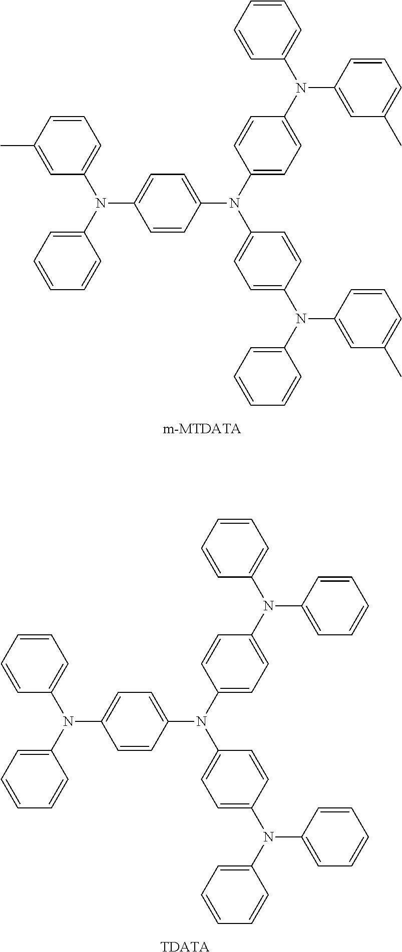

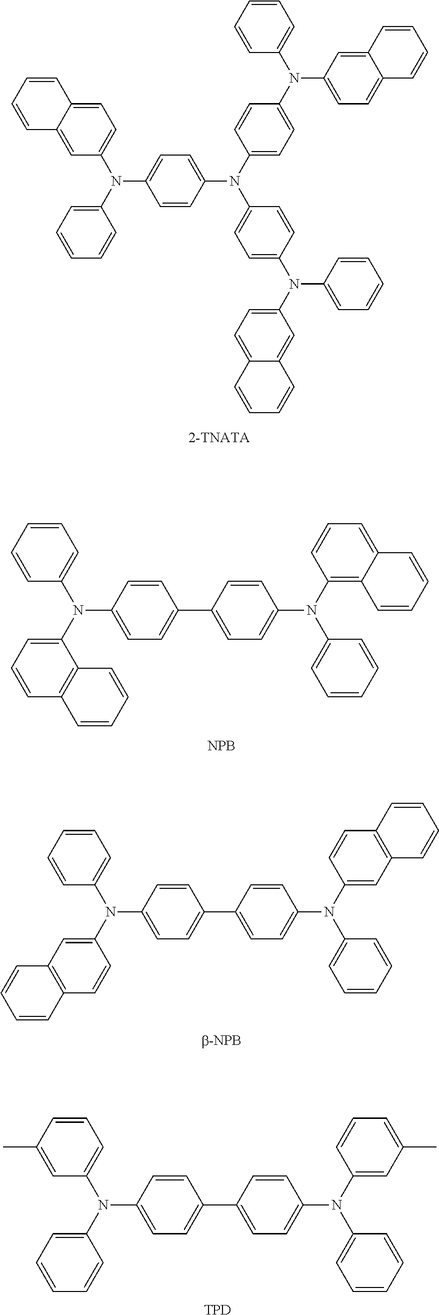

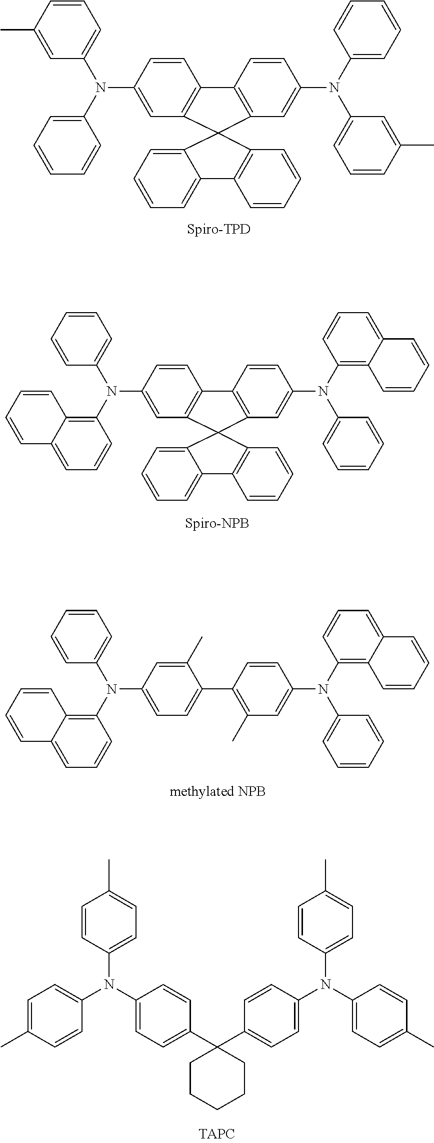

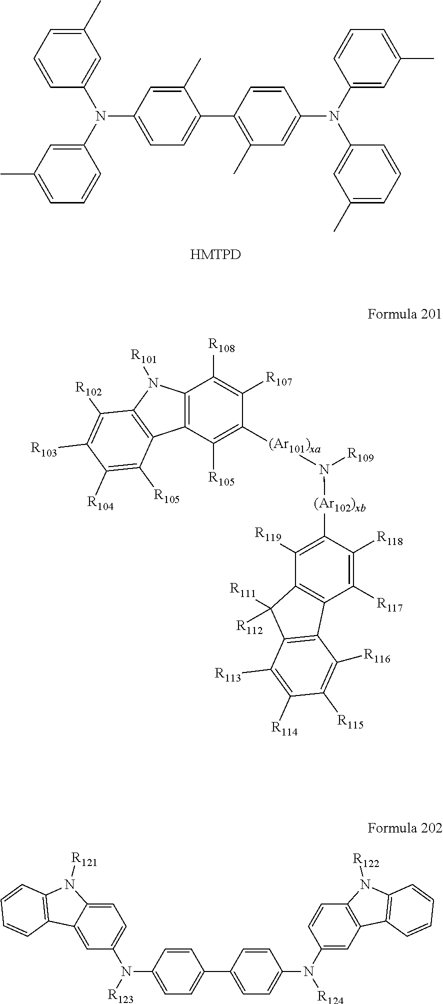

wherein, in Formula 201, Ar₁₀₁ and Ar₁₀₂ may be each independently selected from

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group and a pentacenylene group; and

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, and a monovalent non-aromatic condensed heteropolycyclic group.

In Formula 201, xa may be each independently an integer selected from 0 to 5, and xb may be an integer selected from 0, 1, and 2. In some embodiments, xa may be 1 and xb may be 0, but embodiments are not limited thereto.

In Formula 201 and 202, R₁₀₁ to R₁₀₈, R₁₁₁ to R₁₁₉, and R₁₂₁ to R₁₂₄ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (such as, a methyl group, an ethyl group, a propyl group, a butyl group, a pentyl group, or a hexyl group), and a C₁-C₁₀ alkoxy group (such as, a methoxy group, an ethoxy group, a propoxy group, a butoxy group, or a pentoxy group);

a C₁-C₁₀ alkyl group and a C₁-C₁₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;

a phenyl group, a naphthyl group, an anthracenyl group, a fluorenyl group, and a pyrenyl group; and

a phenyl group, a naphthyl group, an anthracenyl group, a fluorenyl group, and a pyrenyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, and a C₁-C₁₀ alkoxy group, but embodiments are not limited thereto.

In Formula 201, R₁₀₉ may be selected from

a phenyl group, a naphthyl group, an anthracenyl group, and a pyridinyl group; and

a phenyl group, a naphthyl group, an anthracenyl group, and a pyridinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, and a pyridinyl group.

In some embodiments, the compound represented by Formula 201 may be represented by Formula 201A, but embodiments are not limited thereto:

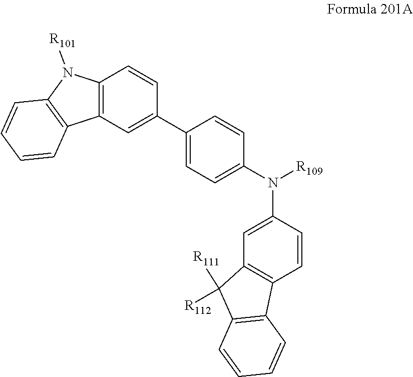

Descriptions for R₁₀₁, R₁₁₁, R₁₁₂, and R₁₀₉ in Formula 201A may be understood by referring descriptions thereof above.

For example, the compound represented by Formula 201 and the compound represented by Formula 202 may include Compounds HT1 to HT20, but embodiments are not limited thereto:

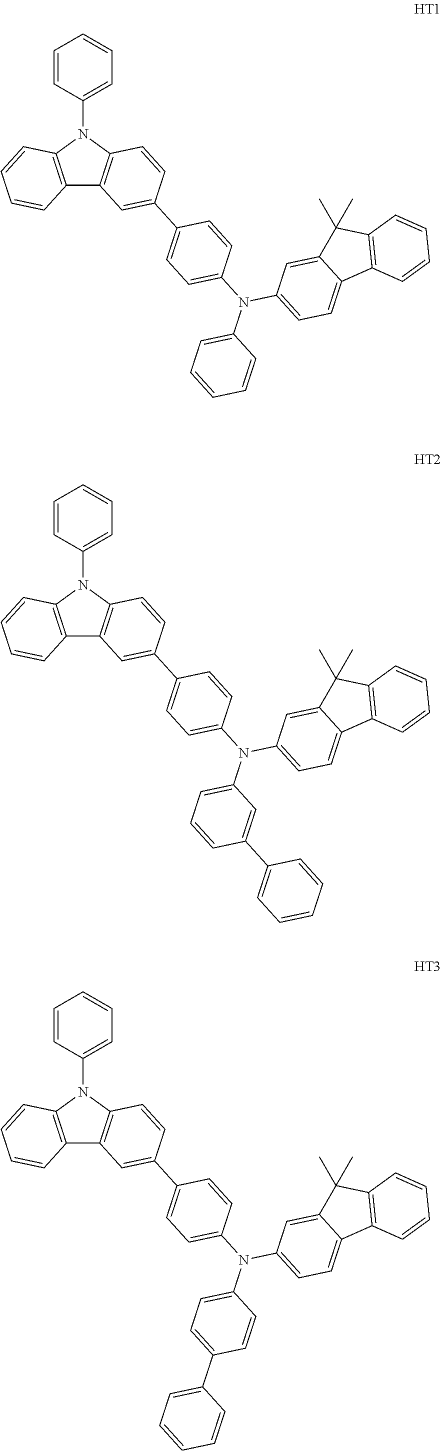 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

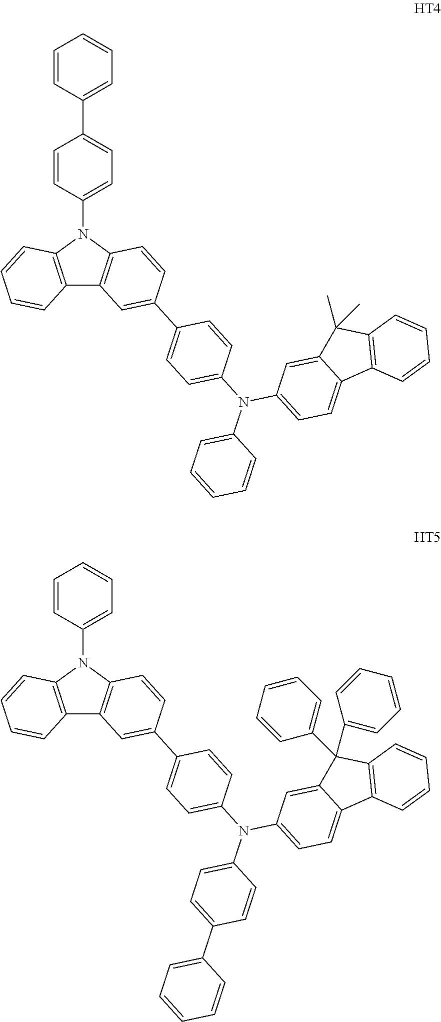 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

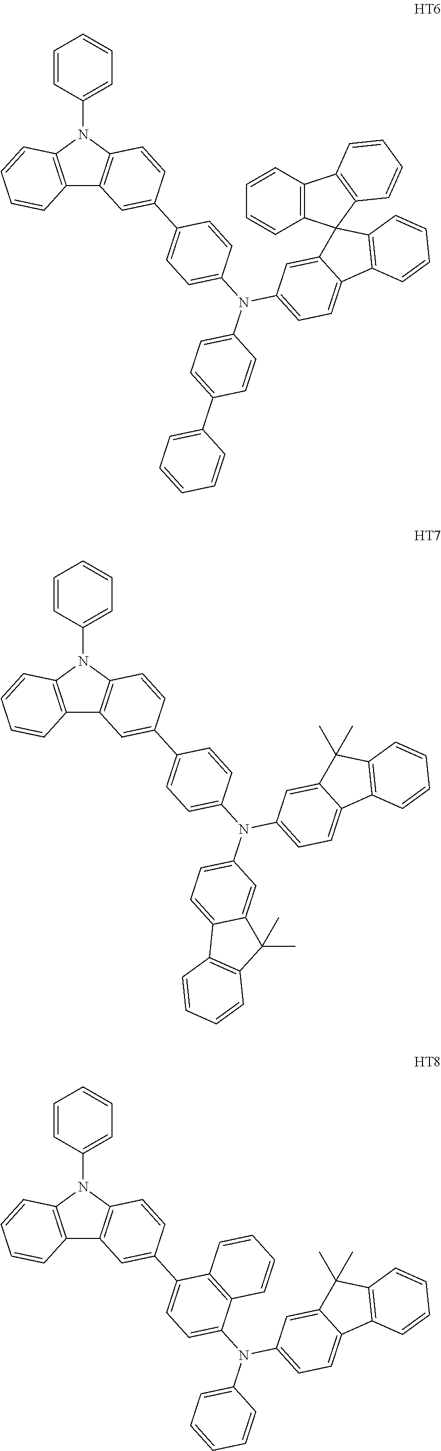 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

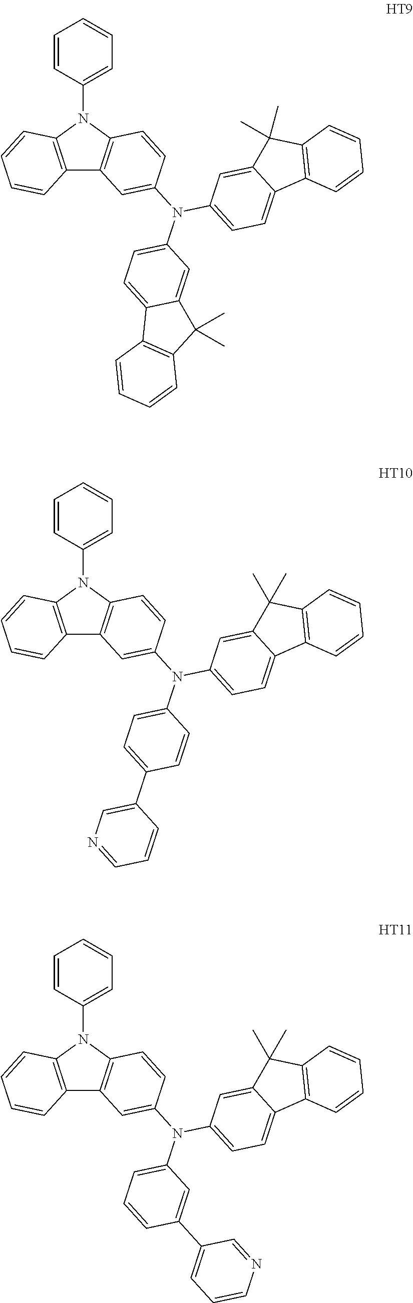 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc4c(c3)c3ccccc3n4-c3ccccc3)cc21 ; CC1(C)c2ccccc2-c2ccc(N(c3cccc(-c4cccnc4)c3)c3ccc4c(c3)c3ccccc3n4-c3ccccc3)cc21]

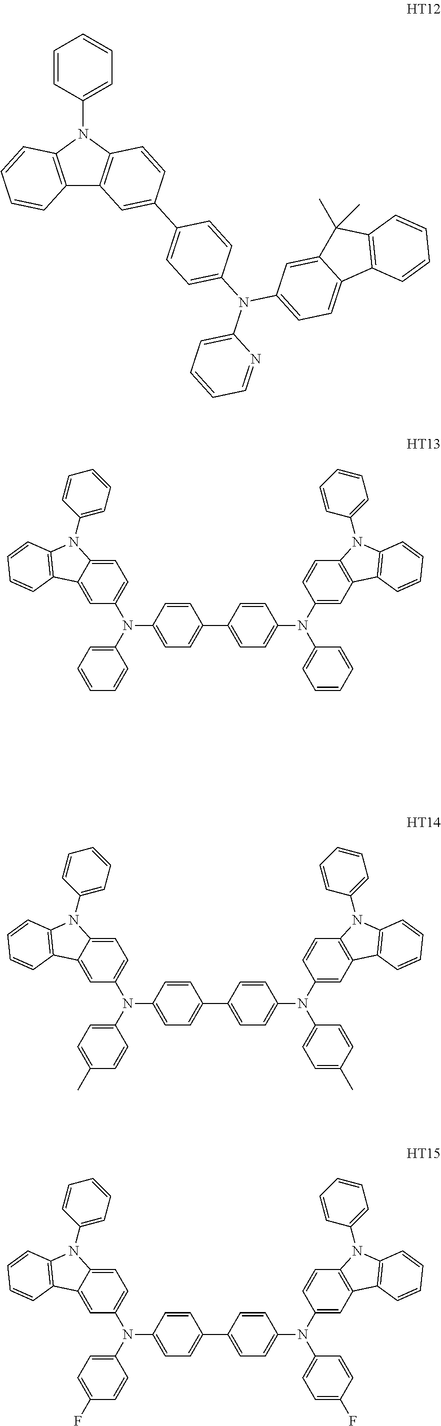 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

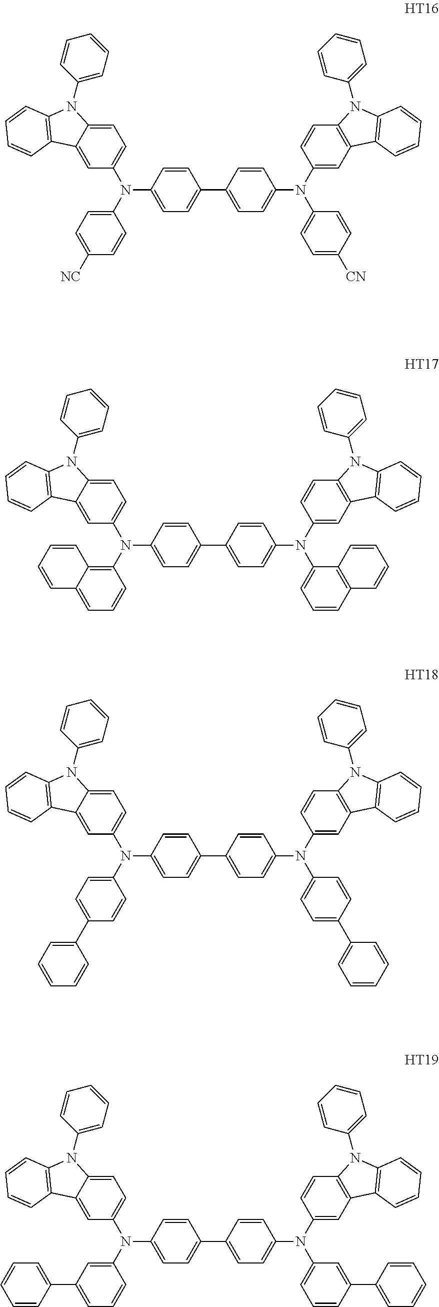 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

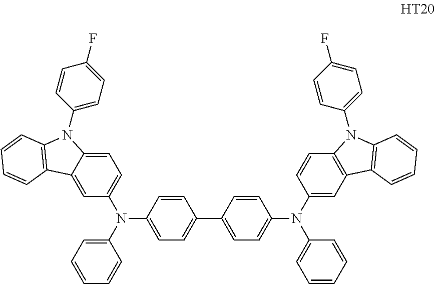 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

The thickness of the hole transport region may be in a range of about 100 Angstroms (Å) to about 10,000 Å, for example, about 100 Å to about 1,000 Å. While not wishing to be bound by a theory, it is understood that when the hole transport region includes a hole injection layer and a hole transport layer, the thickness of the hole injection layer may be in a range of about 100 Å to about 10,000 Å, and for example, about 100 Å to about 1,000 Å, and the thickness of the hole transport layer may be in a range of about 50 Å to about 2,000 Å, and for example, about 100 Å to about 1,500 Å. While not wishing to be bound by a theory, it is understood that when the thicknesses of the hole transport region, the hole injection layer, and the hole transport layer are within these ranges, excellent hole transport characteristics may be obtained without a substantial increase in driving voltage.

The hole transport region may further include, in addition to the mentioned materials above, a charge-generating material to improve conductive properties. The charge-generating material may be homogeneously or non-homogeneously dispersed throughout the hole transport region.

The charge-generating material may be, for example, a p-dopant. The p-dopant may be one selected from a quinone derivative, a metal oxide, and a cyano group-containing compound, but embodiments are not limited thereto. For example, non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide; and a compound containing a cyano group, such as Compound HT-D1 illustrated below, but they are not limited thereto.

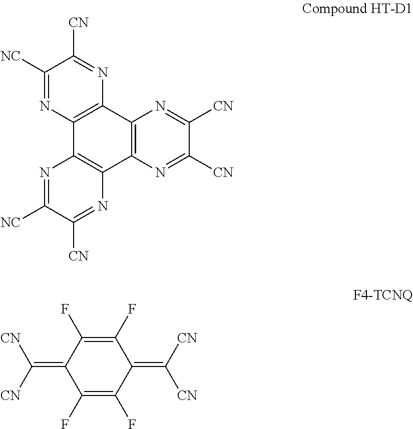

The hole transport region may further include a buffer layer.

The buffer layer may compensate for an optical resonance distance according to a wavelength of light emitted from the emission layer to improve the efficiency of an organic light-emitting device.

An emission layer (EML) may be formed on the hole transport region by using various methods, such as vacuum-deposition, spin coating, casting, or an LB method. When the emission layer is formed by vacuum-deposition or spin coating, vacuum-deposition and coating conditions for the emission layer may be generally similar to the conditions for forming a hole injection layer, though the conditions may vary depending on the compound used.

When the hole transport region includes an electron blocking layer, a material that is used to form the electron blocking layer may be selected from the material used to form an hole transport region and host materials described herein, but embodiments are not limited thereto. In some embodiments, when the hole transport region includes an electron blocking layer, mCP described herein may be used to form the electron blocking layer.

The emission layer may include a host and a dopant and the dopant may include the organometallic compound represented by Formula 1.

The host may include at least one selected from TPBi, TBADN, ADN (also known as “DNA”), CBP, CDBP, TCP, mCP, Compound H50, and Compound H51:

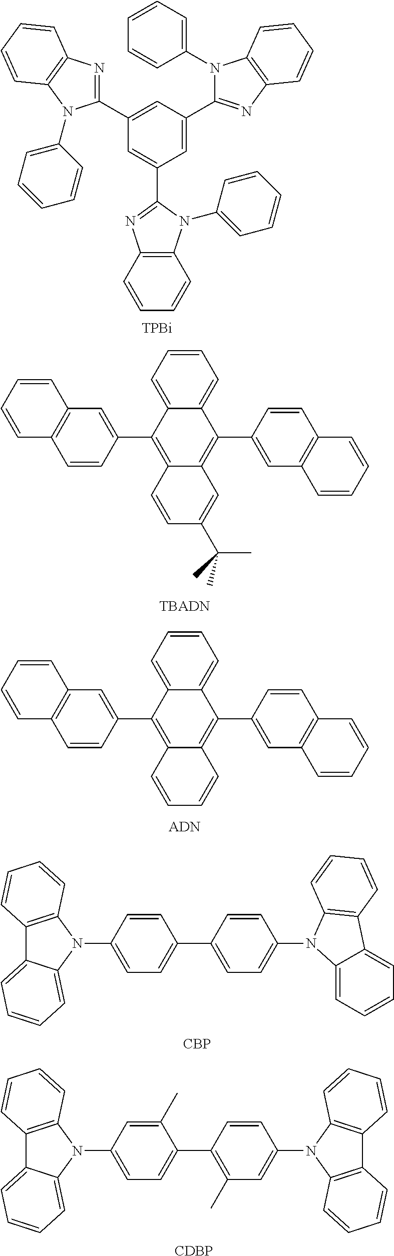

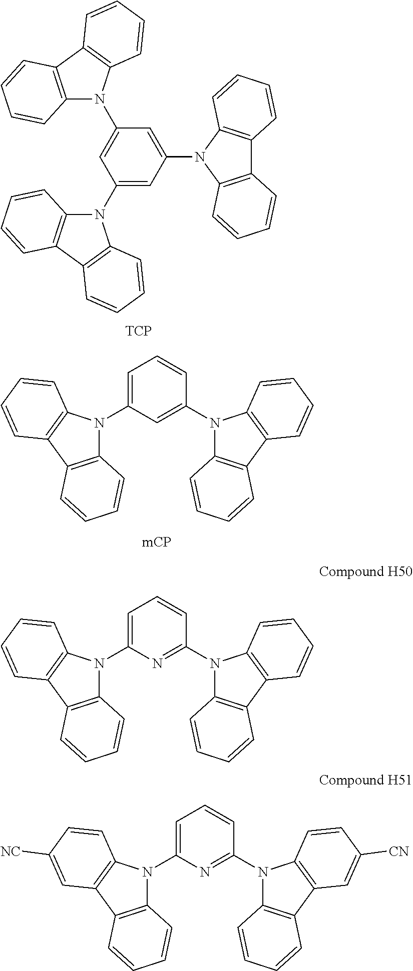

In some embodiments, the host may further include a compound represented by Formula 301:

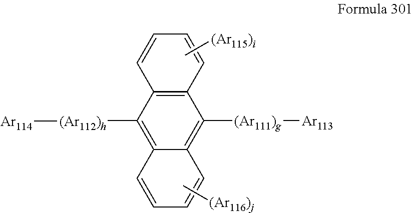

wherein, in Formula 301, An₁₁₁ and Ar₁₁₂ may be each independently selected from

a phenylene group, a naphthylene group, a phenanthrenylene group, and a pyrenylene group; and

a phenylene group, a naphthylene group, a phenanthrenylene group, and a pyrenylene group, each substituted with at least one selected from a phenyl group, a naphthyl group and an anthracenyl group.

In Formula 301, Ar₁₁₃ to Ar₁₁₆ may be each independently selected from

a C₁-C₁₀ alkyl group, a phenyl group, a naphthyl group, a phenanthrenyl group, and a pyrenyl group; and

a phenyl group, a naphthyl group, a phenanthrenyl group, and a pyrenyl group, each substituted with at least one selected from a phenyl group, a naphthyl group and an anthracenyl group.

g, h, i, and j in Formula 301 may be each independently an integer of 0 to 4, for example, 0, 1, or 2.

In Formula 301, Ar₁₁₃ to Ar₁₁₆ may be each independently selected from

a C₁-C₁₀ alkyl group substituted with at least one selected from a phenyl group, a naphthyl group, and an anthracenyl group;

a phenyl group, a naphthyl group, an anthracenyl group, a pyrenyl group, a phenanthrenyl group, and a fluorenyl group;

a phenyl group, a naphthyl group, an anthracenyl group, a pyrenyl group, a phenanthrenyl group, and a fluorenyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a pyrenyl group, a phenanthrenyl group, and a fluorenyl group; and

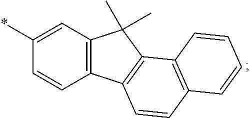 [SMILES: *c1ccc2c(c1)C(C)(C)c1c-2ccc2ccccc12]

but embodiments are not limited thereto.

In some embodiments, the host may include a compound represented by Formula 302:

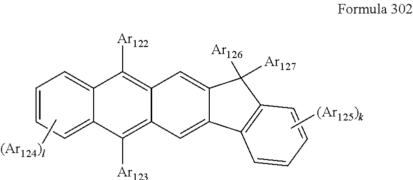

Descriptions for Ar₁₂₂ to Ar₁₂₅ in Formula 302 may be the same as defined in connection with Ar₁₁₃ in Formula 301.

In Formula 302, Ar₁₂₆ and Ar₁₂₇ may be each independently a C₁-C₁₀ alkyl group, e.g., a methyl group, an ethyl group, or a propyl group.

k and l in Formula 302 may be each independently an integer of 0 to 4. In some embodiments, k and l may be 0, 1, or 2.

In some embodiments, the compound represented by Formula 301 and the compound represented by Formula 302 may include Compounds HT1 to HT42, but embodiments are not limited thereto:

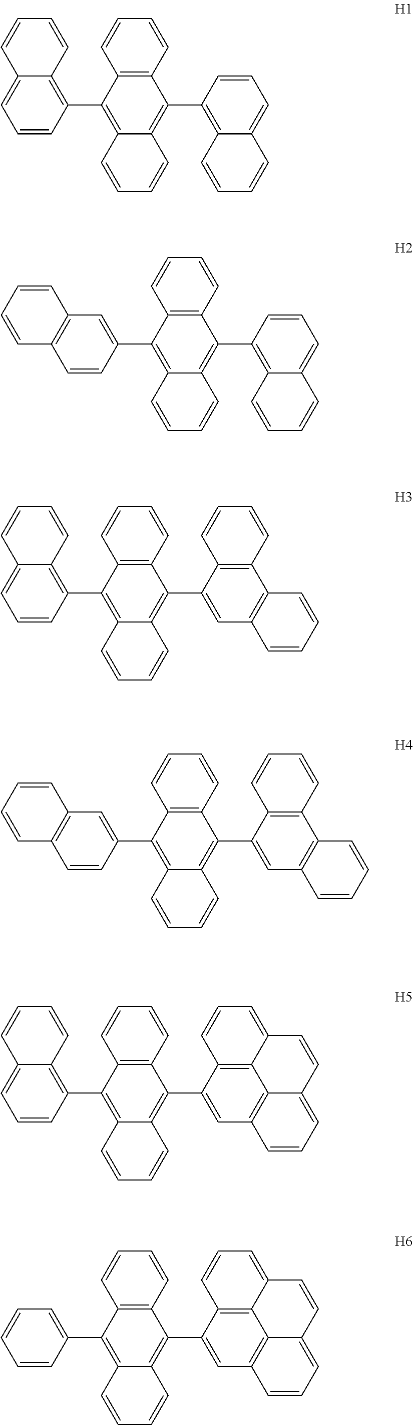

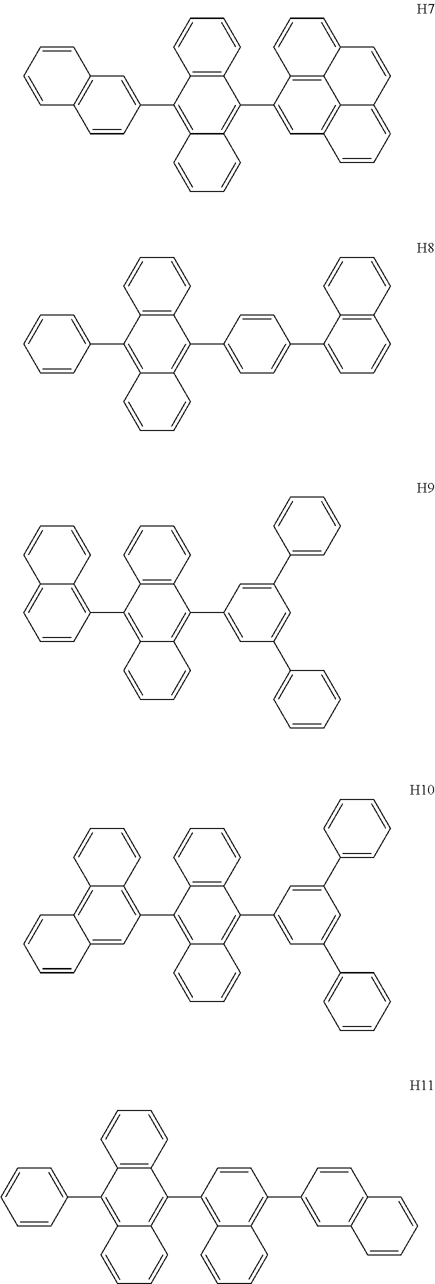

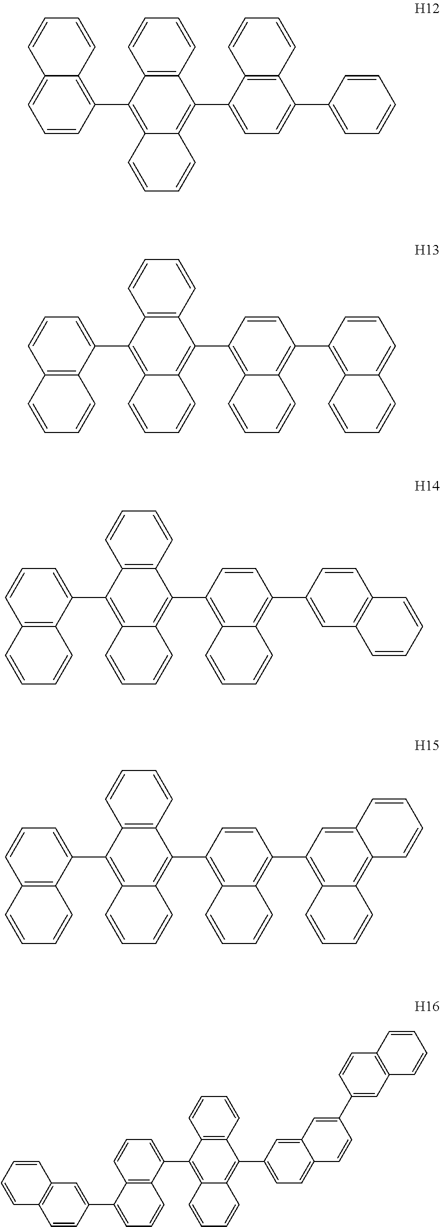

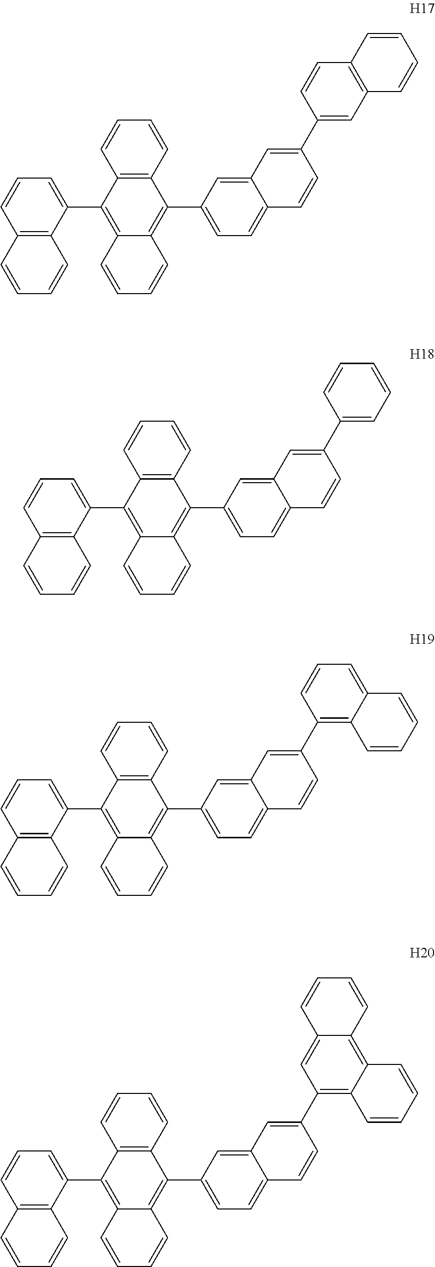

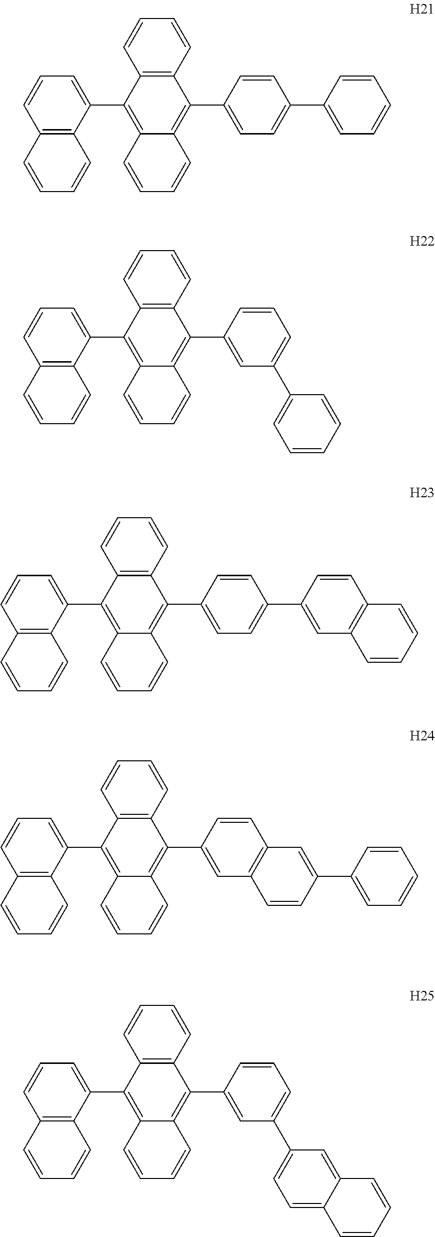

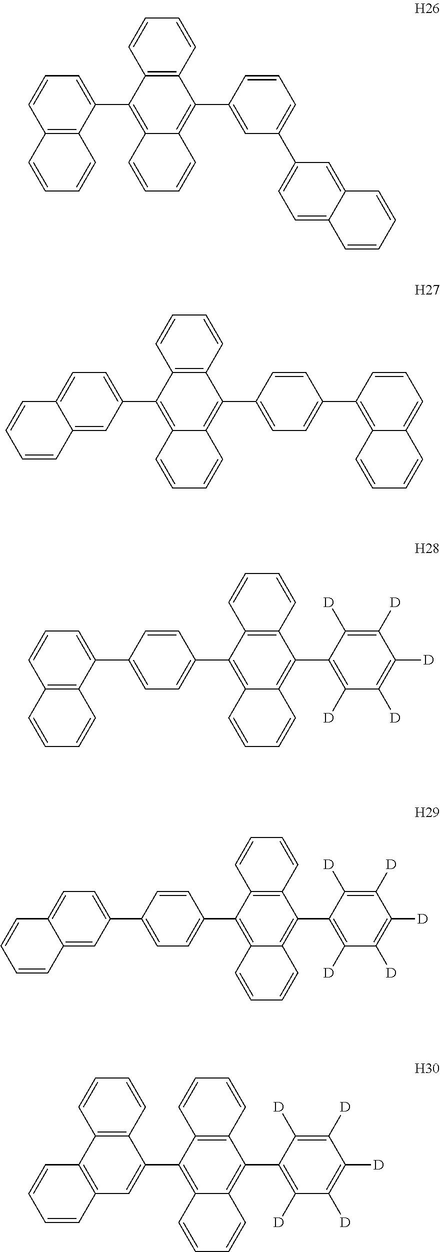

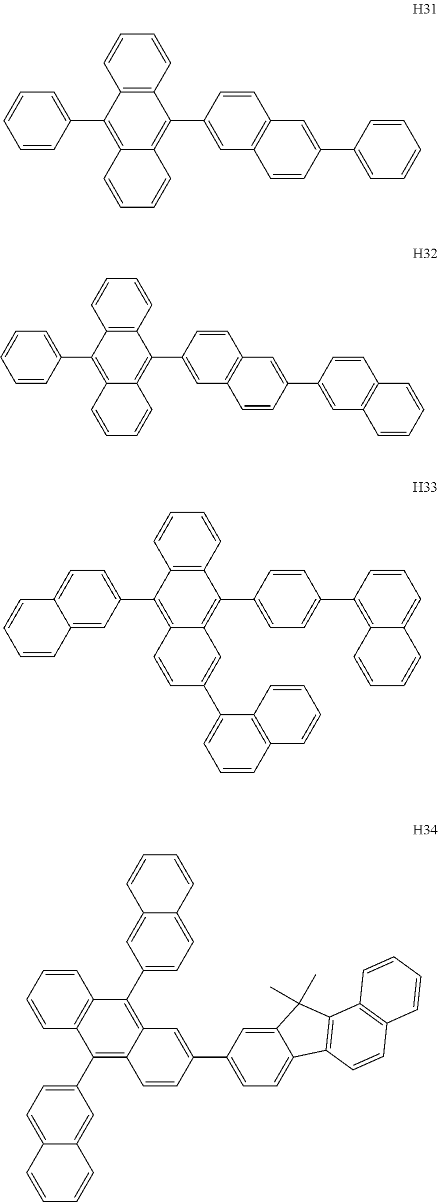

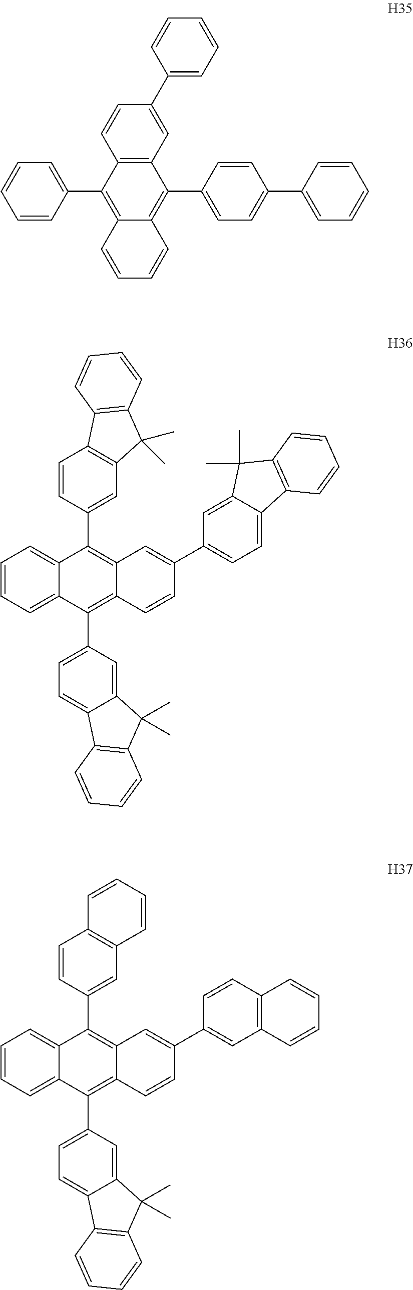

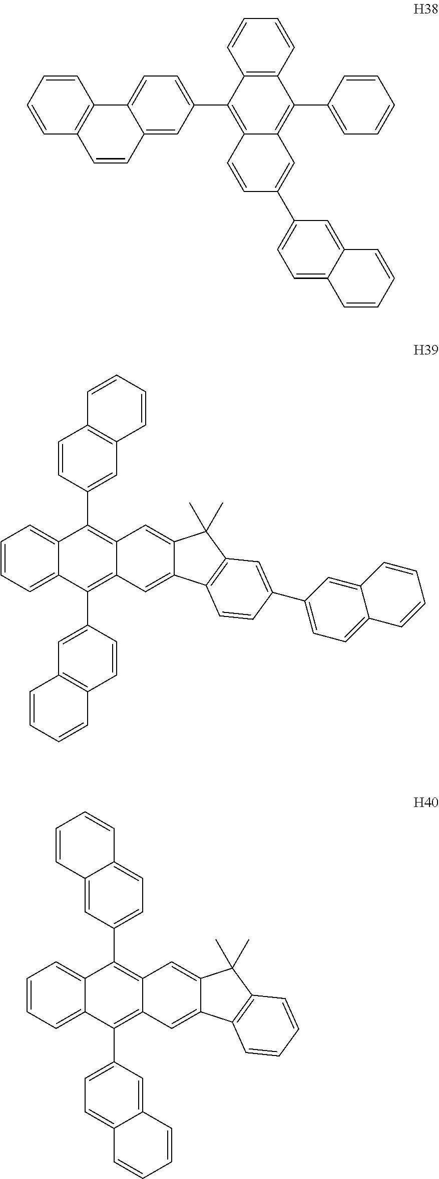

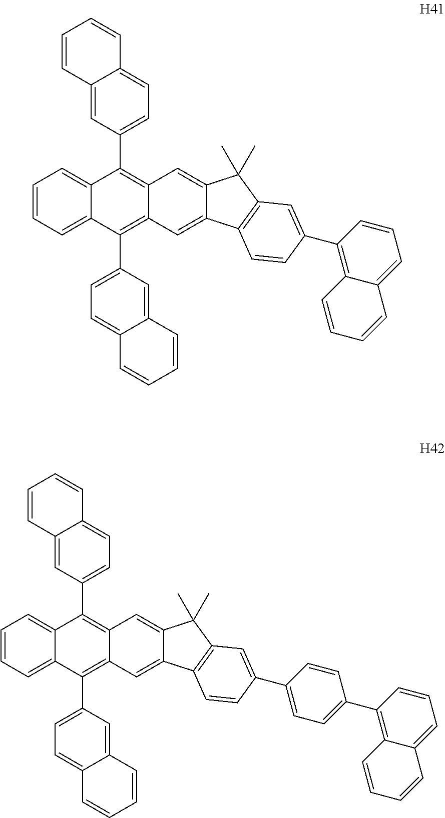

When the organic light-emitting device is a full color organic light-emitting device, the emission layer may be patterned into a red emission layer, a green emission layer, and a blue emission layer. In some embodiments, the emission layer may have a structure in which the red emission layer, the green emission layer, and/or the blue emission layer are layered to emit white light or other various embodiments are possible.

When the emission layer includes the host and the dopant, the amount of the dopant may be selected from a range of about 0.01 part by weight to about 15 parts by weight based on about 100 parts by weight of the host, but embodiments are not limited thereto.

The thickness of the emission layer may be in a range of about 100 Å to about 1,000 Å, for example, about 200 Å to about 600 Å. While not wishing to be bound by a theory, it is understood that when the thickness of the emission layer is within this range, excellent light-emission characteristics may be achieved without a substantial increase in driving voltage.

Then, an electron transport region may be formed on the emission layer.

The electron transport region may include at least one selected from a hole blocking layer, an electron transport layer, and an electron injection layer, but embodiments not limited thereto.

In some embodiments, the electron transport region may have a structure of a hole blocking layer/an electron transport layer/an electron injection layer or an electron transport layer/an electron injection layer, but embodiments are not limited thereto. The electron transport layer may have a single layer structure or a multi-layer structure including two or more different materials.

The conditions for forming a hole blocking layer, an electron transport layer, and an electron injection layer may be inferred based on the conditions for forming the hole injection layer.

When the electron transport region includes a hole blocking layer, the hole blocking layer may, for example, include at least one selected from BCP, Bphen, and Balq, but embodiments are not limited thereto.

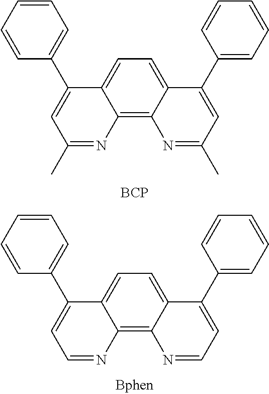

The thickness of the hole blocking layer may be in a range of about 20 Å to about 1,000 Å, for example, about 30 Å to about 300 Å. While not wishing to be bound by a theory, it is understood that when the thickness of the hole blocking layer is within this range, excellent hole blocking characteristics may be achieved without a substantial increase in driving voltage.

The electron transport layer may further include at least one selected from BCP, BPhen, Alq3, BAlq, TAZ, and NTAZ.

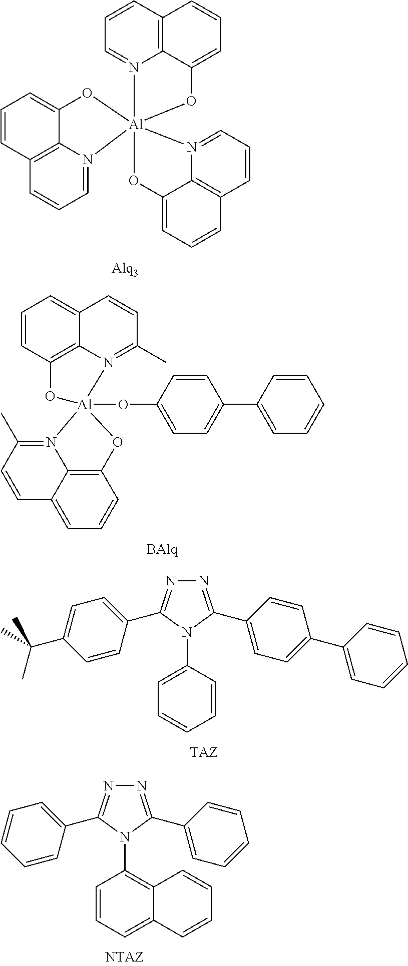

In some embodiments, the electron transport layer may include at least one selected from Compounds ET1 and ET2, but it is not limited thereto.

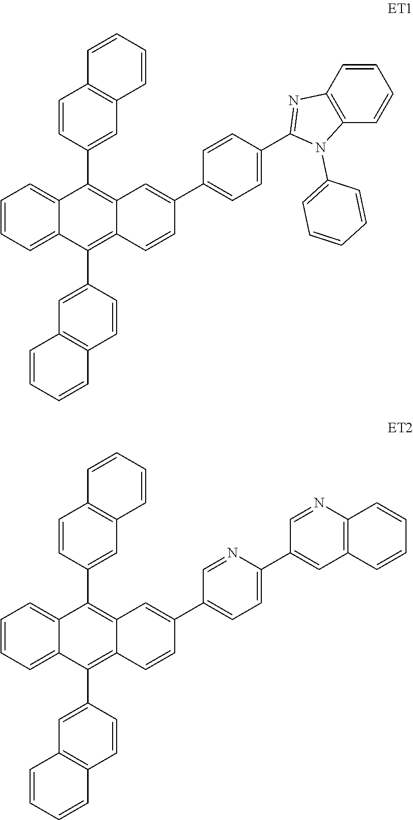 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1]

The thickness of the electron transport layer may be in a range of about 100 Å to about 1,000 Å, for example, about 150 Å to about 500 Å. While not wishing to be bound by a theory, it is understood that when the thickness of the electron transport layer is within this range, excellent electron transport characteristics may be obtained without a substantial increase in driving voltage.

The electron transport layer may further include a metal-containing material in addition to the materials described above.

The metal-containing material may include a Li complex. The Li complex may include, for example, Compound ET-D1 (lithium quinolate, or LiQ) or ET-D2.

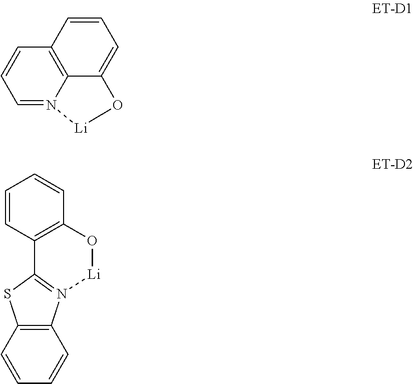

The electron transport region may include an electron injection layer (EIL) that facilitates electron injection from the second electrode 19.

The electron injection layer may include at least one selected from LiF, NaCl, CsF, Li₂O, and BaO.

The thickness of the electron injection layer may be in a range of about 1 Å to about 100 Å, for example, about 3 Å to about 90 Å. While not wishing to be bound by a theory, it is understood that when the thickness of the electron injection layer is within this range, excellent electron injection characteristics may be obtained without a substantial increase in driving voltage.

The second electrode 19 is on the organic layer 15. The second electrode 19 may be a cathode. A material for the second electrode 19 may be a material having a relatively low work function, such as a metal, an alloy, an electrically conductive compound, and a mixture thereof. Detailed examples of the material for forming the second electrode 19 include lithium (Li), magnesium (Mg), aluminum (Al), aluminum-lithium (Al—Li), calcium (Ca), magnesium-indium (Mg—In), and magnesium-silver (Mg—Ag). In some embodiments, ITO or IZO may be used to form a transmissive second electrode 19 to manufacture a top emission light-emitting device, and such a variation may be possible.

Hereinbefore, the organic light-emitting device has been described with reference to FIG. 1, but embodiments are not limited thereto.

A C₁-C₆₀ alkyl group as used herein refers to a linear or branched aliphatic hydrocarbon monovalent group having 1 to 60 carbon atoms. Detailed examples thereof are a methyl group, an ethyl group, a propyl group, an iso-butyl group, a sec-butyl group, a tert-butyl group, a pentyl group, an iso-amyl group, and a hexyl group. A C₁-C₆₀ alkylene group as used herein refers to a divalent group having the same structure as a C₁-C₆₀ alkyl group.

A C₁-C₆₀ alkoxy group as used herein refers to a monovalent group represented by -OA₁₀₁ (wherein A₁₀₁ is the C₁-C₆₀ alkyl group). Detailed examples thereof include a methoxy group, an ethoxy group, and an iso-propyloxy group.

A C₂-C₆₀ alkenyl group as used herein refers to a group formed by substituting at least one carbon double bond in the middle or at the terminal of the C₂-C₆₀ alkyl group. Detailed examples thereof are an ethenyl group, a propenyl group, and a butenyl group. A C₂-C₆₀ alkenylene group as used herein refers to a divalent group having the same structure as a C₂-C₆₀ alkenyl group.

A C₂-C₆₀ alkynyl group as used herein refers to a group formed by substituting at least one carbon triple bond in the middle or at the terminal of the C₂-C₆₀ alkyl group. Detailed examples thereof include an ethenyl group and a propenyl group. A C₂-C₆₀ alkynylene group as used herein refers to a divalent group having the same structure as a C₂-C₆₀ alkynyl group.

A C₃-C₁₀ cycloalkyl group as used herein refers to a monovalent monocyclic saturated hydrocarbon group including 3 to 10 carbon atoms. Detailed examples thereof include a cyclopropyl group, a cyclobutyl group, a cyclopentyl group, a cyclohexyl group, and a cycloheptyl group. A C₃-C₁₀ cycloalkylene group as used herein refers to a divalent group having the same structure as a C₃-C₁₀ cycloalkyl group.

A C₁-C₁₀ heterocycloalkyl group as used herein refers to a monovalent monocyclic group including at least one hetero atom selected from N, O, P, and S as a ring-forming atom and 1 to 10 carbon atoms. Detailed examples thereof include a tetrahydrofuranyl group and a tetrahydrothiophenyl group. A C₁-C₁₀ heterocycloalkylene group as used herein refers to a divalent group having the same structure as a C₁-C₁₀ heterocycloalkyl group.

A C₃-C₁₀ cycloalkenyl group as used herein refers to a monovalent monocyclic group that has 3 to 10 carbon atoms and at least one double bond in its ring, and which is not aromatic. Detailed examples thereof are a cyclopentenyl group, a cyclohexenyl group, and a cycloheptenyl group. A C₃-C₁₀ cycloalkenylene group as used herein refers to a divalent group having the same structure as a C₃-C₁₀ cycloalkenyl group.

A C₁-C₁₀ heterocycloalkenyl group as used herein refers to a monovalent monocyclic group including at least one hetero atom selected from N, O, P, and S as a ring-forming atom, 1 to 10 carbon atoms, and at least one double bond in its ring. Detailed examples of the C₁-C₁₀ heterocycloalkenyl group are a 2,3-dihydrofuranyl group and a 2,3-dihydrothiophenyl group. A C₁-C₁₀ heterocycloalkenylene group as used herein refers to a divalent group having the same structure as a C₁-C₁₀ heterocycloalkenyl group.

A C₆-C₆₀ aryl group as used herein refers to a monovalent group including a carbocyclic aromatic system having 6 to 60 carbon atoms, and a C₆-C₆₀ arylene group as used herein refers to a divalent group including a carbocyclic aromatic system having 6 to 60 carbon atoms. Detailed examples of the C₆-C₆₀ aryl group are a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

A C₁-C₆₀ heteroaryl group as used herein refers to a monovalent group having a carbocyclic aromatic system including at least one hetero atom selected from N, O, P, and S as a ring-forming atom and 1 to 60 carbon atoms. A C₁-C₆₀ heteroarylene group as used herein refers to a divalent group having a carbocyclic aromatic system including at least one hetero atom selected from N, O, P, and S as a ring-forming atom and 1 to 60 carbon atoms. Detailed examples of the C₁-C₆₀ heteroaryl group are a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each includes a plurality of rings, the rings may be fused to each other.

A C₆-C₆₀ aryloxy group as used herein indicates -OA₁₀₂ (wherein A₁₀₂ is the C₆-C₆₀ aryl group), a C₆-C₆₀ arylthio group as used herein indicates -SA₁₀₃ (wherein A₁₀₃ is the C₆-C₆₀ aryl group), and a C₇-C₆₀ arylalkyl group as used herein indicates -A₁₀₄A₁₀₅ (wherein A₁₀₄ is the C₆-C₆₀ aryl group and A₁₀₅ is the C₁-C₆₀ alkyl group).

A C₂-C₆₀ heteroaryloxy group as used herein indicates -OA₁₀₆ (wherein A₁₀₆ is the C₂-C₆₀ heteroaryl group), a C₂-C₆₀ heteroarylthio group as used herein indicates -SA₁₀₇ (wherein A₁₀₇ is the C₂-C₆₀ heteroaryl group), and a C₃-C₆₀ heteroarylalkyl group as used herein indicates -A₁₀₈A₁₀₉ (wherein A₁₀₈ is the C₂-C₆₀ heteroaryl group and A₁₀₉ is the C₁-C₆₀ alkyl group).

A monovalent non-aromatic condensed polycyclic group as used herein refers to a monovalent group that has two or more rings condensed to each other, and has only carbon atoms (for example, the number of carbon atoms may be in a range of 8 to 60) as ring forming atoms, wherein the molecular structure as a whole is non-aromatic in the entire molecular structure. A detailed example of the monovalent non-aromatic condensed polycyclic group is a fluorenyl group. A divalent non-aromatic condensed polycyclic group as used herein refers to a divalent group having the same structure as the monovalent non-aromatic condensed polycyclic group.

A monovalent non-aromatic condensed heteropolycyclic group as used herein refers to a monovalent group that has two or more rings condensed to each other, and has a hetero atom selected from N, O, P, and S, other than carbon atoms (for example, the number of carbon atoms may be in a range of 1 to 60), as ring-forming atoms, wherein the molecular structure as a whole is non-aromatic in the entire molecular structure. The monovalent non-aromatic condensed heteropolycyclic group includes a carbazolyl group. A divalent non-aromatic condensed hetero-polycyclic group as used herein refers to a divalent group having the same structure as the monovalent non-aromatic condensed hetero-polycyclic group.

In the presented specification, at least one of substituents of the substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₇-C₆₀ arylalkyl group, substituted C₁-C₆₀ heteroaryl group, substituted C₂-C₆₀ heteroaryloxy group, substituted C₂-C₆₀ heteroarylthio group, substituted C₃-C₆₀ heteroarylalkyl group, substituted monovalent non-aromatic condensed polycyclic group, and substituted monovalent non-aromatic condensed heteropolycyclic group may be selected from:

a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, a monovalent non-aromatic condensed heteropolycyclic group, —N(Q₁₁)(Q₁₂), —B(Q₁₃)(Q₁₄), and —P(═O)(Q₁₅)(Q₁₆);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, and a monovalent non-aromatic condensed heteropolycyclic group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, a monovalent non-aromatic condensed heteropolycyclic group, —N(Q₂₁)(Q₂₂), —B(Q₂₃)(Q₂₄), and —P(═O)(Q₂₅)(Q₂₆); and

—N(Q₃₁)(Q₃₂), —B(Q₃₃)(Q₃₄), and —P(═O)(Q₃₅)(Q₃₆),

wherein, Q₁ to Q₆, Q₁₁ to Q₁₆, Q₂₁ to Q₂₆, Q₃₁ to Q₃₆, and Q₅₁ to Q₅₃ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₂-C₆₀ heteroaryloxy group, a substituted or unsubstituted C₂-C₆₀ heteroarylthio group, a substituted or unsubstituted C₃-C₆₀ heteroarylalkyl group, a substituted or unsubstituted monovalent non-aromatic condensed polycyclic group, and a substituted or unsubstituted monovalent non-aromatic condensed heteropolycyclic group.

When a group containing a specified number of carbon atoms is substituted with any of the substituents listed above, the number of carbon atoms in the resulting “substituted” group may be the number of atoms contained in the original (base) group plus the number of carbon atoms (if any) contained in the substituent. For example, the “substituted C₁-C₃₀ alkyl” may refer to a C₁-C₃₀ alkyl group substituted with C₆₋₆₀ aryl group, in which the total number of carbon atoms may be C₇-C₉₀.

Hereinafter, an organic light-emitting device according to an embodiment will be described in detail with reference to Synthesis Examples and Examples, however, the inventive concept is not limited thereto. The wording “B was used instead of A” used in describing Synthesis Examples means that an amount of B used was identical to an amount of A used based on molar equivalence.

### EXAMPLE

### Synthesis Example 1

### Synthesis of Compound 1

Synthesis of Compound A2

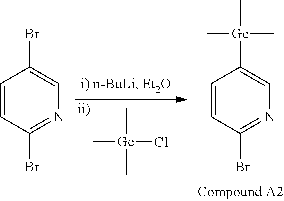

10.0 grams (g) (42.22 millimoles (mmol)) of 2,5-dibromopyridine was mixed with 200 ml of diethyl ether. Then, the mixture was cooled up to a temperature of −78° C. n-BuLi (42.22 mmol) was slowly added thereto, and the mixture was stirred at a temperature of −78° C. for about 1 hour. Then, 5.2 milliliters (mL) (42.22 mmol) of chlorotrimethylgermane (Ge(CH₃)Cl) was added thereto, and a reaction was carried out at a temperature of −78° C. for about 1 hour. The temperature was then raised to room temperature and the reaction was carried out for about 12 hours. An organic layer was extracted therefrom by using dichloromethane and an anhydrous magnesium sulfate (MgSO₄) was added thereto to dry the organic layer. The resultant was filtered and a solvent in the obtained filtrate was removed under reduced pressure. The residual was purified by a column chromatography using ethyl acetate and hexane at a ratio of 1:15 to obtain 6.3 g (54%) of Compound A2. The identity of the obtained compound was confirmed by using LCMS and ¹H NMR.

¹H-NMR (CDCl₃) δ 8.36 (s, 1H), 7.58 (d, 1H), 7.44 (d, 1H), 0.42 (s, 9H)

MS: m/z 275.94 [(M+1)⁺]

Synthesis of Compound A1

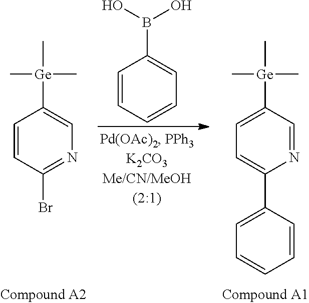

5.00 g (18.20 mmol) of Compound A2, 2.66 g (21.84 mmol) of phenylboronic acid, 0.20 g (0.91 mmol) of Pd(OAc)₂, 0.48 g (1.82 mmol) of triphenylphospine, and 5.03 g (36.40 mmol) of K₂CO₃ were mixed with 60 mL of acetonitrile and 30 mL of methanol. Then, the mixture was stirred at a temperature of 50° C. for about 18 hours, cooled to room temperature, and filtered. An organic layer was extracted therefrom by using dichloromethane and an anhydrous MgSO₄ was added thereto to dry the organic layer. The resultant was filtered and a solvent in the obtained filtrate was removed under reduced pressure. The residual was purified by a column chromatography using ethyl acetate and hexane at a ratio of 1:25 to obtain 2.72 g (55%) of Compound A1. The identity of the obtained compound was confirmed by using LCMS and ¹H NMR.

¹H-NMR (CDCl₃) δ 8.33 (s, 1H), 8.23 (d, 2H), 7.96 (d, 1H), 7.61 (d, 1H), 7.49 (m, 3H), 0.46 (s, 9H)

MS: m/z 273.06 [(M+1)⁺]

Synthesis of Compound B2

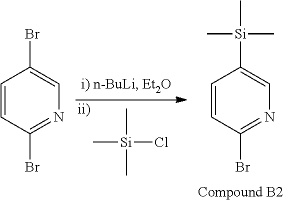

5.6 g (57%) of Compound B2 was obtained in the same manner as Compound A2 in Synthesis Example 1, except that chlorotrimethylsilane (Si(CH₃)Cl) was used instead of chlorotrimethylgermane (Ge(CH₃)Cl). The identity of the obtained compound was confirmed by using LCMS and ¹H NMR.

¹H-NMR (CDCl₃) δ 8.31 (s, 1H), 7.52 (d, 1H), 7.38 (d, 1H), 0.09 (s, 9H)

MS: m/z 230.99 [(M+1)⁺]

Synthesis of Compound B1

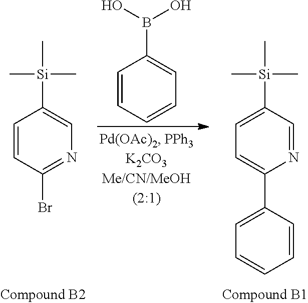

2.43 g (61%) of Compound B2 was obtained in the same manner as Compound A1 in Synthesis Example 1, except that Compound B2 was used instead of Compound A2. The identity of the obtained compound was confirmed by using LCMS and ¹H NMR.

¹H-NMR (CDCl₃) δ 8.27 (s, 1H), 8.19 (d, 2H), 7.90 (d, 1H), 7.57 (d, 1H), 7.41 (m, 3H), 0.10 (s, 9H)

MS: m/z 227.11 [(M+1)⁺]

Synthesis of Compound M2A

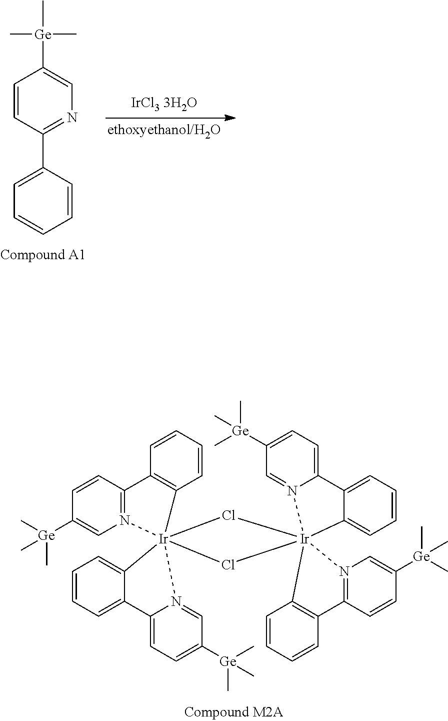

4.10 g (15.08 mmol) of Compound A1 and 2.36 g (6.70 mmol) of iridium chloride were mixed with 60 mL of ethoxyethanol and 20 mL of distilled water, and the result was stirred under reflux for about 24 hours to carry out a reaction. The temperature was then reduced to room temperature. A formed solid was separated by filtration. The solid was thoroughly washed with water, methanol, and hexane in the stated order, and dried in a vacuum oven, thereby obtaining 5.10 g (74%) of Compound M2A.

Synthesis of Compound M1A

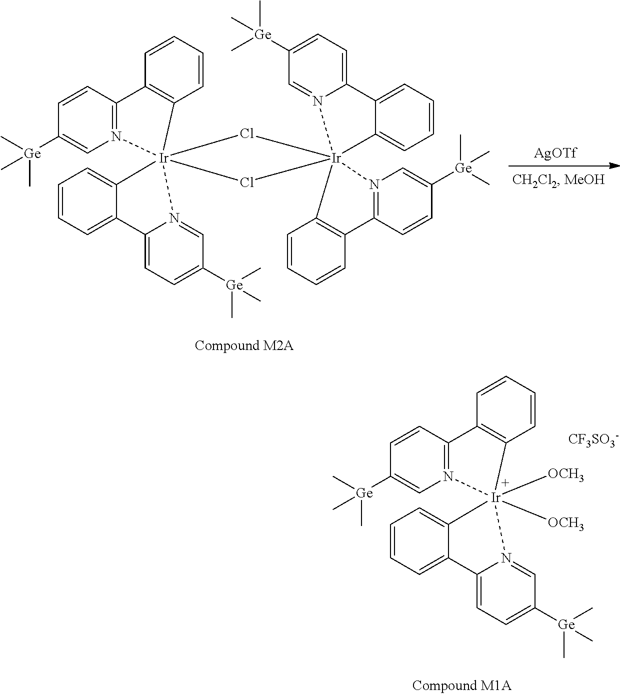

2.64 g (1.71 mmol) of Compound M2A and 0.88 g (3.43 mmol) of AgOTf were added to 12 mL of a mixture solvent of dichloromethane and methanol at a ratio of 3:1 and dissolved. Then, while blocking light by using an aluminum foil, a reaction was carried out by stirring for about 18 hours at room temperature. The formed solid was removed by filtration through a pad of celite, and the filtrate was concentrated under reduced pressure to obtain 2.94 g (72%) of Compound M1A.

Synthesis of Compound 1

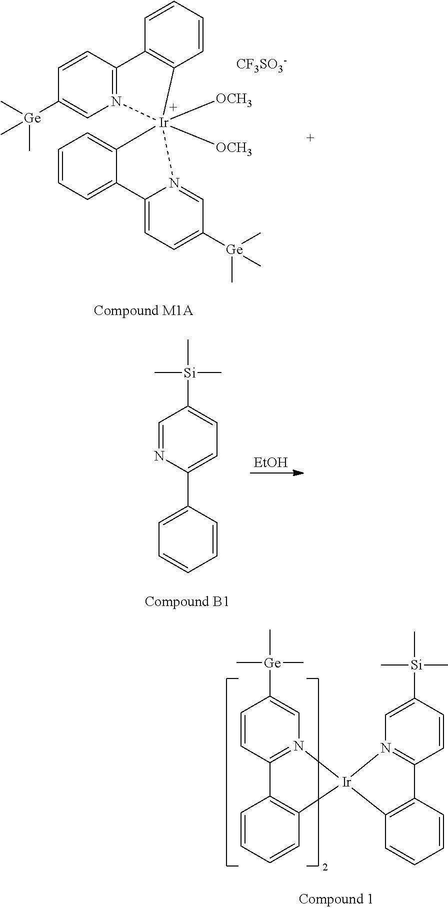

3.96 g (4.18 mmol) of Compound M1A and 1.14 g (5.02 mmol) of Compound B1 were mixed with 20 mL of ethanol, and the resulting mixture was stirred under reflux for about 15 hours to carry out the reaction. The temperature was then reduced to room temperature. The mixture obtained therefrom was filtered to obtain a solid, and the solid was thoroughly washed with ethanol and hexane. The solid was then purified by a column chromatography using ethyl acetate and hexane at a ratio of 1:6 to obtain 1.00 g (26%) of Compound 1. The identity of the obtained compound was confirmed by using LCMS and ¹H NMR.

¹H-NMR (CDCl₃) δ 7.80 (d, 3H), 7.62 (m, 6H), 7.43 (s, 1H), 7.39 (d, 2H), 6.95 (m, 3H), 6.88 (m, 6H), 0.16 (s, 18H), 0.03 (s, 9H)

MS: m/z 959.17 [(M+1)⁺]

### Synthesis Example 2

### Synthesis of Compound 2

Synthesis of Compound C3

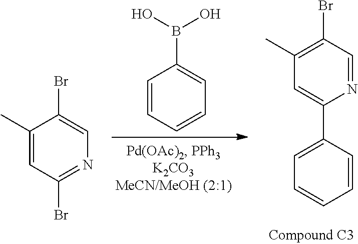

9.6 g (48%) of Compound C3 was obtained in the same manner as Compound A1 in Synthesis Example 1, except that 20.0 g (79.71 mmol) of 2,5-dibromo-4-methylpyridine was used instead of 2,5-dibromo-4-methylpyridine.

Synthesis of Compound C2

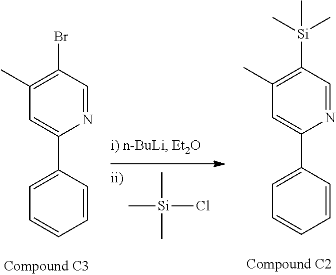

3.79 g (78%) of Compound C2 was obtained in the same manner as Compound B2 in Synthesis Example 1, except that 5.00 g (20.15 mmol) of Compound C3 was used instead of 2,5-dibromopyridine. The identity of the obtained compound was confirmed by using LCMS and ¹H NMR.

¹H-NMR (CDCl₃) δ 8.50 (s, 1H), 7.86 (d, 2H), 7.33 (m, 4H), 2.37 (s, 3H), 0.10 (s, 9H)

MS: m/z 241.13 [(M+1)⁺]

Synthesis of Compound C1

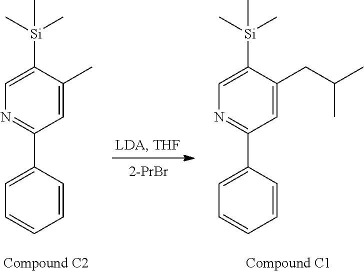 [SMILES: Cc1cc(-c2ccccc2)ncc1[Si](C)(C)C ; CC(C)Cc1cc(-c2ccccc2)ncc1[Si](C)(C)C]

2.30 g (9.53 mmol) of Compound C2 was mixed with 45 mL of tetrahydrofuran (THF), and the mixture was cooled up to a temperature of −78° C. 8.58 mL (17.16 mmol) of lithium diisopropylamide (LDA) was slowly added thereto. The mixture was stirred at −78° C. for about 1 hour to carry out a reaction, and the temperature was then raised to room temperature. The reaction was additionally carried out for about 1.5 hours. Then, the temperature was reduced to −78° C., and 1.48 mL (15.73 mmol) of 2-bromopropane was slowly added thereto. Then, the temperature was raised to room temperature, and the reaction was carried out for about 12 hours. An organic layer was extracted therefrom by using dichloromethane, and MgSO₄ was added thereto to dry the organic layer. The resultant was filtered, and a solvent in the obtained filtrate was removed under reduced pressure. The residual was purified by a column chromatography using ethyl acetate and hexane at a ratio of 4:96 to obtain 2.03 g (75%) of Compound C1. The identity of the obtained compound was confirmed by using LCMS and ¹H NMR.

¹H-NMR (CDCl₃) δ 8.51 (s, 1H), 7.83 (d, 2H), 7.35 (m, 4H), 2.41 (d, 2H), 1.99 (m, 1H), 1.07 (d, 6H), 0.09 (s, 9H)

MS: m/z 283.18 [(M+1)⁺]

Synthesis of Compound 2

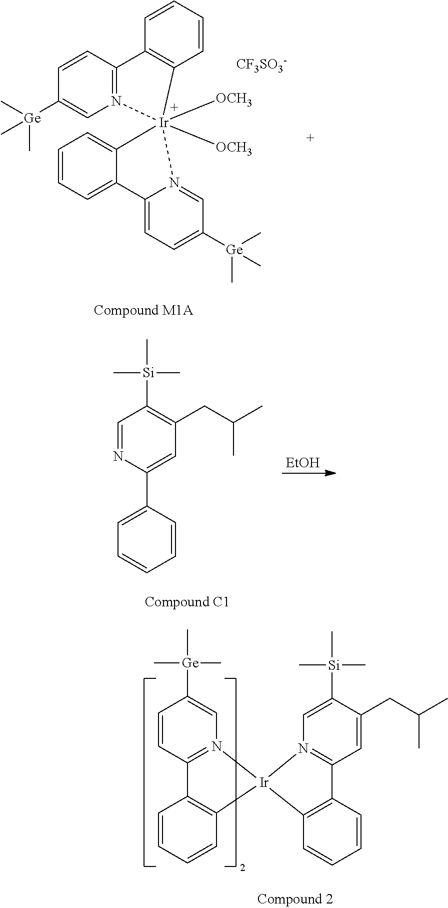

2.94 g (3.10 mmol) of Compound M1A and 1.06 g (3.72 mmol) of Compound C1 were mixed with 15 mL of ethanol, and the result was stirred under refluxing for about 15 hours to carry out a reaction. The temperature was then reduced to room temperature. The mixture obtained therefrom was filtered to obtain a solid. The solid was thoroughly washed with ethanol and hexane and purified by a column chromatography using ethyl acetate and hexane at a ratio of 1:6 to obtain 1.10 g of Compound 2 (35%). The identity of the obtained compound was confirmed by using LCMS and ¹H NMR.

¹H-NMR (CDCl₃) δ 7.64 (d, 2H), 7.45 (m, 6H), 7.29 (s, 1H), 7.26 (s, 1H), 7.22 (s, 1H), 6.75 (m, 9H), 2.41 (d, 2H), 2.00 (m, 1H), 1.07 (d, 6H), 0.10 (d, 18H), −0.12 (s, 9H)

MS: m/z 1015.23 [(M+1)⁺]

### Synthesis Example 3

### Synthesis of Compound 7

Synthesis of Compound M2B

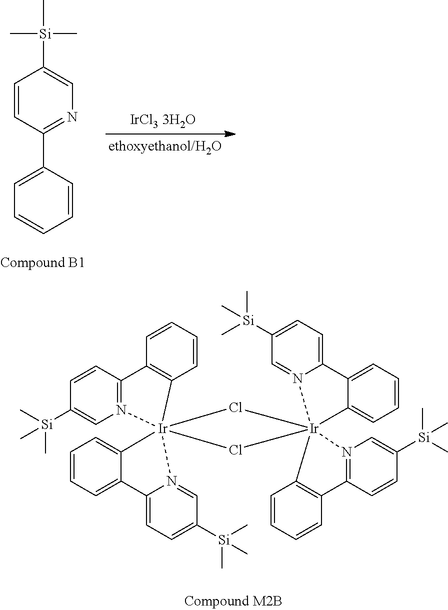

2.08 g (9.15 mmol) of Compound B1 and 1.43 g (4.07 mmol) of iridium chloride were mixed with 30 mL of ethoxyethanol and 10 mL of distilled water, and the result was stirred under reflux for about 24 hours to carry out a reaction. The temperature was then reduced to room temperature. The solid formed therefrom was separated by filtration. The filtered solid was thoroughly washed with water, methanol, and hexane in the stated order, and dried in a vacuum oven to obtain 2.13 g (77%) of Compound M2B.

Synthesis of Compound M1B

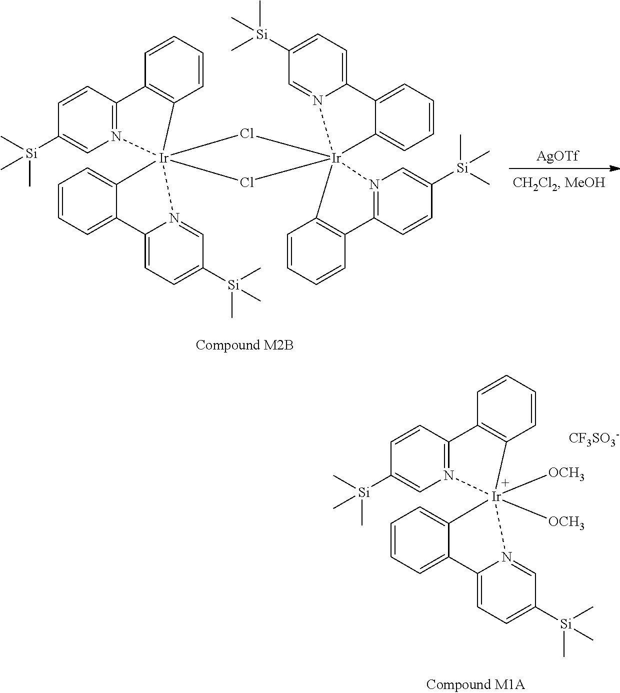

2.13 g (1.56 mmol) of Compound M2B and 0.80 g (3.12 mmol) of AgOTf were added to 12 mL of a mixture solvent of dichloromethane and methanol at a ratio of about 3:1 and dissolved. Then, while blocking light by using an aluminum foil, a reaction was carried out by stirring for about 18 hours at room temperature. The formed solid was removed by filtration through a pad of celite, and the filtrate was concentrated under reduced pressure to obtain 2.29 g (85%) of Compound M1B.

Synthesis of Compound 7

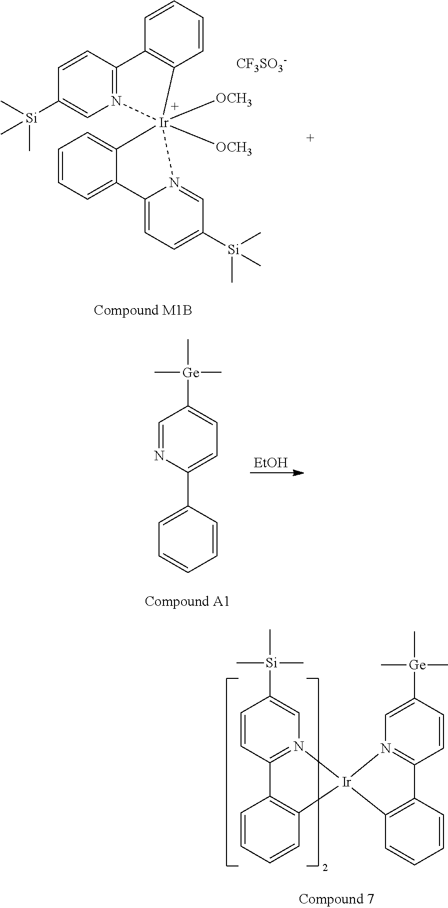

2.29 g (2.67 mmol) of Compound M1B and 0.87 g (3.20 mmol) of Compound A1 were mixed with 15 mL of ethanol, and the resulting mixture was stirred under reflux for about 15 hours to carry out a reaction. The temperature was then reduced to room temperature. The mixture obtained therefrom was filtered to obtain a solid. The solid was then thoroughly washed with ethanol and hexane and purified by a column chromatography using ethyl acetate and hexane at a ratio of 1:6 to obtain 1.00 g (41%) of Compound 7. The identity of the obtained compound was confirmed by using LCMS and ¹H NMR.

1H-NMR (CDCl₃) δ 7.80 (d, 3H), 7.62 (m, 6H), 7.42 (m, 3H), 6.98 (m, 3H), 6.88 (m, 6H), 0.16 (s, 9H), 0.03 (s, 18H)

MS: m/z 915.22 [(M+1)⁺]

### Synthesis Example 4

### Synthesis of Compound 26

Synthesis of Compound D2

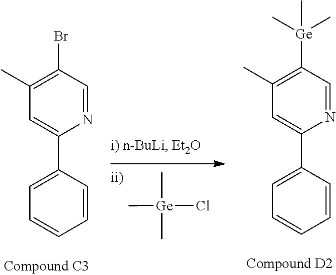

9.1 g (82%) of Compound D2 was obtained in the same manner as Compound A2 in Synthesis Example 1, except that 9.6 g (38.61 mmol) of Compound C3 was used instead of 2,5-dibromopyridine. The identity of the obtained compound was confirmed by using LCMS and ¹H NMR.

1H-NMR (CDCl₃) δ 8.53 (s, 1H), 7.92 (d, 2H), 7.39 (m, 4H), 2.40 (s, 3H), 0.44 (s, 9H)

MS: m/z 287.07 [(M+1)⁺]

Synthesis of Compound D1

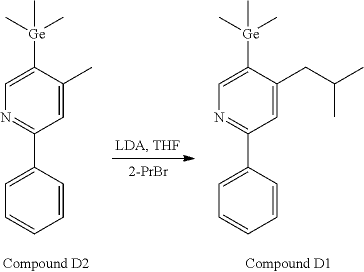

2.30 g (8.04 mmol) of Compound D2 was mixed with 40 mL of THF. Then, the mixture was cooled to a temperature of −78° C., and 7.24 mL (14.48 mmol) of LDA was slowly added thereto. The mixture was stirred at a temperature of −78° C. for about 1 hour to carry out a reaction. The temperature was then raised to room temperature, and the reaction was additionally carried out for about 1.5 hours. The temperature was subsequently reduced to −78° C., and 1.25 mL (13.27 mmol) of 2-bromopropane was slowly added to the reaction mixture. Then, the temperature was raised to room temperature, and the reaction was carried out for about 12 hours. An organic layer was extracted therefrom by using dichloromethane, and MgSO₄ was added thereto to dry the organic layer. The resultant was filtered, and a solvent in the obtained residue was removed under reduced pressure. The residual was purified by a column chromatography using ethyl acetate and hexane at a ratio of 4:96 to obtain 2.0 g (76%) of Compound D1. The identity of the obtained compound was confirmed by using LCMS and ¹H NMR.

1H-NMR (CDCl₃) δ 8.55 (s, 1H), 7.89 (d, 2H), 7.40 (m, 4H), 2.40 (d, 2H), 1.99 (m, 1H), 1.05 (d, 6H), 0.45 (s, 9H)

MS: m/z 329.12 [(M+1)⁺]

Synthesis of Compound M2D

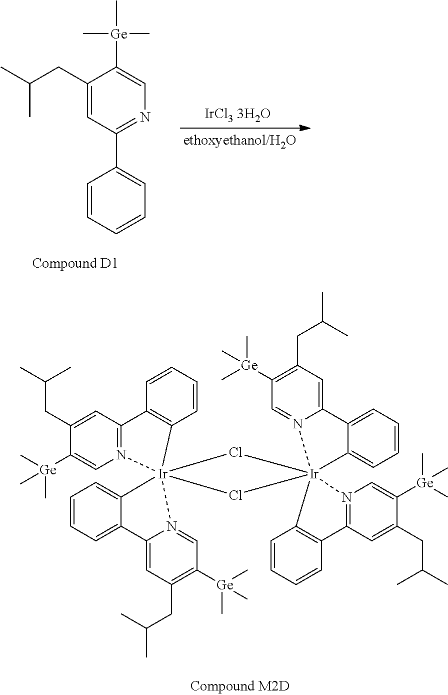

5.03 g (15.34 mmol) of Compound D1 and 2.40 g (6.82 mmol) of iridium chloride were mixed with 60 mL of ethoxyethanol and 20 mL of distilled water. The mixture was then stirred under reflux for about 24 hours to carry out a reaction. The temperature was then reduced to room temperature. The formed solid was separated by filtration. The flited solid was thoroughly washed with water, methanol, and hexane in the stated order, and dried in a vacuum oven, thereby obtaining 4.48 g (75%) of Compound M2D.

Synthesis of Compound M1D

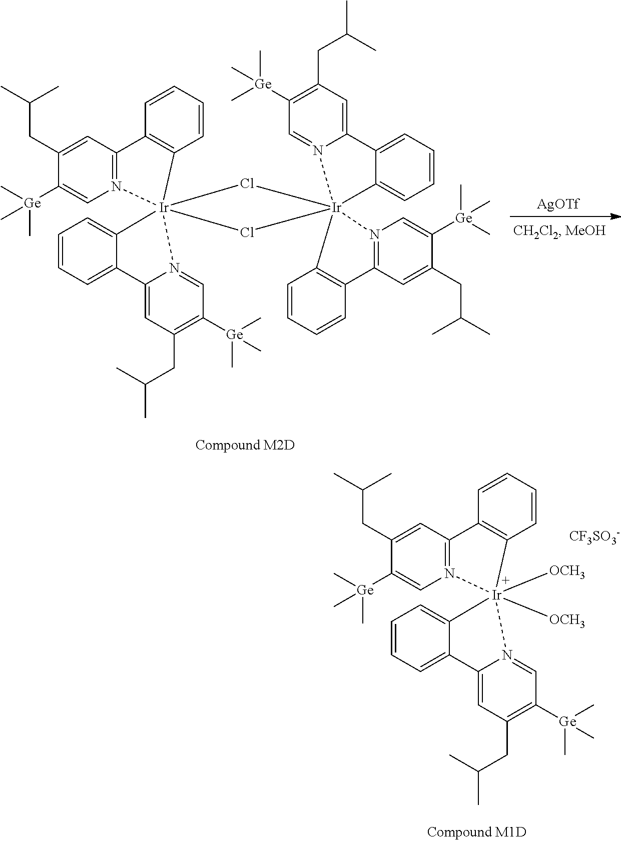

4.48 g (2.54 mmol) of Compound M2D and 1.31 g (5.08 mmol) of AgOTf were added to 12 mL of a mixture solvent of dichloromethane and methanol at a ratio of 3:1. Then, while blocking light by using an aluminum foil, a reaction was carried out by stirring for about 18 hours at room temperature. The formed solid was filtered through a pad of celite, and the filtrate was concentrated under reduced pressure to obtain 4.27 g (79%) of Compound M1D.

Synthesis of Compound 26

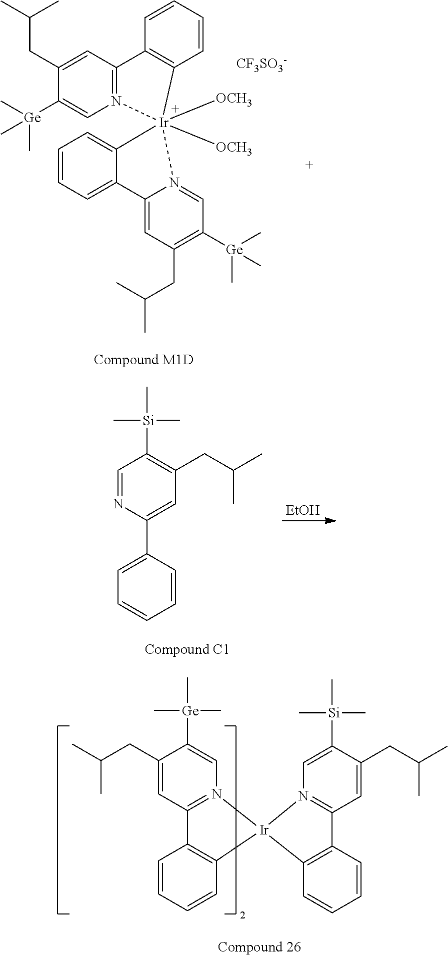

4.27 g (4.03 mmol) of Compound M1 D and 1.26 g (4.43 mmol) of Compound C1 were mixed with 20 mL of ethanol, and the resulting mixture was stirred under reflux for about 15 hours to carry out a reaction. The temperature was then reduced to room temperature. The mixture obtained therefrom was filtered to obtain a solid. The solid was then thoroughly washed with ethanol and hexane. The filtered solid was purified by a column chromatography using ethyl acetate and hexane at a ratio of 1:6 to obtain 1.40 g (31%) of Compound 26. The identity of the obtained compound was confirmed by using LCMS and ¹H NMR.

1H-NMR (CDCl₃) δ 7.55 (m, 6H), 7.29 (m, 3H), 6.72 (m, 9H), 2.46 (d, 2H), 2.40 (d, 4H), 1.84 (m, 3H), 0.80 (m, 18H), −0.01 (s, 18H), −0.13 (s, 9H)

MS: m/z 1129.36 [(M+1)⁺]

### Example 1

An ITO glass substrate was cut to a size of 50 millimeters (mm)×50 mm×0.5 mm. Then, the glass substrate was sonicated in acetone, isopropyl alcohol, and pure water for about 15 minutes in each solvent, and cleaned by exposure to ultraviolet rays with ozone for 30 minutes.

Then, a hole injection layer was formed on an ITO electrode (anode) that is on the glass substrate by vacuum-depositing m-MTDATA at a deposition rate of about 1 Angstroms per second (Å/sec) to have a thickness of about 600 Å. A hole transport layer was formed on the hole injection layer by vacuum-depositing α-NPD at a deposition rate of about 1 Å/sec to have a thickness of about 250 Angstroms (Å).

An emission layer was formed on the hole transport layer by co-depositing Compound 1 (dopant) and CBP (host) at a deposition rate of about 0.1 Å/sec and 1 Å/sec, respectively, to have a thickness of about 400 Å.

A hole blocking layer was formed on the emission layer by vacuum-depositing BAlq at a deposition rate of 1 Å/sec to have a thickness of about 50 Å. Then, an electron transport layer was formed on the hole blocking layer by vacuum-depositing Alq₃ to have a thickness of about 300 Å. An electron injection layer was formed on the electron transport layer by vacuum-depositing LiF to have a thickness of about 10 Å. A second electrode (cathode) was formed on the electron injection layer by vacuum-depositing Al to have a thickness of about 1,200 Å. Accordingly, the manufacture of an organic light-emitting device was completed, in which the organic light-emitting device included a structure of ITO/m-MTDATA (600 Å)/α-NPD (250 Å)/CBP+10% (Compound 2) (400 Å)/Balq (50 Å)/Alq₃ (300 Å)/LiF (10 Å)/Al (1,200 Å).

### Examples 2 to 4 and Comparative Examples 1 to 3

An organic light-emitting device was manufactured in the same manner as in Example 1, except that Compounds listed in Table 2 were used instead of Compound 1 as a dopant in the formation of the emission layer.

### Evaluation Example 1

### Evaluation of Characteristics of Organic Light-Emitting Device

Driving voltage, efficiency, color-coordination, maximum efficiency, and a full width at half maximum (FWHM) and a maximum emission wavelength of an EL spectrum of organic light-emitting devices manufacture in Examples 1 to 4 and Comparative Examples 1 to 3 were evaluated. The results thereof are shown in Table 2. A Keithley 2400 current voltmeter and a luminance meter (Minolta Cs-1000A) were used in evaluation.

TABLE 2

| | | | | | | | Maximum |
|---|---|---|---|---|---|---|---|
| | | Driving | Efficiency | CIE x | Maximum | | emission |
| | | voltage | (Cd/A) | (at | efficiency | FWHM | wavelength |
| | Dopant | (V) | (at driving voltage) | driving voltage) | (Cd/A) | (nm) | (nm) |
| Example 1 | Compound 1 | 4.7 | 52.3 | 0.356 | 74.8 | 76.9 | 520 |
| Example 2 | Compound 2 | 4.9 | 50.7 | 0.347 | 73.5 | 76.6 | 518 |
| Example 3 | Compound 7 | 5.0 | 51.4 | 0.367 | 74.2 | 77.0 | 523 |
| Example 4 | Compound | 4.7 | 54.5 | 0.340 | 78.5 | 76.3 | 516 |
| | 26 | | | | | | |
| Comparative | Compound | 5.4 | 49.2 | 0.374 | 57.7 | 81.8 | 528 |
| Example 1 | R1 | | | | | | |
| Comparative | Compound | 5.2 | 42.0 | 0.331 | 55.0 | 77 | 520 |
| Example 2 | R2 | | | | | | |
| Comparative | Compound | 5.4 | 39.0 | 0.315 | 46.5 | 84 | 513 |
| Example 3 | R3 | | | | | | |

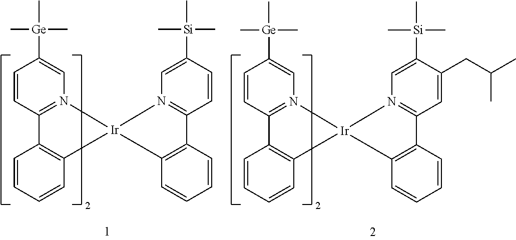

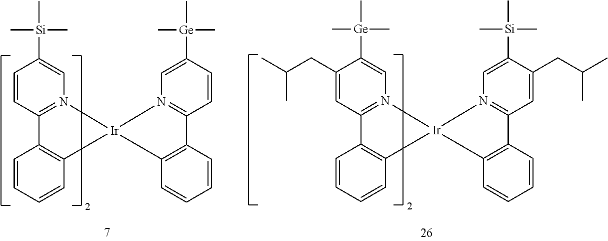

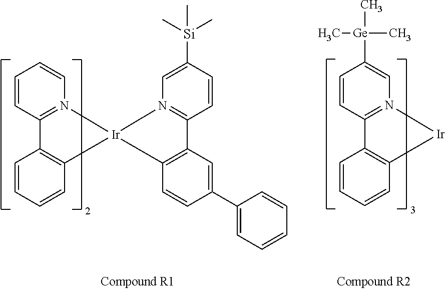

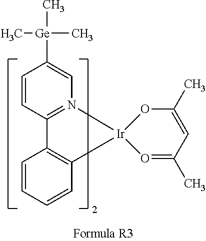

Referring to Table 2, it was found that the CIE x-coordinates of the organic light-emitting devices according to Examples 1 to 4 were in a range of about 0.340 to about 0.367. However, since a CIE x-coordinate of the organic light-emitting device according to Comparative Example 1 was 0.374, it was verified that the organic light-emitting devices according to Examples 1 to 4 have excellent color coordination characteristics, compared to the organic light-emitting device according to Comparative Example 1. In addition, it was confirmed that the efficiency and maximum efficiency of the organic light-emitting devices according to Examples 1 to 4 are excellent, compared to those of the organic light-emitting devices according to Comparative Examples 2 and 3.

As described above, the organometallic compound according to an exemplary embodiment has excellent electric characteristics and thermal stability. Accordingly, an organic light-emitting device including the organometallic compound may have a low driving voltage, high efficiency, and high color coordination.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the FIGURES, it will be understood by those of ordinary skill in the art that various changes in form and details may be made therein without departing from the spirit and scope as defined by the following claims.

What is claimed is:

1. An organometallic compound represented by Formula 1: 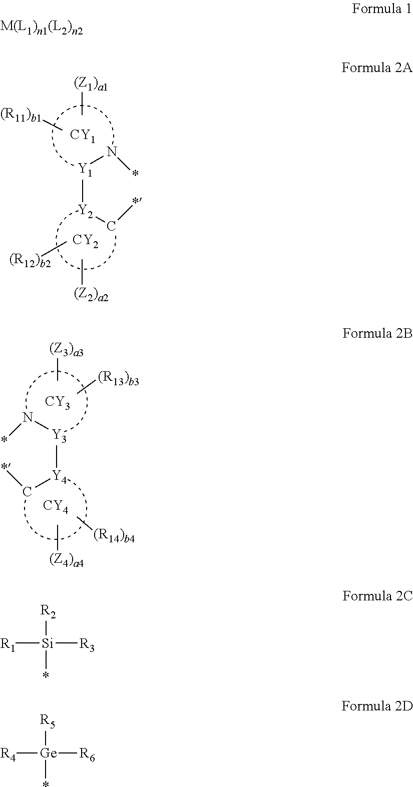
wherein, in Formula 1, M is selected from Ir, Pt, Os Ti, Zr, Hf, Eu, Tb, Tm, and Rh,
in Formula 1, L₁ is selected from ligands represented by Formula 2A,
in Formula 1, L₂ is selected from ligands represented by Formula 2B,
in Formula 1, L₁ and L₂ are different from each other,
in Formula 1, n1 and n2 are each independently selected from 1 and 2, and a sum of n1 and n2 is selected from 2 and 3,
in Formula 2A, Y₁ and Y₂ are each independently selected from C and N, and in Formula 2B, Y₃ and Y₄ are each independently selected from C and N,
in Formulae 2A and 2B, CY₁ and CY₃ are each independently selected from a C₁-C₆₀ heterocyclic group, CY₂ and CY₄ are each independently selected from a C₅-C₆₀ carbocyclic group and a C₁-C₆₀ heterocyclic group, wherein CY₁ and CY₂ are optionally bound to each other additionally via a first linking group, and wherein CY₃ and CY₄ are optionally bound to each other additionally via a second linking group,
in Formulae 2A and 2B, Z₁ to Z₄ are each independently selected from a hydrogen, a deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₂-C₆₀ heteroaryloxy group, a substituted or unsubstituted C₂-C₆₀ heteroarylthio group, a substituted or unsubstituted C₃-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —B(Q₃)(Q₄), and —P(═O)(Q₅)(Q₆),
a1 to a4 are each independently an integer selected from 0 to 4,
in Formula 2A, R₁₁ and R₁₂ are each independently selected from groups represented by Formula 2C, b1 and b2 are each independently an integer selected from 0 to 3, and a sum of b1 and b2 is 1 or greater,
in Formula 2B, R₁₃ and R₁₄ are each independently selected from groups represented by Formula 2D, b3 and b4 are each independently an integer selected from 0 to 3, and a sum of b3 and b4 is 1 or greater,
in Formulae 2C and 2D, R₁ to R₆ are each independently selected from a hydrogen, a deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₂-C₆₀ heteroaryloxy group, a substituted or unsubstituted C₂-C₆₀ heteroarylthio group, a substituted or unsubstituted C₃-C₆₀ heteroarylalkyl group, a substituted or unsubstituted monovalent non-aromatic condensed polycyclic group, a substituted or unsubstituted monovalent non-aromatic condensed heteropolycyclic group, and —Si(Q₅₁)(Q₅₂)(Q₅₃),
when b3 is 1 or greater, at least one selected from R₄ to R₆ in Formula 2D is optionally bound to adjacent Z₃ to form a C₂-C₁₀ saturated or unsaturated ring,
when b4 is 1 or greater, at least one selected from R₄ to R₆ in Formula 2D is optionally bound to adjacent Z₄ to form a C₂-C₁₀ saturated or unsaturated ring,
in Formulae 2A and 2B, * and *′ each indicates a binding site to M in Formula 1, * in Formula 2C indicates a binding site to CY₁ or CY₂ in Formula 2A, and * in Formula 2D indicates a binding site to CY₃ or CY₄ in Formula 2B,
at least one of substituents of the substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₇-C₆₀ arylalkyl group, substituted C₁-C₆₀ heteroaryl group, substituted C₂-C₆₀ heteroaryloxy group, substituted C₂-C₆₀ heteroarylthio group, substituted C₃-C₆₀ heteroarylalkyl group, substituted monovalent non-aromatic condensed polycyclic group, and substituted monovalent non-aromatic condensed heteropolycyclic group is selected from:
a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, a monovalent non-aromatic condensed heteropolycyclic group, —N(Q₁₁)(Q₁₂), —B(Q₁₃)(Q₁₄), and —P(═O)(Q₁₅)(Q₁₆);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, and a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, and a monovalent non-aromatic condensed heteropolycyclic group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₂-C₆₀ heteroaryloxy group, a C₂-C₆₀ heteroarylthio group, a C₃-C₆₀ heteroarylalkyl group, a monovalent non-aromatic condensed polycyclic group, a monovalent non-aromatic condensed heteropolycyclic group, —N(Q₂₁)(Q₂₂), —B(Q₂₃)(Q₂₄), and —P(═O)(Q₂₅)(Q₂₆); and
—N(Q₃₁)(Q₃₂), —B(Q₃₃)(Q₃₄), and —P(═O)(Q₃₅)(Q₃₆),
wherein Q₁ to Q₆, Q₁₁ to Q₁₆, Q₂₁ to Q₂₆, Q₃₁ to Q₃₆, and Q₅₁ to Q₅₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₂-C₆₀ heteroaryloxy group, a substituted or unsubstituted C₂-C₆₀ heteroarylthio group, a substituted or unsubstituted C₃-C₆₀ heteroarylalkyl group, a substituted or unsubstituted monovalent non-aromatic condensed polycyclic group, and a substituted or unsubstituted monovalent non-aromatic condensed heteropolycyclic group.

2. The organometallic compound of claim 1, wherein
in Formulae 2A and 2B,
CY₁ and CY₃ are each independently selected from a pyridine, a pyrimidine, a pyrazine, a triazine, a triazole, an imidazole, and a pyrazole, and
CY₂ and CY₄ are each independently selected from a benzene, a naphthalene, a pyridine, a pyrimidine, a pyrazine, a carbazole, a dibenzofuran, and a dibenzothiophene.

3. The organometallic compound of claim 1, wherein
in Formulae 2A and 2B, Z₁ to Z₄ are each independently selected from
a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, and a C₁-C₂₀ alkoxy group;
a C₁-C₂₀ alkyl group and a C₁-C₂₀ alkoxy group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl (adamantyl) group, a norbornanyl (norbornyl) group, a norbornenyl group, a cyclopentenyl group, a cyclohexenyl group, a cycloheptenyl group, a phenyl group, a naphthyl group, a pyridinyl group, and a pyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, each substituted with at least one selected from a deuterium, —F, —Cl, —Br, —I, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group; and
—B(Q₃)(Q₄) and —P(═O)(Q₅)(Q₆);
wherein Q₃ to Q₆ are each independently selected from
—CH₃, -CD₃, -CD₂H, -CDH₂, —CH₂CH₃, —CH₂CD₃, —CH₂CD₂H, —CH₂CDH₂, —CHDCH₃, —CHDCD₂H, —CHDCDH₂, —CHDCD₃, -CD₂CD₃, -CD₂CD₂H, and -CD₂CDH₂;
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group; and
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group, each substituted with at least one selected from a deuterium, a C₁-C₁₀ alkyl group, and a phenyl group.

4. The organometallic compound of claim 1, wherein
in Formulae 2A and 2B, Z₁ to Z₄ are each independently selected from
a hydrogen, a deuterium, —F, a cyano group, a nitro group, —SF₅, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group;
a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group, each substituted with at least one selected from a deuterium, —F, -CD₃, -CD₂H, -CDH₂, —CF₃, —CF₂H, —CFH₂, a cyano group, a nitro group, a C₁-C₁₀ alkyl group, a C₁-C₁₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group; and
—B(Q₃)(Q₄) and —P(═O)(Q₅)(Q₆),
wherein Q₃ to Q₆ are each independently selected from
—CH₃, -CD₃, -CD₂H, -CDH₂, —CH₂CH₃, —CH₂CD₃, —CH₂CD₂H, —CH₂CDH₂, —CHDCH₃, —CHDCD₂H, —CHDCDH₂, —CHDCD₃, -CD₂CD₃, -CD₂CD₂H, and -CD₂CDH₂;
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group; and
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group, each substituted with at least one selected from a deuterium, a C₁-C₁₀ alkyl group, and a phenyl group.

5. The organometallic compound of claim 1, wherein
in Formulae 2A and 2B, Z₁ to Z₄ are each independently selected from a hydrogen, a deuterium, —F, a cyano group, a nitro group, —SF₅, —CH₃, -CD₃, -CD₂H, -CDH₂, —CF₃, —CF₂H, —CFH₂, groups represented by Formulae 9-1 to 9-19, and groups represented by Formulae 10-1 to 10-36: 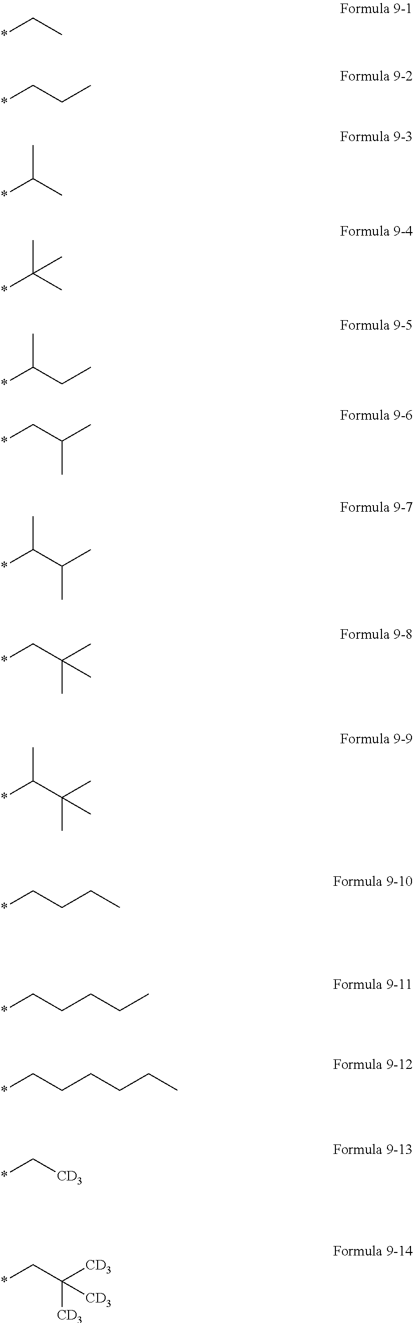 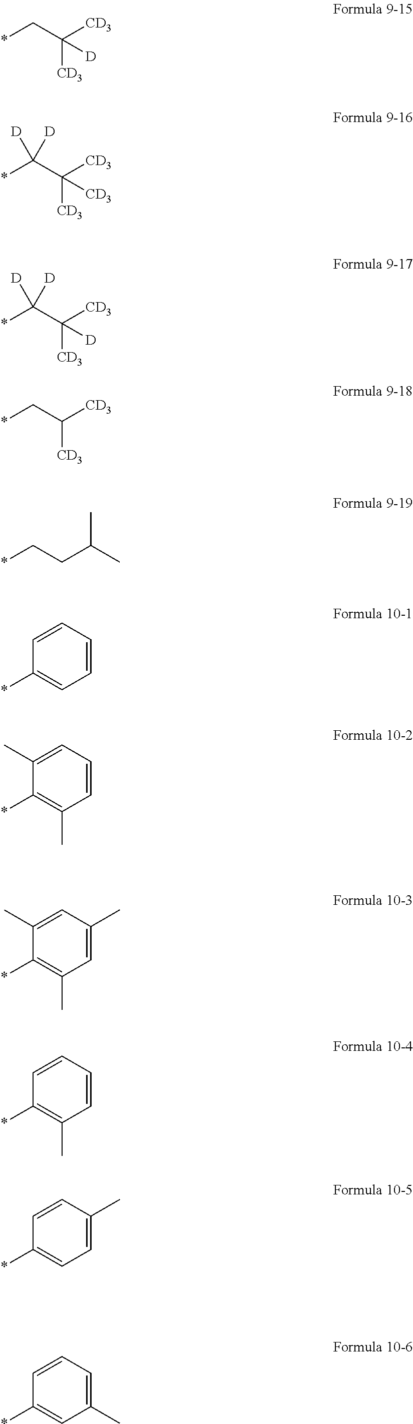 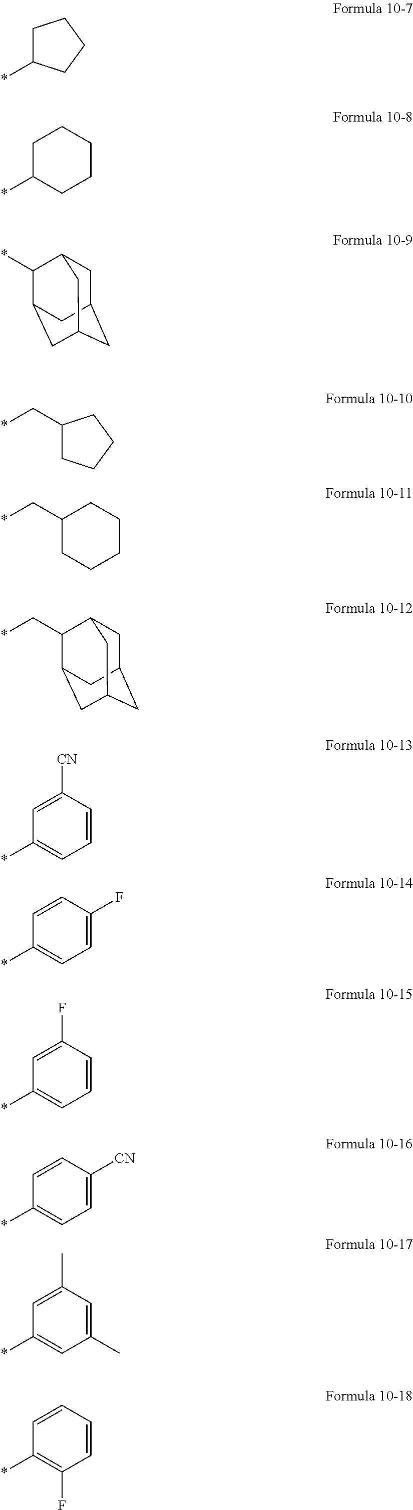 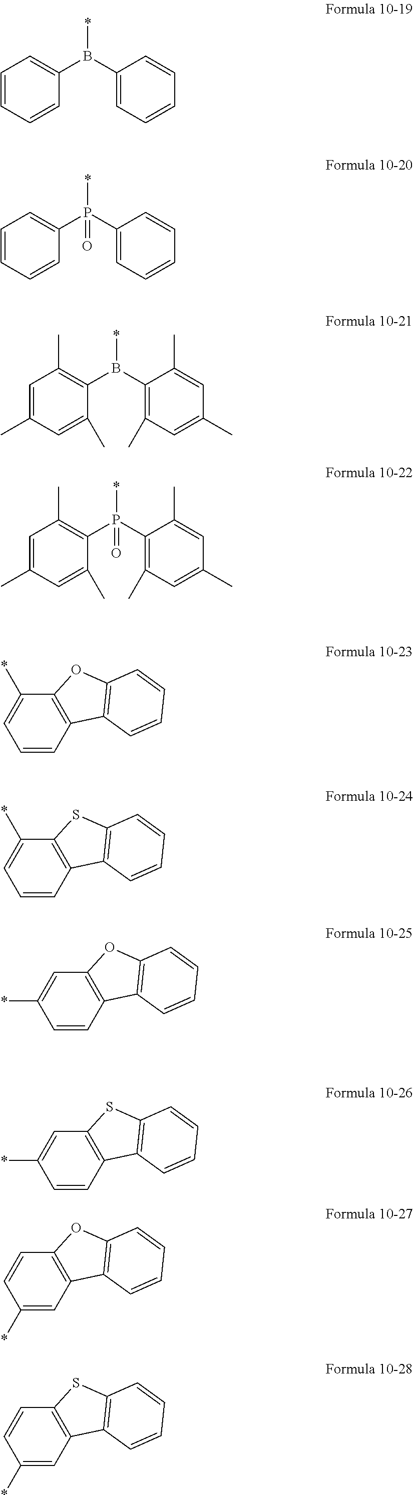 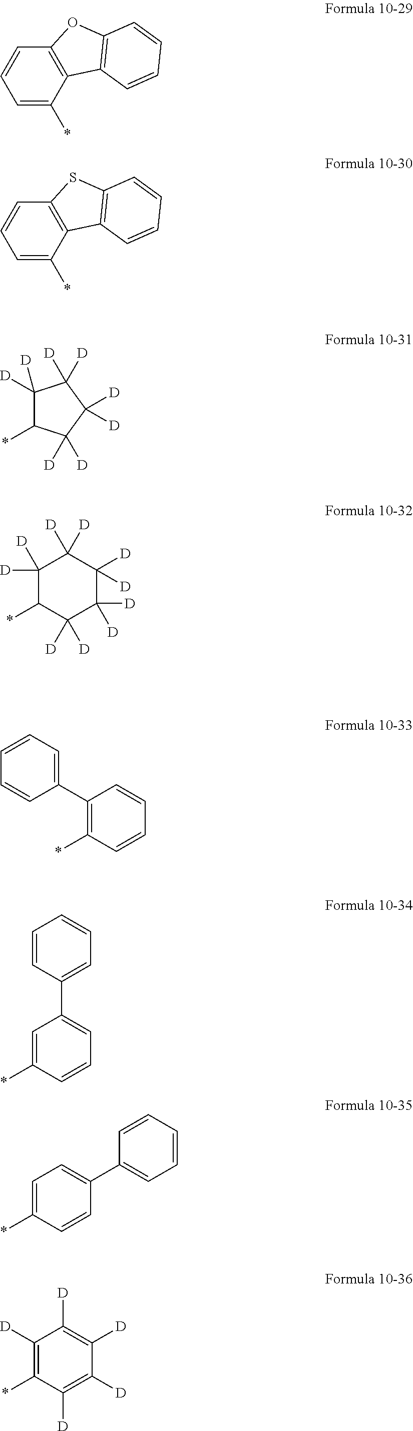
wherein, in Formulae 9-1 to 9-19 and 10-1 to 10-36, * indicates a binding site to a neighboring atom,
and wherein b1 and b3 are 1, and b2 and b4 are 0.

6. The organometallic compound of claim 1, wherein
in Formulae 2C and 2D, R₁ to R₆ are each independently selected from
a hydrogen, a deuterium, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group; and
a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group, each substituted with at least one selected from a deuterium, —F, -CD₃, -CD₂H, -CDH₂, —CF₃, —CF₂H, —CFH₂, a cyano group, a nitro group, a C₁-C₁₀ alkyl group, a C₁-C₁₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group.

7. The organometallic compound of claim 1, wherein
in Formulae 2C and 2D, R₁ to R₆ are each independently selected from —CH₃, -CD₃, -CD₂H, -CDH₂, groups represented by Formulae 9-1 to 9-19, and a phenyl group: 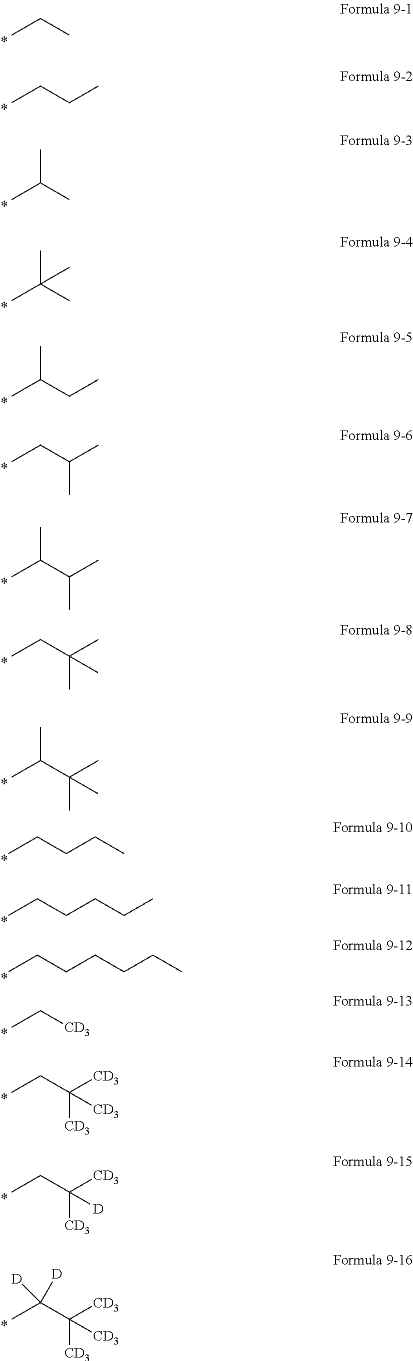 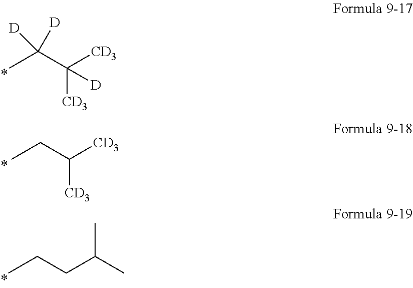
wherein, in Formulae 9-1 to 9-19, * indicates a binding site to a neighboring atom.

8. The organometallic compound of claim 1, wherein
in Formulae 2C and 2D,
R₁ to R₆ are each independently selected from —CH₃, -CD₃, -CD₂H, -CDH₂, groups represented by Formulae 9-1 to 9-19, and a phenyl group,
in Formula 2C,
R₁ to R₃ are identical to one another; or
R₁ and R₂ are different from each other, and R₁ and R₃ are identical to each other, and
in Formula 2D,
R₄ to R₆ are identical to one another; or
R₄ and R₅ are different from each other, and R₄ and R₆ are identical to each other: 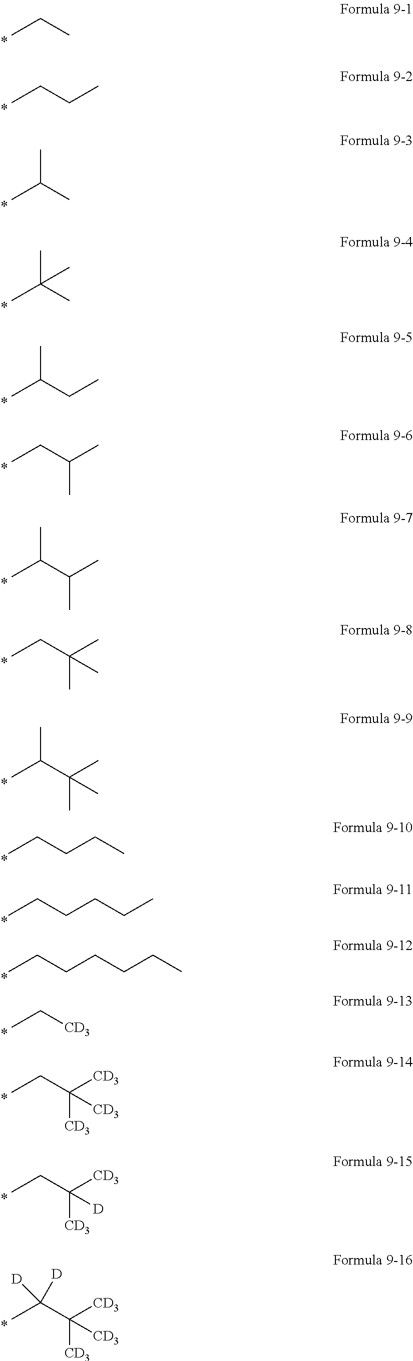 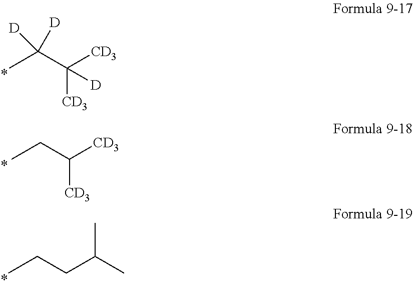
wherein, in Formulae 9-1 to 9-19, * indicates a binding site to a neighboring atom.

9. The organometallic compound of claim 1, wherein, in Formula 1, L₁ is selected from Formulae 3-1 to 3-130: 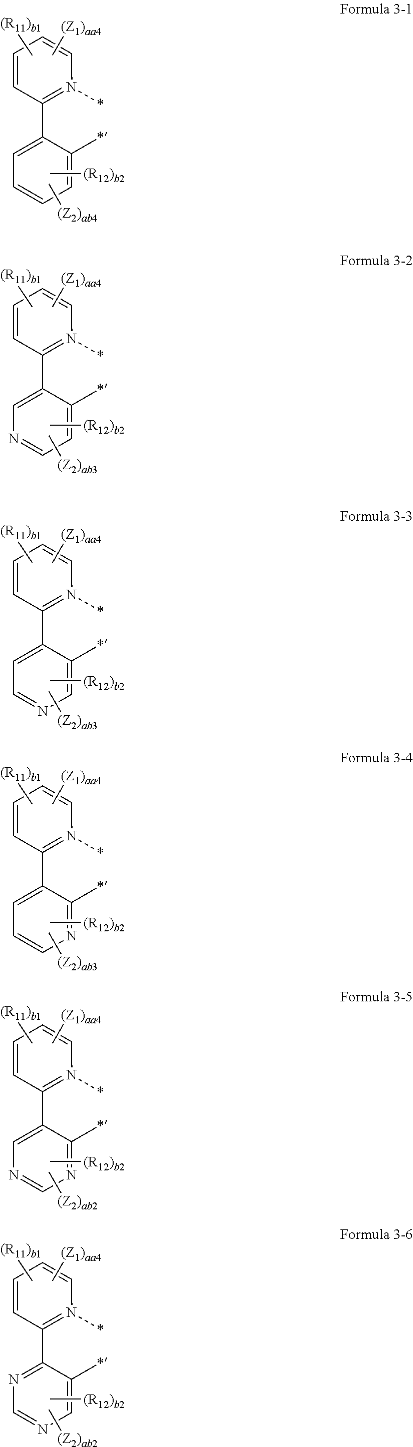 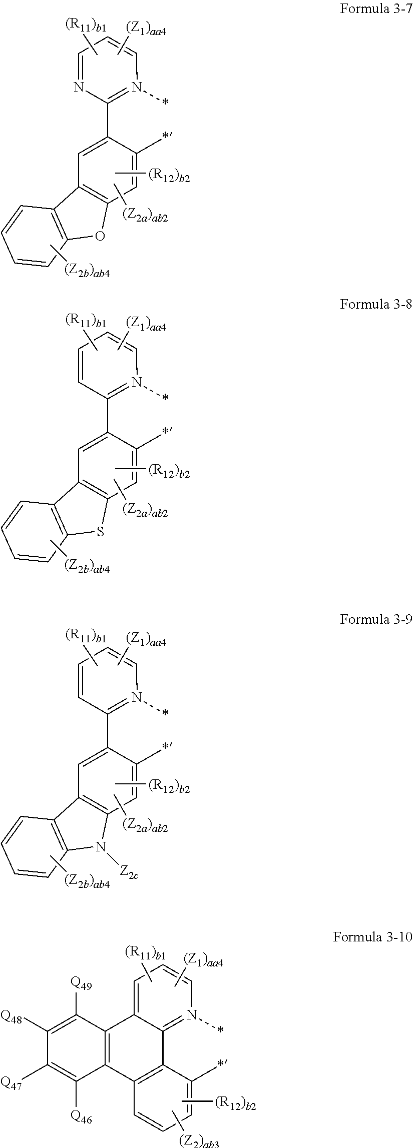 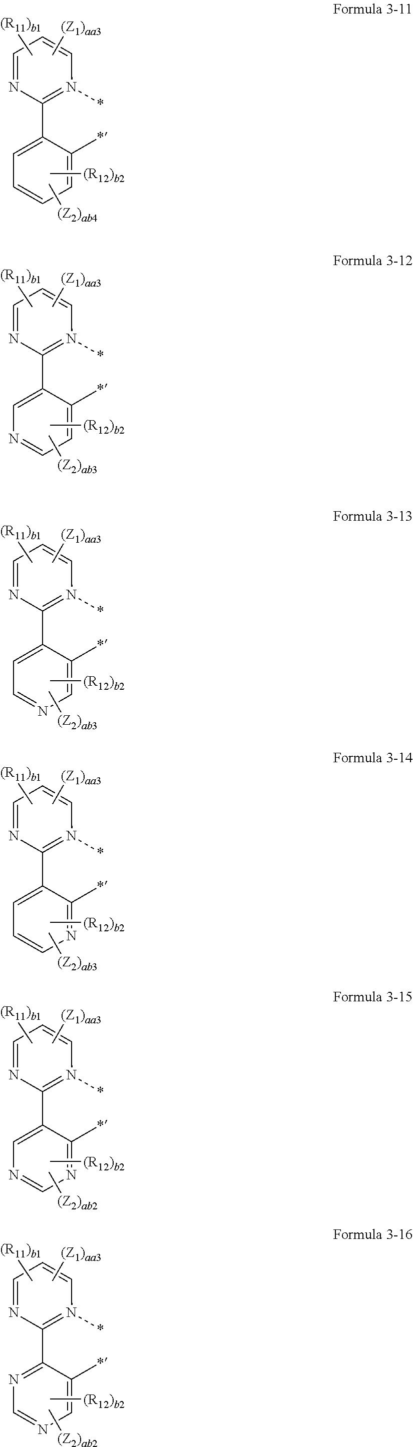 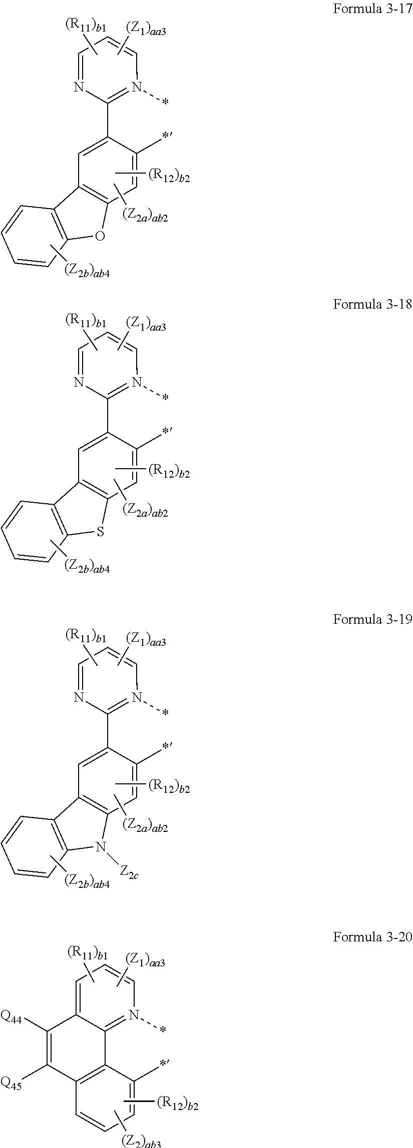 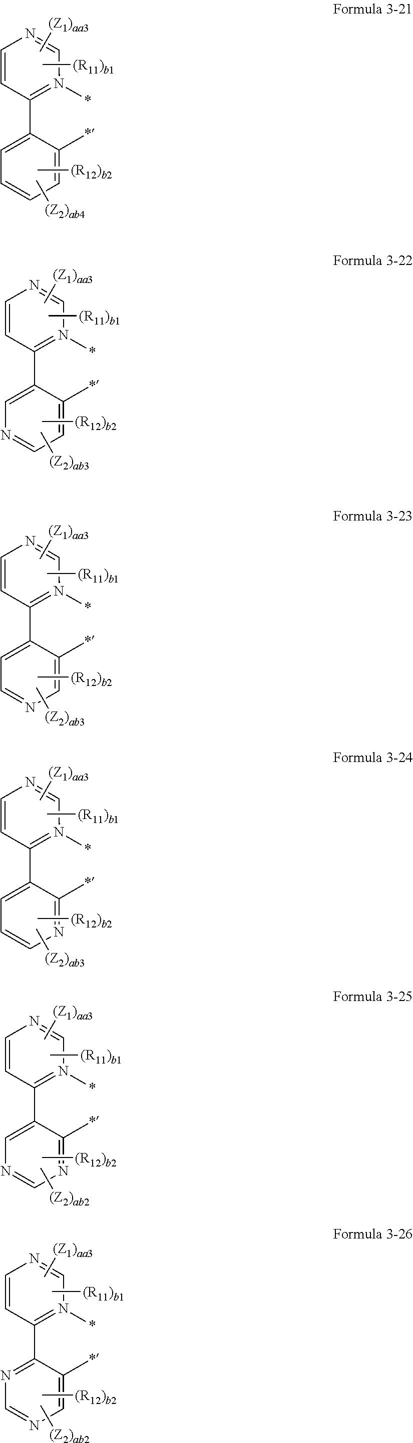 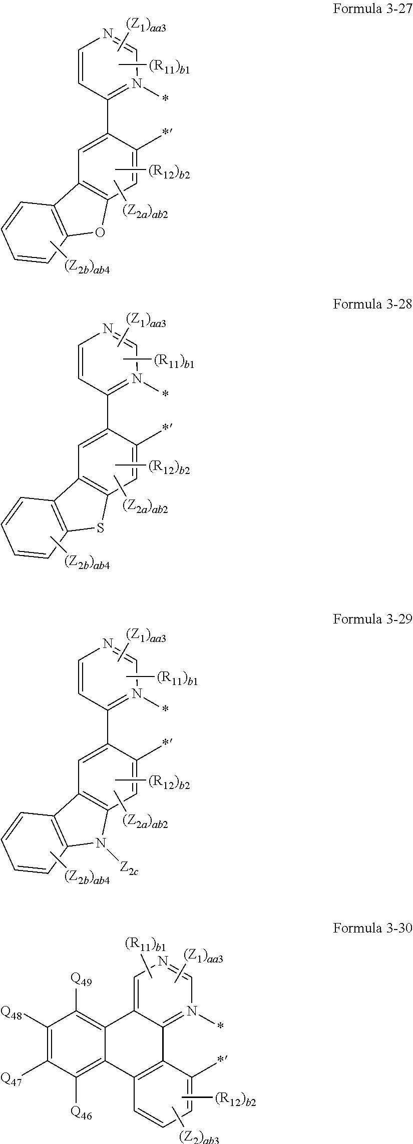 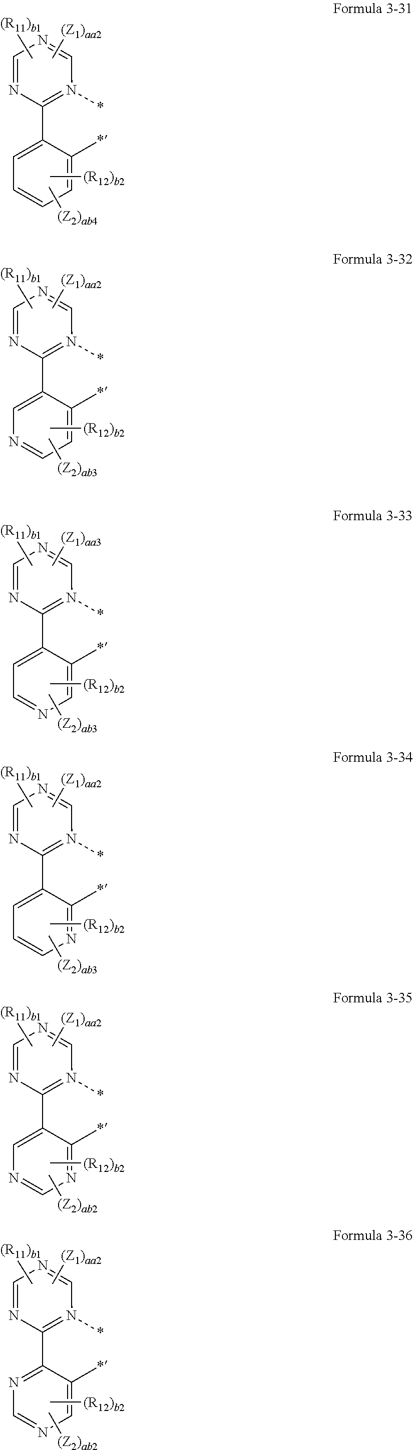 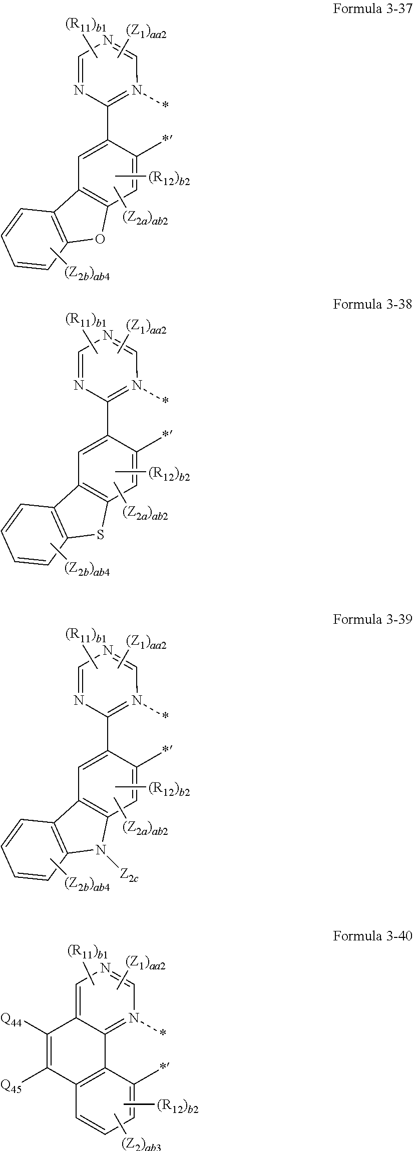 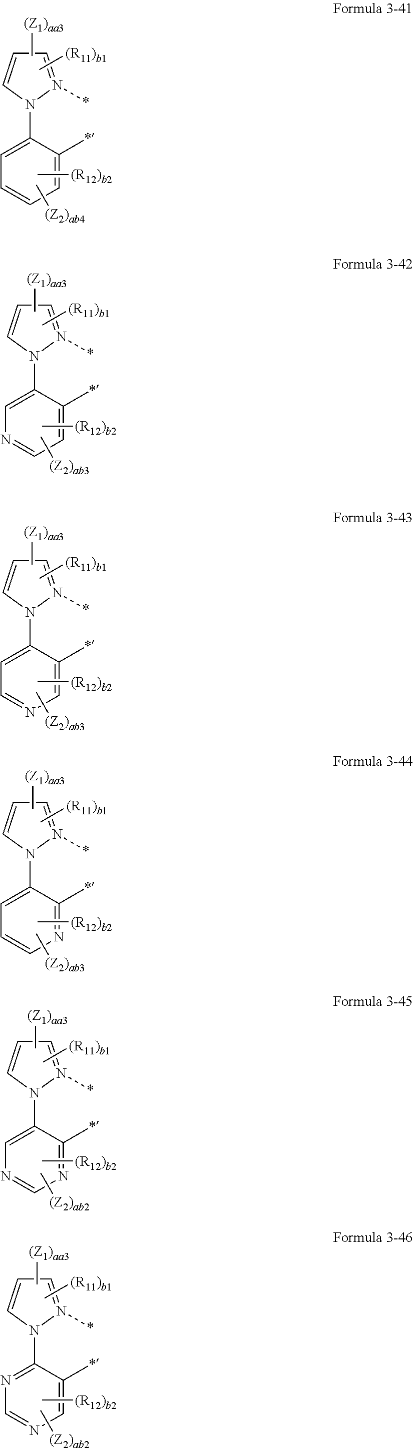 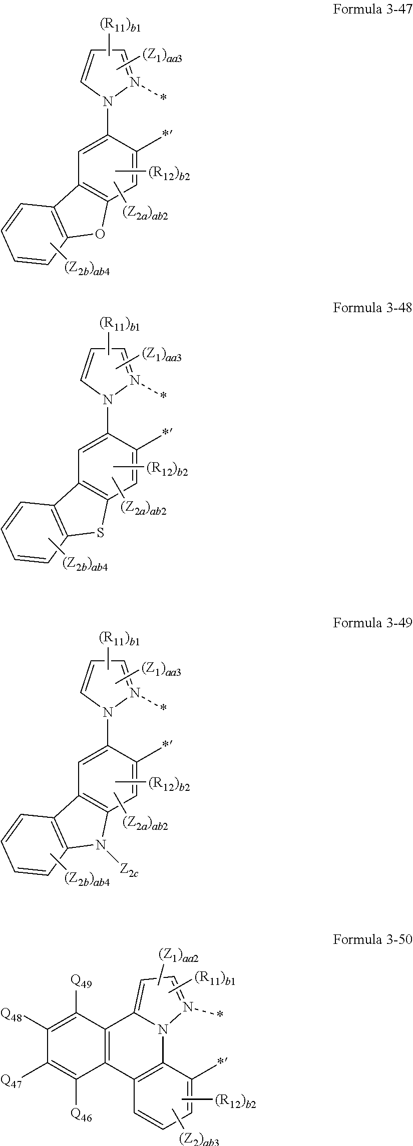 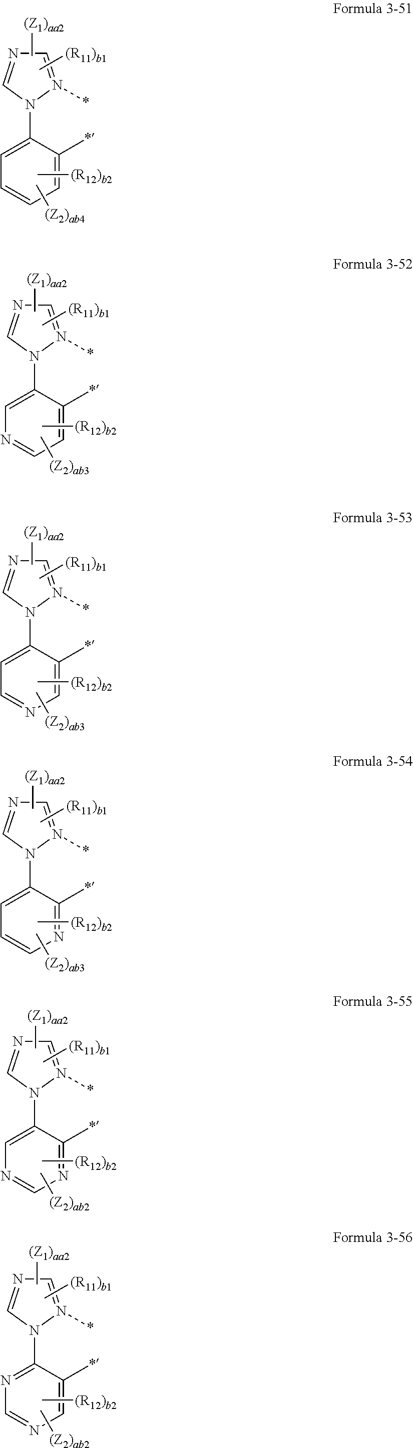 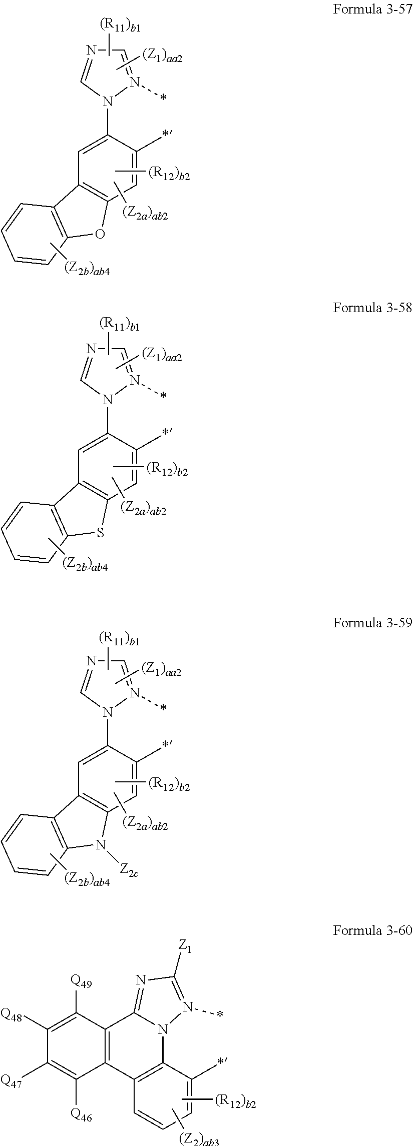 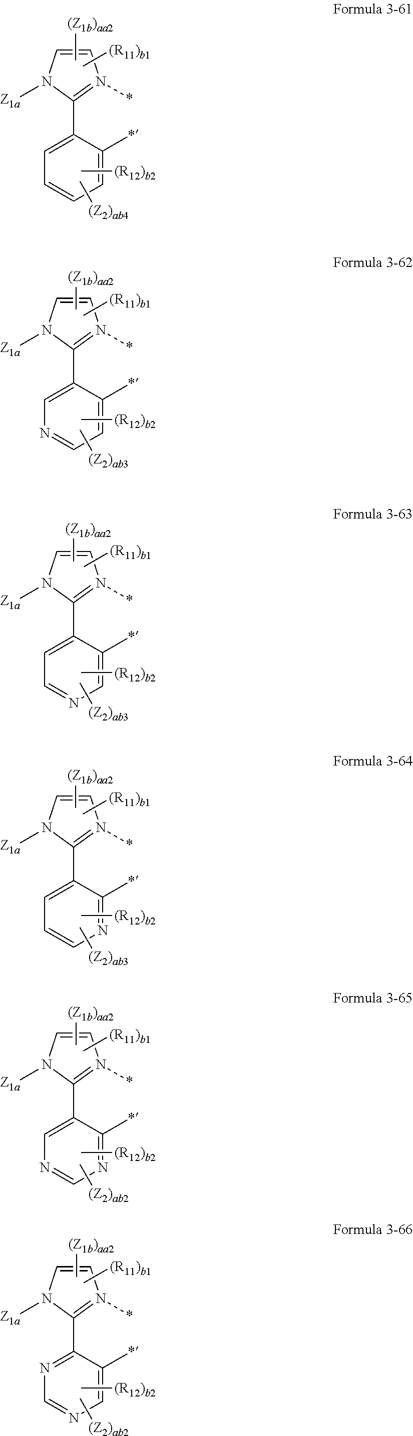 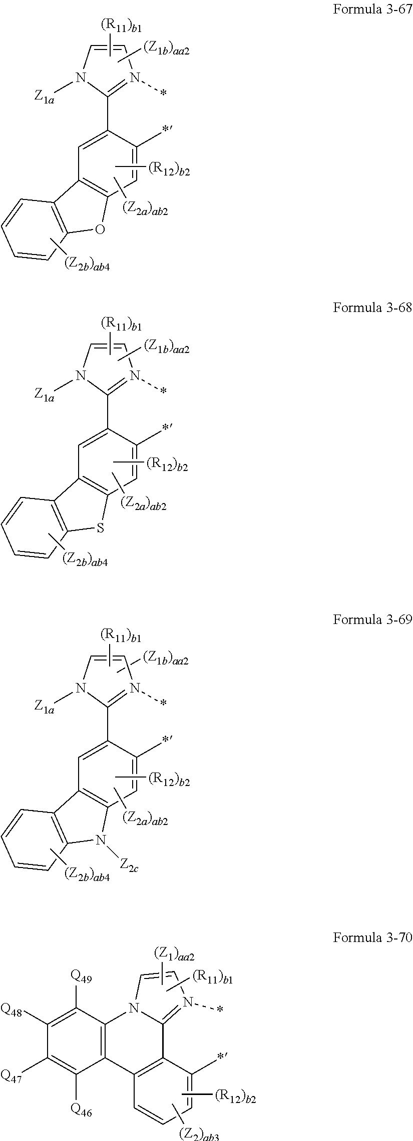 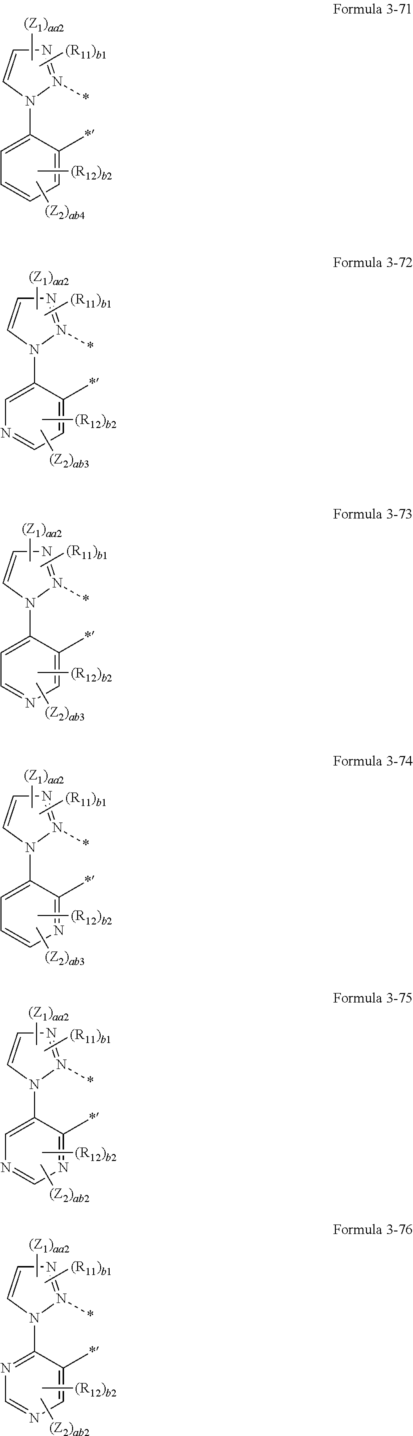 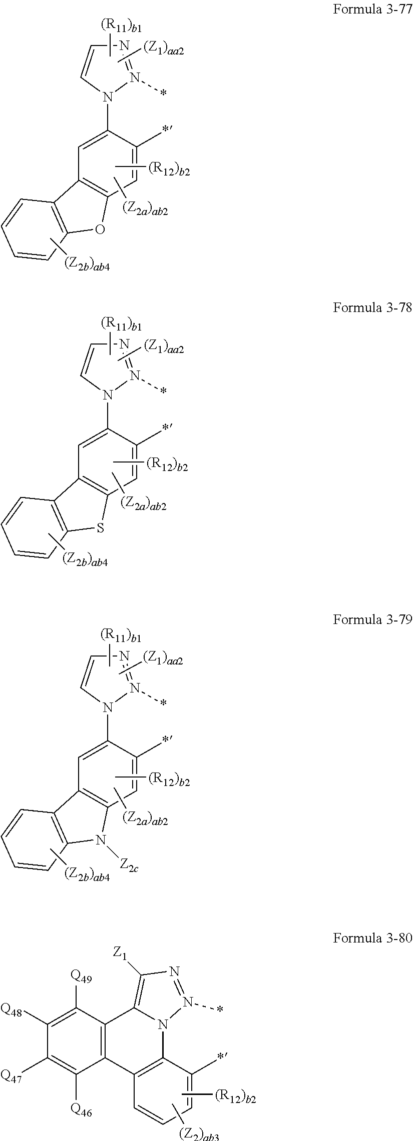 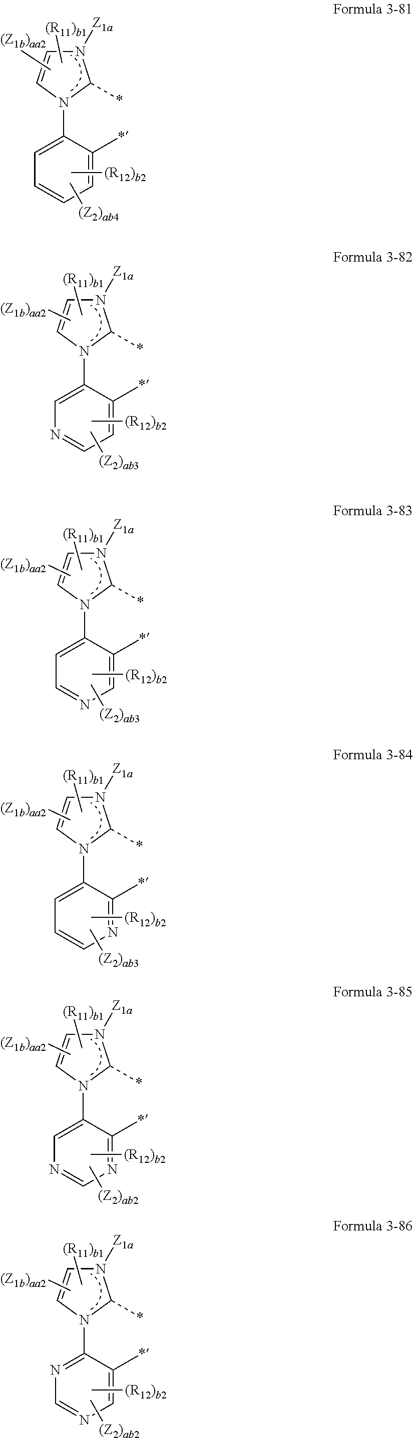 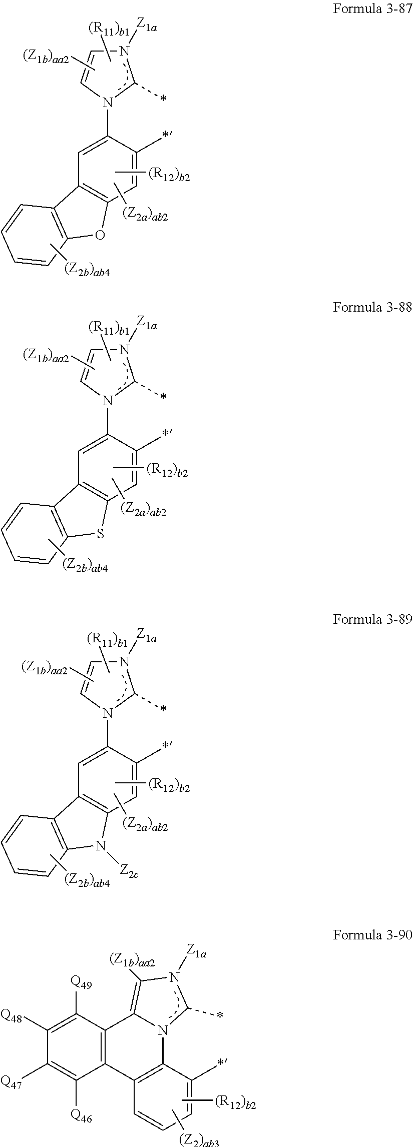 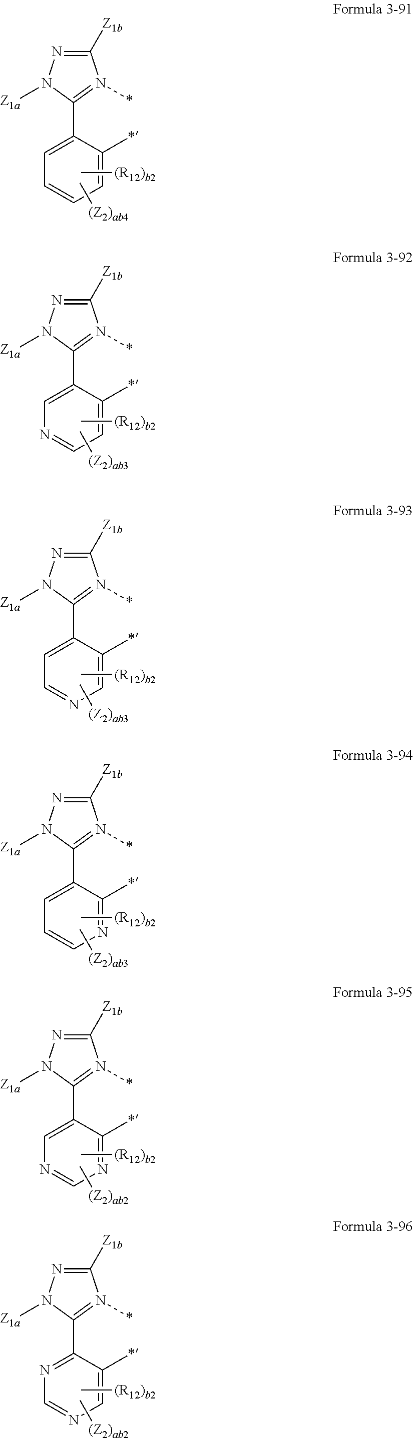 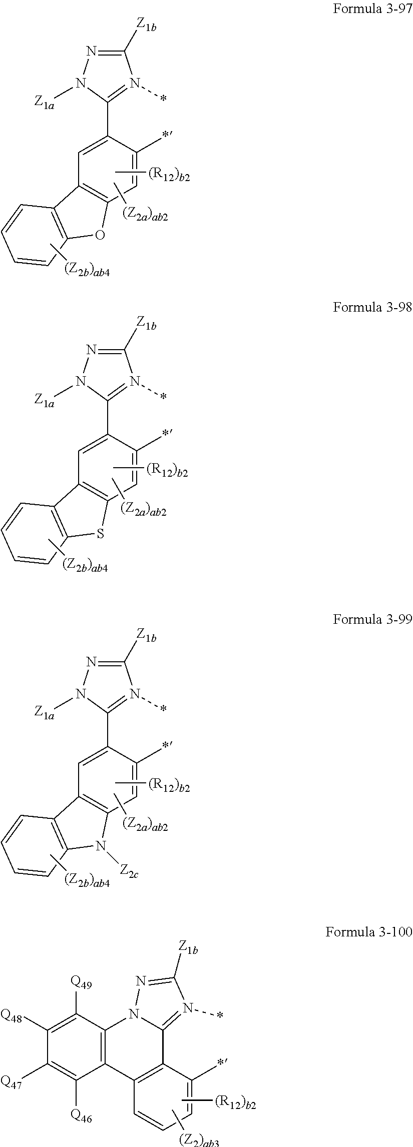 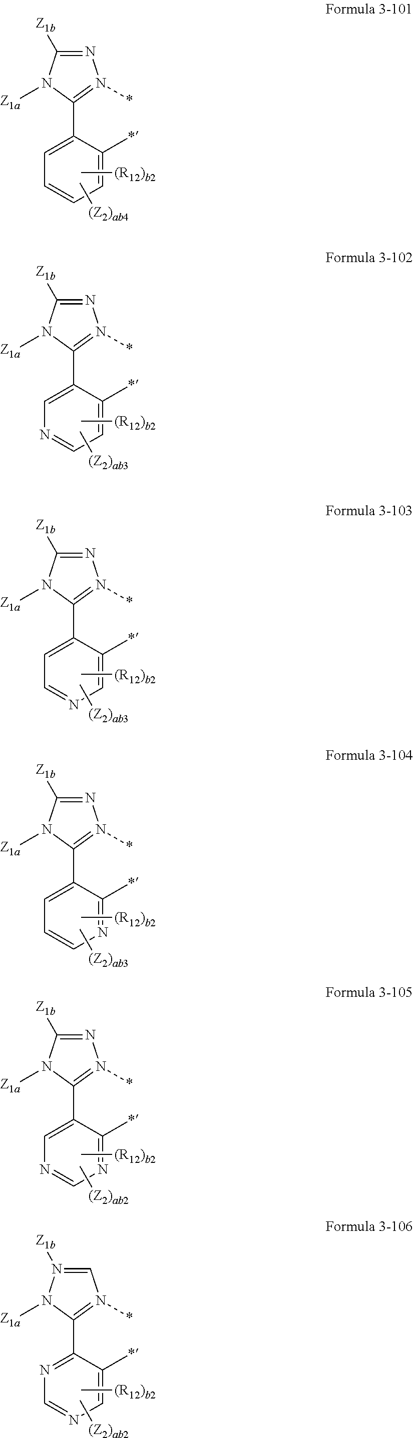 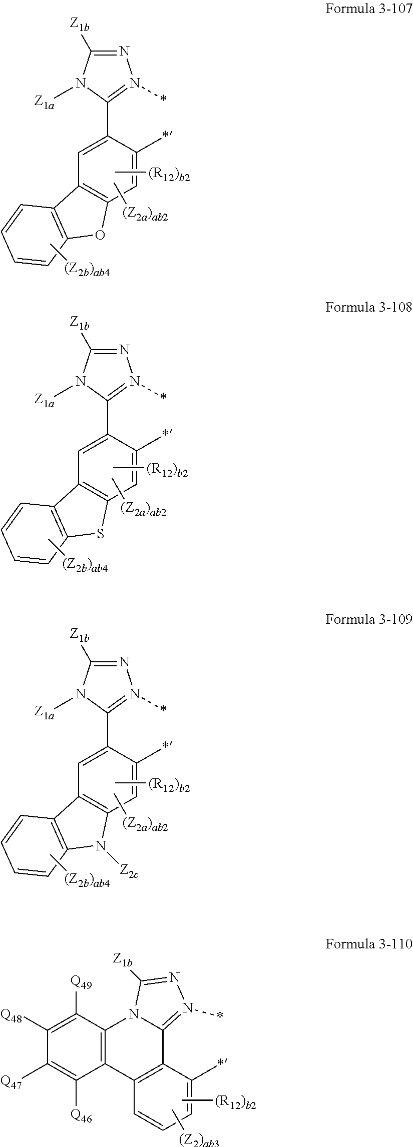 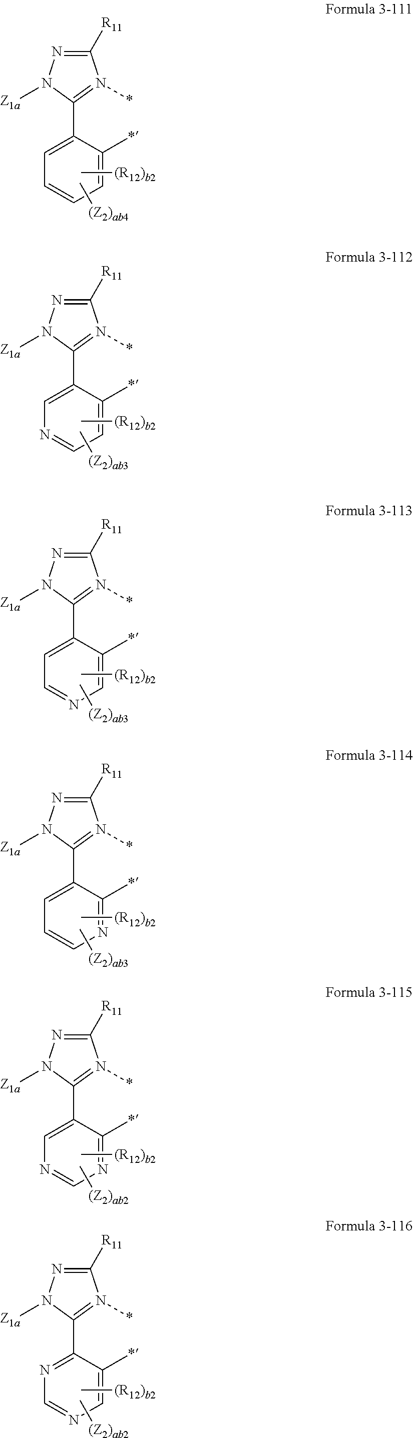 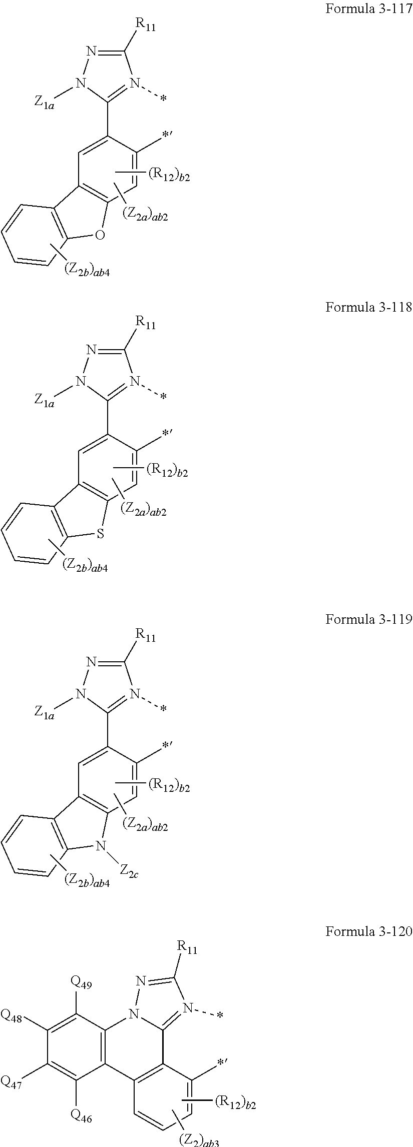 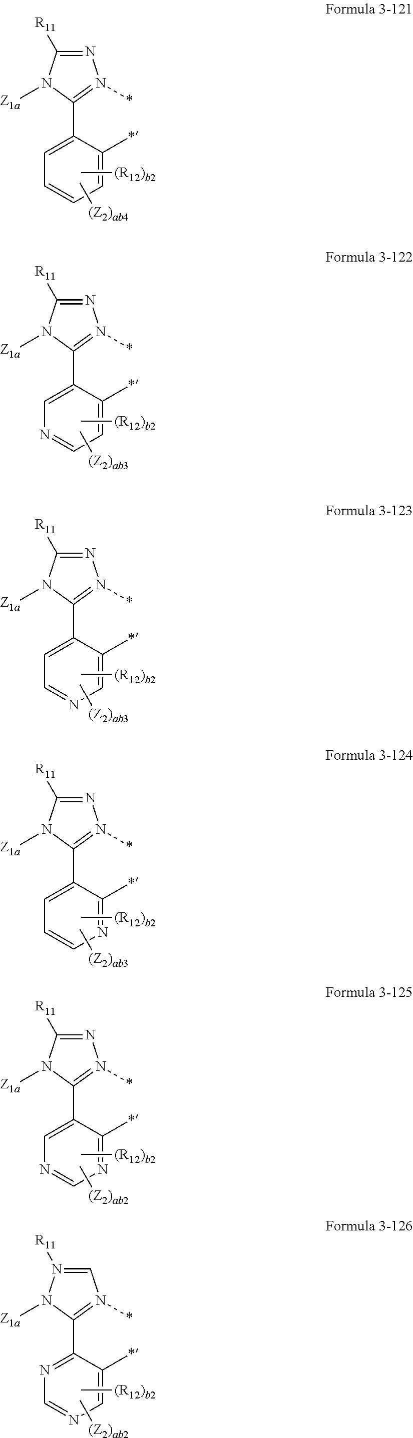 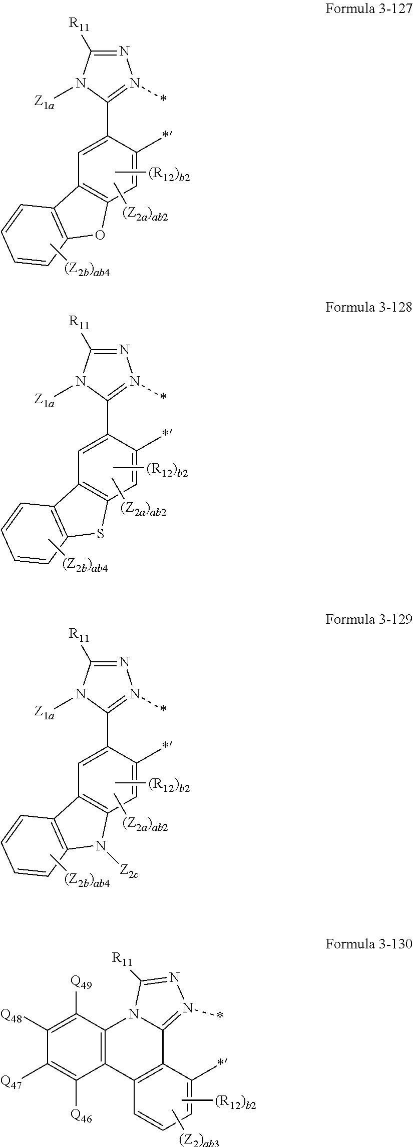
wherein, in Formulae 3-1 to 3-130,
Z₁ and Z₂ are the same as in claim 1,
Z₁ₐ and Z_{1b} are each independently the same as Z₁ in claim 1,
Z₂ₐ, Z_{2b}, and Z_{2b} are each independently the same as Z₂ in claim 1,
Q₄₄ to Q₄₉ are each independently selected from
a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;
a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a pyridinyl group, and a pyrimidinyl group; and
a phenyl group, a naphthyl group, a pyridinyl group, and a pyrimidinyl group
aa2 and ab2 are each independently selected from 1 and 2,
aa3 and ab3 are each independently an integer selected from 1 to 3,
aa4 and ab4 are each independently an integer selected from 1 to 4,
R₁₁ and R₁₂ are selected from groups represented by Formula 2C,
b1 and b2 are each independently selected from 0, 1, and 2, a sum of b1 and b2 is 1 or greater, and b2 in Formulae 1-111 to 1-130 is selected from 1 and 2, and
* and *′ each indicates a binding site to M.

10. The organometallic compound of claim 1, wherein
in Formula 1, L₁ is selected from ligands represented by Formulae 3-1A to 3-1J: 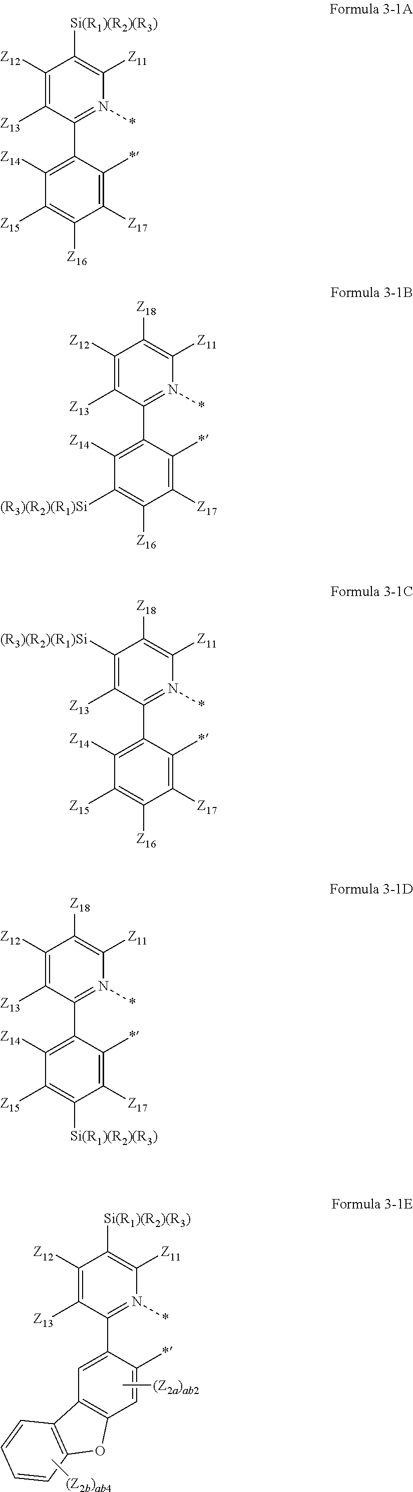 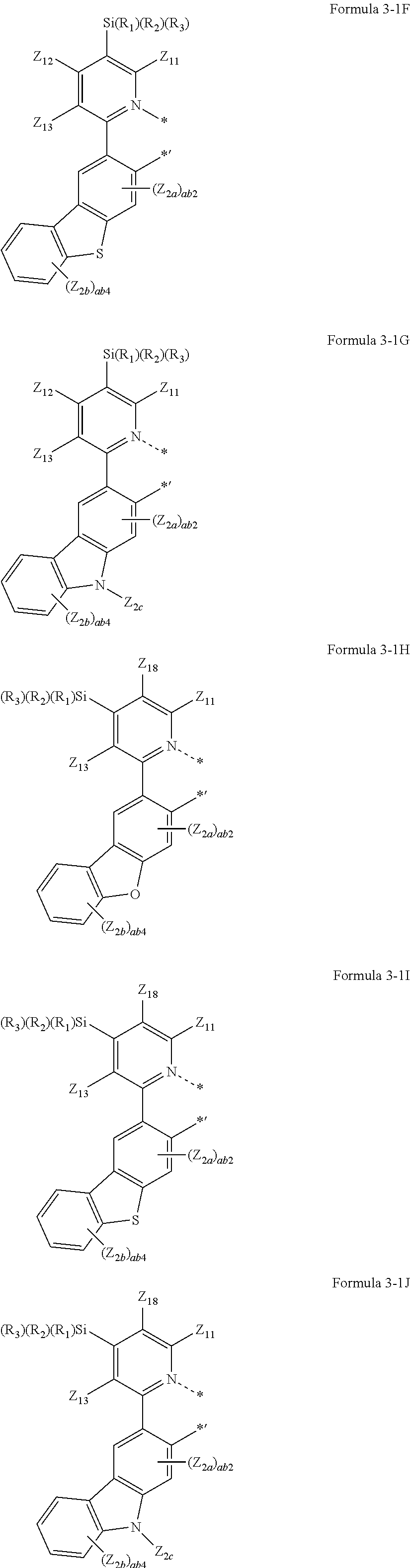
wherein, in Formulae 3-1A to 3-1J,
Z₁₁ to Z₁₃ and Z₁₈ are the same as Z₁ in claim 1,
Z₁₄ to Z₁₇ and Z₂ₐ to Z_{2c} are the same as Z₂ in claim 1,
ab2 is an integer selected from 0 to 2,
ab4 is an integer selected from 0 to 4,
R₁ to R₃ are the same as in claim 1, and
* and *′ each indicates a binding site to M in Formula 1.

11. The organometallic compound of claim 10, wherein, in Formula 1, L₁ is selected from ligands represented by Formulae 3-1A and 3-1E, and Z₁₂ in Formula 3-1A is not a hydrogen.

12. The organometallic compound of claim 1, wherein, in Formula 1, L₁ is selected from ligands represented by Formulae 3-1(1) to 3-1(114): 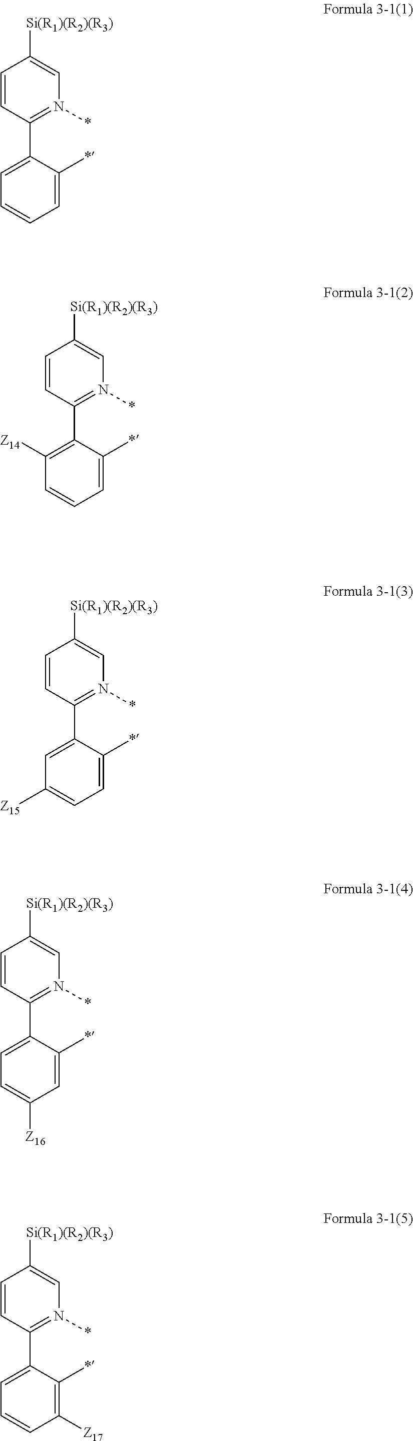 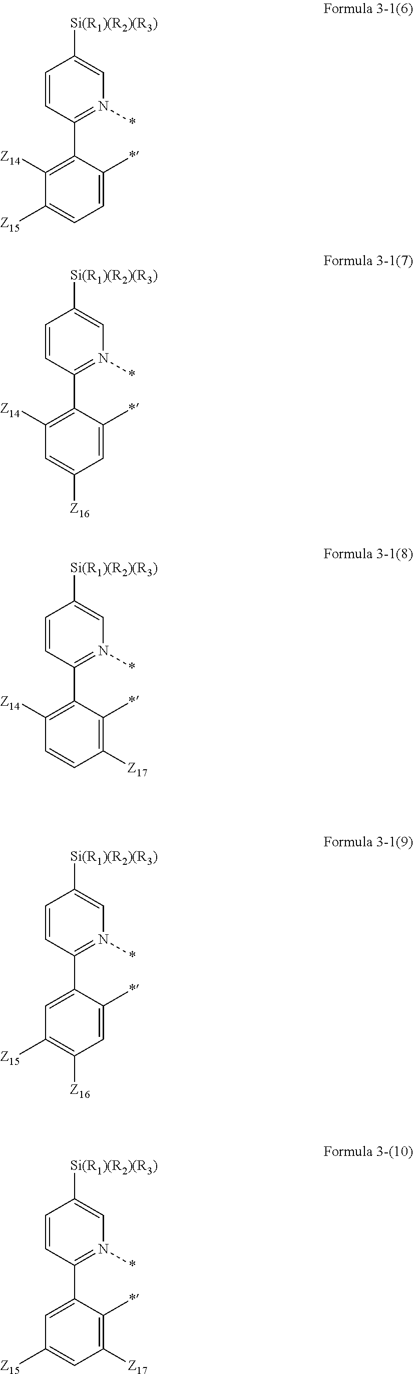 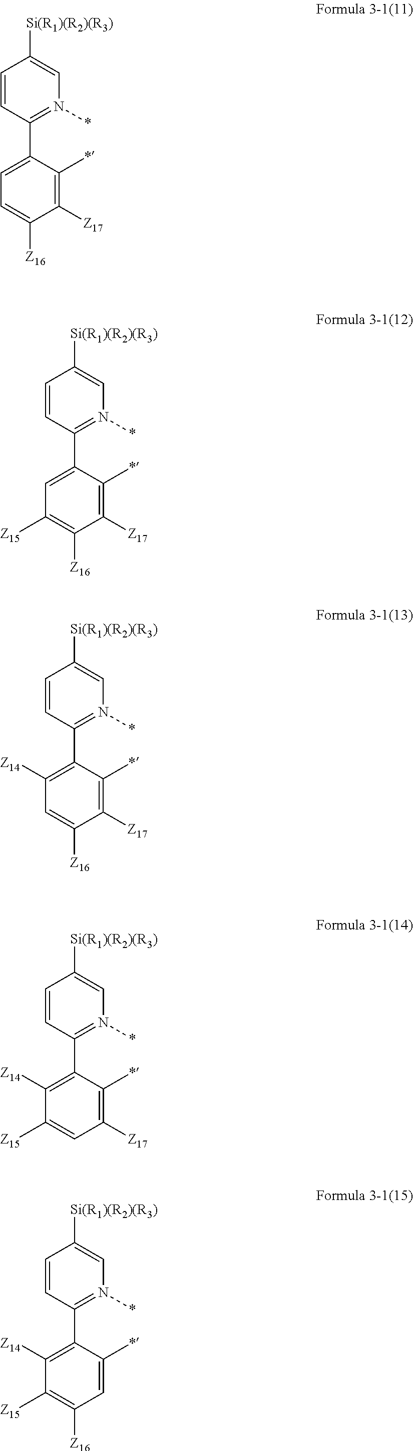 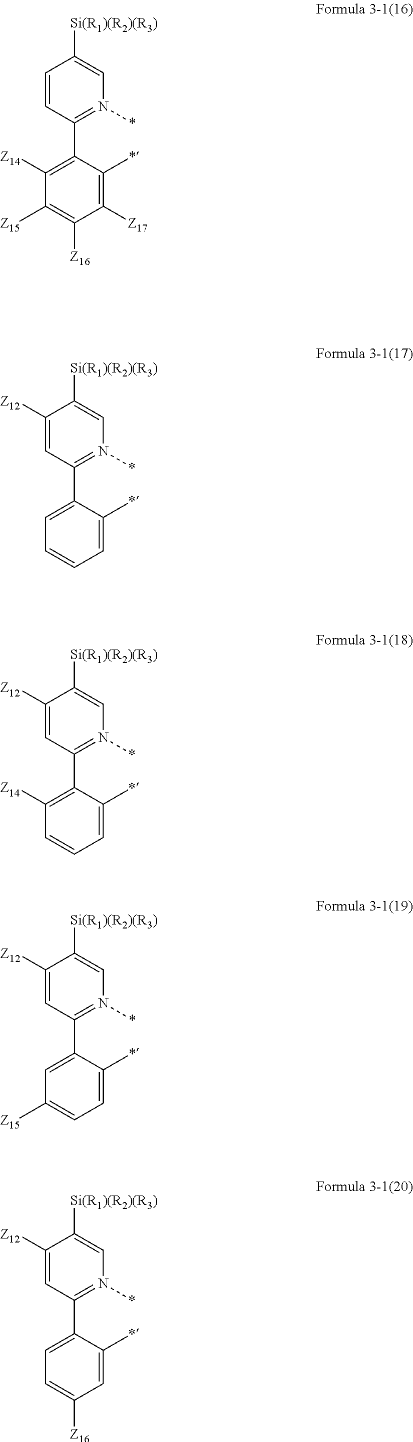 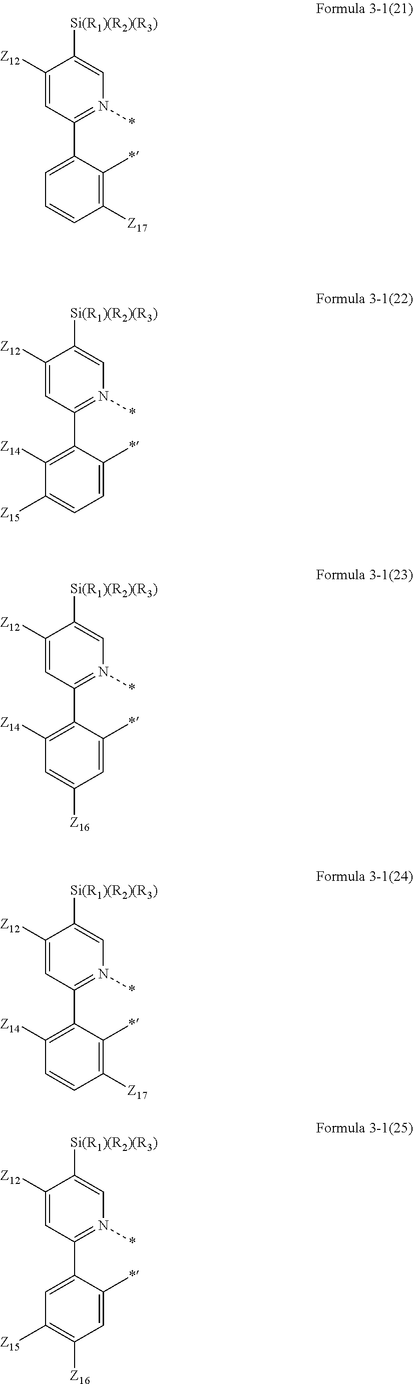 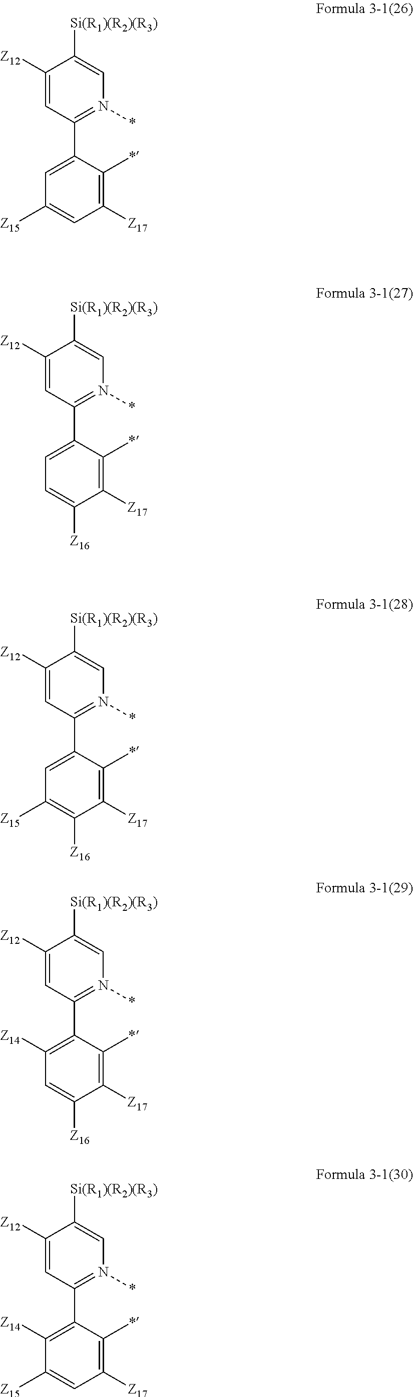 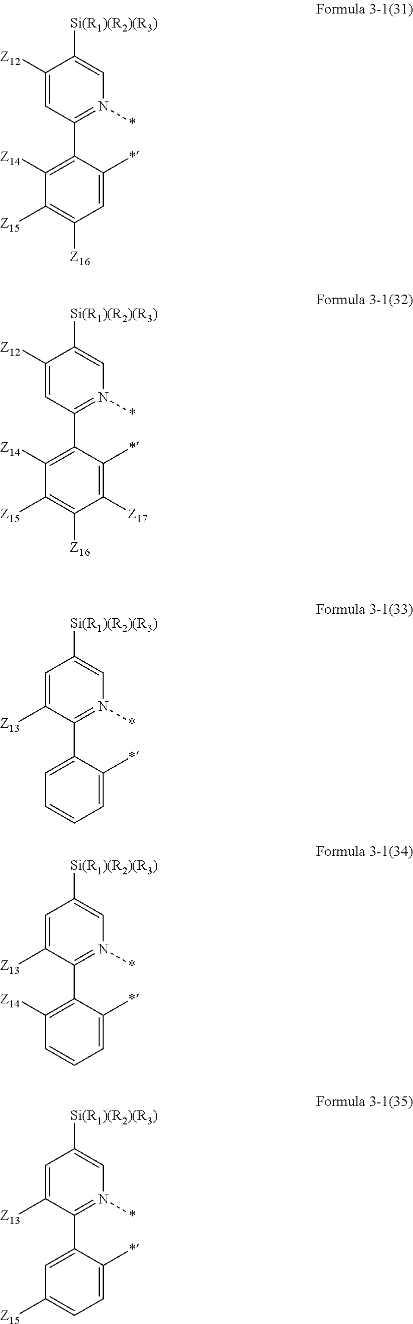 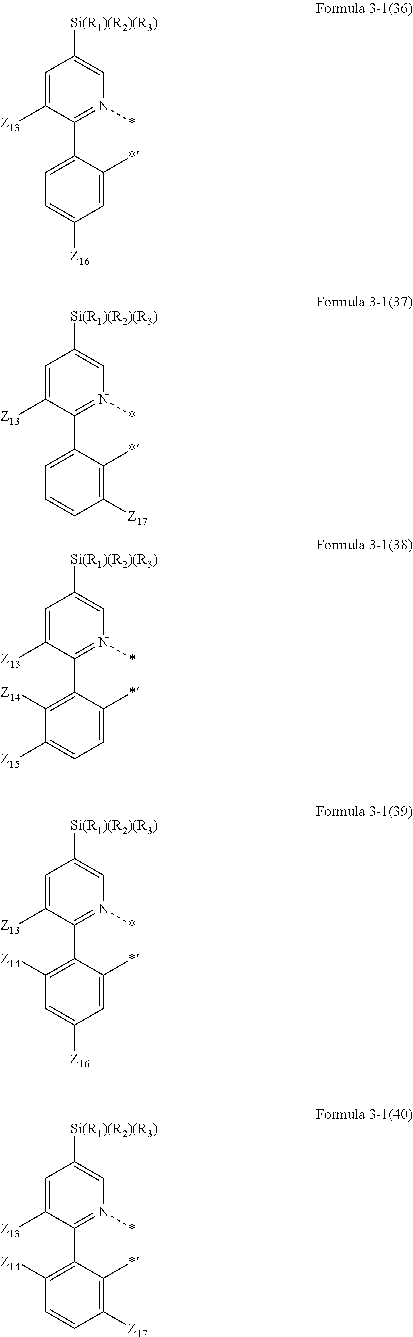 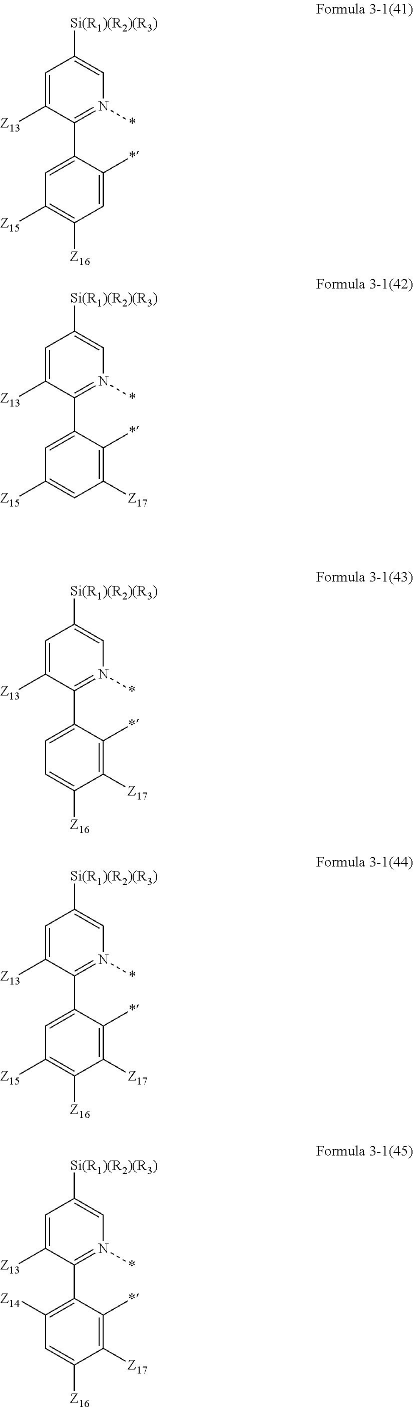 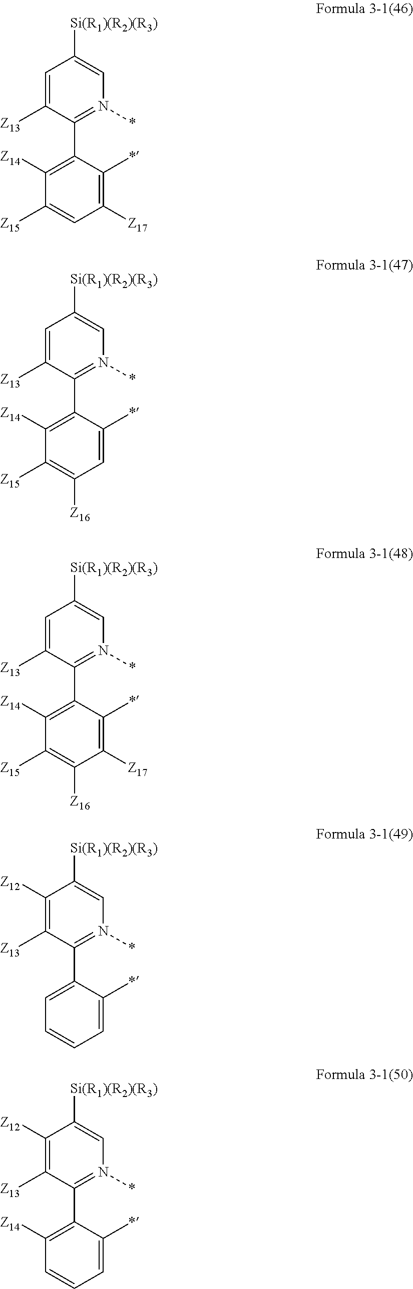 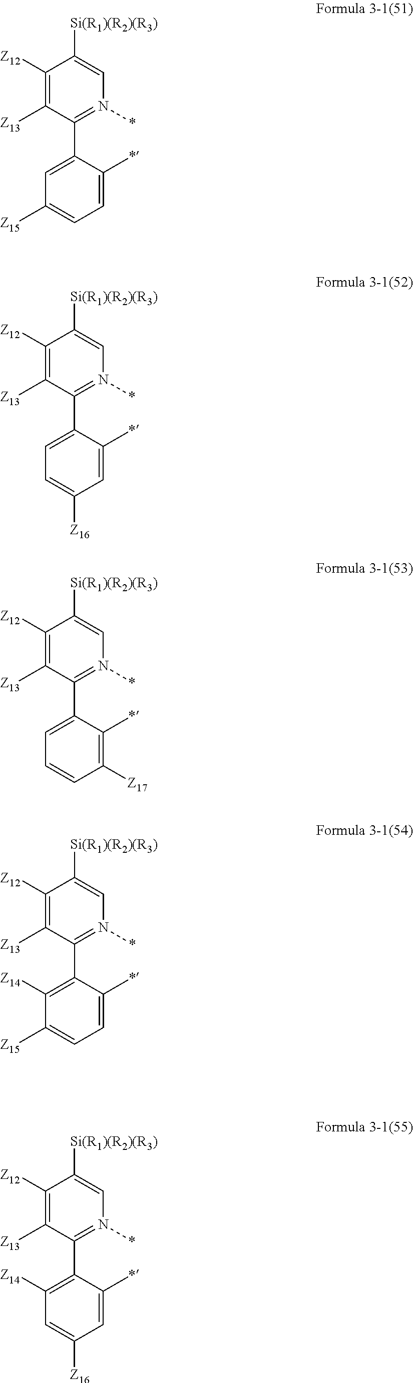 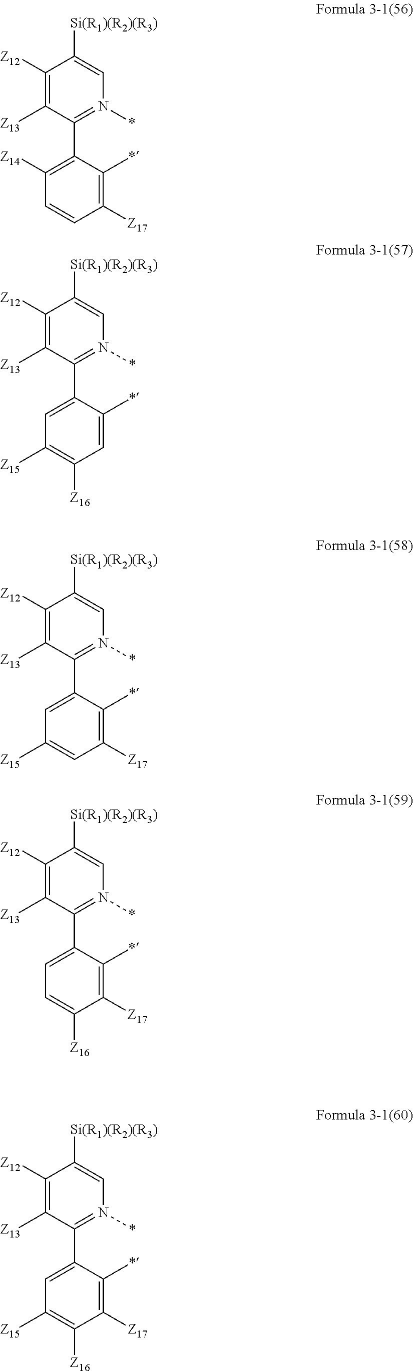 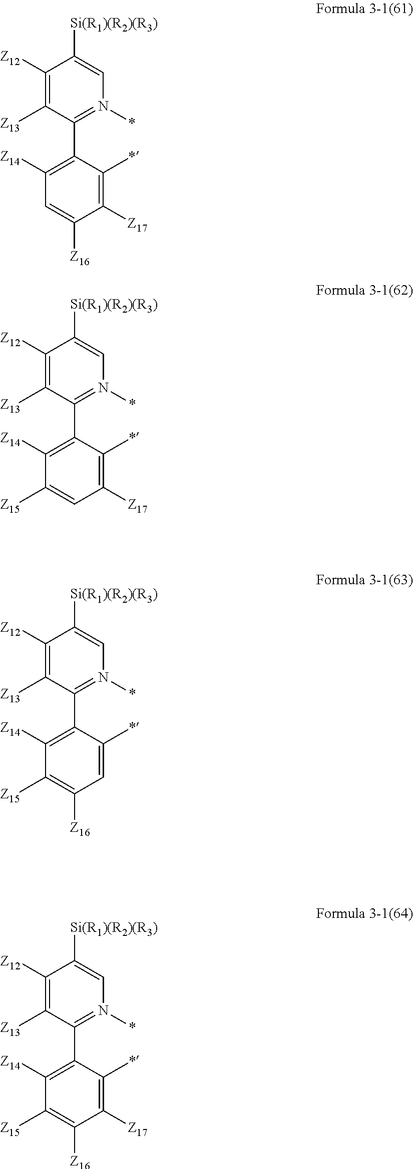 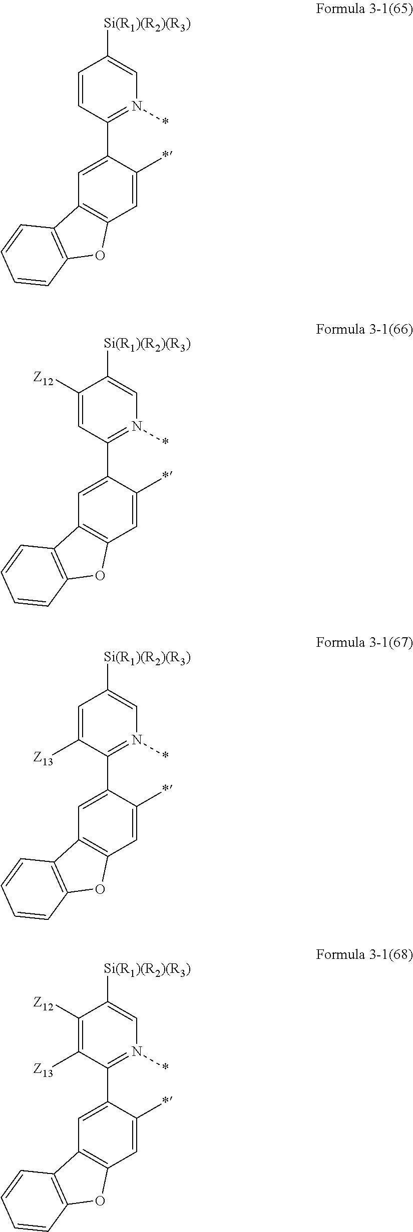 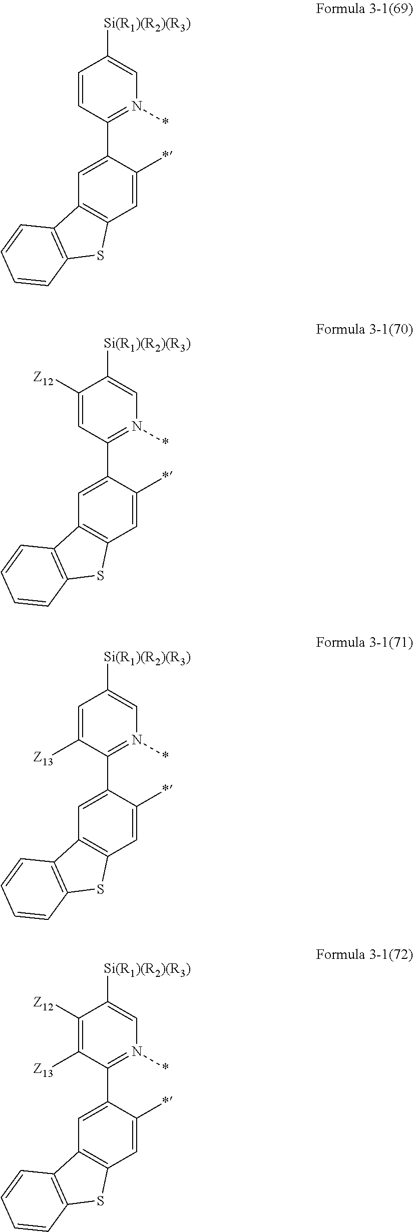 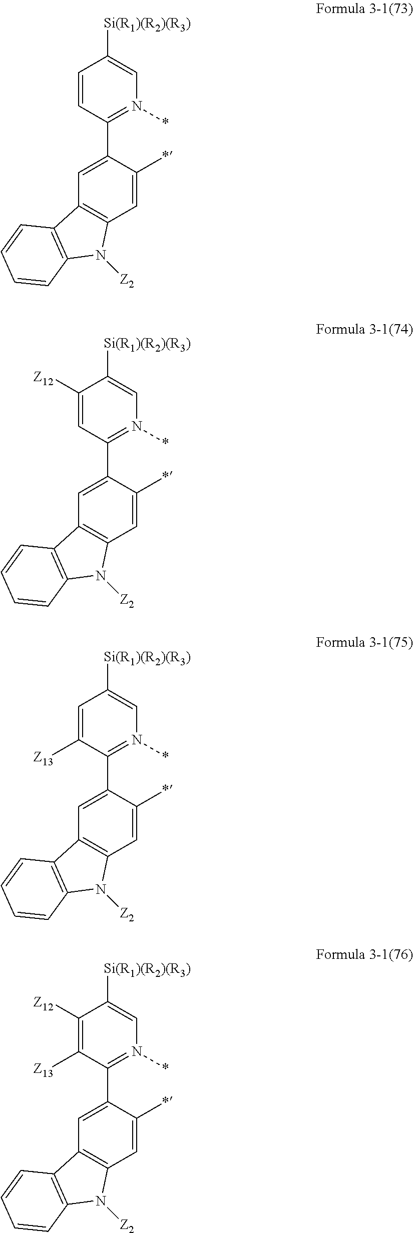 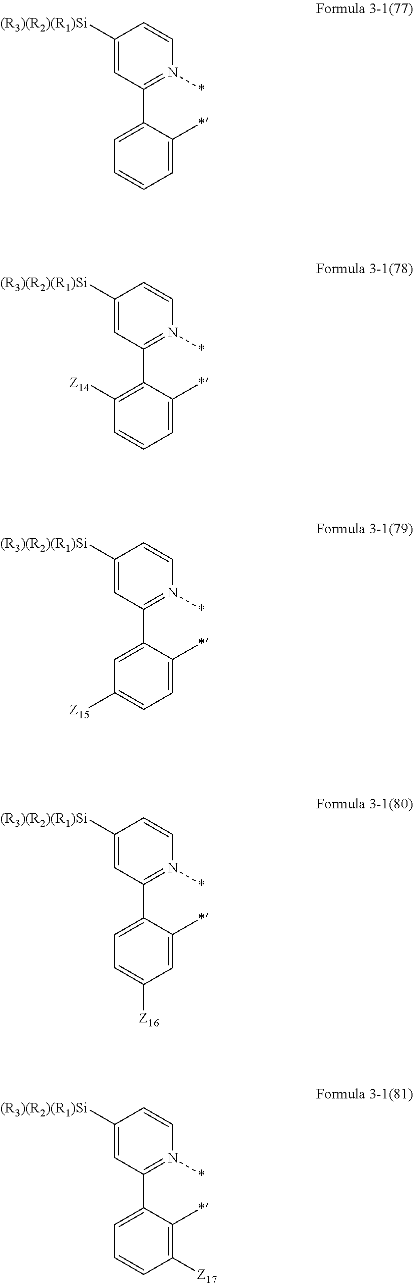 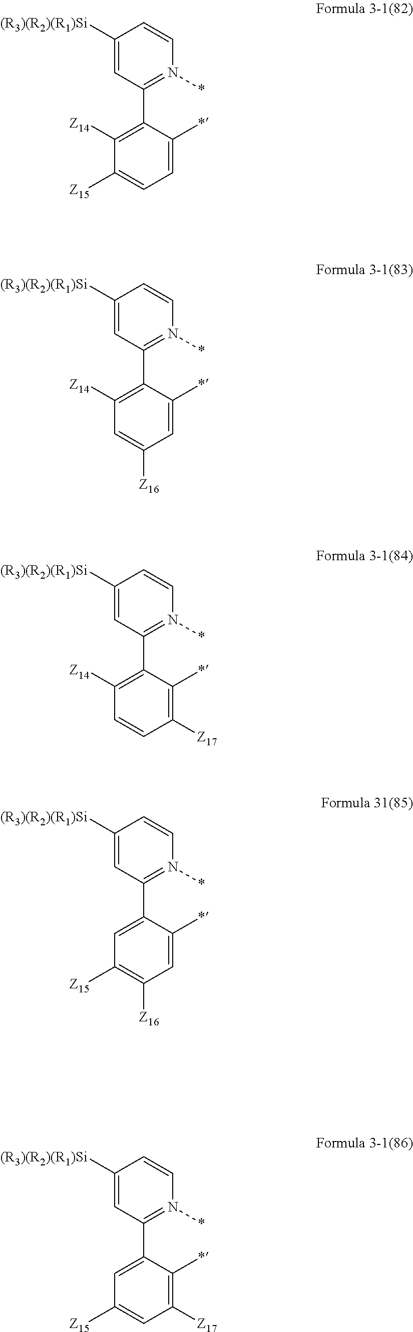 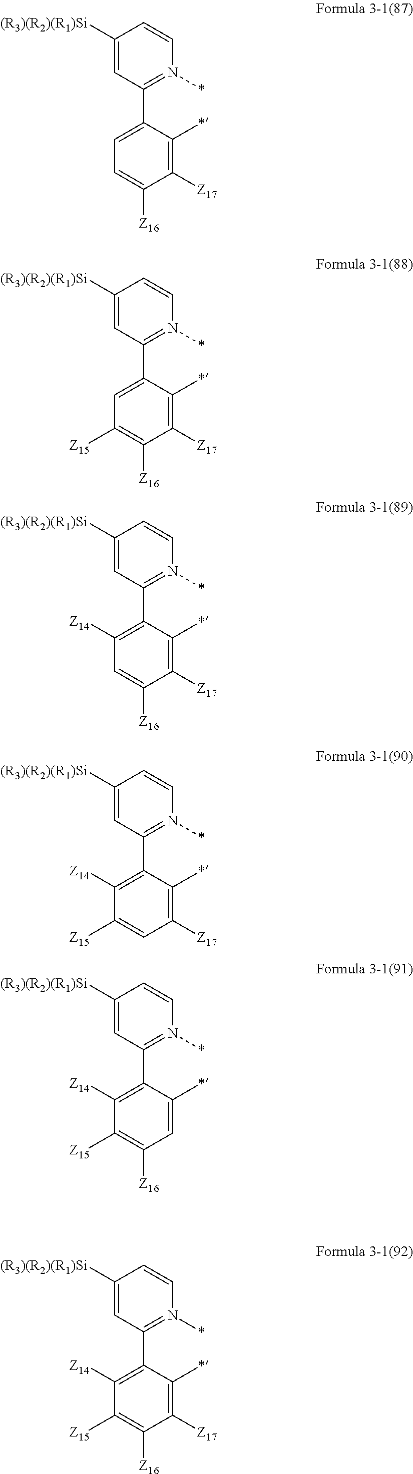 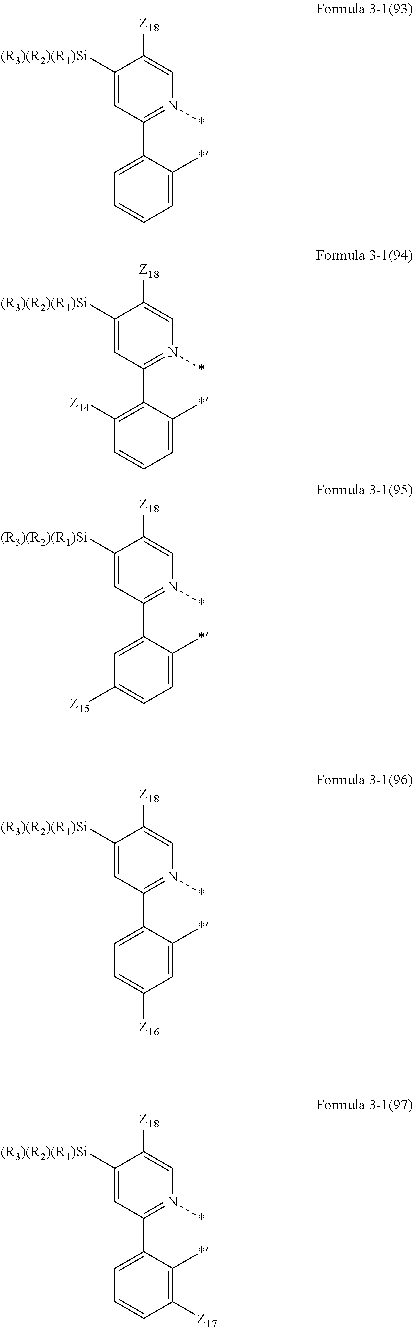 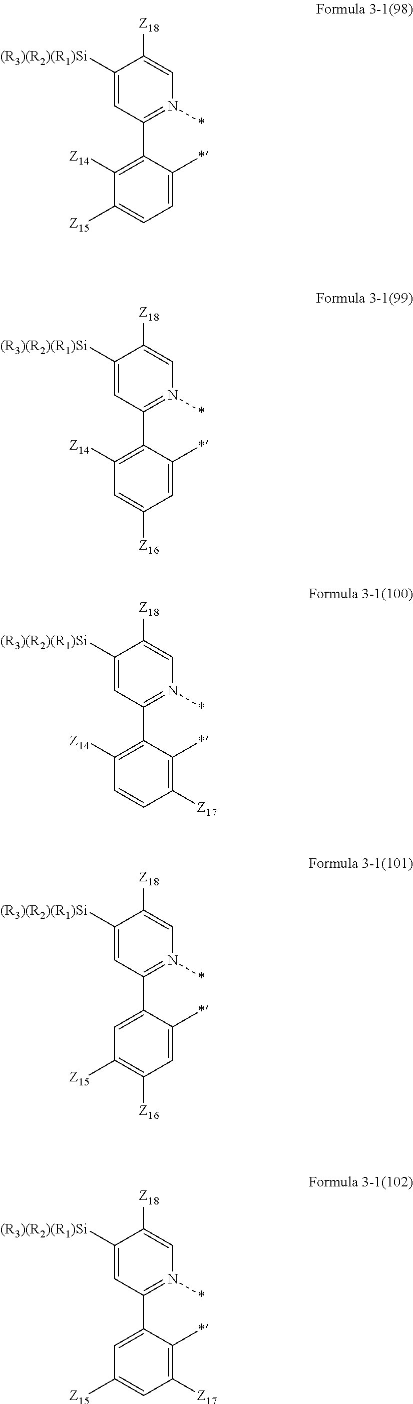 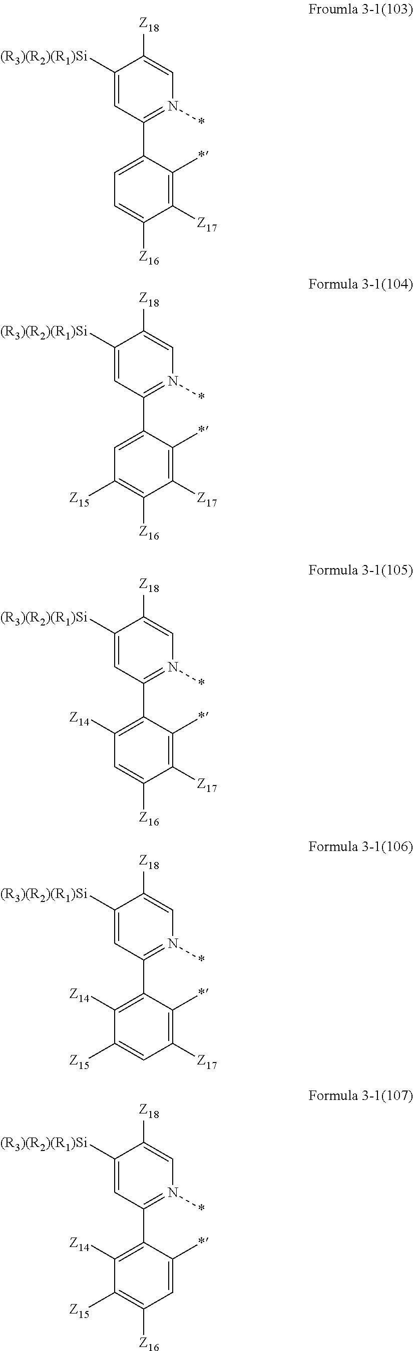 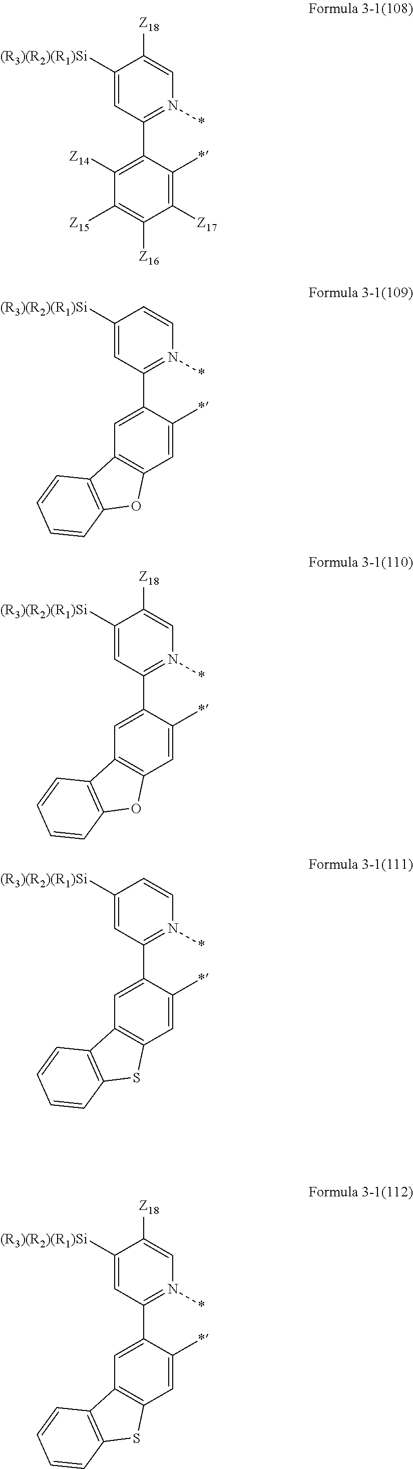 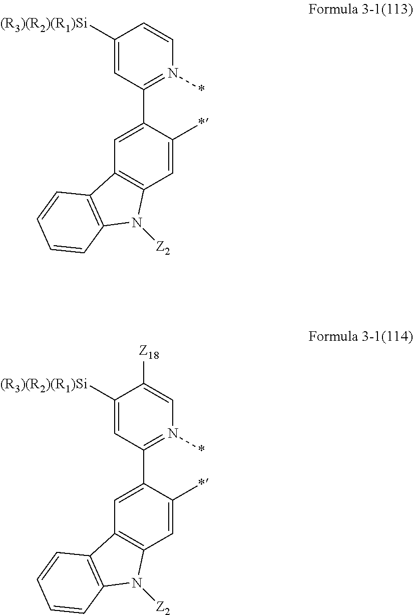
wherein, in Formulae 3-1(1) to 3-1(114),
Z₂ and Z₁₂ to Z₁₈ are each independently selected from a deuterium, —F, a cyano group, a nitro group, —SF₅, —CH₃, -CD₃, -CD₂H, -CDH₂, —CF₃, —CF₂H, —CFH₂, groups represented by Formulae 9-1 to 9-19, and groups represented by Formulae 10-1 to 10-36,
R₁ to R₃ are each independently selected from —CH₃, -CD₃, -CD₂H, -CDH₂, groups represented by Formulae 9-1 to 9-19, and a phenyl group, and
* and *′ each indicates a binding site to M in Formula 1: 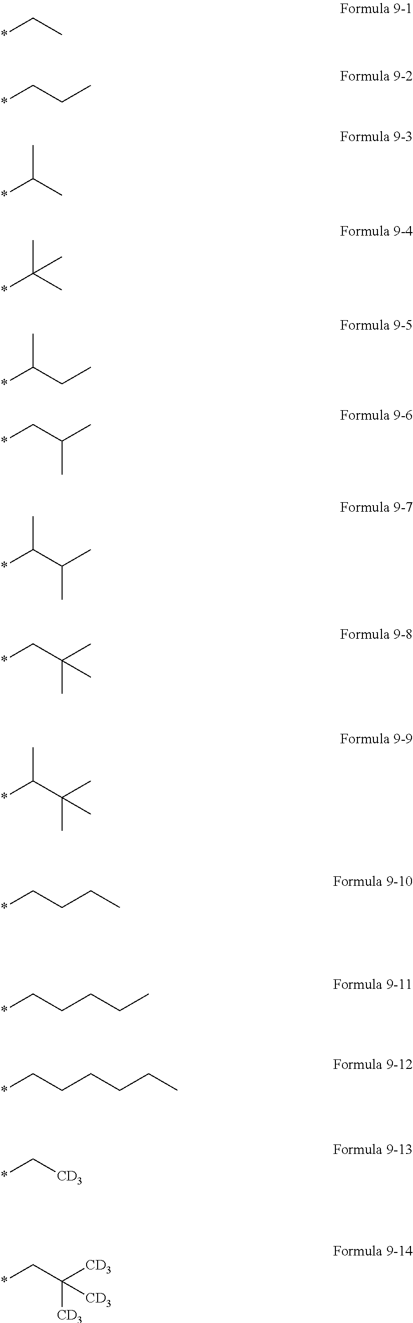 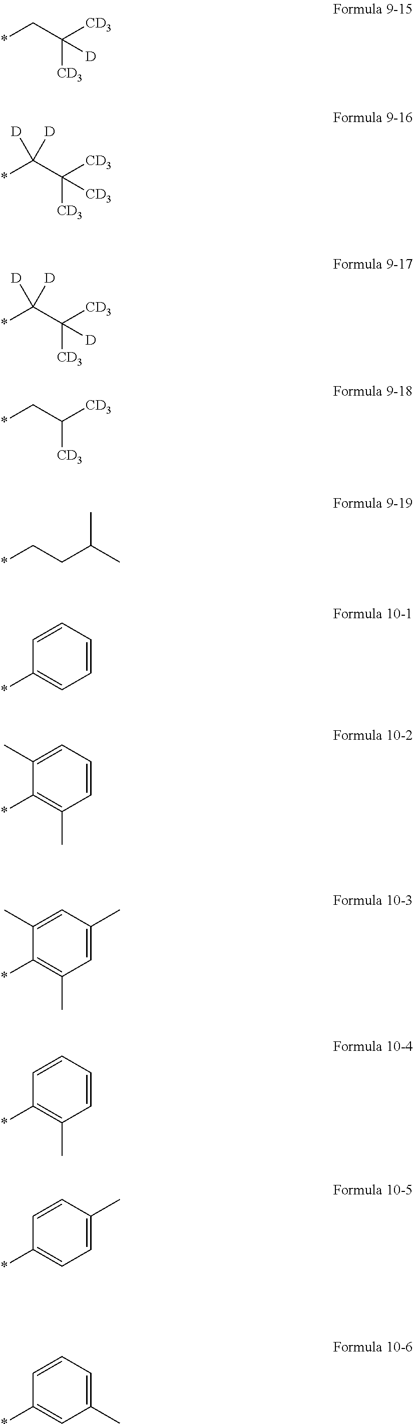 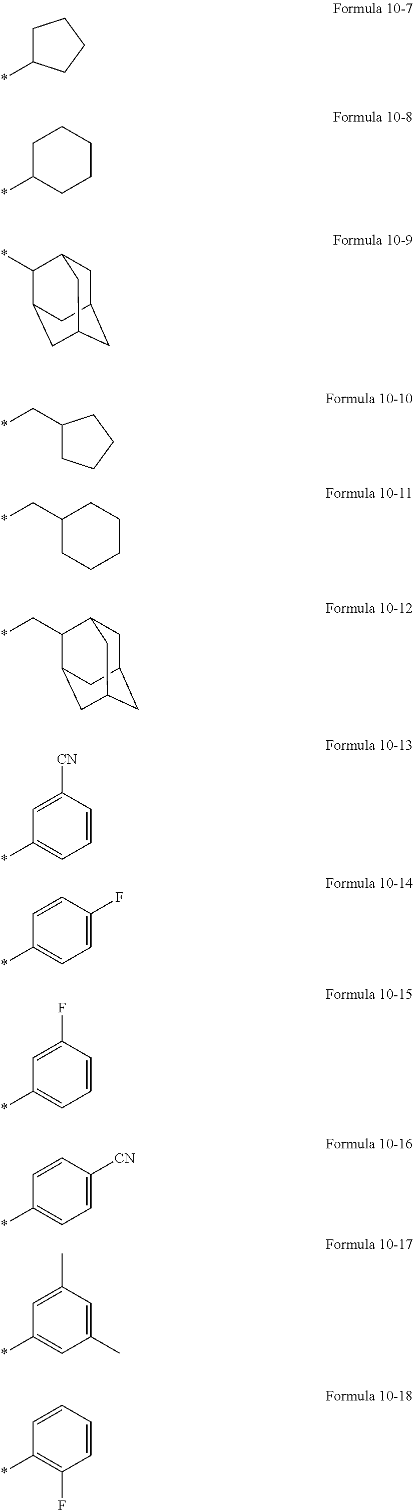 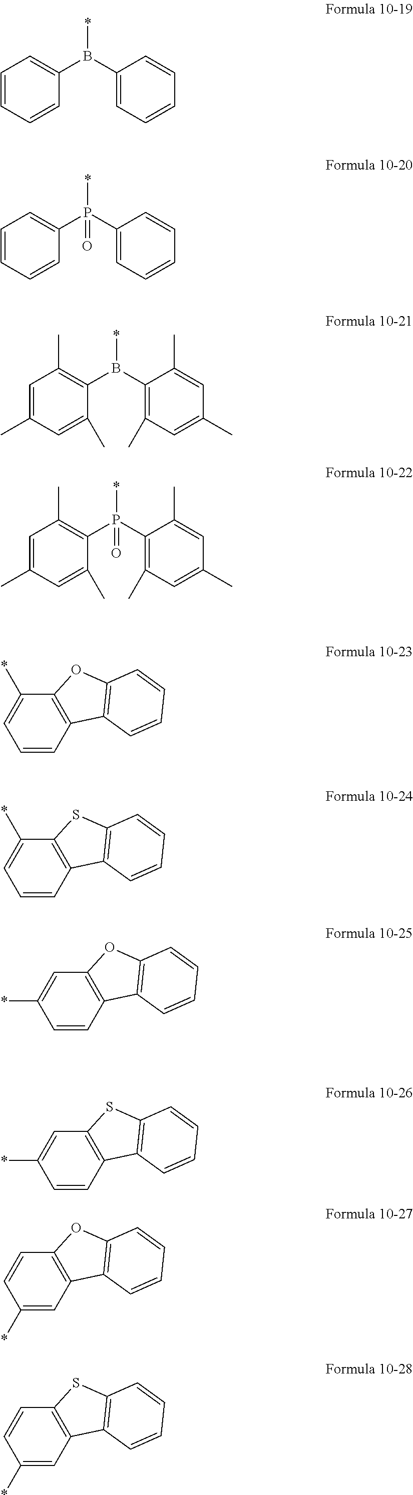 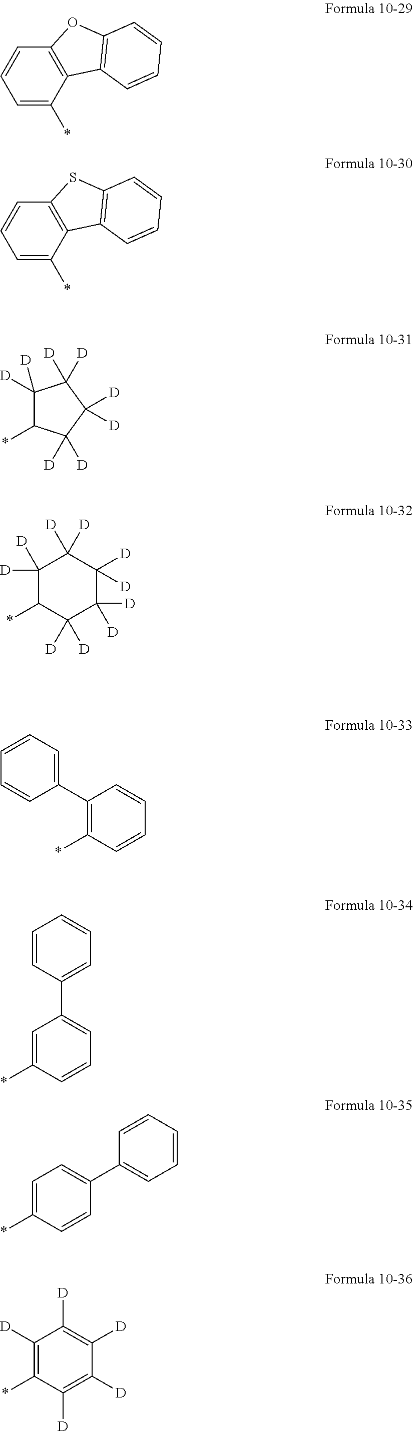
in Formulae 9-1 to 9-19 and 10-1 to 10-36, * indicates a binding site to a neighboring atom.

13. The organometallic compound of claim 1, wherein L₂ is selected from ligands represented by Formulae 2B(1) to 2B(10): 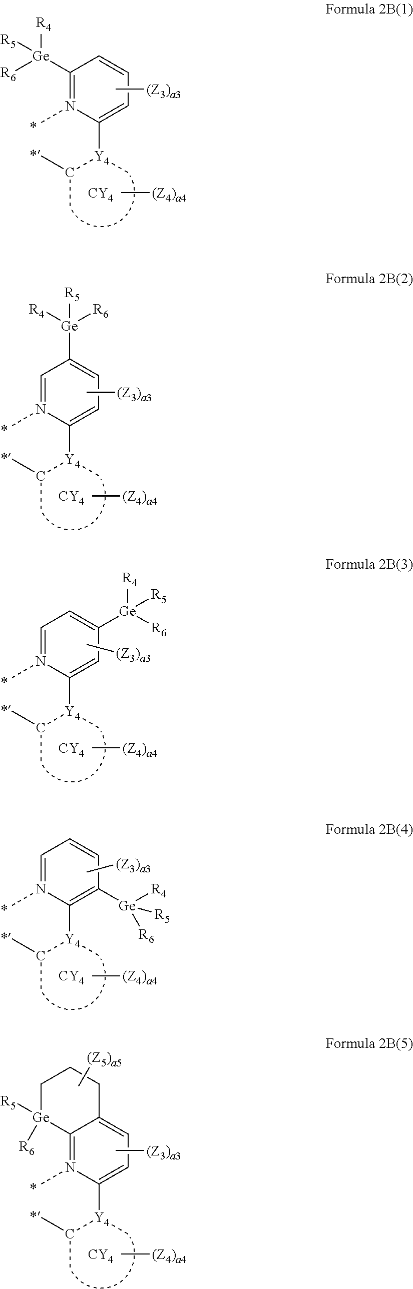 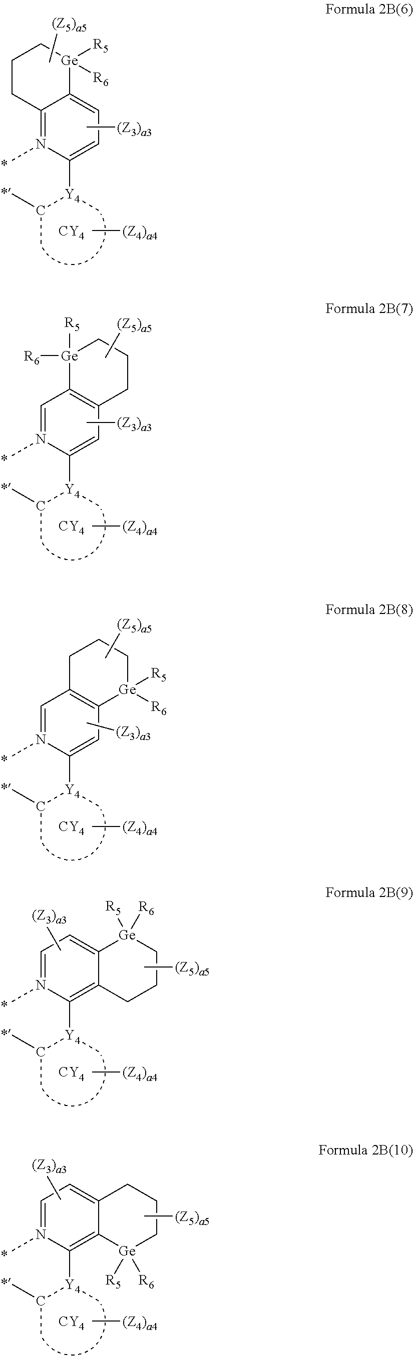
wherein, in Formulae 2B(1) to 2B(10),
Z₃, Z₄, a3, a4, and R₄ to R₆ are the same as in claim 1,
CY₄ is selected from a benzene, a naphthalene, a carbazole, a dibenzofuran, and a dibenzothiophene,
description for Z₅ is the same with as Z₃,
a5 is an integer selected from 1 to 6, and
* and *′ each indicates a binding site to M in Formula 1.

14. The organometallic compound of claim 1, wherein L₂ is selected from ligands represented by Formulae 2B-1 to 2B-114: 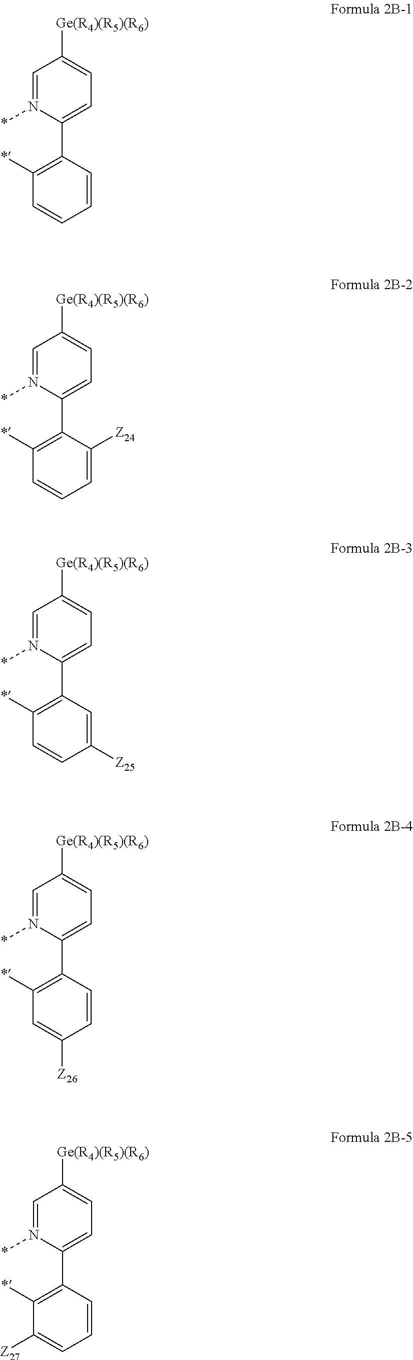 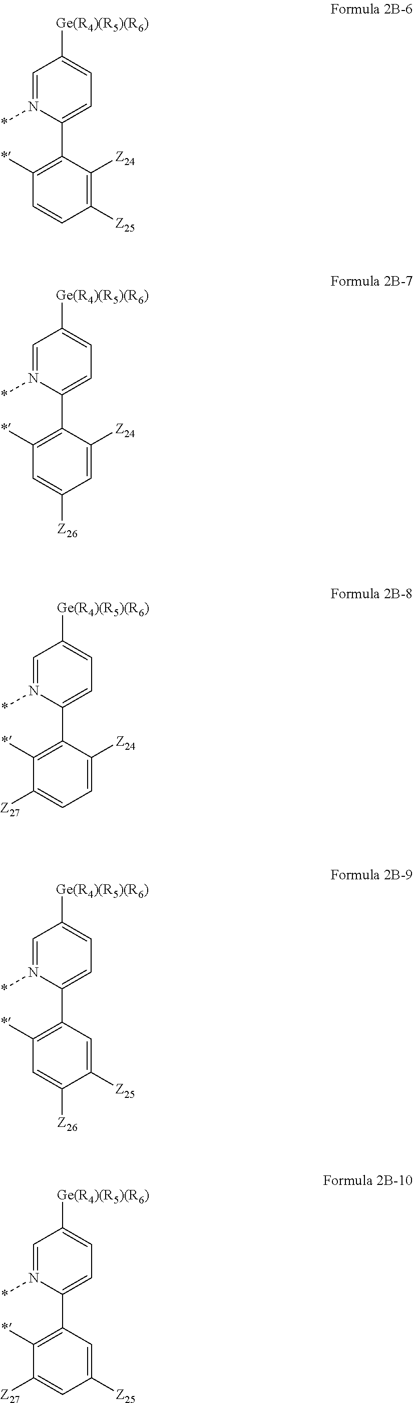 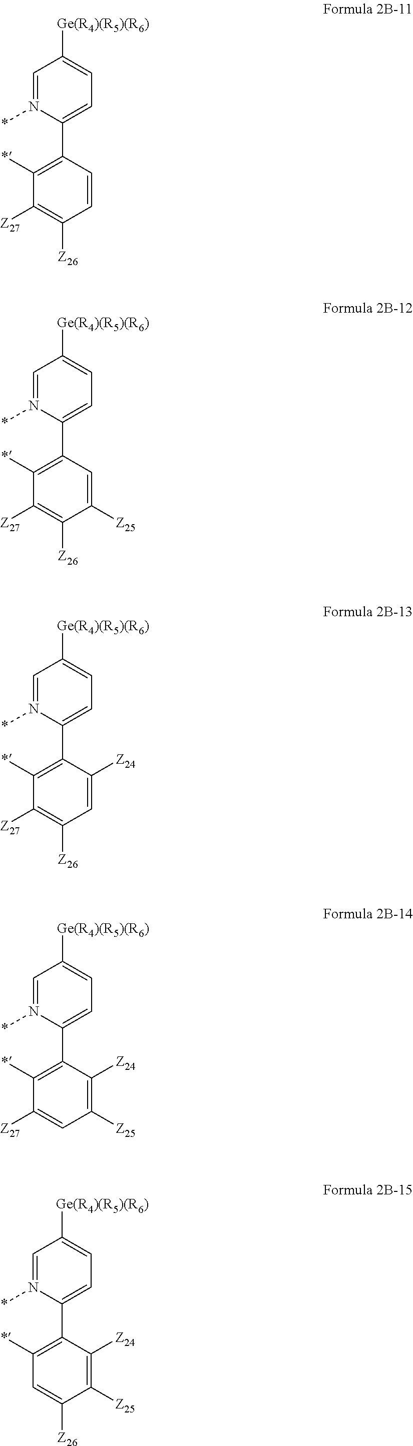 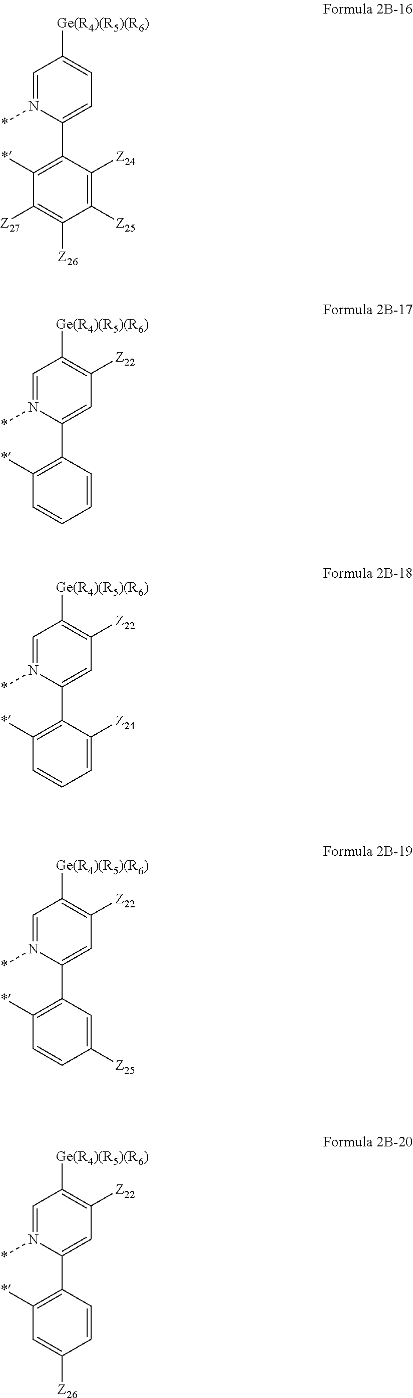 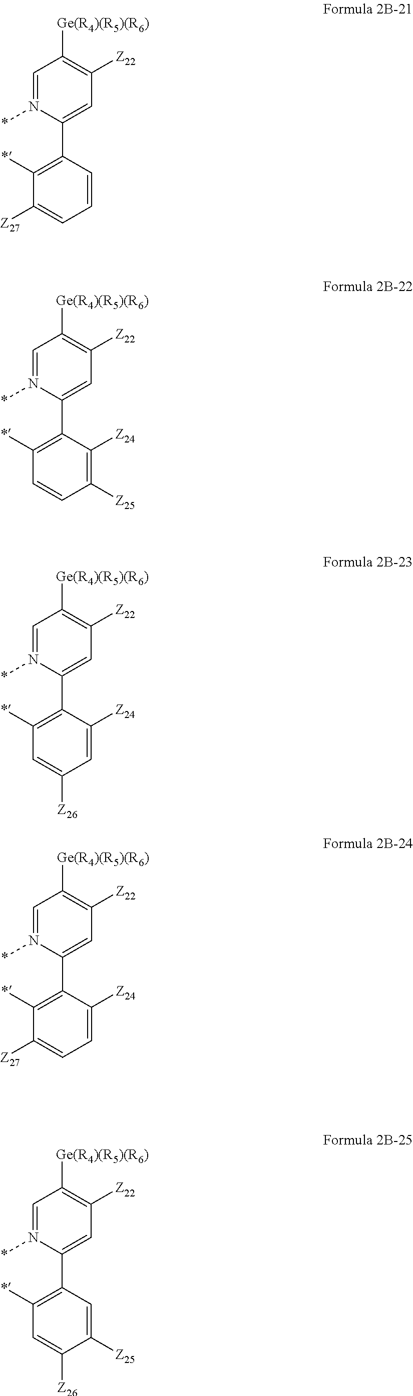 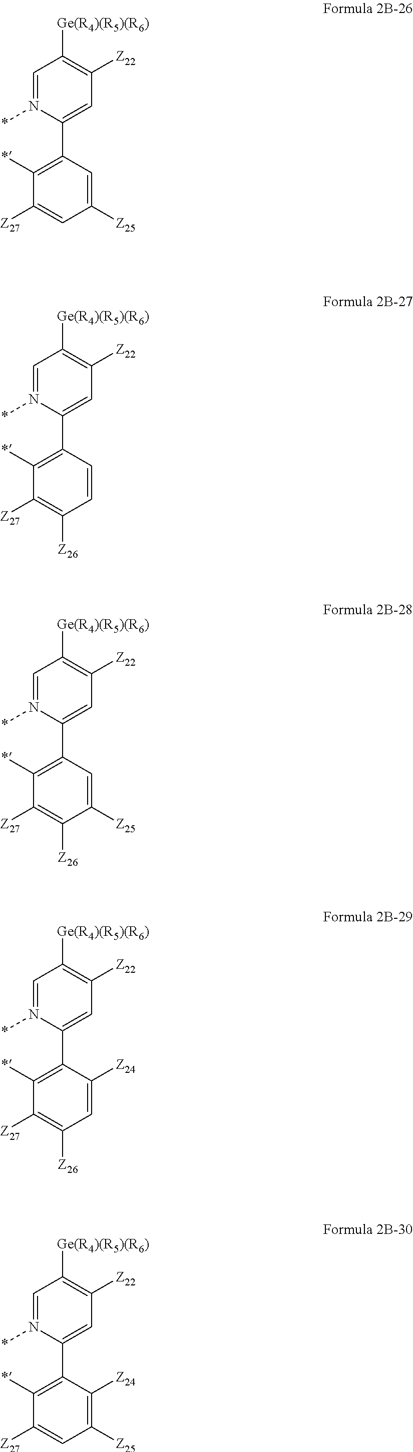 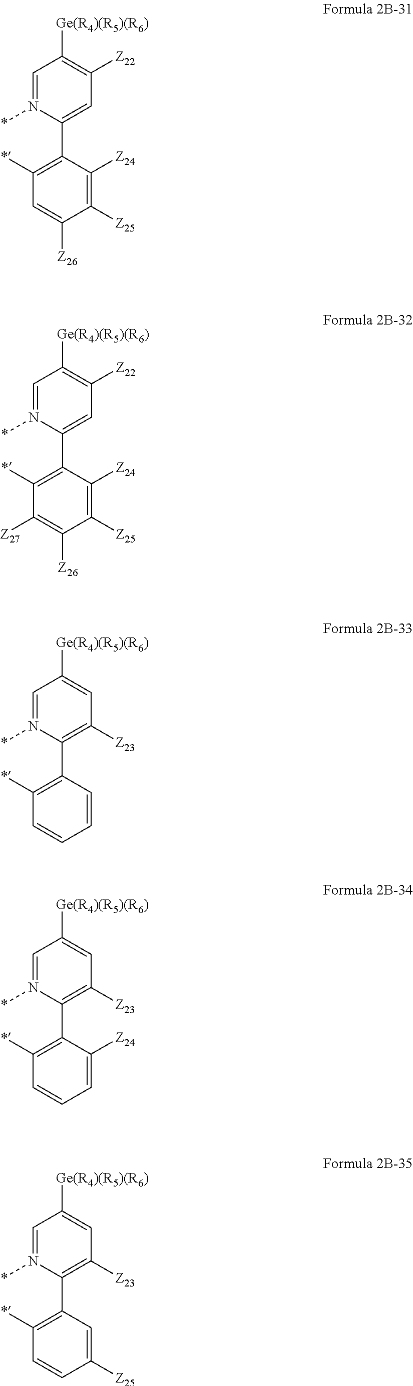 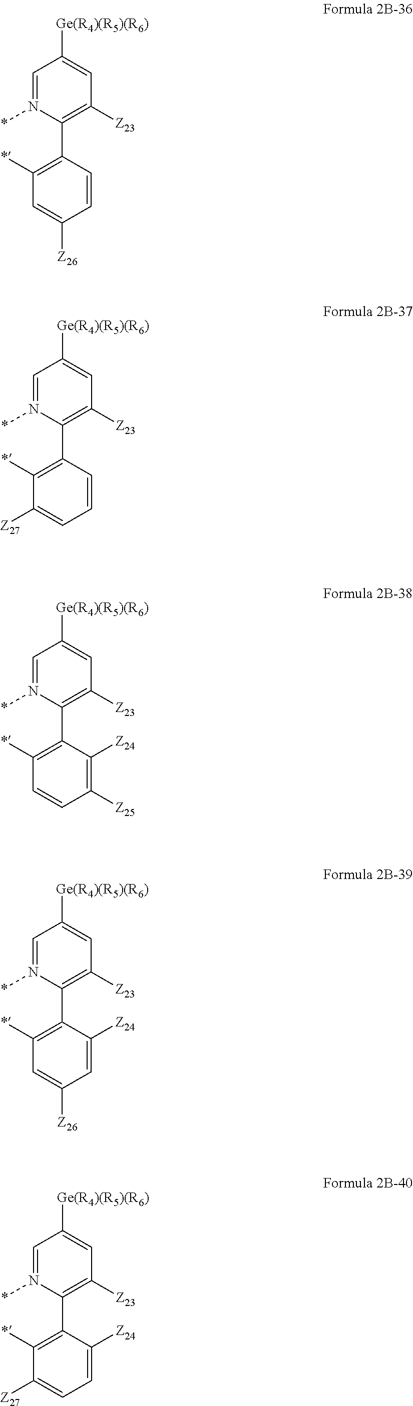 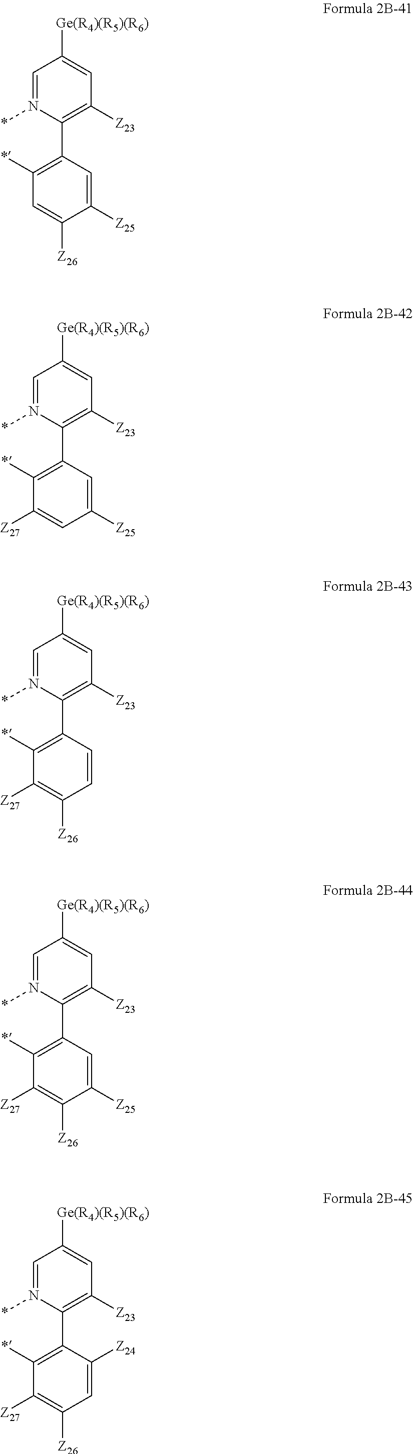 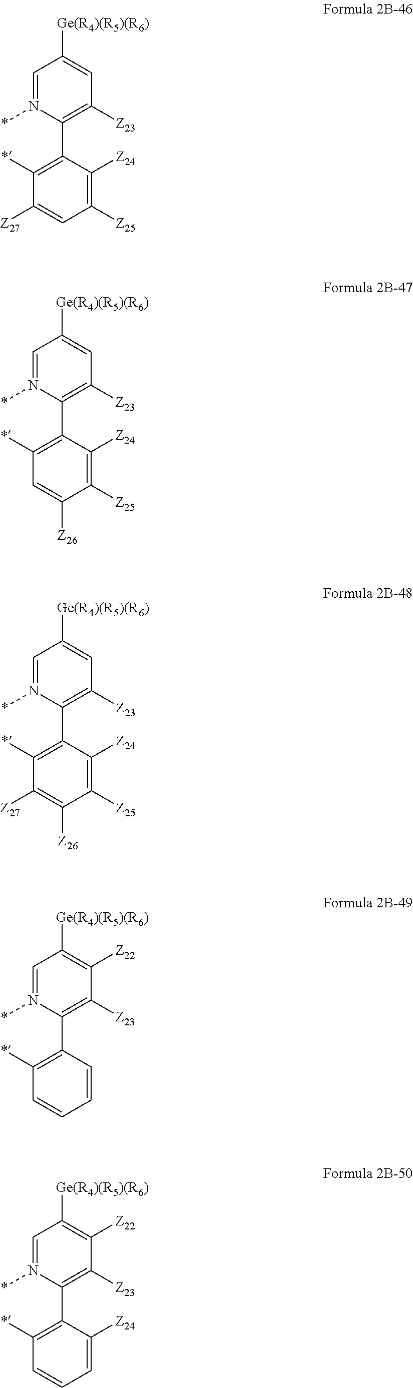 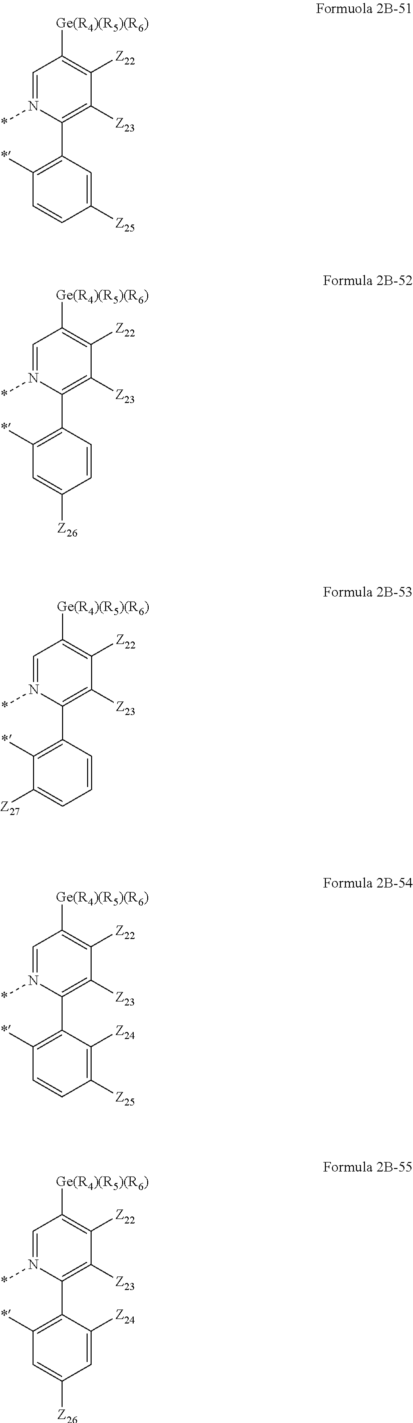 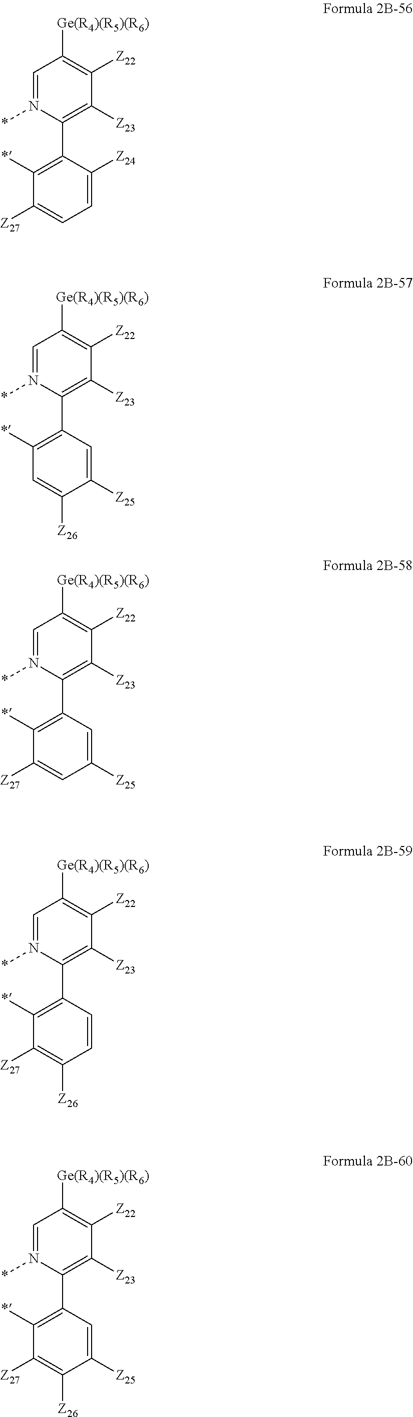 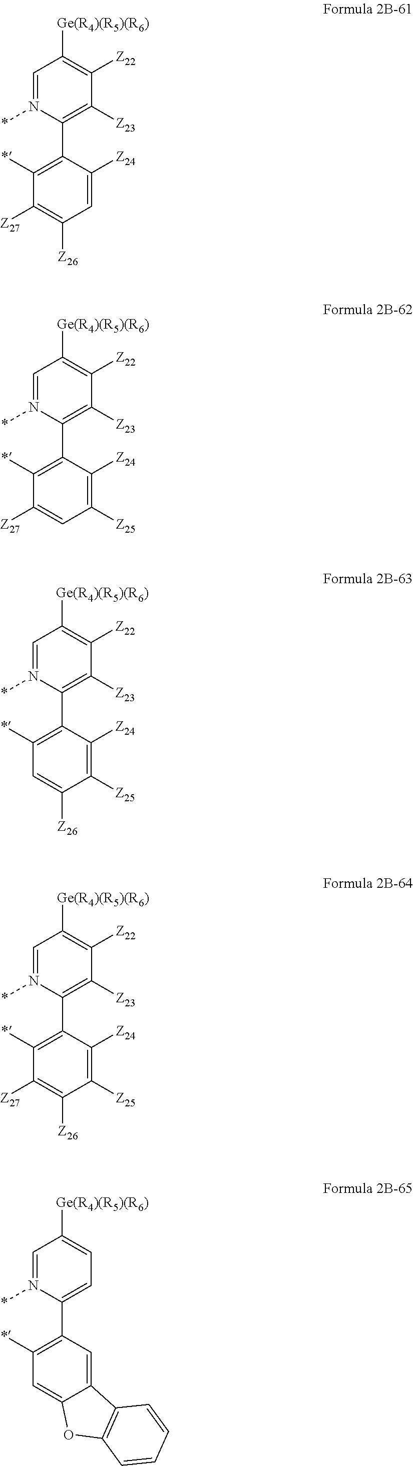 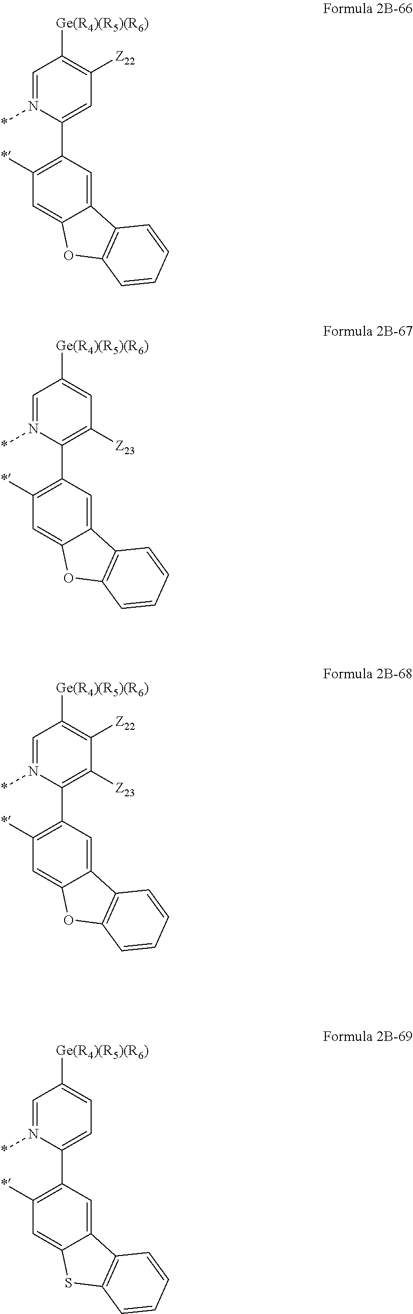 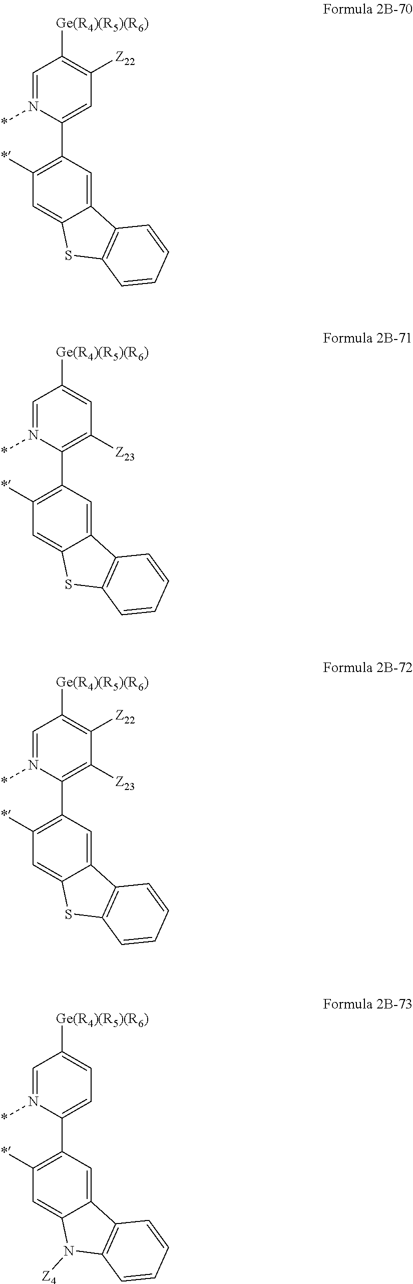 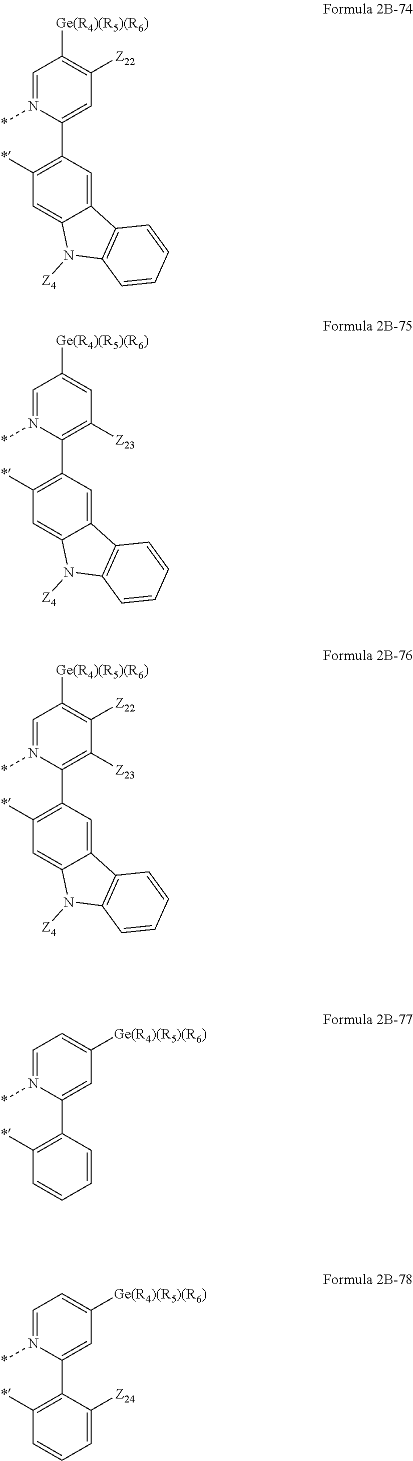 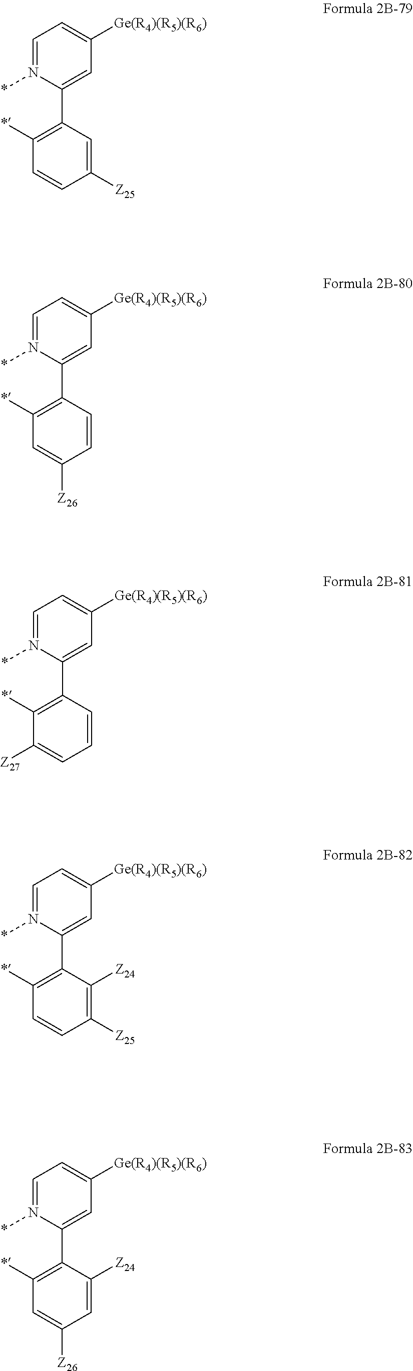 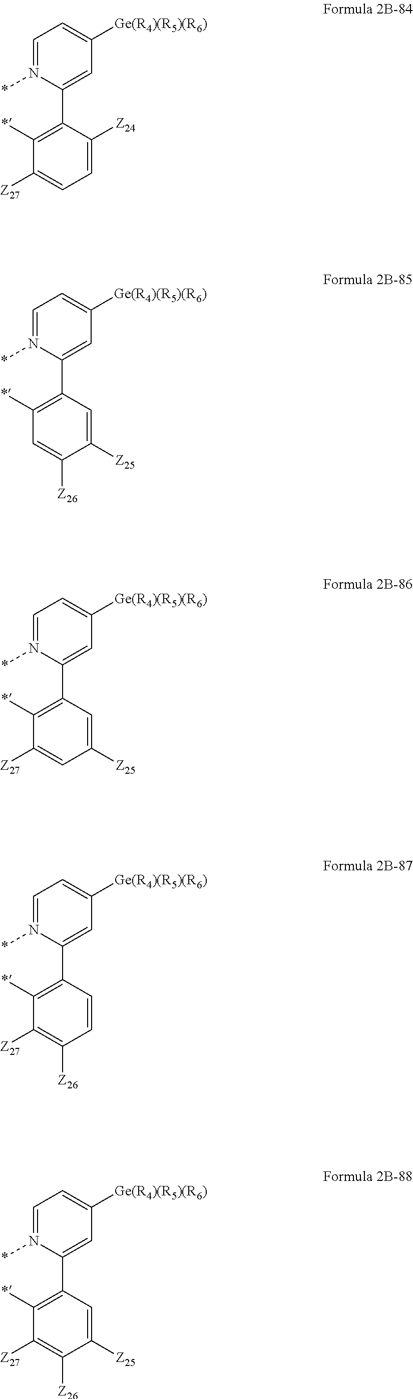 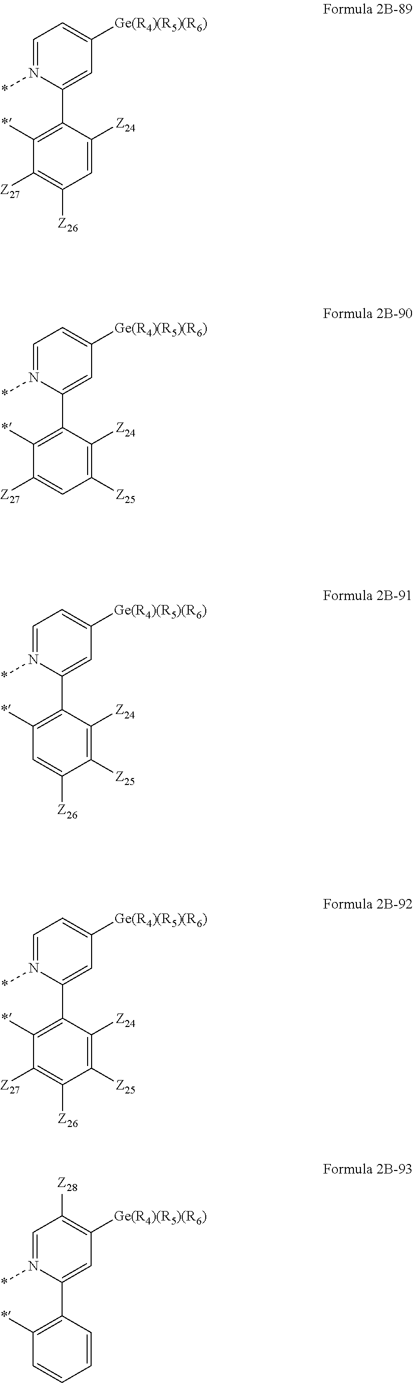 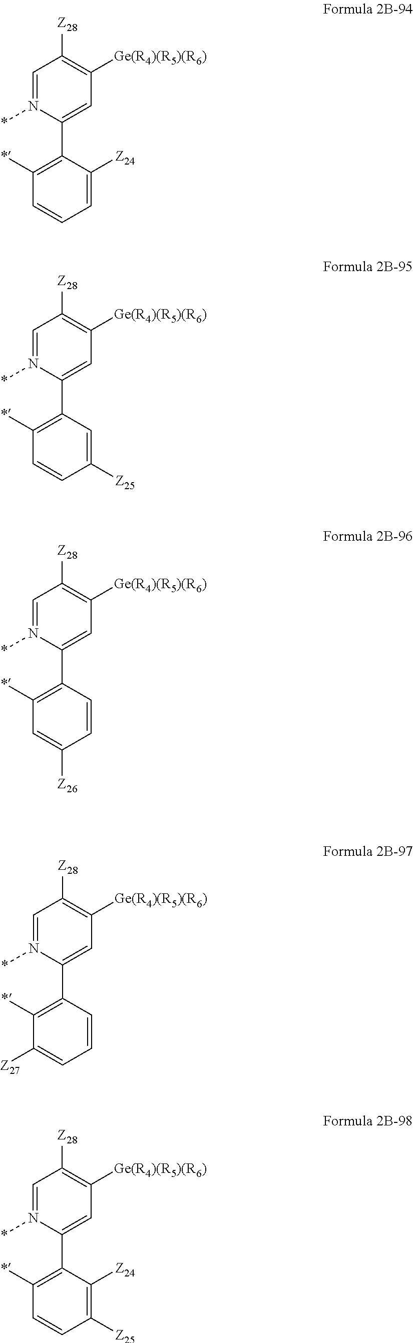 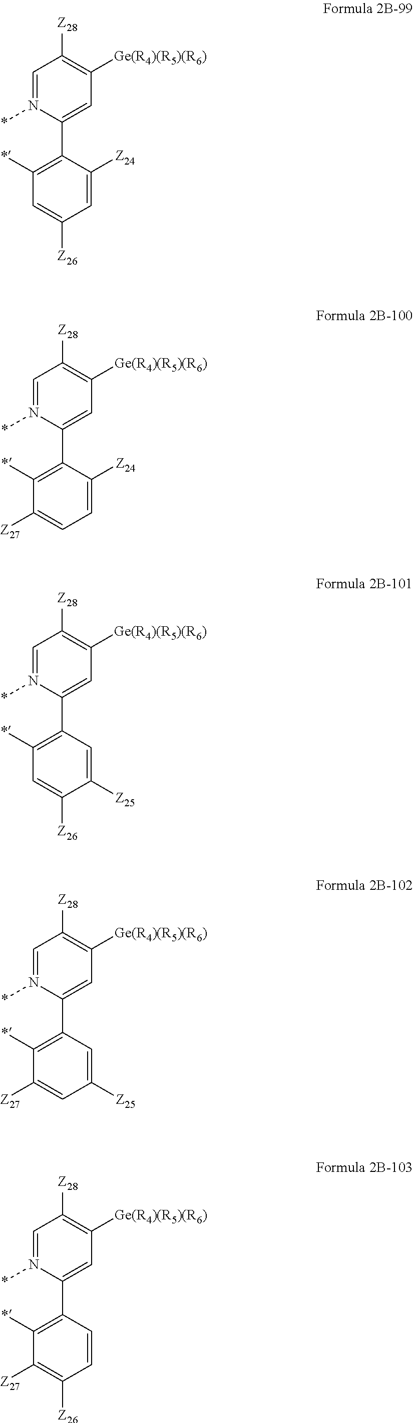 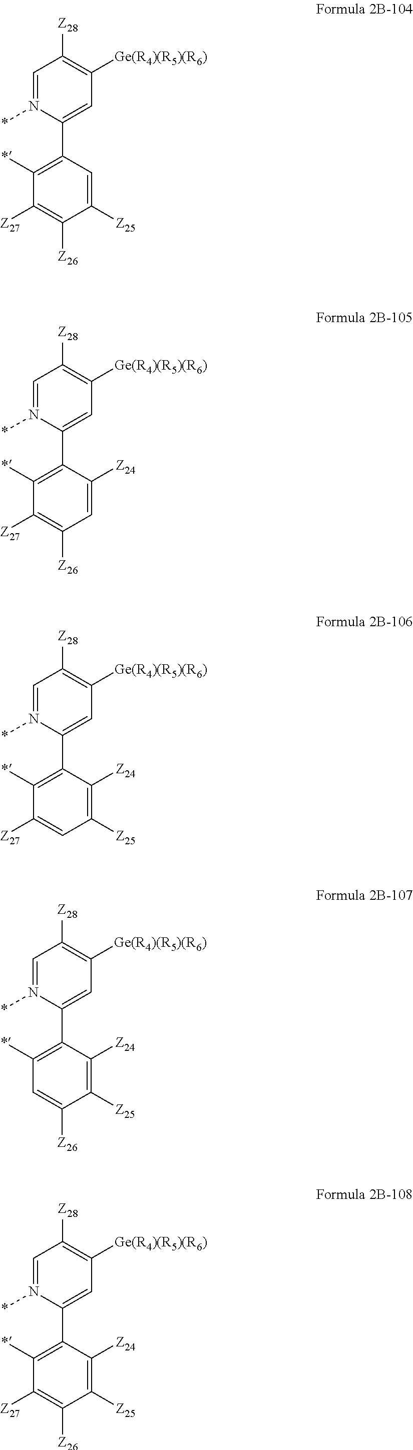 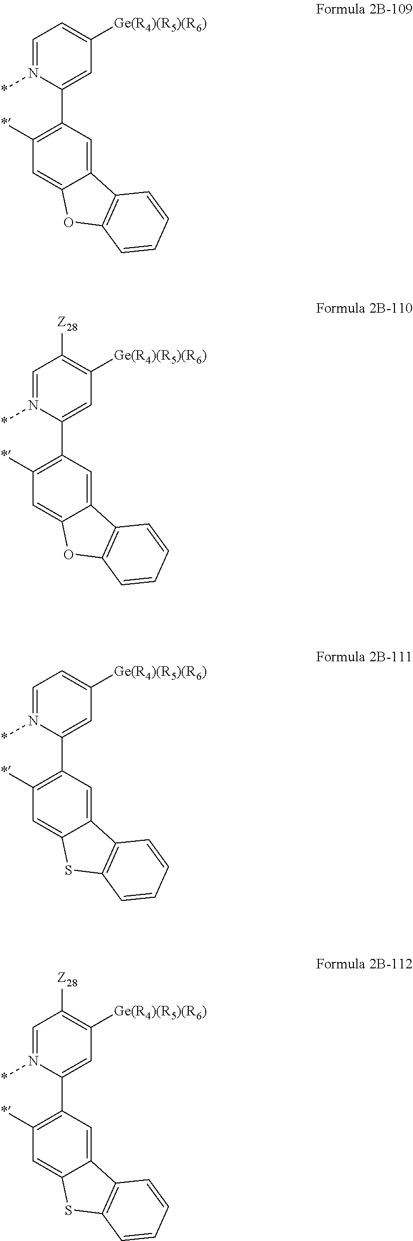 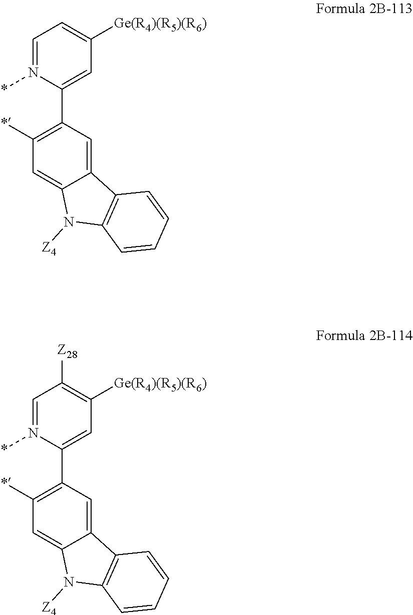
wherein, in Formula 2B-1 to 2B-114,
Z₂₂, Z₂₃, and Z₂₈ are the same as Z₃ in claim 1,
Z₂₄ to Z₂₇ are the same as Z₄ in claim 1, and
* and *′ each indicates a binding site to M in Formula 1.

15. The organometallic compound of claim 14, wherein
Z₄ and Z₂₂ to Z₂₈ are each independently selected from a deuterium, —F, a cyano group, a nitro group, —SF₅, —CH₃, -CD₃, -CD₂H, -CDH₂, —CF₃, —CF₂H, —CFH₂, groups represented by Formulae 9-1 to 9-19, and groups represented by Formulae 10-1 to 10-36,
R₄ to R₆ are each independently selected from —CH₃, -CD₃, -CD₂H, -CDH₂, groups represented by Formulae 9-1 to 9-19, and a phenyl group, and
* and *′ each indicates a binding site to M in Formula 1: 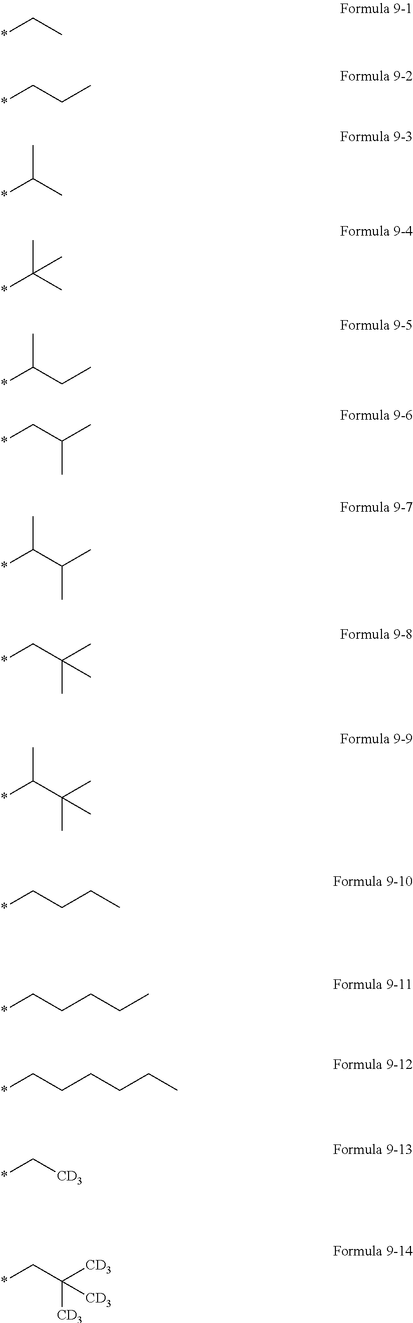 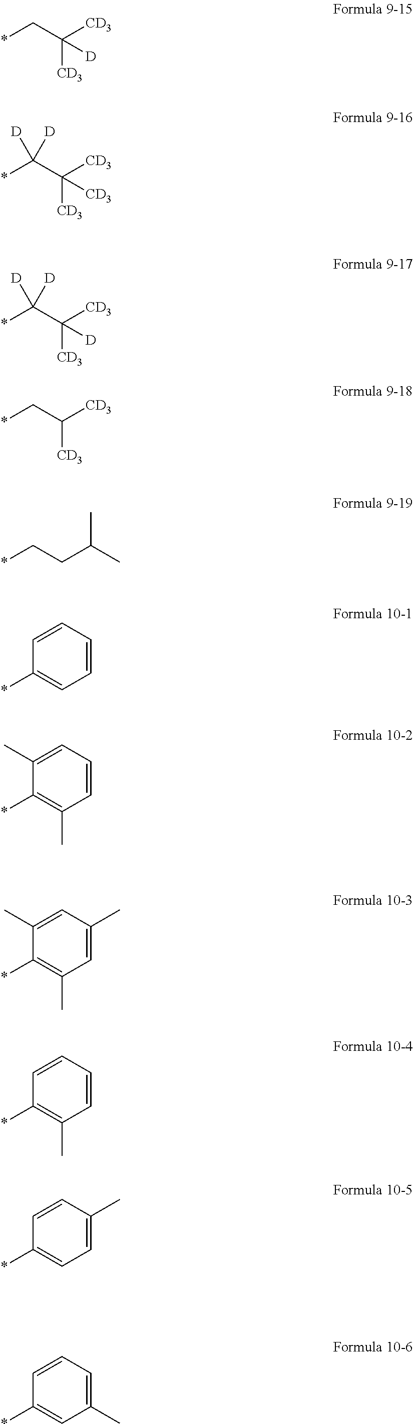 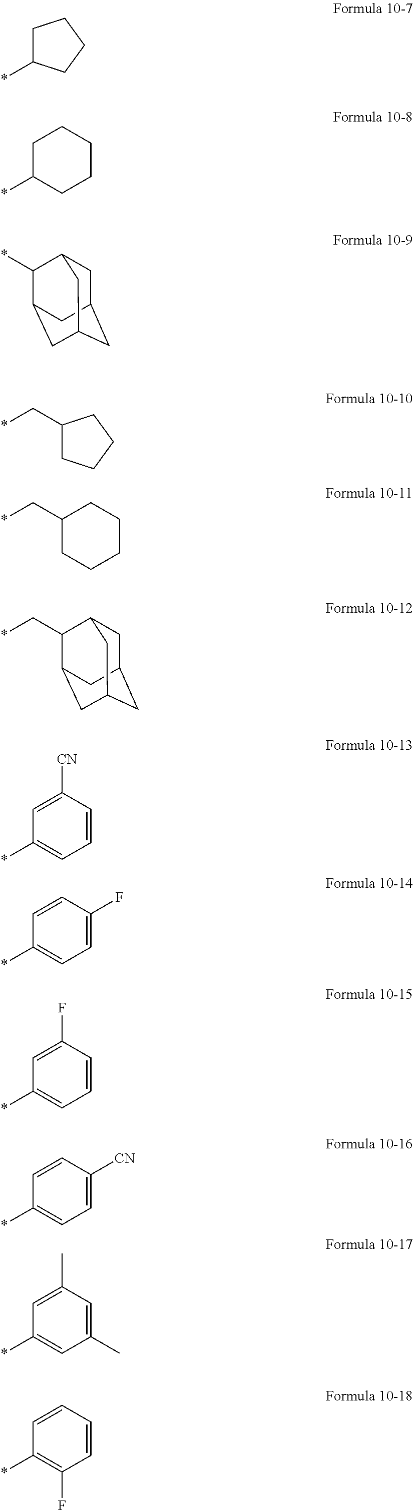 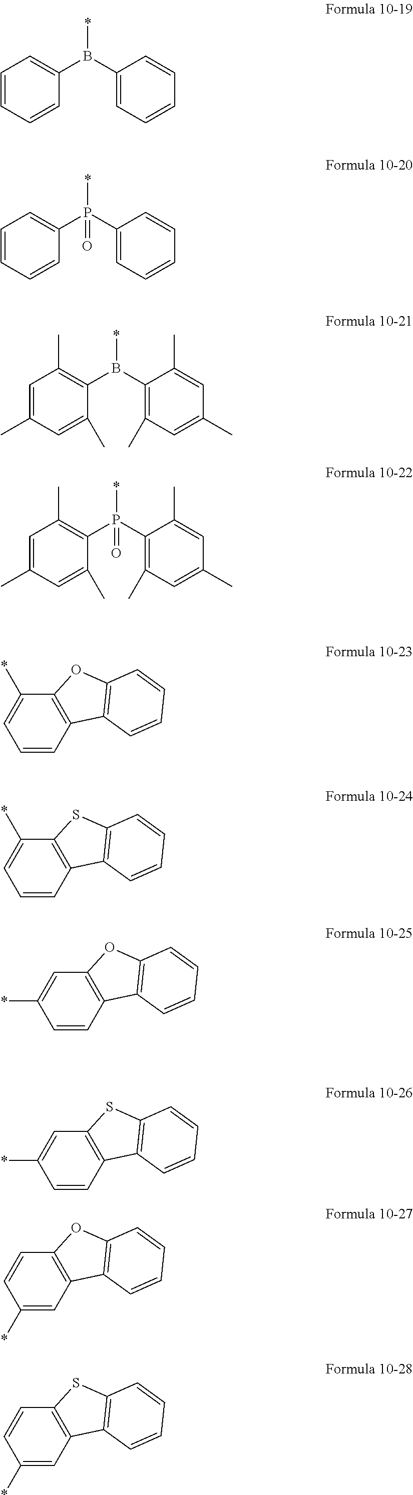 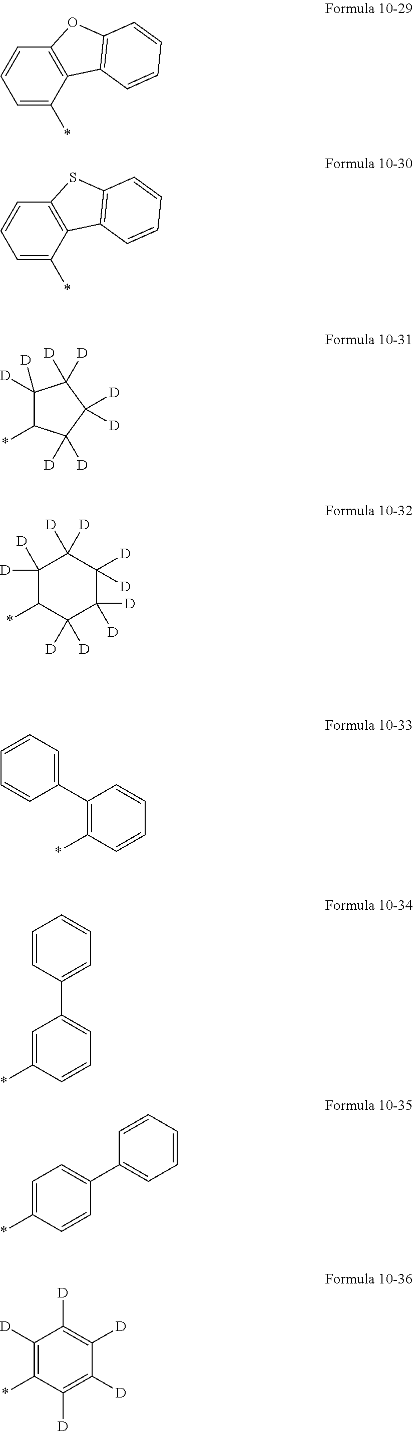
wherein, in Formulae 9-1 to 9-19 and 10-1 to 10-36, * indicates a binding site to a neighboring atom.

16. The organometallic compound of claim 1 selected from Compounds 1 to 110:

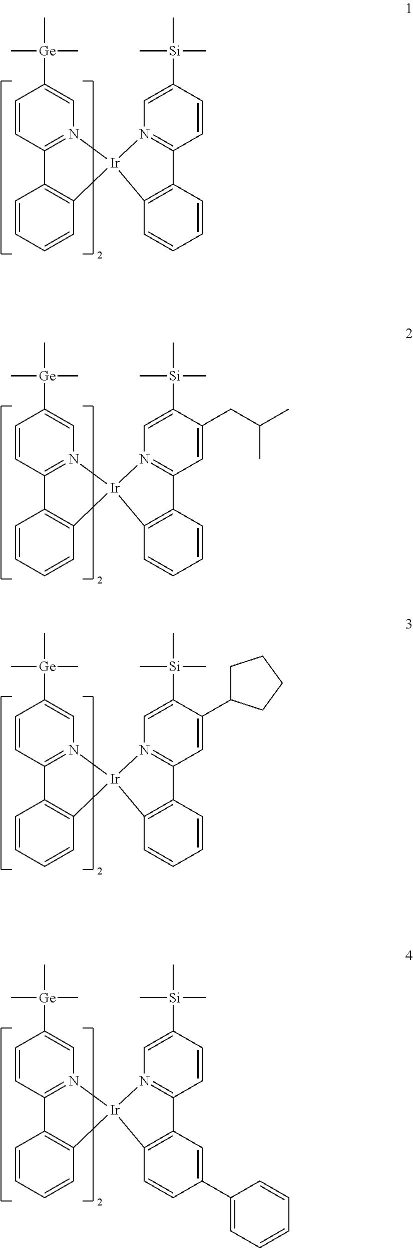

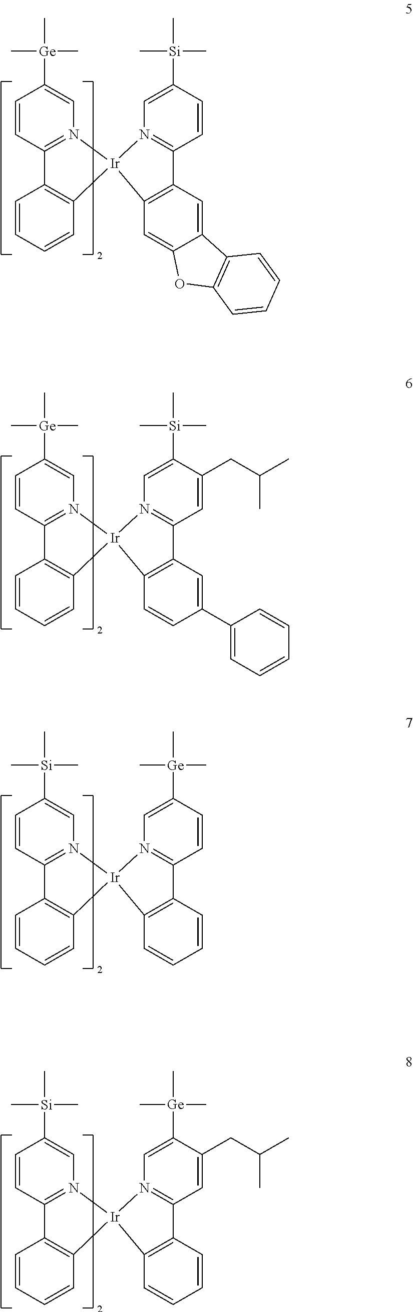

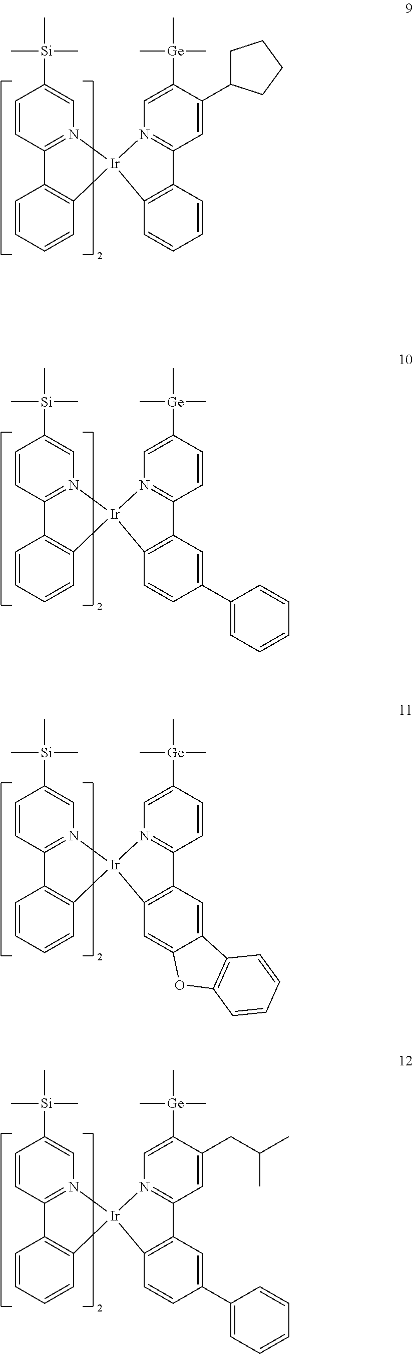

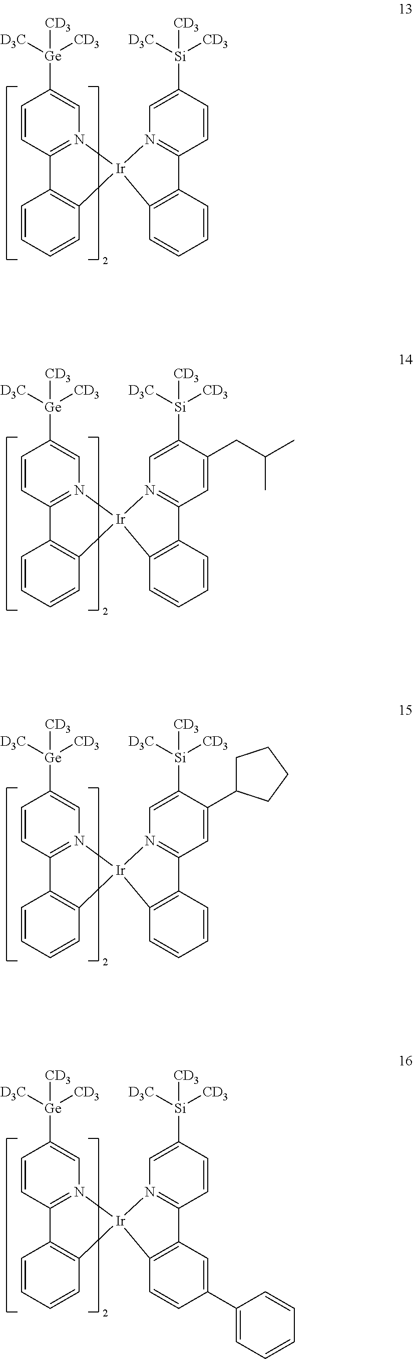

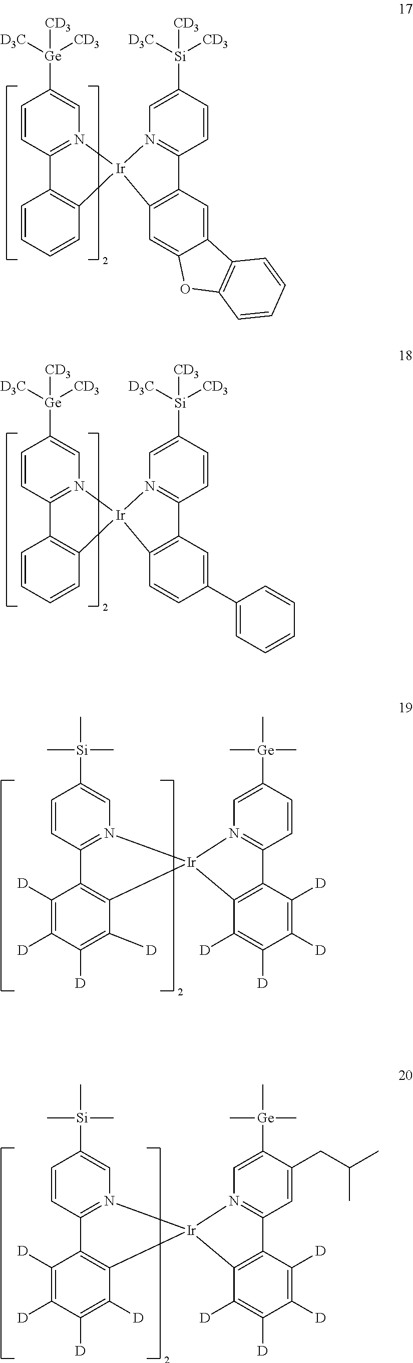

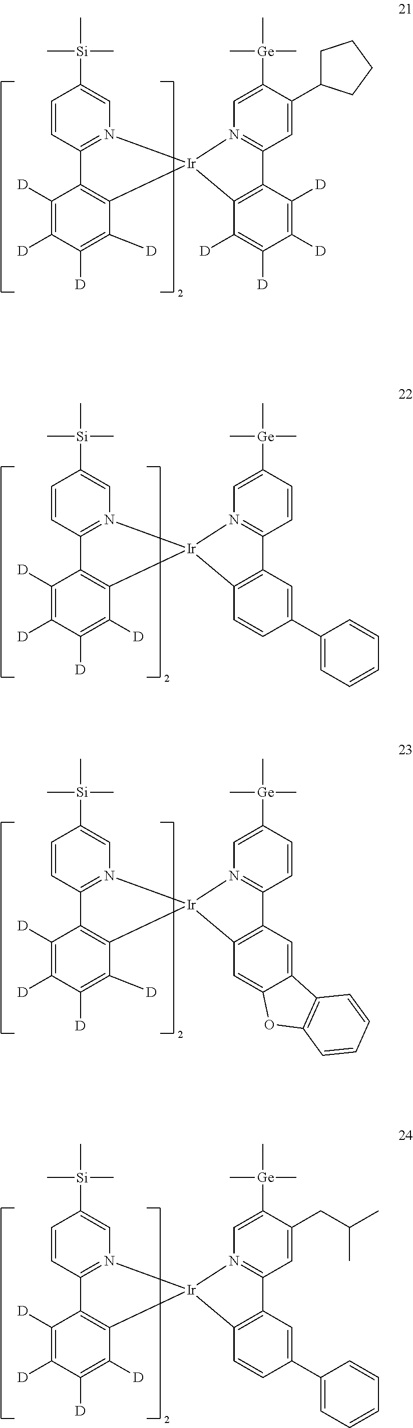

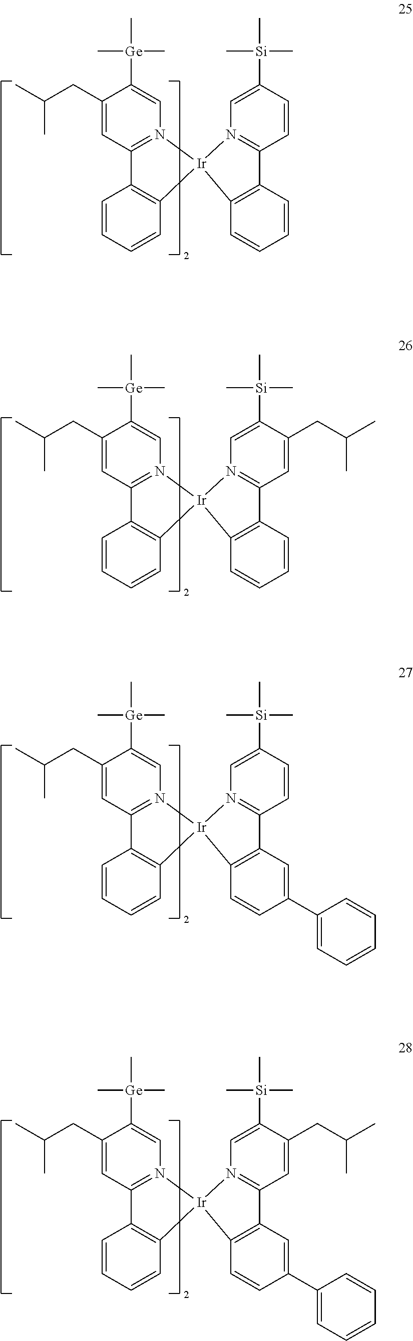

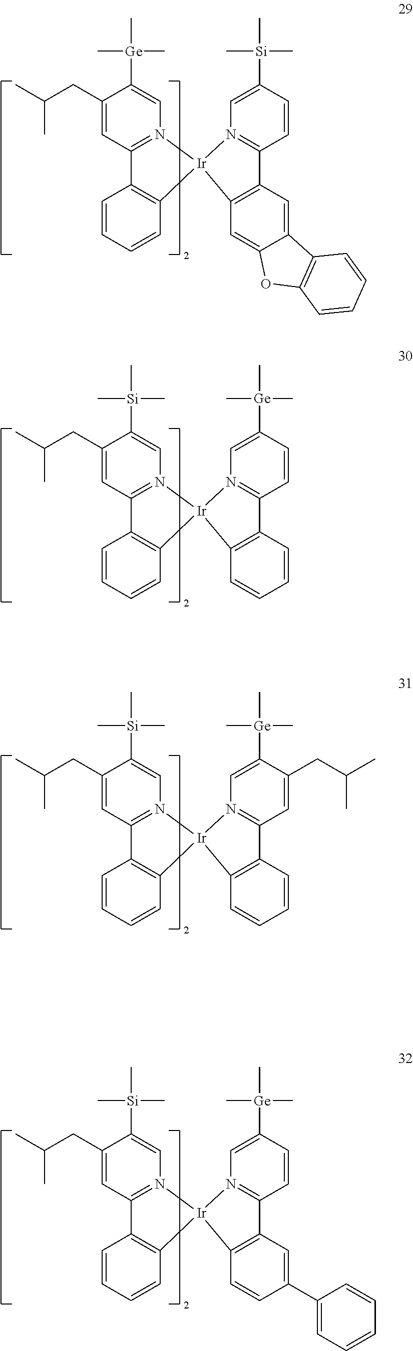

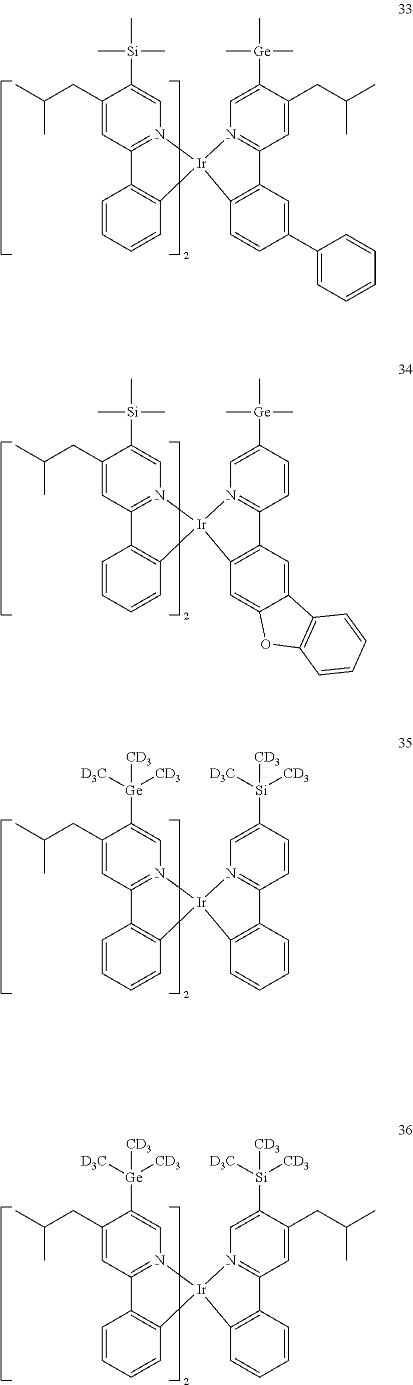

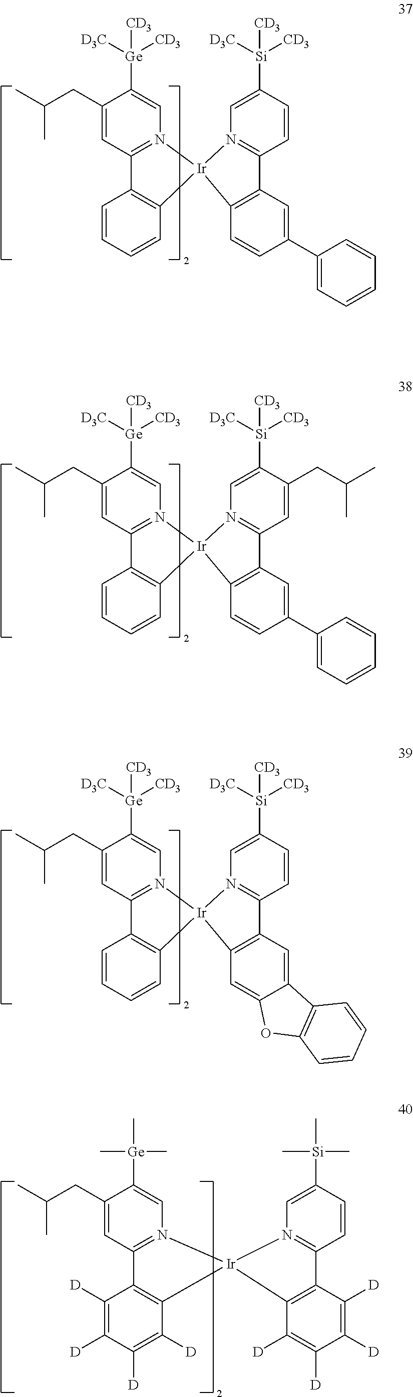

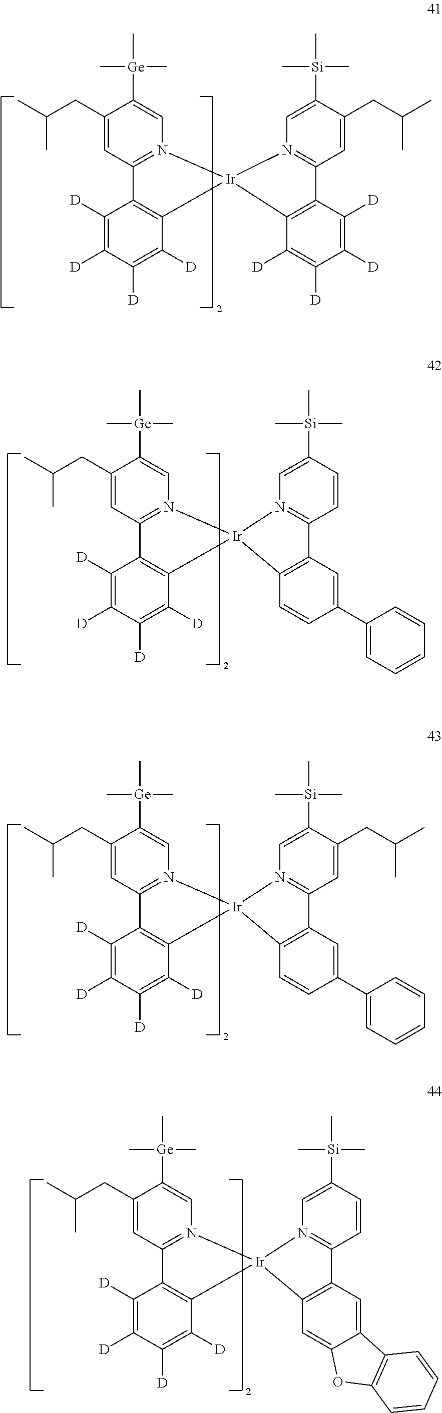

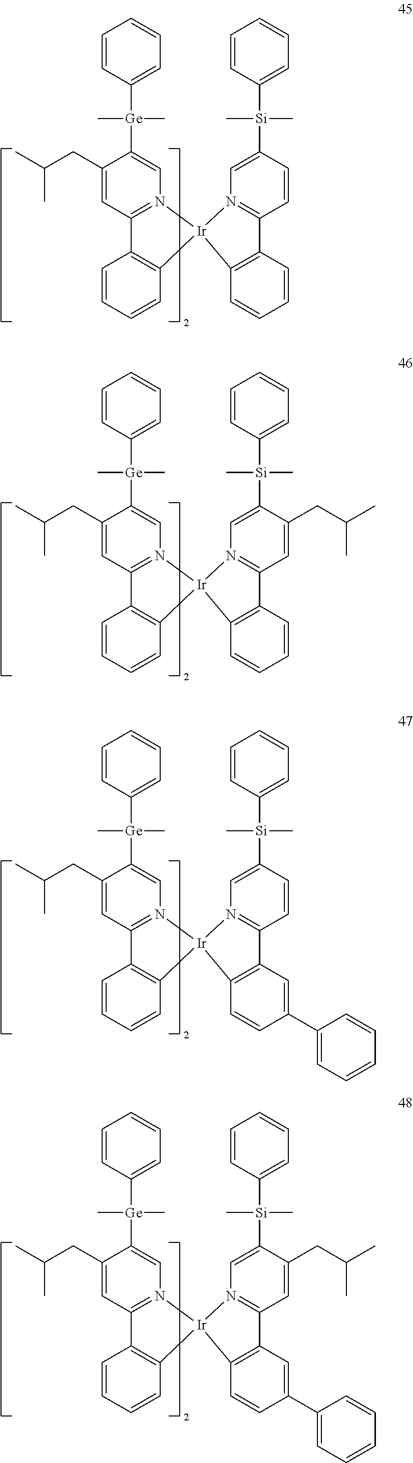

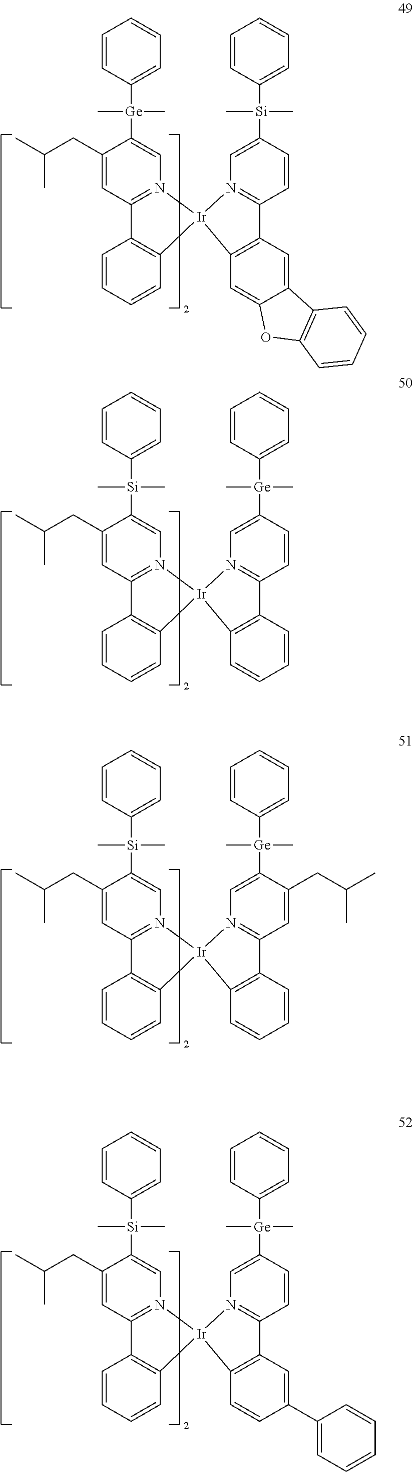

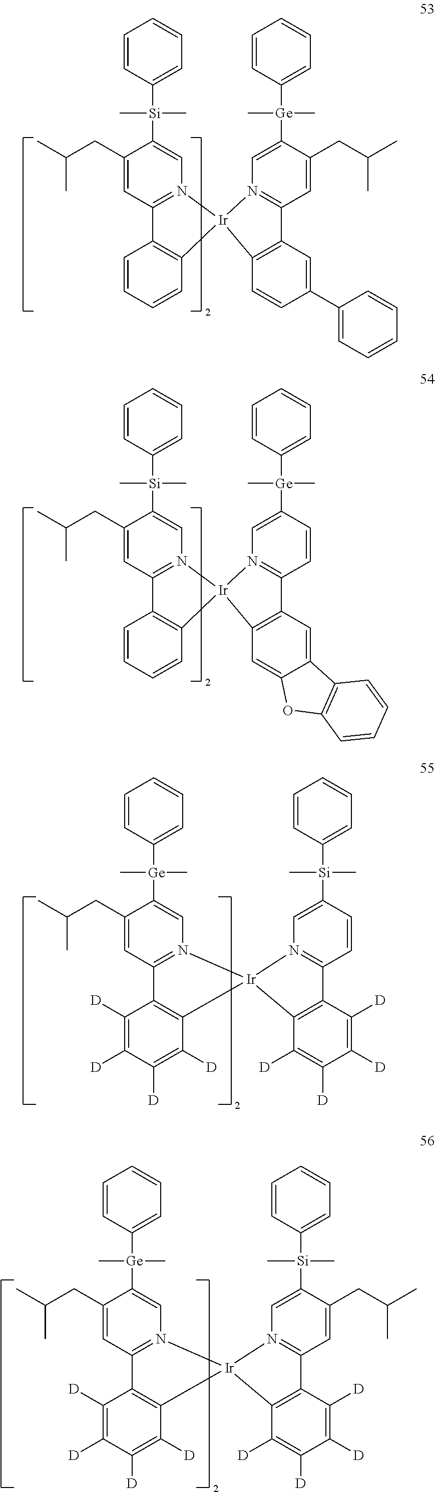

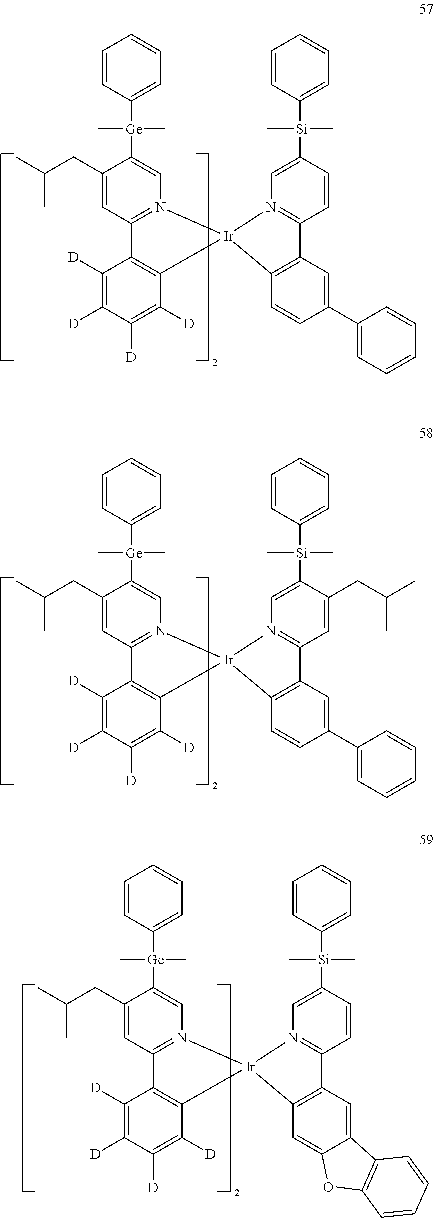

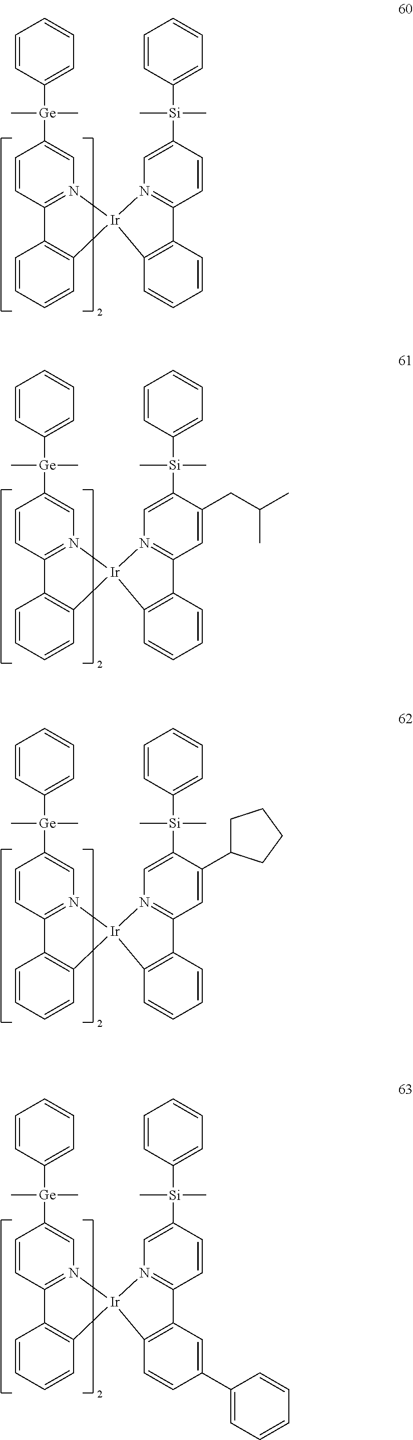

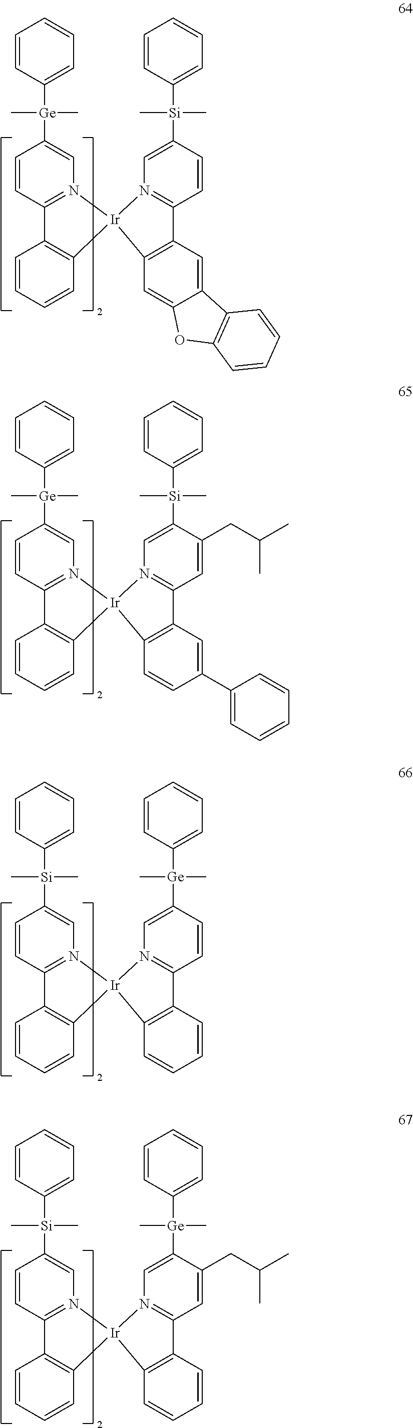

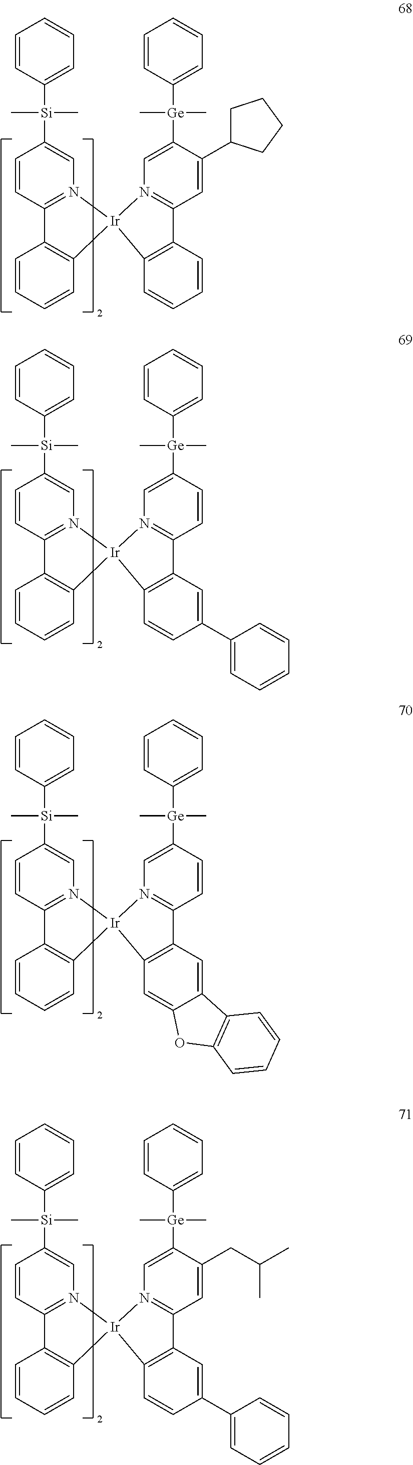

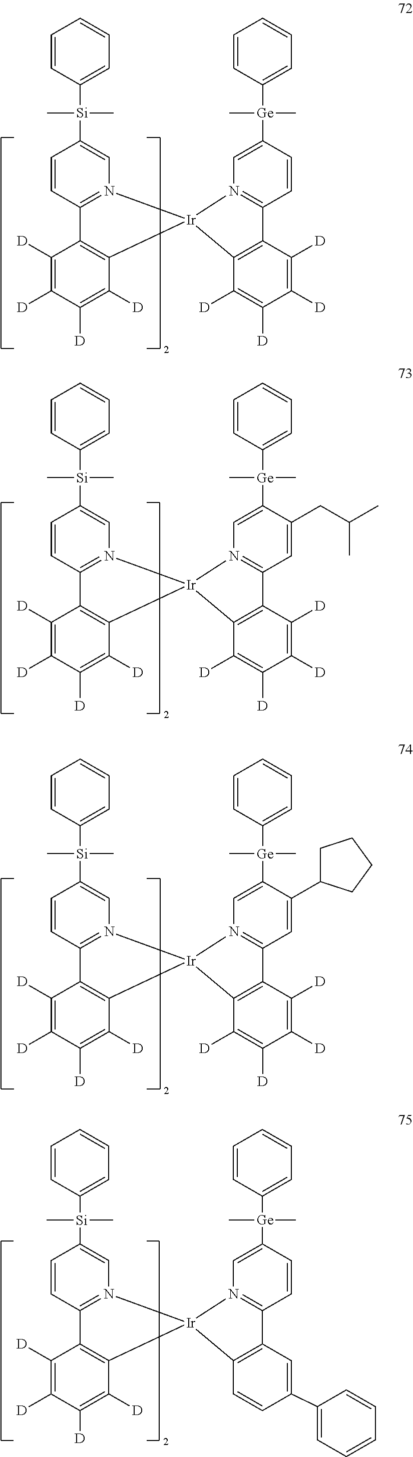

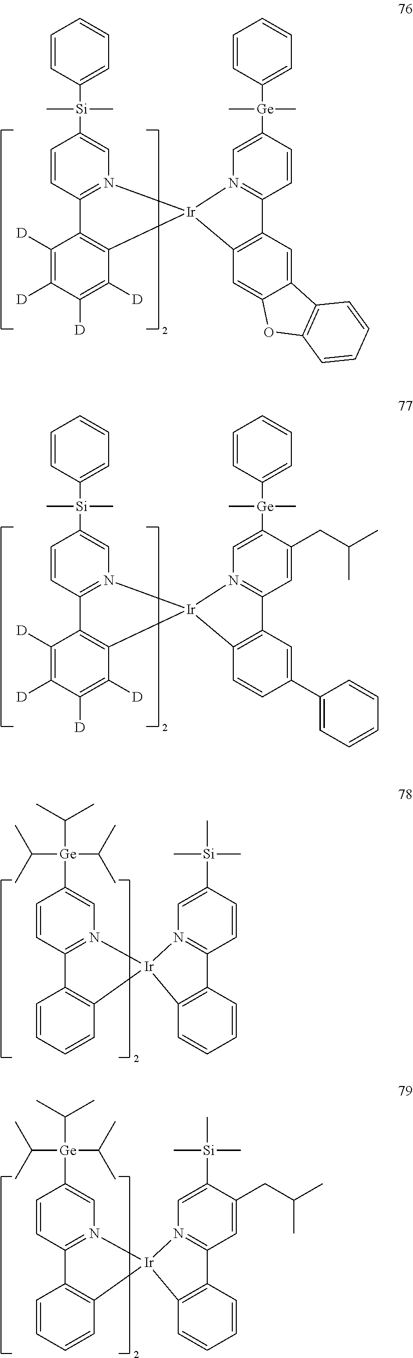

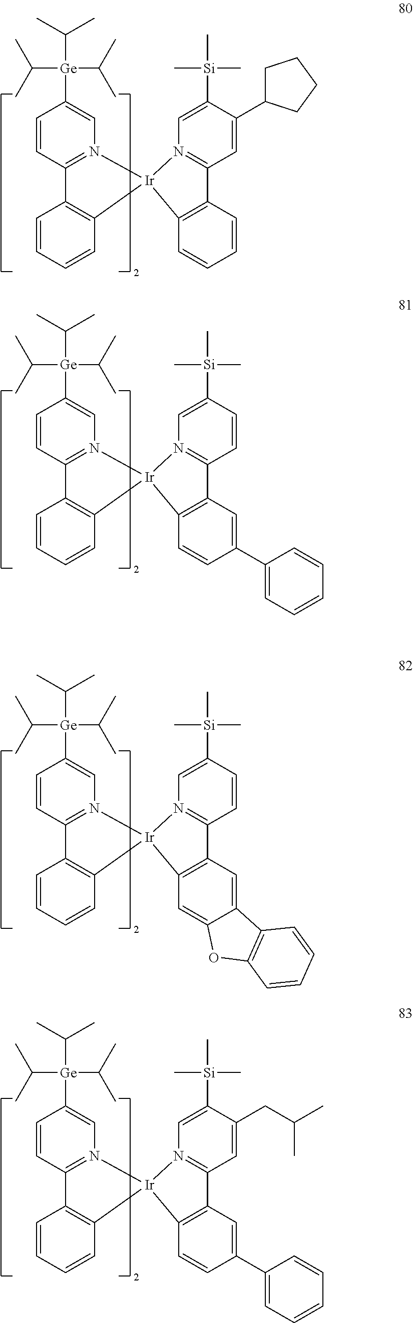

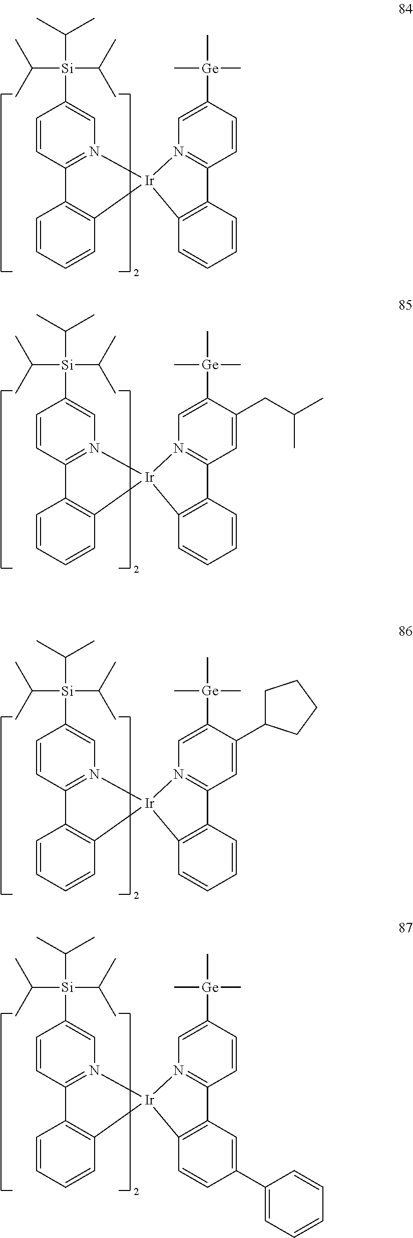

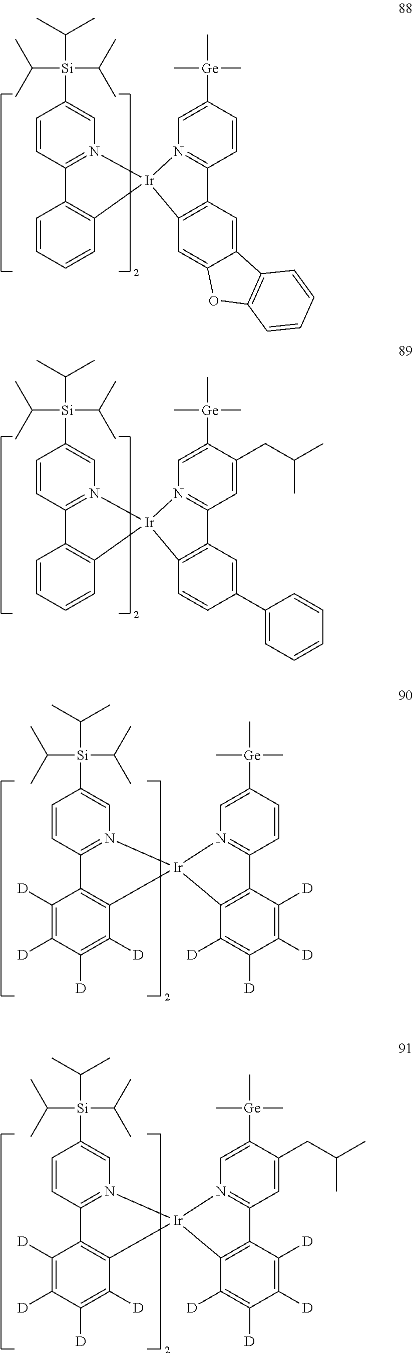

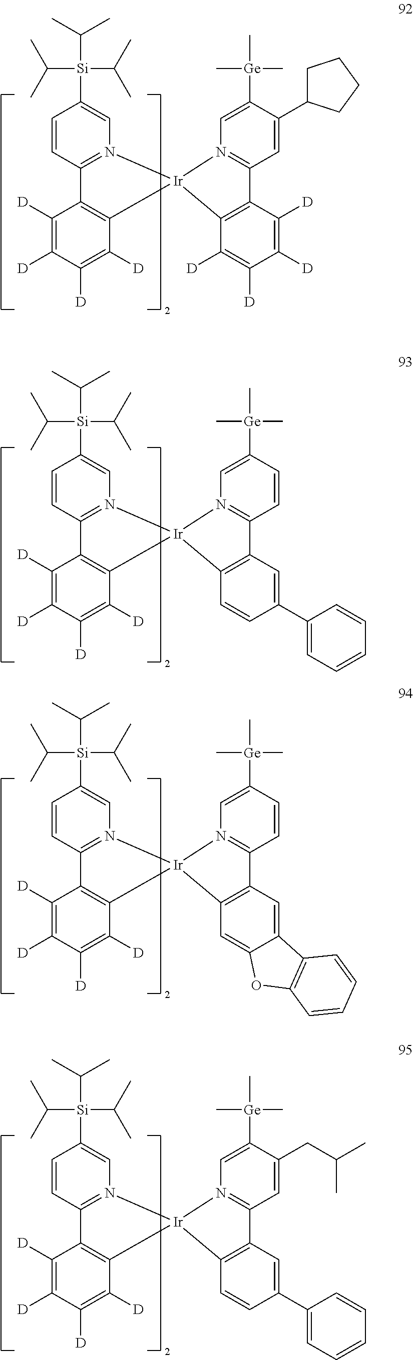

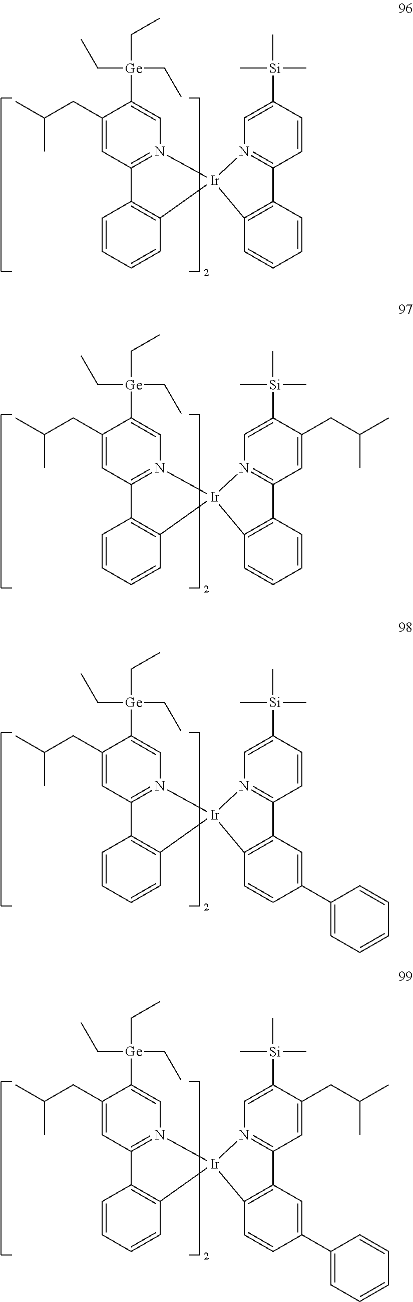

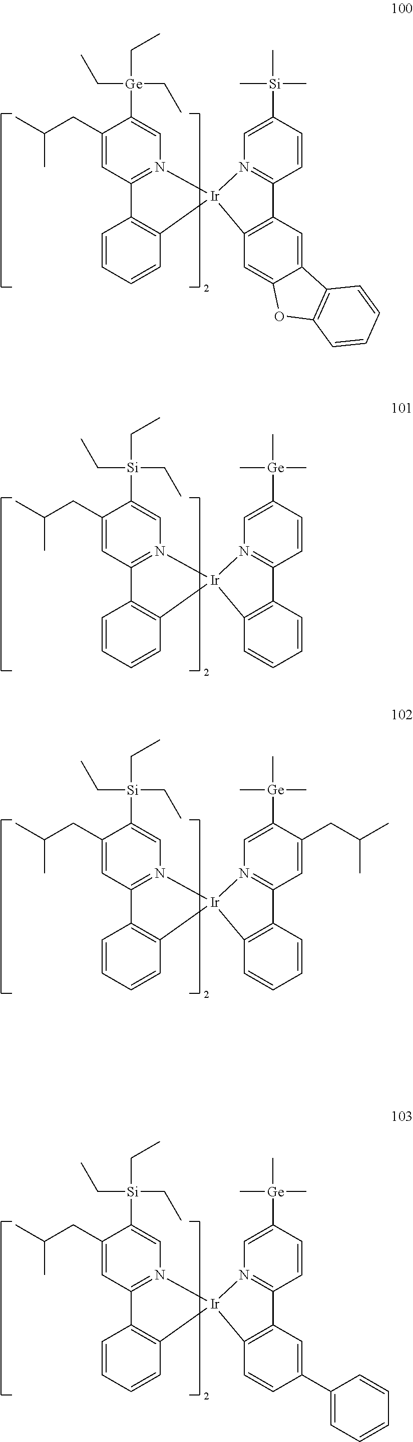

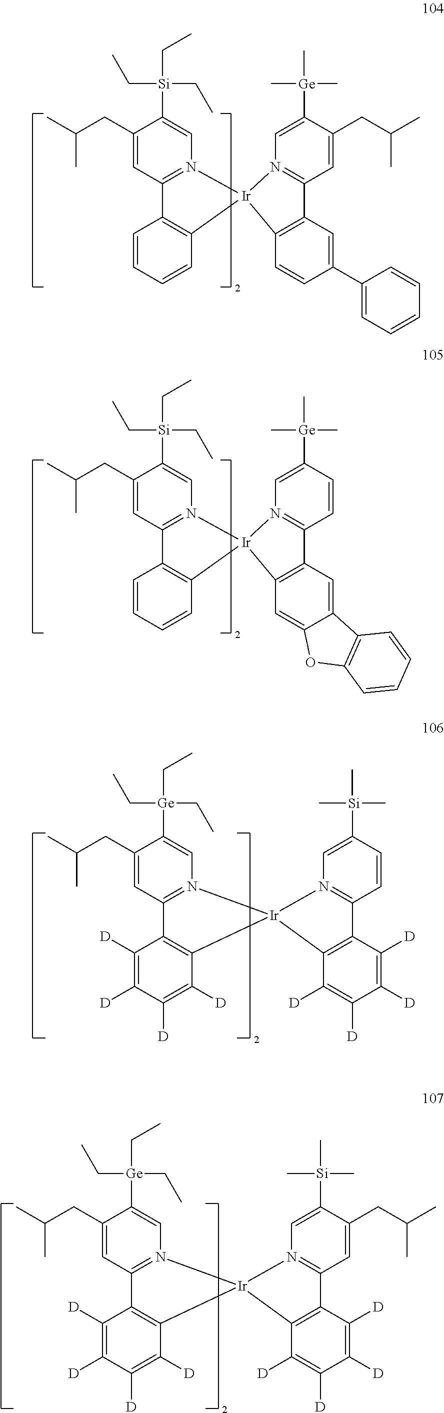

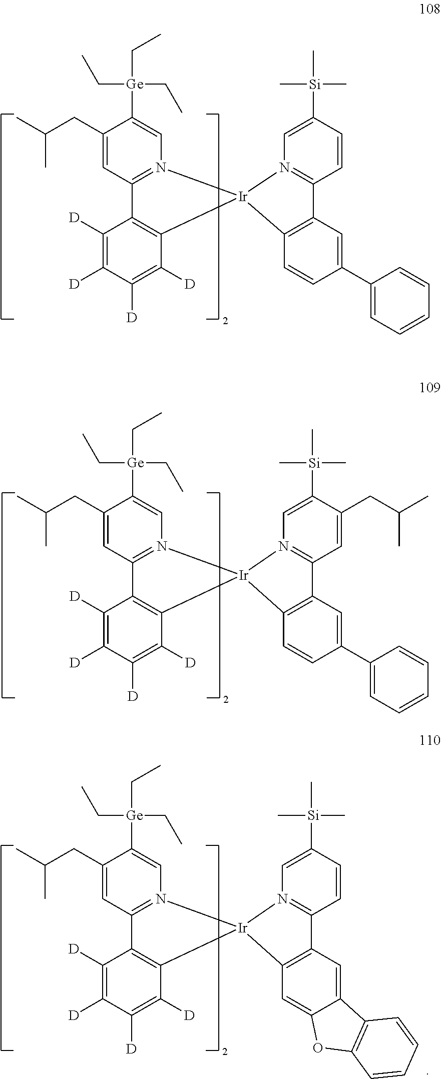

17. An organic light-emitting device, comprising:
a first electrode;
a second electrode; and
an organic layer disposed between the first electrode and the second electrode,
wherein the organic layer comprises an emission layer and at least one organometallic compound of claim 1.

18. The organic light-emitting device of claim 17, wherein
the first electrode is an anode,
the second electrode is a cathode, and
the organic layer comprises:
i) a hole transport region disposed between the first electrode and the emission layer, wherein the hole transport region comprises at least one selected from a hole injection layer, a hole transport layer, and an electron blocking layer, and
ii) an electron transport region disposed between the emission layer and the second electrode, wherein the electron transport region comprises at least one selected from a hole blocking layer, an electron transport layer, and an electron injection layer.

19. The organic light-emitting device of claim 17, wherein the emission layer comprises the organometallic compound.

20. The organic light-emitting device of claim 19, wherein the organometallic compound acts as a dopant, and wherein the emission layer further comprises a host.
